(19) United States
(12) Patent Application Publication
(10) Pub. No.: US 2026/0362746 A1
(43) Pub. Date: Nov. 12, 2026

(54) SEMICONDUCTOR DEVICE AND MEMORY DEVICE

(71) Applicant: SEMICONDUCTOR ENERGY LABORATORY CO., LTD., Atsugi-shi, Kanagawa-ken (JP)

(72) Inventors: Fumito ISAKA, Zama, Kanagawa (JP); Yuji EGI, Atsugi, Kanagawa (JP); Toshikazu OHNO, Atsugi, Kanagawa (JP); Naoki OKUNO, Yamato, Kanagawa (JP); Hironobu TAKAHASHI, Isehara, Kanagawa (JP); Hitoshi KUNITAKE, Machida, Tokyo (JP); Tetsuya KAKEHATA, Isehara, Kanagawa (JP)

(21) Appl. No.: 19/119,974

(22) PCT Filed: Oct. 16, 2023
(86) PCT No.: PCT/IB2023/060395

§ 371 Date: Apr. 10, 2025

(30) Foreign Application Priority Data
Oct. 21, 2022 (JP) 2022-168999
Oct. 28, 2022 (JP) 2022-173106

(51) Int. Cl. H10D 30/67; H10B 12/00; H10D 62/60

(52) U.S. Cl. CPC H10D 30/6755; H10B 12/33; H10D 30/6728; H10D 30/6731; H10D 30/6757; H10D 62/60; H10D 30/6734

(57) ABSTRACT

A semiconductor device that can be miniaturized or highly integrated is provided. An oxide semiconductor suitable for the semiconductor device is provided. The oxide semiconductor is formed to have a small difference in thickness between a portion provided along a first surface and a portion provided along a second surface inclined to the first surface. An oxide semiconductor film in which an aluminum concentration is higher than or equal to 0.01 atomic % and lower than or equal to 10 atomic % is formed by an ALD method using a precursor whose aluminum content is greater than or equal to 0.01 ppm and less than or equal to 500 ppm. Furthermore, crystallinity of the oxide semiconductor is increased by performing impurity removal treatment such as microwave treatment.

### TECHNICAL FIELD

One embodiment of the present invention relates to a film formation method of a metal oxide. Another embodiment of the present invention relates to a transistor using the metal oxide and a manufacturing method of the transistor. Another embodiment of the present invention relates to a semiconductor device using the metal oxide and a manufacturing method of the semiconductor device. Another embodiment of the present invention relates to a memory device using the metal oxide and a manufacturing method of the memory device.

Note that one embodiment of the present invention is not limited to the above technical field. Examples of the technical field of one embodiment of the present invention include a semiconductor device, a display device, a light-emitting device, a power storage device, a memory device, an electronic appliance, a lighting device, an input device (e.g., a touch sensor), an input/output device (e.g., a touch panel), a method for driving any of them, and a method for manufacturing any of them.

In this specification and the like, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display device, a light-emitting device, a lighting device, and an electronic appliance themselves are semiconductor devices and each of them includes a semiconductor device in some cases.

### BACKGROUND ART

In recent years, semiconductor devices have been developed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode serving as a connection terminal.

A semiconductor circuit (IC chip) of an LSI, a CPU, a memory, or the like is mounted on a circuit board, for example, a printed wiring board, to be used as one of components of a variety of electronic appliances.

A technique in which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a semiconductor material applicable to the transistor and further, an oxide semiconductor has been attracting attention as another material.

It is known that a transistor including an oxide semiconductor has an extremely low leakage current in a non-conduction state. For example, Patent Document 1 discloses a low-power-consumption CPU utilizing a feature of a low leakage current of the transistor including an oxide semiconductor. Furthermore, for example, Patent Document 2 discloses a memory device that can retain stored contents for a long time by utilizing a feature of a low leakage current of the transistor including an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film.

Furthermore, by employing vertical transistors, an integrated circuit with higher density can be achieved. For example, Patent Document 4 discloses a vertical transistor in which a side surface of an oxide semiconductor is covered with a gate electrode with a gate insulator therebetween.

For oxide semiconductors, a CAAC (c-axis aligned crystalline) structure and an ne (nanocrystalline) structure, which are neither a single crystal structure nor an amorphous structure, have been discovered (see Non-Patent Document 2 and Non-Patent Document 3).

Non-Patent Document 2 and Non-Patent Document 3 disclose a technique for forming a transistor with the use of an oxide semiconductor having the CAAC structure.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Documents

[Non-Patent Document 1] M. Oota et. al, “3D-Stacked CAAC—In—Ga—Zn Oxide FETs with Gate Length of 72 nm”, IEDM Tech. Dig., 2019, pp. 50-53
[Non-Patent Document 2] S. Yamazaki et al., “SID Symposium Digest of Technical Papers”, 2012, volume 43, issue 1, pp. 183-186.
[Non-Patent Document 3] S. Yamazaki et al., “Japanese Journal of Applied Physics”, 2014, volume 53, Number 4S, pp. 04ED18-1-04ED18-10.

### SUMMARY OF THE INVENTION

### Problems to be Solved by the Invention

An object of one embodiment of the present invention is to provide a novel metal oxide and a film formation method thereof. Another object of one embodiment of the present invention is to provide a transistor, a semiconductor device, or a memory device that can be miniaturized or highly integrated. Another object of one embodiment of the present invention is to provide a transistor, a semiconductor device, or a memory device with high reliability. Another object of one embodiment of the present invention is to provide a transistor with a high on-state current. Another object of one embodiment of the present invention is to provide a transistor with favorable electrical characteristics. Another object of one embodiment of the present invention is to provide a semiconductor device or a memory device with reduced power consumption. Another object of one embodiment of the present invention is to provide a memory device that operates at high speed. Another object of one embodiment of the present invention is to provide a method for manufacturing any of the above transistor, semiconductor device, or memory device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including an oxide semiconductor, a first conductor, a second conductor, a third conductor, and a first insulator; the first conductor and the second conductor each include a portion in contact with the oxide semiconductor; the third conductor overlaps with the oxide semiconductor with the first insulator therebetween; the oxide semiconductor includes a first portion provided along a first surface and a second portion provided along a second surface inclined to the first surface; a ratio of a thickness of the second portion to a thickness of the first portion is greater than or equal to 0.8 and less than or equal to 1.2; the oxide semiconductor includes indium and one or more selected from gallium, tin, and zinc; and an aluminum concentration in the oxide semiconductor is higher than or equal to 0.01 atomic % and lower than or equal to 10 atomic %.

Another embodiment of the present invention is a semiconductor device including an oxide semiconductor, a first conductor, a second conductor, a third conductor, a first insulator, and a second insulator; the first insulator is in contact with a top surface of the first conductor; the second conductor is positioned over the first insulator; the oxide semiconductor includes a first portion in contact with the top surface of the first conductor, a second portion in contact with a side surface of the first insulator, and a third portion in contact with the second conductor; the second insulator is positioned over the oxide semiconductor; the third conductor is positioned over the second insulator and overlaps with the oxide semiconductor with the second insulator therebetween; a ratio of a thickness of the second portion to a thickness of the first portion is greater than or equal to 0.8 and less than or equal to 1.2; the oxide semiconductor includes indium and one or more selected from gallium, tin, and zinc; and an aluminum concentration in the oxide semiconductor is higher than or equal to 0.01 atomic % and lower than or equal to 10 atomic %.

Another embodiment of the present invention is a semiconductor device including an oxide semiconductor, a first conductor, a second conductor, a third conductor, a first insulator, and a second insulator; the first insulator is in contact with a top surface of the first conductor; the second conductor is positioned over the first insulator; the first insulator and the second conductor include a first opening portion reaching the first conductor; the oxide semiconductor includes a first portion in contact with the top surface of the first conductor and a second portion in contact with a side surface of the first insulator and includes a third portion in contact with the second conductor inside the first opening portion; the second insulator is positioned over the oxide semiconductor; the third conductor is positioned over the second insulator and overlaps with the oxide semiconductor with the second insulator therebetween, in a position overlapping with the first opening portion; a ratio of a thickness of the second portion to a thickness of the first portion is greater than or equal to 0.8 and less than or equal to 1.2; the oxide semiconductor includes indium and one or more selected from gallium, tin, and zinc; and an aluminum concentration in the oxide semiconductor is higher than or equal to 0.01 atomic % and lower than or equal to 10 atomic %.

An aluminum concentration in the oxide semiconductor is preferably higher than or equal to 0.01 atomic % and lower than or equal to 5 atomic %.

A carbon concentration in the oxide semiconductor is preferably higher than or equal to 1×10¹⁷ atoms/cm³ and lower than or equal to 5×10¹⁹ atoms/cm³.

Another embodiment of the present invention is a memory device including the above semiconductor device, a fourth conductor, a third insulator, and a capacitor; the capacitor includes a fifth conductor, a fourth insulator over the fifth conductor, and the first conductor over the fourth insulator; a second opening portion reaching the fourth conductor is provided in the third insulator; and at least part of the fifth conductor, at least part of the fourth insulator, and at least part of the first conductor are placed in the second opening portion.

Another embodiment of the present invention is a method for forming a film of a metal oxide including a first step of supplying a first compound containing indium into a chamber and then supplying an oxidizer into the chamber and a second step of supplying a second compound into the chamber and then supplying the oxidizer into the chamber. In the method, an aluminum content in the first compound is greater than or equal to 0.01 ppm and less than or equal to 500 ppm, an aluminum content in the second compound is less than the aluminum content in the first compound, and the second compound contains gallium, tin, or zinc.

Another embodiment of the present invention is a method for forming a film of a metal oxide including a first step of supplying a first compound containing indium into a chamber and then supplying an oxidizer into the chamber and a second step of supplying a second compound into the chamber and then supplying the oxidizer into the chamber. In the method, an aluminum content in the first compound is greater than or equal to 0.01 ppm and less than or equal to 500 ppm, an aluminum content in the second compound is less than the aluminum content in the first compound, and a sum of time for supplying the oxidizer in the first step and time for supplying the oxidizer in the second step is longer than or equal to 90 seconds.

The second compound preferably contains gallium or zinc.

It is preferable that each of the first step and the second step be performed one or more times and then microwave treatment be performed in an atmosphere containing oxygen.

It is preferable that as a first cycle, each of the first step and the second step be performed one or more times and then microwave treatment be performed in an atmosphere containing oxygen, and the first cycle be repeated a plurality of times.

Another embodiment of the present invention is a semiconductor device including a first insulator, an oxide semiconductor covering the first insulator, a first conductor and a second conductor over the oxide semiconductor, a second insulator placed over the first conductor and the second conductor and including an opening overlapping with a region between the first conductor and the second conductor, a third insulator placed in the opening and placed over the oxide semiconductor, and a third conductor placed in the opening and placed over the third insulator; in a cross-sectional view in a channel width direction, a height of the first insulator is longer than a width of the first insulator; the oxide semiconductor includes a first portion provided along a first surface and a second portion provided along a second surface inclined to the first surface; a ratio of a thickness of the second portion to a thickness of the first portion is greater than or equal to 0.8 and less than or equal to 1.2; the oxide semiconductor contains indium and one or more selected from gallium, tin, and zinc; and an aluminum concentration in the oxide semiconductor is higher than or equal to 0.01 atomic % and lower than or equal to 10 atomic %. An aluminum concentration in the oxide semiconductor is further preferably higher than or equal to 0.01 atomic % and lower than or equal to 5 atomic %. A carbon concentration in the oxide semiconductor is preferably higher than or equal to 1×10¹⁷ atoms/cm³ and lower than or equal to 5×10¹⁹ atoms/cm³.

In a plan view, a side surface of an opening in the second insulator is preferably aligned or substantially aligned with a side surface of the first conductor and a side surface of the second conductor.

The first conductor preferably functions as one of a source electrode and a drain electrode of a transistor. The second conductor preferably functions as the other of the source electrode and the drain electrode of the transistor. The third conductor preferably functions as a gate electrode of the transistor.

In a cross-sectional view in a channel width direction of the transistor, it is preferable that on one side surface of the first insulator, the oxide semiconductor and the third conductor face each other with the third insulator therebetween and on the other side surface of the first insulator, the oxide semiconductor and the third conductor face each other with the third insulator therebetween.

In a cross-sectional view in a channel width direction of the transistor, it is preferable that the first conductor be in contact with the oxide semiconductor on one side surface side and the other side surface side of the first insulator and the second conductor be in contact with the oxide semiconductor on one side surface side and the other side surface side of the first insulator.

In a cross-sectional view in a channel width direction of the transistor, the height of the first insulator is preferably greater than or equal to 2 times and less than or equal to 20 times the width of the first insulator.

Another embodiment of the present invention is a memory device including the above semiconductor device and a capacitor, and one electrode of the capacitor is electrically connected to the first conductor of the semiconductor device. The capacitor is preferably placed over the third conductor. At least part of the capacitor preferably overlaps with the oxide semiconductor and the third conductor.

### Effect of the Invention

One embodiment of the present invention can provide a novel metal oxide and a film formation method thereof. Another embodiment of the present invention can provide a transistor, a semiconductor device, or a memory device that can be miniaturized or highly integrated. Another embodiment of the present invention can provide a transistor, a semiconductor device, or a memory device with high reliability. Another embodiment of the present invention can provide a transistor with a high on-state current. Another embodiment of the present invention can provide a transistor with favorable electrical characteristics. Another embodiment of the present invention can provide a semiconductor device or a memory device with reduced power consumption. Another embodiment of the present invention can provide a memory device that operates at high speed. Another embodiment of the present invention can provide a method for manufacturing any of the above transistor, semiconductor device, or memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A to FIG. 1E are cross-sectional views illustrating an example of a film formation method of a metal oxide.

FIG. 2A to FIG. 2D are cross-sectional views illustrating examples of metal oxides.

FIG. 3A to FIG. 3D are cross-sectional views illustrating examples of metal oxides.

FIG. 4A to FIG. 4C are diagrams illustrating examples of atomic ratio ranges of metal oxides.

FIG. 5A to FIG. 5D are cross-sectional views illustrating an example of a film formation method of a metal oxide.

FIG. 6A to FIG. 6C are cross-sectional views illustrating an example of a film formation method of a metal oxide.

FIG. 7 is a plan view and a cross-sectional view illustrating an example of a deposition apparatus.

FIG. 8A and FIG. 8B are cross-sectional views illustrating an example of a deposition apparatus.

FIG. 9A to FIG. 9C are cross-sectional views each illustrating an example of a deposition apparatus.

FIG. 10A and FIG. 10B are cross-sectional views illustrating an example of a deposition apparatus.

FIG. 11A and FIG. 11B are diagrams each illustrating an example of a film formation method of a metal oxide.

FIG. 12A and FIG. 12B are diagrams each illustrating an example of a film formation method of a metal oxide.

FIG. 13 is a diagram illustrating an example of a film formation method of a metal oxide.

FIG. 14A to FIG. 14D are cross-sectional views illustrating examples of a memory device.

FIG. 15A is a plan view illustrating an example of a memory device. FIG. 15B and FIG. 15C are cross-sectional views illustrating an example of the memory device. FIG. 15D is a circuit diagram illustrating an example of the memory device.

FIG. 16A and FIG. 16B are cross-sectional views illustrating an example of a memory device.

FIG. 17A to FIG. 17D are cross-sectional views illustrating examples of a memory device.

FIG. 18A and FIG. 18B are cross-sectional views illustrating an example of a memory device.

FIG. 19A to FIG. 19D are cross-sectional views illustrating examples of a memory device.

FIG. 20A and FIG. 20B are cross-sectional views illustrating an example of a memory device.

FIG. 21A is a plan view illustrating an example of a semiconductor device. FIG. 21B to FIG. 21D are cross-sectional views illustrating an example of the semiconductor device.

FIG. 22A and FIG. 22B are cross-sectional views illustrating an example of a semiconductor device.

FIG. 23A is a plan view illustrating an example of a semiconductor device. FIG. 23B to FIG. 23D are cross-sectional views each illustrating an example of the semiconductor device.

FIG. 24A and FIG. 24B are cross-sectional views each illustrating an example of a semiconductor device.

FIG. 25A to FIG. 25C are cross-sectional views each illustrating an example of a semiconductor device.

FIG. 26A and FIG. 26C are plan views illustrating examples of a memory device. FIG. 26B and FIG. 26D are cross-sectional views illustrating examples of the memory device.

FIG. 27A is a plan view illustrating an example of a memory device. FIG. 27B is a cross-sectional view illustrating an example of the memory device.

FIG. 28A is a plan view illustrating an example of a memory device. FIG. 28B is a cross-sectional view illustrating an example of the memory device.

FIG. 29A is a plan view illustrating an example of a memory device. FIG. 29B is a cross-sectional view illustrating an example of the memory device.

FIG. 30A to FIG. 30C are planar layouts illustrating examples of a memory device.

FIG. 31A to FIG. 31C are planar layouts illustrating examples of a memory device.

FIG. 32 is a cross-sectional view illustrating an example of a memory device.

FIG. 33 is a block diagram illustrating an example of a memory device.

FIG. 34A and FIG. 34B are schematic views illustrating an example of a memory device.

FIG. 35A to FIG. 35D are circuit diagrams illustrating an example of a memory device.

FIG. 36 is a circuit diagram illustrating an example of a memory device.

FIG. 37A and FIG. 37B are diagrams illustrating examples of electronic components.

FIG. 38A and FIG. 38B are diagrams each illustrating an example of an electronic appliance. FIG. 38C to FIG. 38E are diagrams illustrating an example of a large computer.

FIG. 39 is a diagram illustrating an example of a device for space.

FIG. 40 is a diagram illustrating an example of a storage system that can be used in a data center.

FIG. 41 shows an XPS analysis result in Example 1.

FIG. 42A and FIG. 42B each show Hall effect measurement results in Example 1.

FIG. 43 shows SIMS analysis results in Example 1.

FIG. 44 shows SIMS analysis results in Example 1.

FIG. 45 shows SIMS analysis results in Example 1.

FIG. 46A and FIG. 46B each show SIMS analysis results in Example 1.

FIG. 47 shows SIMS analysis results in Example 1.

FIG. 48 shows I_{d}−V_{g} characteristics of a transistor in Example 1.

FIG. 49A to FIG. 49D are each a cross-sectional observation image of an IGZO film in Example 1.

FIG. 50A to FIG. 50D each show SIMS analysis results in Example 2.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

In this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

A transistor is a kind of semiconductor element and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification.

In this specification and the like, a transistor is an element having at least three terminals including a gate, a drain, and a source. In addition, the transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

Functions of a “source” and a “drain” are sometimes replaced with each other when a transistor of opposite polarity is used or when the direction of current is changed in circuit operation, for example. Therefore, the terms “source” and “drain” can be switched in this specification.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. In addition, oxygen vacancies (also referred to as V_{O}) are formed in an oxide semiconductor in some cases by entry of impurities, for example.

In this specification and the like, an oxynitride refers to a material that contains more oxygen than nitrogen in its composition. A nitride oxide refers to a material that contains more nitrogen than oxygen in its composition.

The contents of elements such as hydrogen, oxygen, carbon, and nitrogen in a film can be analyzed by secondary ion mass spectrometry (SIMS) or X-ray photoelectron spectroscopy (XPS), for example. When the content percentage of a target element is high (e.g., higher than or equal to 0.5 atomic %, or higher than or equal to 1 atomic %), XPS is suitable. By contrast, when the content percentage of a target element is low (e.g., lower than or equal to 0.5 atomic %, or lower than or equal to 1 atomic %), SIMS is suitable. To compare the contents of elements, analysis with a combination of SIMS and XPS is preferably used.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode and a wiring.

Unless otherwise specified, off-state current in this specification and the like refers to leakage current between a source and a drain of a transistor in an off state (also referred to as a non-conduction state or a cutoff state). Unless otherwise specified, an off state refers to, in an n-channel transistor, a state where a voltage V_{gs} between its gate and source is lower than a threshold voltage Vₜₕ (in a p-channel transistor, higher than Vₜₕ).

In this specification and the like, a top surface shape of a component means the contour shape of the component in a plan view. A plan view means that the component is observed from a normal direction of a surface where the component is formed or from a normal direction of a surface of a support (e.g., a substrate) where the component is formed.

In this specification and the like, the tapered shape refers to a shape such that at least part of a side surface of a component is inclined to a substrate surface or a formation surface. For example, a tapered shape preferably includes a region where the angle between the inclined side surface and the substrate surface or the formation surface (such an angle is also referred to as a taper angle) is less than 90°. Note that the side surface, the substrate surface, and the formation surface of the component are not necessarily completely flat and may be substantially flat with a slight curvature or substantially flat with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

### Embodiment 1

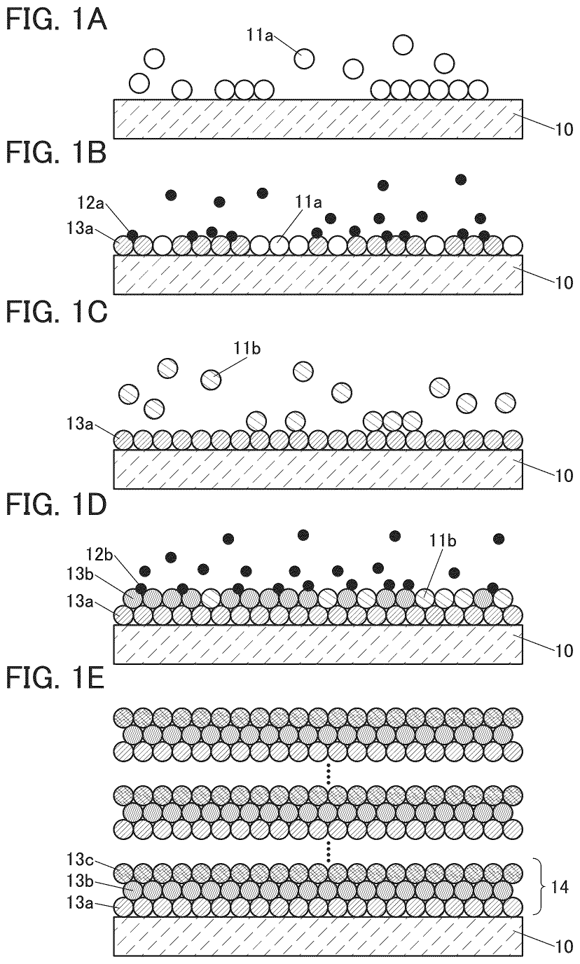

In this embodiment, a metal oxide of one embodiment of the present invention and a film formation method thereof will be described with reference to FIG. 1 to FIG. 13.

A metal oxide of one embodiment of the present invention can be used as any of a semiconductor material, an insulating material, and a conductive material depending on the kind, combination, composition, and the like of elements constituting the metal oxide. The metal oxide of one embodiment of the present invention can be used for a semiconductor layer of a transistor, for example. The metal oxide is referred to as an oxide semiconductor or an oxide in some cases.

A film formation method of a metal oxide which is one embodiment of the present invention employs an ALD (Atomic Layer Deposition) method, and thus enables formation of a film with a uniform and extremely small thickness. The method is therefore suitable for film formation of a metal oxide included in a miniaturized transistor.

In the film formation method of a metal oxide which is one embodiment of the present invention, one or both of an inorganic precursor and an organic precursor can be used. An organic precursor is a precursor containing carbon as its constituent element, and an inorganic precursor is a precursor not containing carbon as its constituent element.

A metal oxide film formed using an inorganic precursor can have a lower impurity concentration (e.g., at least one of a hydrogen concentration, a carbon concentration, and a nitrogen concentration) in the film than a metal oxide film formed using an organic precursor.

The film formation temperature of a metal oxide in the case of using an organic precursor can be lower than that in the case of using an inorganic precursor.

Here, when a metal oxide film is formed using a precursor containing impurities, the impurities enter the metal oxide, which might adversely affect the physical property of the metal oxide as well as the characteristics of a semiconductor device using the metal oxide.

For example, a large amount of aluminum, which is an impurity, contained in a metal oxide that does not contain aluminum as its main component might affect the physical property of the metal oxide. Here, examples of the metal oxide that does not contain aluminum as its main component include indium zinc oxide (In—Zn oxide) and indium gallium zinc oxide (In—Ga—Zn oxide, also referred to as IGZO).

For example, when aluminum in an oxidized state (Al₂O₃ or the like) exists in an IGZO film, the resistance of the IGZO film is increased. The use of the high-resistance IGZO film as a semiconductor layer lowers the on-state current of a transistor.

Meanwhile, aluminum has a high bond dissociation energy with oxygen and functions as a carrier-inhibiting element. Specifically, the bond dissociation energy between aluminum and oxygen is higher than the bond dissociation energy between Ga and oxygen. Thus, when aluminum exists in an IGZO film, oxygen vacancies (V_{O}) are less likely to be generated. When the IGZO film in which V_{O} is less likely to be generated is used as the semiconductor layer, negative-bias photodegradation of the transistor can be inhibited. Accordingly, aluminum in the metal oxide is not necessarily completely removed and may be contained in the metal oxide to the extent that aluminum does not adversely affect the metal oxide.

In view of this, in the film formation method of the metal oxide of one embodiment of the present invention, a metal oxide that does not contain aluminum as its main component is formed using a precursor having a small aluminum content. This can inhibit an increase in the concentration of aluminum in the deposited metal oxide.

In the case of a metal oxide film formed by an ALD method, even heat treatment after formation of the metal oxide film cannot completely remove impurities in some cases. Meanwhile, performing high-temperature treatment at a temperature as high as the highest temperature during the manufacturing process of a transistor or a semiconductor device (e.g., a temperature exceeding 700 °C) for forming a metal oxide film with a low impurity content results in decreased productivity.

Thus, in the film formation method of the metal oxide of one embodiment of the present invention, sufficient supply of an oxidizer reduces the carbon concentration in the film. For example, the total time of steps for supplying an oxidizer in the whole film formation process of the metal oxide is sufficiently long. Alternatively, the proportion of ozone (O₃) contained in the oxidizer is increased.

As impurity removal treatment, microwave treatment is preferably performed in an oxygen-containing atmosphere after film formation. Performing the microwave treatment in an oxygen-containing atmosphere can remove impurities in the film. This can inhibit an impurity contained in a raw material such as a precursor from remaining in the metal oxide. Accordingly, the impurity concentration in the metal oxide can be reduced. Furthermore, the crystallinity of the metal oxide can be increased.

The impurity removal treatment in an atmosphere containing oxygen is preferably performed intermittently during film formation. By performing the impurity removal treatment during film formation, impurities can be removed more certainly than the case of performing the impurity removal treatment after film formation. The impurity removal treatment may be performed in both during film formation and after film formation.

As described above, by the film formation method of a metal oxide which is one embodiment of the present invention, a metal oxide with few impurities used for a semiconductor layer of a miniaturized transistor can be formed. In addition, by the film formation method of a metal oxide which is one embodiment of the present invention, a metal oxide with high crystallinity used for a semiconductor layer of a miniaturized transistor can be formed. Accordingly, a miniaturized transistor with favorable electrical characteristics can be achieved. Furthermore, a miniaturized transistor with favorable reliability can be achieved. In particular, a metal oxide having a CAAC structure is preferably formed.

Specifically, one embodiment of the present invention is a film formation method of a metal oxide including a first step where a first compound containing indium is supplied to a chamber and then an oxidizer is supplied to the chamber, and a second step where a second compound is supplied to the chamber and then the oxidizer is supplied to the chamber. The film formation method may further include a third step where a third compound is supplied to the chamber and then the oxidizer is supplied to the chamber.

The aluminum content of the first compound is preferably greater than or equal to 0.001 ppm, greater than or equal to 0.01 ppm, or greater than or equal to 0.1 ppm, and preferably less than or equal to 1000 ppm, further preferably less than or equal to 500 ppm, still further preferably less than or equal to 100 ppm, yet still further preferably less than or equal to 50 ppm, yet still further preferably less than or equal to 10 ppm, yet still further preferably less than or equal to 1 ppm.

The second compound and the third compound each preferably contain at least one of gallium, tin, and zinc. The preferable range of the aluminum content of the second compound and the preferable range of the aluminum content of the third compound are each similar to the preferable range of the aluminum content of the first compound. In particular, the second compound and the third compound each preferably have a lower aluminum content than the first compound.

In the film formation process of the metal oxide, the total time for supplying an oxidizer in one cycle is preferably longer than or equal to 10 seconds, further preferably longer than or equal to 30 seconds, still further preferably longer than or equal to 60 seconds, yet still further preferably longer than or equal to 90 seconds, yet still further preferably longer than or equal to 120 seconds, and preferably shorter than or equal to 150 seconds, shorter than or equal to 200 seconds, shorter than or equal to 250 seconds, or shorter than or equal to 300 seconds. In the case where the metal oxide film is formed using both the first compound and the second compound, performing each of the first step and the second step once is regarded as one cycle. The total time for supplying the oxidizer in one cycle corresponds to the sum of time for supplying the oxidizer in the first step and time for supplying the oxidizer in the second step. In the case where the metal oxide film is formed using the three compounds, that is, the third compound in addition to the first and second compounds, performing each of the first step, the second step, and the third step once is regarded as one cycle. The total time for supplying the oxidizer in one cycle corresponds to the sum of times for supplying the oxidizers in the first to third steps.

The time for supplying the oxidizer is preferably longer, in which case the carbon concentration in the metal oxide can be lower. Meanwhile, the time for supplying the oxidizer is preferably shorter, in which case the time required for forming the metal oxide film is shorter.

In supplying the oxidizer, the proportion of ozone in the gas is preferably higher than or equal to 10%, further preferably higher than or equal to 20%, still further preferably higher than or equal to 30%, yet still further preferably higher than or equal to 40%, yet still further preferably higher than or equal to 50%, yet still further preferably higher than or equal to 60%, yet still further preferably higher than or equal to 70%, yet still further preferably higher than or equal to 80%, yet still further preferably higher than or equal to 90%, particularly preferably 100%. It is preferable that the proportion of ozone be higher because oxidation of the metal can be promoted and the carbon concentration in the metal oxide can be reduced.

In supplying the oxidizer, the substrate temperature is preferably higher than or equal to 150 °C, higher than or equal to 200 °C, or higher than or equal to 250 °C. As the upper limit of the substrate temperature, the lower one between the decomposition temperature of a precursor such as the first compound and the decomposition temperature of ozone (e.g., 300 °C) can be employed. The substrate temperature is preferably increased, in which case the impurity concentration in the metal oxide can be reduced.

In the film formation method of a metal oxide which is one embodiment of the present invention, it is preferable that each of the first step and the second step be performed one or more times, and then impurity removal treatment be performed in an atmosphere containing oxygen. By the impurity removal treatment, impurities contained in the metal oxide are released from the film. By the impurity removal treatment, hydrogen, carbon, nitrogen, and the like contained in the metal oxide are preferably released from the film. In addition, oxygen is preferably supplied to the metal oxide by the impurity removal treatment. In this case, the amount of oxygen vacancies (V_{O}) and impurities in the metal oxide can be reduced. The use of a metal oxide with a reduced amount of oxygen vacancies (V_{O}) and impurities can improve the electrical characteristics and reliability of a transistor.

Examples of the impurity removal treatment include plasma treatment, microwave treatment, and heat treatment.

When plasma treatment or microwave treatment is performed, the substrate temperature is preferably higher than or equal to room temperature (e.g., 25 °C), higher than or equal to 100 °C, higher than or equal to 200 °C, higher than or equal to 300 °C, or higher than or equal to 400 °C, and lower than or equal to 500 °C or lower than or equal to 450 °C. The heat treatment temperature is preferably higher than or equal to 100 °C, higher than or equal to 200 °C, higher than or equal to 300 °C, or higher than or equal to 400 °C, and lower than or equal to 500 °C or lower than or equal to 450 °C.

The temperature of the impurity removal treatment is particularly preferably set lower than or equal to the maximum temperature in the manufacturing process of a transistor or a semiconductor device, in which case the impurity content in the metal oxide can be reduced without decrease in productivity. For example, when the maximum temperature in manufacturing a transistor or a semiconductor device including the metal oxide of one embodiment of the present invention is lower than or equal to 500 °C, preferably lower than or equal to 450 °C, the productivity of the transistor or the semiconductor device can be improved.

In addition, the impurity removal treatment is preferably performed at a temperature lower than the decomposition temperatures of the first compound and the second compound. In the case where the third compound is used, the impurity removal treatment is preferably performed at a temperature lower than the decomposition temperature of the third compound. In addition, the impurity removal treatment may be performed at a temperature higher than 500 °C (e.g., higher than 500 °C and lower than or equal to 700 °C).

The impurity removal treatment may be performed while irradiation with light (e.g., ultraviolet light) is performed. This can promote release of impurities. Examples of a light source include a laser and a mercury lamp. For example, an oxygen radical is generated by photoexcitation to react with hydrogen, carbon, nitrogen, or the like, so that impurities in a film can be reduced and crystallization can be promoted. In some cases, impurities are removed even at a low heating temperature more easily in the case where light irradiation is performed than in the case where light irradiation is not performed.

In addition, light irradiation may be performed during film formation. For example, while the first compound is supplied to the chamber and/or while the oxidizer is supplied to the chamber in the first step, the formation surface of the metal oxide may be irradiated with light. The same applies to the second step and the third step.

Performing each of the first step and the second step one or more times and then performing the impurity removal treatment in an atmosphere containing oxygen are regarded as a first cycle, and the first cycle is preferably repeated a plurality of times.

Alternatively, performing each of the first step and the second step one or more times and then performing the impurity removal treatment in an atmosphere containing oxygen are regarded as the first cycle, and performing each of the first step and the second step one or more times in the order different from that of the first cycle and then performing the impurity removal treatment in an atmosphere containing oxygen are regarded as a second cycle. It is preferable that the first cycle and the second cycle be performed alternately a plurality of times.

In each of the first cycle and the second cycle, the impurity removal treatment is preferably performed every time the first step or the second step that is less frequent or both of the first step and the second step are performed more than or equal to 5 times and less than or equal to 10 times.

Impurities cannot be sufficiently removed only by performing the impurity removal treatment after film formation of the metal oxide. When the impurity removal treatment is performed intermittently (with an interval) during film formation, the impurities in the metal oxide can be removed sufficiently.

One embodiment of the present invention is a film formation method of an indium compound by an ALD method, in which a precursor containing indium (e.g., a triethylindium precursor) is supplied to a chamber and then an oxidizer is supplied to the chamber. The aluminum content of the precursor is preferably greater than or equal to 0.001 ppm, greater than or equal to 0.01 ppm, or greater than or equal to 0.1 ppm, and preferably less than or equal to 1000 ppm, further preferably less than or equal to 500 ppm, still further preferably less than or equal to 100 ppm, yet still further preferably less than or equal to 50 ppm, yet still further preferably less than or equal to 10 ppm, yet still further preferably less than or equal to 1 ppm.

### <Metal Oxide>

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor might lead to unstable electrical characteristics of the transistor. Hence, a metal oxide used in a semiconductor layer of a transistor preferably has a small number of lattice defects.

A transistor using a metal oxide is likely to change its electrical characteristics especially in the case where oxygen vacancies (V_{O}) and impurities exist in a region of the metal oxide where a channel is formed, which might degrade the reliability. In some cases, a defect that is an oxygen vacancy into which hydrogen in the vicinity of the oxygen vacancy has entered (hereinafter sometimes referred to as V_{O}H) is formed, which generates an electron serving as a carrier. Therefore, when the channel formation region in the metal oxide includes oxygen vacancies, the transistor is likely to have normally-on characteristics (characteristics with which, even when no voltage is applied to the gate electrode, the channel exists and current flows through the transistor). Therefore, oxygen vacancies and impurities are preferably reduced as much as possible in the channel formation region in the metal oxide. In other words, it is preferable that the region of the metal oxide where a channel is formed have a reduced carrier concentration and be of an i-type (intrinsic) or substantially i-type.

The kind of a lattice defect that is likely to exist in a metal oxide and the number of lattice defects that exist vary depending on the structure of the metal oxide, a film formation method of the metal oxide, or the like.

The structure of a metal oxide is classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure.

Note that there is no particular limitation on the crystallinity of the metal oxide of one embodiment of the present invention.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, for the semiconductor layer of the transistor, a metal oxide including a crystal part is preferably used and a metal oxide with high crystallinity is further preferably used. For example, it is preferable to use the metal oxide having the CAAC structure or the metal oxide having the single crystal structure. The use of the metal oxide for a transistor enables a transistor having favorable electrical characteristics. In addition, a transistor with high reliability can be achieved.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS (a c-axis aligned crystalline oxide semiconductor).

The c-axis of the above crystal is preferably aligned in the normal direction with respect to the formation surface or film surface of the metal oxide. This enables the plurality of layers to be placed parallel to or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is located at the center. The second layer has a coordination geometry of atoms that has a trigonal bipyramidal or tetrahedral structure of oxygen in which a metal included in the second layer is located at the center. The third layer has a coordination geometry of atoms that has a trigonal bipyramidal or tetrahedral structure of oxygen in which a metal included in the third layer is located at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element of a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

The metal oxide of one embodiment of the present invention preferably contains at least indium or zinc. In particular, indium and zinc are preferably contained. In addition to them, at least one metal element with the same valence as indium or zinc is preferably contained. Examples of the metal element include gallium and tin. Furthermore, one or more kinds selected from yttrium, boron, titanium, iron, nickel, germanium, zirconium, molybdenum, lanthanum, cerium, neodymium, hafnium, tantalum, tungsten, magnesium, calcium, cobalt, aluminum, and the like may be contained.

Here, the case where the metal oxide is an In-M-Zn oxide that contains indium (In), an element M, and zinc (Zn) is considered. The element M is gallium or tin. Examples of other elements that can be used as the element M include yttrium, boron, titanium, iron, nickel, germanium, zirconium, molybdenum, lanthanum, cerium, neodymium, hafnium, tantalum, tungsten, magnesium, calcium, cobalt, and aluminum. Note that a combination of two or more of the above elements may be used as the element M.

Examples of the metal oxide of one embodiment of the present invention include indium zinc oxide (In—Zn oxide), indium tin oxide (In—Sn oxide), indium titanium oxide (In—Ti oxide), indium gallium oxide (In—Ga oxide), indium gallium tin oxide (In—Ga—Sn oxide), gallium zinc oxide (also referred to as Ga—Zn oxide or GZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO).

When the proportion of the number of indium atoms in the total number of atoms of all the metal elements contained in the metal oxide is increased, the field-effect mobility of the transistor can be increased.

Note that the metal oxide may contain, instead to indium, one or more kinds of metal elements with large period numbers in the periodic table of the elements. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements included in the metal oxide, a high on-state current and excellent frequency characteristics of the transistor can be achieved.

In the description of this embodiment, In—Ga—Zn oxide is sometimes taken as an example of the metal oxide.

For the formation of a metal oxide having the layered crystal structure, an atomic layer is preferably deposited one by one. Since an ALD method is employed as the film formation method of a metal oxide in one embodiment of the present invention, a metal oxide having the layered crystal structure is easily formed.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as deposition of an extremely thin film, deposition on a component with a high aspect ratio, deposition of a film having few defects such as pinholes, deposition with excellent coverage, and low-temperature deposition. The use of plasma in a PEALD method is sometimes preferable because it enables deposition at a lower temperature. Note that a precursor used in an ALD method sometimes contains an element such as carbon or chlorine. Thus, in some cases, a film provided by an ALD method contains a larger amount of an element such as carbon or chlorine than a film provided by another film formation method. Note that these elements can be quantified by XPS or SIMS. The film formation method of a metal oxide of one embodiment of the present invention, which employs an ALD method and one or both of a film formation condition with a high substrate temperature and impurity removal treatment, can sometimes form a film with smaller amounts of carbon and chlorine than a method employing an ALD method without the film formation condition with a high substrate temperature or the impurity removal treatment.

Unlike a deposition method in which particles ejected from a target or the like are deposited, an ALD method is a deposition method in which a film is formed by reaction at a surface of an object. Thus, the ALD method is a deposition method that enables favorable step coverage almost regardless of the shape of an object to be processed. In particular, an ALD method enables excellent step coverage and excellent thickness uniformity and thus is suitable for covering a surface of an opening portion with a high aspect ratio, for example. However, the ALD method has a relatively low deposition rate, and thus is preferably used in combination with another deposition method with a high deposition rate, such as a sputtering method or a CVD method, in some cases. For example, a method in which a sputtering method is used to deposit a first metal oxide, and an ALD method is used to deposit a second metal oxide over the first metal oxide can be given. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film in which the composition is continuously changed can be deposited. In the case where the film is formed while the source gas is changed, as compared to the case where the film is formed using a plurality of deposition chambers, the time taken for the deposition can be shortened because the time taken for transfer and pressure adjustment is omitted. Thus, the productivity of the semiconductor device can be increased in some cases.

### <Transistor Including Metal Oxide>

Next, the case where a metal oxide (oxide semiconductor) is used for a transistor will be described. Hereinafter, a transistor using an oxide semiconductor in the semiconductor layer is sometimes referred to as an OS transistor, and a transistor using silicon in the semiconductor layer is sometimes referred to as a Si transistor.

When a metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length greater than or equal to 2 nm and less than or equal to 30 nm can be fabricated.

An oxide semiconductor having a low carrier concentration is preferably used for a channel formation region of a transistor. For example, the carrier concentration of the channel formation region of the oxide semiconductor is preferably lower than or equal to 1×10¹⁸ cm⁻³, lower than or equal to 1×10¹⁷ cm³, lower than or equal to 1×10¹⁶ cm³, lower than 1×10¹⁵ cm 3, lower than or equal to 1×10¹⁴ cm³, lower than or equal to 1×10¹³ cm³, lower than or equal to 1×10¹² cm⁻³, lower than or equal to 1×10¹¹ cm³, or lower than or equal to 1×10¹⁰ cm³. The lower limit of the carrier concentration of the channel formation region is not particularly limited and can be, for example, 1× 10⁻⁹ cm⁻³.

In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, it is preferable that the impurity concentration in an adjacent film be also reduced. Examples of the impurity include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can inhibit the short-channel effect. In other words, the OS transistor is a transistor where the short-channel effect does not appear or the short-channel effect hardly appears.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as an S value), and an increase in leakage current. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor, and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure where the channel formation region is an n⁻-type region and the source region and the drain region are n⁺-type regions. The OS transistor with the above structure can have favorable electrical characteristics even when a semiconductor device is miniaturized or highly integrated. For example, the semiconductor device can have favorable electrical characteristics even when the OS transistor has a channel length or gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm due to appearance of the short-channel effect. Thus, an OS transistor can be used as a transistor with a short channel length more suitably than a Si transistor. Note that the gate length refers to the length of a gate electrode in a direction in which carriers move inside a channel formation region during an operation of the transistor.

Miniaturization of an OS transistor can improve the high frequency characteristics of the transistor. Specifically, the cutoff frequency of the transistor can be increased. When the gate length of the OS transistor is within any of the above ranges, the cutoff frequency of the transistor can be greater than or equal to 50 GHz, preferably greater than or equal to 100 GHz, further preferably greater than or equal to 150 GHz at room temperature, for example.

### <Impurity in Metal Oxide>

Here, the influence of each impurity in the metal oxide (oxide semiconductor) will be described.

As described above, when a large amount of aluminum is contained unintentionally in the oxide semiconductor, the physical properties of the oxide semiconductor might be affected. For example, when aluminum in an oxidized state (Al₂O₃ or the like) exists, the resistance of the oxide semiconductor is increased. The use of the high-resistance oxide semiconductor for the channel formation region of the transistor lowers the on-state current of the transistor.

Meanwhile, aluminum has a high bond dissociation energy with oxygen and functions as a carrier-inhibiting element. When aluminum exists in the oxide semiconductor, oxygen vacancies (V_{O}) are less likely to be generated. When the oxide semiconductor in which V_{O} is less likely to be generated is used for the channel formation region of the transistor, negative-bias photodegradation of the transistor can be inhibited.

Thus, the aluminum concentration in the oxide semiconductor is preferably low so that both favorable reliability and favorable electrical characteristics of the transistor can be achieved. Alternatively, the aluminum concentration is preferably extremely low so that the on-state current of the transistor is sufficiently high.

For example, the aluminum concentration in the channel formation region of the oxide semiconductor, which is obtained by STEM-EDX, is preferably higher than or equal to 0.01 atomic % and preferably lower than or equal to 10 atomic %, further preferably lower than or equal to 5 atomic %, still further preferably lower than or equal to 3 atomic %, yet still further preferably lower than or equal to 1 atomic %, yet still further preferably lower than or equal to 0.1 atomic %. Alternatively, the aluminum concentration may be lower than or equal to 0.01 atomic %.

The aluminum concentration in the channel formation region of the oxide semiconductor, which is obtained by SIMS, is preferably lower than or equal to 1×10²² atoms/cm³, further preferably lower than or equal to 1×10²¹ atoms/cm³, still further preferably lower than or equal to 1×10²⁰ atoms/cm³, yet still further preferably lower than or equal to 5×10¹⁹ atoms/cm³, yet still further preferably lower than or equal to 1×10¹⁹ atoms/cm³, yet still further preferably lower than or equal to 5×10¹⁸ atoms/cm³, yet still further preferably lower than or equal to 1×10¹⁸ atoms/cm³.

It is known that it is difficult to accurately obtain data in the vicinity of a surface of a sample and in the vicinity of an interface between films formed using different materials by the SIMS analysis in principle. In view of this, when the concentration of a certain element in a film is analyzed by SIMS, the average value in a region in which the values do not extremely vary and are substantially constant is employed as the element concentration. Furthermore, when the thickness of a film to be measured is small, a region where substantially constant values can be obtained cannot be found in some cases due to the influence of the element in an adjacent film. In this case, the maximum value or the minimum value of the element concentration can be employed as the element concentration in the film. Furthermore, in the case where a peak indicating a maximum value and a valley indicating a minimum value do not exist, the value of the inflection point can be employed as the element concentration.

Note that an Al 2p spectrum obtained by subjecting the oxide semiconductor to XPS analysis can show the existence of aluminum, and furthermore, the state of the existing aluminum. For example, in the case where the peak position is found in the range of 74.2 eV to 74.8 eV, it can be said that aluminum exists in an oxidized state.

When silicon or carbon, which is one of Group 14 elements, is contained in the oxide semiconductor, defect states are formed in the oxide semiconductor. Thus, the carbon concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³. The silicon concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when nitrogen is contained in the oxide semiconductor, trap states are sometimes formed. This might make the electrical characteristics of the transistor unstable. Therefore, the nitrogen concentration in the channel formation region in the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet still further preferably lower than or equal to 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is obtained by SIMS, is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, stable electrical characteristics can be given.

### <Film Formation Method 1>

Next, the film formation method of a metal oxide which is one embodiment of the present invention will be described. Hereinafter, a film formation method of a metal oxide with a deposition apparatus employing an ALD method (hereinafter, also referred to as an ALD apparatus) will be described.

In a deposition apparatus employing an ALD method, deposition is performed in such a manner that a first source gas (also referred to as a precursor or a metal precursor in some cases) and a second source gas (also referred to as a reactant, an oxidizer, or a nonmetallic precursor in some cases) are alternately introduced into a chamber for reaction, and then the introduction of these source gases is repeated. Note that the source gases to be introduced can be switched by switching the respective switching valves (also referred to as high-speed valves in some cases), for example. When the source gases are introduced, an inert gas such as nitrogen (N₂), argon (Ar), or helium (He) may be introduced as a carrier gas with the source gases into the chamber. With the use of a carrier gas, the source gases can be inhibited from being adsorbed onto an inner side of a pipe and an inner side of a valve and can be introduced into the chamber, even in the case where the volatility of the source gases is low or the vapor pressure is low. Moreover, uniformity of the formed film is improved, which is preferable.

An example of a method employing an ALD method for depositing a metal oxide having the layered crystal structure including three layers, which is one embodiment of the present invention, is described with reference to FIG. 1A to FIG. 1E.

First, as a first step, as illustrated in FIG. 1A, a precursor 11a is introduced into a chamber so that the precursor 11a is adsorbed onto a surface of a substrate 10.

Here, as illustrated in FIG. 1A, the precursor 11a is adsorbed onto the surface of the substrate 10, whereby a self-limiting mechanism of surface chemical reaction works and no more precursor 11a is adsorbed onto a layer of the precursor 11a over the substrate 10. Note that the proper range of substrate temperatures at which the self-limiting mechanism of surface chemical reaction works is also referred to as an ALD Window. The ALD Window is determined by the temperature characteristics, vapor pressure, decomposition temperature, and the like of a precursor.

Next, as a second step, an inert gas (e.g., argon, helium, or nitrogen) or the like is introduced into the chamber, so that excess precursors 11a, a reaction product, and the like are released from the chamber. The second step is also called purge.

Instead of introduction of an inert gas into the chamber, vacuum evacuation may be performed to release surplus precursors, a reaction product, and the like from the chamber in the second step. In this specification and the like, vacuum evacuation means evacuation under a pressure at least lower than an atmospheric pressure (in a reduced-pressure state).

Next, as a third step, as illustrated in FIG. 1B, a reactant 12a (e.g., an oxidizer) is introduced into the chamber to react with the precursor 11a adsorbed onto the surface of the substrate 10, whereby part of components contained in the precursor 11a is released while a metal element constituting the precursor 11a are kept adsorbed onto the substrate 10. Thus, a layer of an oxide 13a, which is formed by oxidation of part of the precursor 11a, is formed on the surface of the substrate 10.

Examples of an oxidizer include ozone (O₃), oxygen (O₂), water (H₂O), dinitrogen monoxide (N₂O), and hydrogen peroxide (H₂O₂), and plasma, a radical, and an ion thereof.

In the case where a plasma ALD method is employed, oxygen may be constantly supplied as an oxidizer and plasma may be generated in the third step. Accordingly, in the third step, oxygen plasma is formed and serves as the reactant 12a. In this case, the precursor 11a that does not react with oxygen that has been heated to the above temperature is used in a step other than the third step.

Next, as a fourth step, introduction of an inert gas or vacuum evacuation is performed, whereby a surplus of the reactant 12a, a reaction product, and the like are released from the chamber.

Then, as illustrated in FIG. 1C, a precursor 11b containing a metal element different from that in the precursor 11a is introduced and a step similar to the first step is performed, so that the precursor 11b is adsorbed onto a surface of the layer of the oxide 13a.

Here, as illustrated in FIG. 1C, the precursor 11b is adsorbed onto the layer of the oxide 13a, whereby a self-limiting mechanism of surface chemical reaction works and no more precursor 11b is adsorbed onto a layer of the precursor 11b over the substrate 10.

Next, as in the second step, by introduction of an inert gas or vacuum evacuation, a surplus of the precursor 11b, a reaction product, and the like are released from the chamber.

Then, as illustrated in FIG. 1D, a reactant 12b is introduced into the chamber and a step similar to the third step is performed. Thus, a layer of an oxide 13b, which is formed by oxidation of part of the precursor 11b, is formed over the layer of the oxide 13a.

The reactant 12b may be the same as or different from the reactant 12a.

Then, as in the fourth step, by introduction of an inert gas or vacuum evacuation, a surplus of the reactant 12b, a reaction product, and the like are released from the chamber.

Furthermore, the first step to the fourth step are performed in a similar manner, whereby a layer of an oxide 13c can be formed over the layer of the oxide 13b. When the layer of the oxide 13c is formed, a compound including a metal element different from those of the precursor 11a and the precursor 11b is used as a precursor. The reactant may be the same as one or both of the reactants 12a and 12b, or may be different from both of the reactants 12a and 12b.

As described above, by performing the steps for forming the oxide 13a to the oxide 13c repeatedly, a metal oxide having a layered crystal structure in which the stacked-layer structure 14 including the oxide 13a to the oxide 13c is repeated can be formed (FIG. 1E). That is, an oxide layer can be formed through the first step to the fourth step, which are regarded as one set (also referred to as one cycle), and by repeating the set, a layered crystal structure in which a plurality of oxide layers are stacked can be formed.

The thickness of the metal oxide having a layered crystal structure is preferably greater than or equal to 1 nm and less than 100 nm, further preferably greater than or equal to 3 nm and less than 20 nm.

In the formation of a metal oxide having a layered crystal structure, specifically, a metal oxide having the CAAC structure, it is preferable that the steps illustrated in FIG. 1 be performed while the substrate is being heated. The substrate temperature is preferably higher than or equal to 200 °C and lower than or equal to 600 °C, further preferably higher than or equal to 300 °C and lower than or equal to 450 °C. In addition, the substrate temperature is preferably lower than the decomposition temperatures of precursors that are used. Accordingly, in deposition by an ALD method, the plurality of precursors that are used can be adsorbed onto an object (e.g., a substrate) without being decomposed.

By performing the deposition while the substrate is heated within such a temperature range, an impurity such as hydrogen or carbon contained in the precursor, the reactant, or the like can be removed from the metal oxide in each of the first step to the fourth step. For example, carbon in the metal oxide can be released as CO₂ or CO. In addition, for example, hydrogen in the metal oxide can be released as H₂O. Furthermore, metal atoms and oxygen atoms are rearranged concurrently with removal of the impurity, so that layers of oxides can be arranged orderly. Thus, a metal oxide having a layered crystal structure with high crystallinity, specifically, a metal oxide having a CAAC structure can be formed.

Note that FIG. 1A illustrates an example where the precursor 11a is adsorbed onto the substrate 10; however, the present invention is not limited thereto. For example, an insulating film (an insulating film containing one or more of oxygen, nitrogen, silicon, aluminum, hafnium, and the like), a conductive film (a conductive film containing one or more of tungsten, tantalum, molybdenum, zirconium, aluminum, titanium, and the like), or the like may be provided over the substrate 10 and the precursor 11a may be adsorbed thereonto. Alternatively, the precursor 11a may be adsorbed onto a component formed using an insulating film, a conductive film, and the like over the substrate 10.

In order to perform deposition while the substrate is heated within the above temperature range, the decomposition temperature of a precursor used for the deposition is preferably not too low. Meanwhile, too high a decomposition temperature is not preferable because the precursor is difficult to handle and the substrate temperature during deposition needs to be extremely high. For example, the decomposition temperature of the precursor is preferably higher than or equal to 200 °C and lower than or equal to 700 °C, further preferably higher than or equal to 300 °C and lower than or equal to 650 °C, still further preferably higher than or equal to 400 °C and lower than or equal to 600 °C.

An inorganic precursor contains few impurities such as hydrogen and carbon, and thus can inhibit an increase in impurity concentration in a formed metal oxide. Meanwhile, an inorganic precursor often has a higher decomposition temperature than an organic precursor.

In view of the above, in the film formation method of a metal oxide which is one embodiment of the present invention, an organic precursor is used, film formation is performed while the substrate is heated, or impurity removal treatment is performed, for example, whereby an increase in impurity concentration in the formed metal oxide can be inhibited.

There is no particular limitation on the frequency of the impurity removal treatment. Higher frequency is preferable in terms of ease of impurity removal, but the productivity might be decreased in this case. Lower frequency is preferable in terms of a short film formation process time of the metal oxide, but impurity removal might be insufficient in this case. In repetition of steps for forming the oxide 13a to the oxide 13c, for example, the impurity removal treatment is preferably performed every time a plurality of oxide layers are formed. For example, it is also possible to perform the impurity removal treatment every time any one of the oxide 13a to the oxide 13c is formed; however, it is preferable to perform the impurity removal treatment every time a plurality of oxide layers are formed or every time a plurality of stacked-layer structures 14 are formed, in which case the process can be simplified. Alternatively, the impurity removal treatment may be performed once after the metal oxide film is formed.

For example, the impurity removal treatment may be performed every time n oxide layers are formed (n is an integer greater than or equal to 1 and less than or equal to 100, preferably greater than or equal to 2 and less than or equal to 50, further preferably greater than or equal to 5 and less than or equal to 30 layers). For example, the metal oxide can be formed by repetition of the following steps of: forming the oxides 13a, 13b, 13c, 13a, and 13b in this order; performing the impurity removal treatment; forming the oxides 13c, 13a, 13b, 13c, and 13a in this order; performing the impurity removal treatment; forming the oxides 13b, 13c, 13a, 13b, and 13c in this order; and then performing the impurity removal treatment.

For example, the impurity removal treatment may be performed every time m stacked-layer structures 14 are formed (m is an integer greater than or equal to 1 and less than or equal to 50, preferably greater than or equal to 2 and less than or equal to 30, further preferably greater than or equal to 5 and less than or equal to 10).

As described above, examples of the impurity removal treatment include plasma treatment, microwave treatment, and heat treatment. The impurity removal treatment may be performed while light irradiation is performed.

A chamber where the impurity removal treatment is performed may be the same as or different from a chamber where the first step to the fourth step are performed. That is, a chamber for the deposition may be the same as or different from a chamber for the impurity removal treatment.

When plasma treatment or microwave treatment is performed, the substrate temperature is preferably higher than or equal to room temperature (e.g., 25 °C), higher than or equal to 100 °C, higher than or equal to 200 °C, higher than or equal to 300 °C, or higher than or equal to 400 °C, and lower than or equal to 500 °C or lower than or equal to 450 °C. The heat treatment temperature is preferably higher than or equal to 100 °C, higher than or equal to 200 °C, higher than or equal to 300 °C, or higher than or equal to 400 °C, and lower than or equal to 500 °C or lower than or equal to 450 °C. The temperature of the impurity removal treatment is particularly preferably set lower than or equal to the maximum temperature in the manufacturing process of a transistor or a semiconductor device, in which case the impurity content in the metal oxide can be reduced without a decrease in productivity.

In the case where oxygen plasma is used in the third step and the treatment time of the third step is set long, the third step can also serve as plasma treatment as the impurity removal treatment. For example, the third step may be performed longer once every few times so as to serve as the impurity removal treatment.

Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz. The microwave treatment can also be referred to as microwave excitation high-density plasma treatment.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHZ and less than or equal to 2.5 GHZ, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the film efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably higher than or equal to room temperature (25 °C) and lower than or equal to 750 °C, further preferably higher than or equal to 300 °C and lower than or equal to 500 °C, and can be higher than or equal to 400 °C and lower than or equal to 450 °C.

After the microwave treatment or plasma treatment is performed, heat treatment may be successively performed without exposure to the air. The heat treatment temperature is preferably higher than or equal to 100 °C and lower than or equal to 750 °C, further preferably higher than or equal to 300 °C and lower than or equal to 500 °C, still further preferably higher than or equal to 400 °C and lower than or equal to 450 °C, for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%.

The heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in an atmosphere of mixing a nitrogen gas and an oxygen gas, the proportion of the oxygen gas is preferably approximately 20%. The heat treatment may be performed under reduced pressure. Alternatively, heat treatment may be performed in a nitrogen gas or inert gas atmosphere, and then another heat treatment may be performed in an atmosphere containing an oxidizing gas at higher than or equal to 10 ppm, higher than or equal to 1%, or higher than or equal to 10% in order to compensate for released oxygen. The heat treatment may be performed under an atmosphere of ultra-dry air (air in which water content is lower than or equal to 20 ppm, preferably lower than or equal to 1 ppm, further preferably lower than or equal to 10 ppb).

The gas used in the heat treatment is preferably highly purified. For example, the amount of moisture contained in the gas used in the heat treatment is preferably less than or equal to 1 ppb, further preferably less than or equal to 0.1 ppb, still further preferably less than or equal to 0.05 ppb. The heat treatment performed using a highly purified gas can prevent entry of moisture or the like into the metal oxide as much as possible.

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O.

The heat treatment is preferably performed after formation of the metal oxide (after formation of all the predetermined number of the stacked-layer structures 14 but before formation of another film with a different material or composition). In particular, the heat treatment is preferably performed without exposure to the air successively after the deposition by an ALD method. Thus, the heat treatment can be performed after the deposition of the metal oxide without increasing an impurity such as hydrogen or carbon in the film. The heat treatment is performed at preferably higher than or equal to 100 °C and lower than or equal to 500 °C, further preferably higher than or equal to 200 °C and lower than or equal to 500 °C, still further preferably higher than or equal to 250 °C and lower than or equal to 500 °C, yet still further preferably higher than or equal to 300 °C and lower than or equal to 500 °C, yet still further preferably higher than or equal to 350 °C and lower than or equal to 450 °C, yet still further preferably higher than or equal to 400 °C and lower than or equal to 450 °C. Note that the heat treatment is performed in a nitrogen gas or inert gas atmosphere, or an atmosphere containing an oxidizing gas at higher than or equal to 10 ppm, higher than or equal to 1%, or higher than or equal to 10%. The heat treatment may be performed under reduced pressure. Alternatively, heat treatment may be performed in a nitrogen gas or inert gas atmosphere, and then another heat treatment may be performed in an atmosphere containing an oxidizing gas at higher than or equal to 10 ppm, higher than or equal to 1%, or higher than or equal to 10% in order to compensate for released oxygen.

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which can improve crystallinity. Thus, a metal oxide having a layered crystal structure with high crystallinity, specifically, a metal oxide having a CAAC structure can be formed.

Plasma treatment or microwave treatment may be performed after formation of the metal oxide.

FIG. 1 illustrates the structure in which the stacked-layer structure 14 including the oxide 13a to the oxide 13c is repeated; however, the present invention is not limited thereto. For example, a single layer, two layers, or four or more layers of an oxide may be repeatedly formed in a metal oxide. In FIG. 1, the oxide 13a, the oxide 13b, and the oxide 13c are repeatedly stacked without changing the order; however, the present invention is not limited thereto. For example, the order of the oxide 13a, the oxide 13b, and the oxide 13c may be changed. Alternatively, the compositions of the oxide 13a, the oxide 13b, and the oxide 13c may be changed in the film. In FIG. 1, different oxide layers are provided to be adjacent to each other in the order of the oxide 13a, the oxide 13b, and the oxide 13c; however, the present invention is not limited thereto. A structure may be employed in which the same oxide layers are successively provided in the order of, for example, the oxide 13a, the oxide 13a, the oxide 13b, the oxide 13b, the oxide 13c, and the oxide 13c.

In the following description of this specification, in the case of using ozone, oxygen, and water as a reactant or an oxidizer, they include not only those in gas and molecular states but also those in a plasma state, a radical state, and an ion state, unless otherwise specified. In the case where a film is formed using an oxidizer in a plasma state, a radical state, or an ion state, a radical ALD apparatus or a plasma ALD apparatus, which will be described later, may be used.

In order to remove an impurity such as carbon or hydrogen contained in a precursor, the precursor is preferably made to react with an oxidizer sufficiently. For example, pulse time for introducing an oxidizer may be made longer. A preferable example of time for which an oxidizer is supplied in one cycle in the film formation process of the metal oxide is as described above. Alternatively, an oxidizer may be introduced a plurality of times. In the case where an oxidizer is introduced a plurality of times, the same kind of oxidizer may be introduced or different kinds of oxidizers may be introduced; for example, after water is introduced as a first oxidizer to the chamber, vacuum evacuation may be performed, ozone or oxygen which does not contain hydrogen may be introduced as a second oxidizer to the chamber, and vacuum evacuation may be performed.

Note that in the above description, an example in which the second source gas is introduced into the chamber after the first source gas is introduced into the chamber is shown; however, the present invention is not limited thereto. The first source gas may be introduced into the chamber after the second source gas is introduced into the chamber. In other words, deposition may be performed in the following manner: the third step and the fourth step are performed first, the first step, the second step, the third step, and the fourth step are performed, and then the first step to the fourth step are repeated. Alternatively, deposition may be performed by repeating the third step and the fourth step a plurality of times, and repeating the first step to the fourth step.

In this manner, the third step and the fourth step are preferably performed once or more before the first step because the deposition atmosphere in the chamber can be controlled. For example, O₃ and O₂ are introduced as oxidizers in the third step, so that the chamber can have an oxygen atmosphere. Deposition performed in the chamber having an oxygen atmosphere is preferable because the formed film can have a high oxygen concentration. Furthermore, oxygen can also be supplied to the insulator and the oxide that are to be bases of the film. A semiconductor device formed by such a method can have favorable characteristics and obtain high reliability. Moreover, for example, introduction of water as an oxidizer in the third step can form a hydrophilic group on the formation surface. Accordingly, the precursor can have a much improved adsorption property.

After the first step and the second step, introduction of the second source gas in the third step and vacuum evacuation or introduction of an inert gas in the fourth step may be repeated a plurality of times. That is, after the first step, the second step, the third step, the fourth step, the third step, and the fourth step are performed, that is, after the third step and the fourth step are repeated, the first step and the second step may be performed.

For example, O₃ and O₂ are introduced as oxidizers in the third step, introduction of an inert gas is performed in the fourth step, and then these steps may be repeated a plurality of times. In the case where the third step and the fourth step are repeated, it is not necessary to repeat the introduction of the same kind of source gas. For example, H₂O may be used as an oxidizer in the third step in the first cycle, and O₃ may be used as an oxidizer in the third steps in and after the second cycle.

In this manner, the introduction of an oxidizer and the introduction of an inert gas (or vacuum evacuation) in the chamber are repeated a plurality of times in a short time, whereby excess hydrogen atoms, carbon atoms, and the like can be more certainly removed from the precursor adsorbed onto the substrate surface, and can be released to the outside of the chamber. When the number of the kinds of the oxidizer is increased to two, more excess hydrogen atoms and the like can be removed from the precursor adsorbed onto the substrate surface. In this manner, hydrogen atoms are prevented from being taken into the film during the deposition, so that water, hydrogen, and the like contained in the formed film can be reduced.

The above-described method enables formation of a film that releases water molecules, the number of which is greater than or equal to 1.0×10¹³ molecules/cm² and less than or equal to 1.0×10¹⁶ molecules/cm² and preferably greater than or equal to 1.0×10¹³ molecules/cm² and less than or equal to 3.0×10¹⁵ molecules/cm² in TDS analysis in the range of a surface temperature from 100 °C to 700 °C or from 100 °C to 500 °C.

An ALD method is a method in which deposition is performed through reaction of a precursor and a reactant using thermal energy. A temperature required for the reaction between the precursor and the reactant is determined by the temperature characteristics, vapor pressure, decomposition temperature, and the like thereof and is set to higher than or equal to 100 °C and lower than or equal to 600 °C, preferably higher than or equal to 200 °C and lower than or equal to 600 °C, further preferably higher than or equal to 300 °C and lower than or equal to 600 °C.

Moreover, an ALD method in which treatment is performed by introducing a plasma-excited reactant into the chamber as a third source gas in addition to the precursor and the reactant which react with each other is referred to as a plasma ALD method in some cases. In this case, a plasma generation apparatus is provided in the introduction portion of the third source gas. Inductively coupled plasma (ICP) can be used for plasma generation. On the other hand, an ALD method in which reaction between the precursor and the reactant is performed using thermal energy is sometimes referred to as a thermal ALD method.

In a plasma ALD method, deposition is performed by introducing a plasma-excited reactant in the third step. Alternatively, deposition is performed in way in which the first step to the fourth step are repeated while a plasma-excited reactant (a second reactant) is introduced. In this case, the reactant introduced in the third step is referred to as a first reactant. In the plasma ALD method, the same material as the above-described oxidizer can be used for the second reactant used as the third source gas. In other words, plasma-excited ozone, oxygen, and water can be used as the second reactant. Other than oxidizer, a nitriding agent may be used as the second reactant. As the nitriding agent, nitrogen (N₂) or ammonia (NH₃) can be used. A mixed gas of nitrogen (N₂) and hydrogen (H₂) can also be used as the nitriding agent. For example, a mixed gas of nitrogen (N₂) of 5% and hydrogen (H₂) of 95% can be used as the nitriding agent. Deposition is performed while plasma-excited nitrogen or ammonia is introduced, whereby a nitride film such as a metal nitride film can be formed.

Argon (Ar), helium (He), or nitrogen (N₂) may be used as a carrier gas for the second reactant. The use of a carrier gas such as argon, helium, or nitrogen is preferable because plasma is easily discharged and the plasma-excited second reactant is easily generated. Note that in the case where an oxide film such as a metal oxide film is formed by a plasma ALD method and nitrogen is used as a carrier gas, nitrogen enters the film and a desired film quality cannot be obtained in some cases. In this case, argon or helium is preferably used as the carrier gas.

By an ALD method, an extremely thin film can be deposited to have a uniform thickness. In addition, the coverage of an uneven surface with the film is high.

When deposition is performed by a plasma ALD method, deposition can be performed at a lower temperature than that by a thermal ALD method. By a plasma ALD method, for example, deposition can be performed without decreasing the deposition rate even at a temperature lower than or equal to 100 °C in some cases.

In the case where a plasma ALD method is employed, by generating plasma while a plasma source for inductively coupled plasma (ICP), electron cyclotron resonance plasma (ECR), or the like is apart from a substrate, plasma damage can be reduced.

### <Atomic Arrangement in Crystal of Metal Oxide>

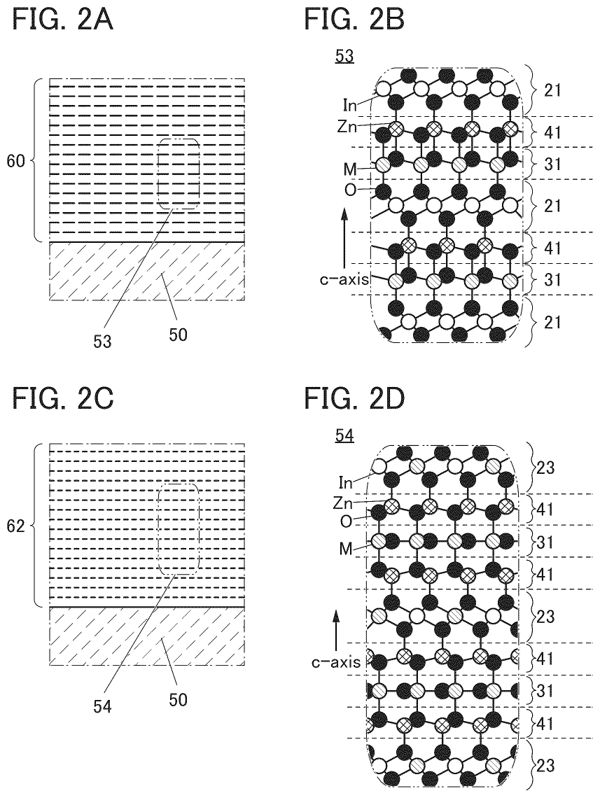

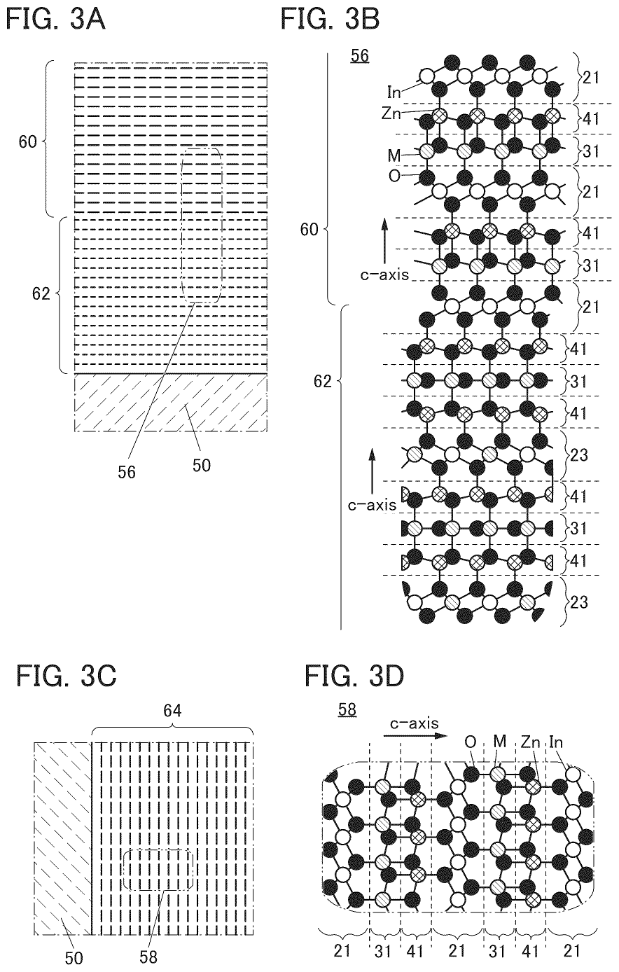

Here, atomic arrangement in the crystal when the metal oxide having a layered crystal structure is an In-M-Zn oxide is described with reference to FIG. 2A to 2D and FIG. 3A to FIG. 3D. In FIG. 2B, FIG. 2D, FIG. 3B, and FIG. 3D, an atom is represented by a sphere (a circle) and a bond between a metal atom and an oxygen atom is represented by a line. In FIG. 2B, FIG. 2D, FIG. 3B, and FIG. 3D, the c-axis direction in the crystal structure of the In-M-Zn oxide is indicated by the arrows (c-axis) in the drawings. The a-b plane direction in the crystal structure of the In-M-Zn oxide is the direction perpendicular to the c-axis direction indicated by the arrows in FIG. 2B, FIG. 2D, FIG. 3B, and FIG. 3D.

FIG. 2A is a diagram illustrating an oxide 60 including an In-M-Zn oxide formed on a structure body 50. Here, the structure body refers to a component included in a semiconductor device such as a transistor. The structure body 50 includes a substrate, conductors such as a gate electrode, a source electrode, and a drain electrode, an insulator such as a gate insulating film, an interlayer insulating film, and a base insulating film, a semiconductor such as a metal oxide or silicon, and the like. In FIG. 2A, a deposition surface of the structure body 50 is placed parallel to a substrate (not illustrated).

FIG. 2B is an enlarged view illustrating the atomic arrangement in the crystal in a region 53, which is part of the oxide 60 in FIG. 2A. Here, the composition of the oxide 60 illustrated in FIG. 2A and FIG. 2B is In:M:Zn=1:1:1 [atomic ratio], and the crystal structure is a YbFe₂O₄ type structure. The element M is a metal element having a valence of +3.

As illustrated in FIG. 2B, the crystal included in the oxide 60 has repetitive stacking of a layer 21 containing indium (In) and oxygen, a layer 31 containing the element M and oxygen, and a layer 41 containing zinc (Zn) and oxygen in this order. The layer 21, the layer 31, and the layer 41 are placed parallel or substantially parallel to the deposition surface of the structure body 50. That is, the a-b plane of the oxide 60 is parallel or substantially parallel to the deposition surface of the structure body 50, and the c-axis of the oxide 60 is substantially parallel to the normal direction of the deposition surface of the structure body 50.

When the layer 21, the layer 31, and the layer 41 included in the above crystal are each composed of one metal element and oxygen as illustrated in FIG. 2B, arrangement with favorable crystallinity is achieved to increase the mobility of the metal oxide.

Note that the In-M-Zn oxide with In:M. Zn=1:1:1 [atomic ratio] is not limited to the structure illustrated in FIG. 2B. The stacking order of the layer 21, the layer 31, and the layer 41 may be changed. For example, the layer 21, the layer 41, and the layer 31 may be stacked repeatedly in this order. Alternatively, the layer 21, the layer 31, the layer 41, the layer 21, the layer 41, and the layer 31 may be stacked repeatedly in this order. Part of the element M in the layer 31 may be substituted by zinc and part of zinc in the layer 41 may be substituted by the element M.

Although an example of forming the In-M-Zn oxide whose composition is In:M:Zn=1:1:1 [atomic ratio] is described above, a crystalline In-M-Zn oxide whose composition formula is represented by In₍₁₊ₐ₎M₍₁₋ₐ₎O₃(ZnO)ₘ (a is a real number greater than 0 and less than 1 and m is a positive number) can have a layered crystal structure in a similar manner. As an example, an In-M-Zn oxide with In:M:Zn=1:3:4 [atomic ratio] is described with reference to FIG. 2C and FIG. 2D.

FIG. 2C is a diagram illustrating an oxide 62 including an In-M-Zn oxide formed on the structure body 50. FIG. 2D is an enlarged view illustrating the atomic arrangement in the crystal in a region 54, which is part of the oxide 62 in FIG. 2C.

As illustrated in FIG. 2D, the crystal included in the oxide 62 includes a layer 23 containing indium (In), the element M, and oxygen, the layer 41 containing zinc (Zn) and oxygen, and the layer 31 containing the element M and oxygen. In the oxide 62, the plurality of layers are stacked repeatedly in the order of the layer 23, the layer 41, the layer 31, and the layer 41. The layer 23, the layer 31, and the layer 41 are placed parallel or substantially parallel to the deposition surface of the structure body 50. That is, the a-b plane of the oxide 62 is parallel or substantially parallel to the deposition surface of the structure body 50, and the c-axis of the oxide 62 is parallel or substantially parallel to the normal direction of the deposition surface of the structure body 50.

The In-M-Zn oxide with In:M:Zn=1:3:4 [atomic ratio] is not limited to the structure illustrated in FIG. 2D, and the structure may change within a range where In:M:Zn=1:3:4 [atomic ratio] is maintained. The stacking order of the layer 23, the layer 31, and the layer 41 may be changed, for example. Part of the element M in the layer 31 may be substituted by zinc and part of zinc in the layer 41 may be substituted by the element M. The layer 21 or the layer 31 may be formed instead of the layer 23.

As illustrated in FIG. 3A, a stacked-layer structure may be employed in which the oxide 62 is formed over the structure body 50 and the oxide 60 is formed thereover. Here, FIG. 3B is an enlarged view illustrating the atomic arrangement in the crystal in a region 56, which is part of the oxide 62 and the oxide 60 in FIG. 3A.

As described above, the oxide 62 is an In-M-Zn oxide with In:M:Zn=1:3:4 [atomic ratio], and the oxide 60 is an In-M-Zn oxide with In:M:Zn=1:1:1 [atomic ratio]. That is, the oxide illustrated in FIG. 3A is an oxide film in which the atomic ratio changes in the film. Furthermore, when the oxide 62 has a layered crystal structure as illustrated in FIG. 3B, the crystallinity of the oxide 60 over the oxide 62 can be favorable.

The oxide 62 and the oxide 60 are not limited to the structure illustrated in FIG. 3B, and the structures of the oxide 62 and the oxide 60 may be changed as described above. The layer 21 is placed at the boundary between the oxide 62 and the oxide 60 in FIG. 3B; however, the present invention is not limited thereto. For example, the layer 23 may be formed at the boundary between the oxide 62 and the oxide 60.

As described above, an ALD method enables deposition of a film on a component with a high aspect ratio and also enables deposition of a film with excellent coverage on a side surface of a structure body. By employing an ALD method, a metal oxide having crystallinity such as a CAAC structure can be easily formed regardless of the orientation of the deposition surface. For example, a metal oxide with good coverage can be formed on a top surface, a bottom surface, a side surface, and a surface with a slope of a structure body even when the structure body has a projected shape or a recessed shape. In other words, a metal oxide that has a substantially uniform thickness in the normal direction can be formed on each deposition surface. As for the metal oxide that is formed on each of the top surface, the bottom surface, the side surface, and the surface with the slope of the structure body, the ratio of the minimum thickness to the maximum thickness can be greater than or equal to 0.5 and less than or equal to 1, preferably greater than or equal to 0.7 and less than or equal to 1, further preferably greater than or equal to 0.9 and less than or equal to 1. At this time, in the case where the metal oxide has a crystal structure, the c-axis thereof is aligned in a direction substantially parallel to the normal direction of each of the deposition surfaces. In other words, the c-axis is aligned perpendicularly to each of the deposition surfaces.

Here, FIG. 3C illustrates a case where a deposition surface of the structure body 50 is placed perpendicular to a substrate (not illustrated) and an oxide 64 is formed on the surface of the structure body 50. FIG. 3D is an enlarged view of a region 58, which is part of the oxide 64 in FIG. 3C. FIG. 3D illustrates a state where, on the side surface of the structure body 50, the layer 21 containing indium (In), the layer 31 containing the element M, and the layer 41 containing zinc (Zn) are stacked with respect to the deposition surface. The layer 21 containing indium is placed parallel or substantially parallel to the deposition surface of the structure body 50, the layer 31 containing the element M is placed thereover to be parallel or substantially parallel to the deposition surface of the structure body 50, and further the layer 41 containing zinc is placed thereover to be parallel or substantially parallel to the deposition surface of the structure body 50. That is, the a-b plane of the oxide 60 is parallel or substantially parallel to the deposition surface of the structure body 50, and the c-axis of the oxide 60 is parallel or substantially parallel to the normal direction of the deposition surface of the structure body 50. Note that FIG. 3C and FIG. 3D show the example of the In-M-Zn oxide with In:M:Zn=1:1:1 [atomic ratio], but an oxide with a different atomic ratio can also be formed on the surface of the structure body 50 whose deposition surface is placed perpendicular to the substrate.

The examples of the metal oxide with In:M:Zn=1:1:1 [atomic ratio] and the metal oxide with In:M:Zn=1:3:4 [atomic ratio] are shown in the above; however, the present invention is not limited thereto.

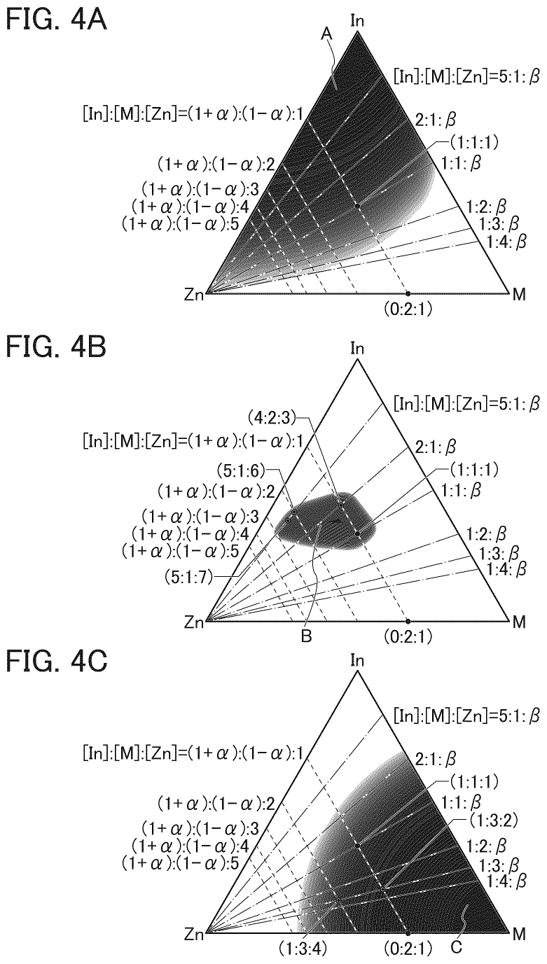

Preferred ranges of the atomic ratio of indium, the element M, and zinc contained in the metal oxide that can be used as the oxide described in one embodiment of the present invention are described below with reference to FIG. 4A, FIG. 4B, and FIG. 4C. Note that the proportion of oxygen atoms is not illustrated in FIG. 4A, FIG. 4B, and FIG. 4C. In addition, the terms of the atomic ratio of indium, the element M, and zinc contained in the metal oxide are denoted by [In], [M], and [Zn], respectively.

In FIG. 4A, FIG. 4B, and FIG. 4C, broken lines indicate a line representing an atomic ratio of [In]:[M]:[Z]=(1+α):(1−α):1(−1≤α≤1), a line representing an atomic ratio of [In]:[M]:[Zn]=(1+α):(1−α):2, a line representing an atomic ratio of [In]:[M]:[Zn]=(1+α):(1−α):3, a line representing an atomic ratio of [In]:[M]:[Zn]=(1+α):(1−α):4, and a line representing an atomic ratio of [In]:[M]:[Zn]=(1+α):(1−α):5.

Furthermore, dashed-dotted lines indicate a line representing an atomic ratio of [In]:[M]:[Zn]=5:1:β (β≥0), a line representing an atomic ratio of [In]:[M]:[Z]=2:1:β, a line representing an atomic ratio of [In]:[M]:[Zn]=1:1:β, a line representing an atomic ratio of [In]:[M]:[Zn]=1:2:β, a line representing an atomic ratio of [In]:[M]:[Zn]=1:3:β, and a line representing an atomic ratio of [In]:[M]:[Zn]=1:4:β.

A metal oxide with an atomic ratio of [In]:[M]:[Zn]=0:2:1 and the neighborhood thereof in FIG. 4A, FIG. 4B, and FIG. 4C tends to have a spinel crystal structure.

In addition, a plurality of phases coexist in the metal oxide in some cases (two-phase coexistence, three-phase coexistence, or the like). For example, with an atomic ratio having a value in the neighborhood of [In]:[M]:[Zn]=0:2:1, two phases of a spinel crystal structure and a layered crystal structure are likely to coexist. In addition, with an atomic ratio having a value in the neighborhood of [In]:[M]:[Zn]=1:0:0, two phases of a bixbyite crystal structure and a layered crystal structure are likely to coexist. In the case where a plurality of phases coexist in the metal oxide, a grain boundary is formed between different crystal structures in some cases.

A region A in FIG. 4A shows an example of the preferred ranges of the atomic ratio of indium, the element M, and zinc contained in a metal oxide.

When the metal oxide has a higher content percentage of indium, the carrier mobility (electron mobility) of the metal oxide can be increased. Thus, a metal oxide having a high content percentage of indium has higher carrier mobility than a metal oxide having a low content percentage of indium.

By contrast, when the content percentage of indium and zinc in a metal oxide becomes lower, carrier mobility becomes lower. Thus, with an atomic ratio of [In]:[M]:[Zn]=0:1:0 and the neighborhood thereof (e.g., a region C in FIG. 4C), the insulating property becomes better. Note that since the region C includes a region that is likely to have the above spinel crystal structure, it is preferable to employ a composition with which the region that is likely to have the spinel crystal structure is avoided.

For example, the metal oxide used for a channel formation region and a low-resistance region preferably bas an atomic ratio represented by the region A in FIG. 4A. The metal oxide used for the channel formation region and the low-resistance region may have an atomic ratio of In:Ga:Zn=4:2:3 to 4.1 and approximately a value in the neighborhood thereof, for example. Alternatively, the metal oxide may have an atomic ratio of In:Ga:Zn=1:1:1 and approximately a value in the neighborhood thereof, for example. On the other hand, in the case where the metal oxide is provided to surround the channel formation region and the low-resistance region, the metal oxide preferably has an atomic ratio represented by the region C in FIG. 4C, with which a relatively high insulating property is obtained. The metal oxide provided to surround the channel formation region and the low-resistance region may have an atomic ratio of In:Ga:Zn=1:3:4 and approximately a value in the neighborhood thereof, or an atomic ratio of In:Ga:Zn=1:3:2 and approximately a value in the neighborhood thereof. Alternatively, the metal oxide provided to surround the channel formation region and the low-resistance region may be formed using a metal oxide that is equivalent to a metal oxide used as the channel formation region and the low-resistance region.

In the region A, particularly in a region B illustrated in FIG. 4B, an excellent metal oxide having high carrier mobility and high reliability can be obtained.

Note that the region B includes [In]:[M]:[Zn]=4:2:3 to 4.1 and a value in the neighborhood thereof. The value in the neighborhood includes [In]:[M]:[Zn]=5:3:4, for example. In addition, the region B includes [In]:[M]:[Zn]=5:1:6 and a value in the neighborhood thereof and [In]:[M]:[Zn]=5:1:7 and a value in the neighborhood thereof. The region B includes [In]:[M]:[Zn]=1:1:1 and a value in the neighborhood thereof.

As described above, the electrical conductivity of the metal oxide largely varies depending on the atomic ratio. By depositing a metal oxide by an ALD method as described above, a metal oxide having a layered crystal structure corresponding to the atomic ratio can be deposited. Thus, by employing an ALD method, a metal oxide corresponding to required characteristics can be deposited.

### <Film Formation Method 2>

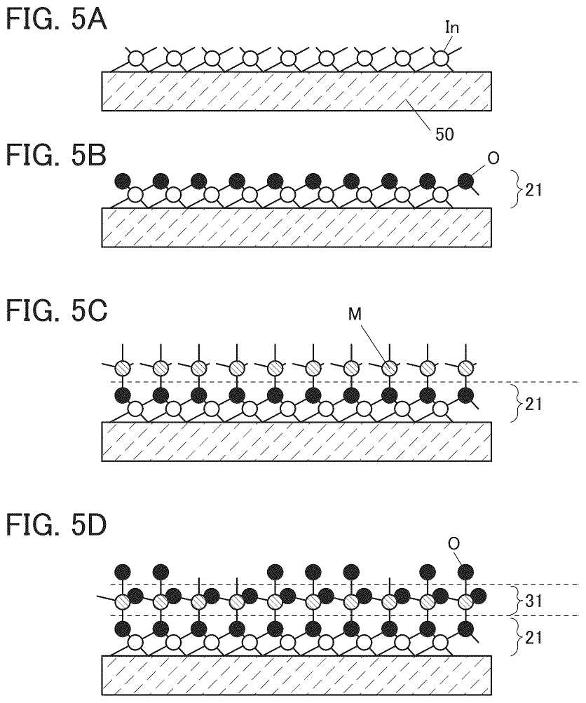

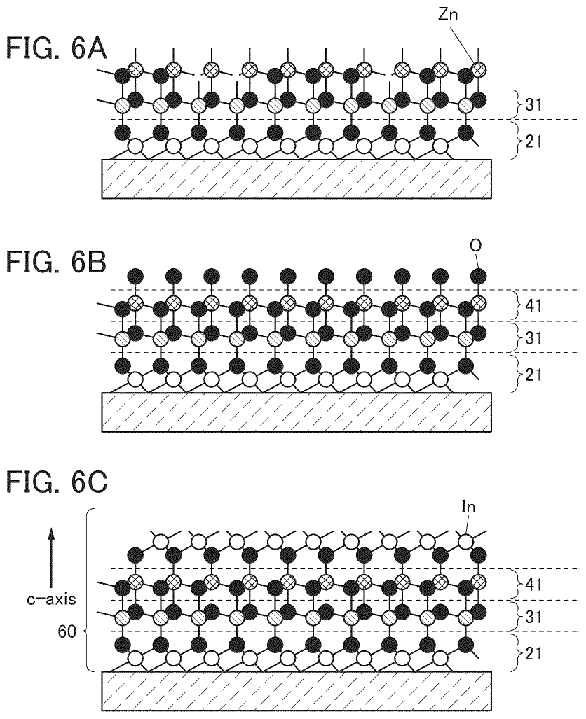

Next, details of a method for forming the oxide 60 including the In-M-Zn oxide illustrated in FIG. 2A and FIG. 2B are described with reference to FIG. 5A to FIG. 5D and FIG. 6A to FIG. 6C.

First, as illustrated in FIG. 5A, a source gas that contains a precursor containing indium is introduced into a chamber, so that the precursor is adsorbed onto the surface of the structure body 50.

The aluminum content of the precursor containing indium is preferably greater than or equal to 0.001 ppm, greater than or equal to 0.01 ppm, or greater than or equal to 0.1 ppm, and preferably less than or equal to 1000 ppm, further preferably less than or equal to 500 ppm, still further preferably less than or equal to 100 ppm, yet still further preferably less than or equal to 50 ppm, yet still further preferably less than or equal to 10 ppm, yet still further preferably less than or equal to 1 ppm. The aluminum content of the precursor containing indium may be less than or equal to 0.001 ppm.

As the precursor used in this embodiment, a precursor that is purified by performing distillation (also referred to as rectification) two or more times is preferably used. The use of such a precursor is preferable because a metal oxide with few impurities can be easily formed. Distillation is preferably performed a plurality of times, in which case impurities derived from a starting material used for manufacturing the precursor can be further inhibited from remaining in the precursor. Note that the present invention is not limited to the above, and a precursor that is purified by performing distillation once, i.e., single distillation, may be used. The use of the single distillation is preferable because the manufacturing cost can be reduced.

Here, the source gas containing a precursor contains a carrier gas such as argon, helium, or nitrogen in addition to the precursor.

Examples of the precursor containing indium include trimethylindium (Structural Formula (101) below), triethylindium (Structural Formula (102) below), ethyldimethylindium, tris(1-methylethyl) indium, tris(2,2,6,6-tetramethyl-3,5-heptanedionato) indium, cyclopentadienylindium, indium (III) acetylacetonate, (diethylphosphino)dimethylindium, chlorodimethylindium, bromodimethylindium, dimethyl(2-propanolato) indium, trifluoroindium (indium (III) fluoride), indium (III) chloride, indium (III) bromide, and indium (III) iodide.

Next, introduction of the source gas is stopped and the chamber is purged, whereby a surplus precursor, a reaction product, and the like are released from the chamber. Then, as illustrated in FIG. 5B, an oxygen-containing oxidizer is introduced as a reactant into the chamber to react with the adsorbed precursor, and components other than indium are released while indium is adsorbed onto the substrate, so that the layer 21 in which indium and oxygen are bonded to each other is formed.

As the oxidizer, ozone (O₃), oxygen (O₂), water (H₂O), dinitrogen monoxide (N₂O), and hydrogen peroxide (H₂O₂), and plasma, a radical, and an ion thereof can be used.

In supplying the oxidizer, the proportion of ozone in the gas is preferably higher than or equal to 10%, further preferably higher than or equal to 20%, still further preferably higher than or equal to 30%, yet still further preferably higher than or equal to 40%, yet still further preferably higher than or equal to 50%, yet still further preferably higher than or equal to 60%, yet still further preferably higher than or equal to 70%, yet still further preferably higher than or equal to 80%, yet still further preferably higher than or equal to 90%, particularly preferably 100%. It is preferable that the proportion of ozone be higher because oxidation of the metal can be promoted and the carbon concentration in the metal oxide can be reduced.

After that, introduction of the oxidizer is stopped and the chamber is purged, whereby a surplus reactant, a reaction product, and the like are released from the chamber.

Subsequently, as illustrated in FIG. 5C, a source gas that contains a precursor containing the element M is introduced into the chamber, so that the precursor is adsorbed onto the layer 21. Here, gallium or tin is preferably used as the element M.

The aluminum content of the precursor containing the element M is preferably greater than or equal to 0.001 ppm, greater than or equal to 0.01 ppm, or greater than or equal to 0.1 ppm, and preferably less than or equal to 1000 ppm, further preferably less than or equal to 500 ppm, still further preferably less than or equal to 100 ppm, yet still further preferably less than or equal to 50 ppm, yet still further preferably less than or equal to 10 ppm, yet still further preferably less than or equal to 1 ppm. The aluminum content of the precursor containing the element M may be less than or equal to 0.001 ppm.

Examples of a precursor containing gallium include trimethylgallium, triethylgallium (Structural Formula (103) below), tris(dimethylamido) gallium (Structural Formula (104) below), triphenylgallium, diethyl(3-methyl-2,4-cyclopropanedien-1-yl) gallium, [4-(1,1-dimethyl)phenyl]dimethylgallium, dimethyl (4-methylphenyl) gallium, dimethylphenylgallium, methyldiphenylgallium, ethyldimethylgallium, dimethylmethylenegallium, gallium (III) acetylacetonate, tris(2,2,6,6-tetramethyl-3,5-heptanedionato) gallium, dimethyl(2-methyl-2-propanolato) gallium, methoxydimethylgallium, hydroxydimethylgallium, (methanethiolato)dimethylgallium, chlorodimethylgallium, chlorodiethylgallium, chlorodipropylgallium, bromodimethylgallium, bromodiethylgallium, dimethyliodogallium, chlorobis(2,2-dimethylpropyl) gallium, gallium (III) fluoride, gallium (III) chloride, gallium (III) bromide, and gallium (III) iodide.

Examples of a precursor containing tin include tetramethyltin, tetraethyltin, tetraethenyltin, tetraallyltin, tributylvinyltin, allyltributyltin, tributylstannylacetylene, tributylphenyltin, chlorotrimethyltin, chlorotriethyltin, tin (IV) fluoride, tin (IV) chloride, tin (IV) bromide, and tin (IV) iodide.

Next, introduction of the source gas is stopped and the chamber is purged, whereby a surplus precursor, a reaction product, and the like are released from the chamber.

Then, as illustrated in FIG. 5D, an oxidizer is introduced as a reactant into the chamber to react with the adsorbed precursor, and components other than the element M are released while the element M is adsorbed onto the substrate, so that the layer 31 in which the element M and oxygen are bonded to each other is formed. At this time, part of oxygen adsorbed onto the layer 31 may be included in the layer 41 described later.

After that, introduction of the oxidizer is stopped and the chamber is purged, whereby a surplus reactant, a reaction product, and the like are released from the chamber.

Then, as illustrated in FIG. 6A, a source gas that contains a precursor containing zinc is introduced into the chamber, so that the precursor is adsorbed onto the layer 31. At this time, part of the layer 41 in which zinc is bonded to oxygen is formed in some cases.

The aluminum content of the precursor containing zinc is preferably greater than or equal to 0.001 ppm, greater than or equal to 0.01 ppm, or greater than or equal to 0.1 ppm, and preferably less than or equal to 1000 ppm, further preferably less than or equal to 500 ppm, still further preferably less than or equal to 100 ppm, yet still further preferably less than or equal to 50 ppm, yet still further preferably less than or equal to 10 ppm, yet still further preferably less than or equal to 1 ppm. The aluminum content of the precursor containing zine may be less than or equal to 0.001 ppm.

Examples of the precursor containing zinc include dimethylzinc, diethylzinc (Structural Formula (105) below), bis(1-methylethyl) zinc, bis(1,1-dimethylethyl) zinc, dibutylzinc, diethenylzinc, dicyclohexylzinc, bis(2,2,6,6-tetramethyl-3,5-heptanedionato) zinc, zinc fluoride, zinc chloride, chloromethylzinc, zinc bromide, bromomethylzinc, and zinc iodide.

Next, introduction of the source gas is stopped and the chamber is purged, whereby a surplus precursor, a reaction product, and the like are released from the chamber.

Then, as illustrated in FIG. 6B, an oxidizer is introduced as a reactant into the chamber to react with the adsorbed precursor, and components other than zinc are released while zinc is adsorbed onto the substrate, so that the layer 41 in which zinc and oxygen are bonded to each other is formed.

Here, the total time for supplying the oxidizer in the three steps illustrated in FIG. 5B, FIG. 5D, and FIG. 6B is preferably longer than or equal to 10 seconds, further preferably longer than or equal to 30 seconds, still further preferably longer than or equal to 60 seconds, yet still further preferably longer than or equal to 90 seconds, yet still further preferably longer than or equal to 120 seconds, and preferably shorter than or equal to 150 seconds, shorter than or equal to 200 seconds, shorter than or equal to 250 seconds, or shorter than or equal to 300 seconds.

The time for supplying the oxidizer is preferably longer, in which case the carbon concentration in the oxide 60 can be lower. Meanwhile, the time for supplying the oxidizer is preferably shorter, in which case the time required for forming a film of the oxide 60 is shorter.

After that, introduction of the oxidizer is stopped and the chamber is purged, whereby a surplus reactant, a reaction product, and the like are released from the chamber.

Next, the layer 21 is formed again over the layer 41 by the above-described method (see FIG. 6C). By repeating the above-described method, the oxide 60 can be formed over the substrate or the structure body.

Here, examples of the above-listed precursors are shown below.

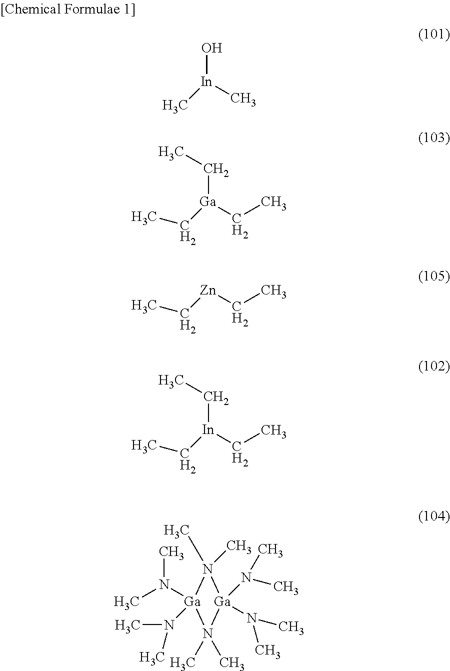

Some of the above-listed precursors containing the metal elements further contain one or both of carbon and chlorine. A film that is formed using a precursor containing carbon may contain carbon. A film that is formed using a precursor containing halogen such as chlorine may contain halogen such as chlorine.

The steps illustrated in FIG. 5A to FIG. 5D and FIG. 6A to FIG. 6C are preferably performed while the substrate is being heated. The substrate temperature is, for example, preferably higher than or equal to 150 °C, higher than or equal to 200 °C, or higher than or equal to 250 °C. The substrate temperature is preferably lower than or equal to 600 °C, lower than or equal to 500 °C, lower than or equal to 450 °C, lower than or equal to 400 °C, or lower than or equal to the decomposition temperature of the precursor. When ozone is used as the oxidizer, the substrate temperature is preferably lower than or equal to the decomposition temperature of ozone. By performing the deposition while the substrate is being heated in such a temperature range, an impurity such as hydrogen or carbon contained in the precursor, the reactant, or the like can be removed from the metal oxide in each of the steps in FIG. 5A to FIG. 6C. For example, carbon in the metal oxide can be released as CO₂ and CO, and hydrogen in the metal oxide can be released as H₂O. Furthermore, metal atoms and oxygen atoms are rearranged concurrently with removal of the impurity, so that layers of oxides can be arranged orderly. Thus, a metal oxide including a crystal part can be formed. Moreover, a metal oxide having a layered crystal structure with high crystallinity, for example, a metal oxide having a CAAC structure can be formed.

The impurity removal treatment is preferably performed intermittently during formation of the oxide 60. For example, the impurity removal treatment is preferably performed every time a three-layer stacked structure of the layer 21, the layer 31, and the layer 41 is formed n times (n is an integer greater than or equal to 1 and less than or equal to 50, preferably greater than or equal to 2 and less than or equal to 30, further preferably greater than or equal to S and less than or equal to 10). Preferably, the impurity removal treatment is performed also after the formation of the oxide 60.

By performing the impurity removal treatment, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which can improve crystallinity. Thus, a metal oxide including a crystal part can be formed. Moreover, a metal oxide having a layered crystal structure with high crystallinity, specifically, a metal oxide having a CAAC structure can be formed.

As described above, the oxide 60 is formed by an ALD method, whereby the metal oxide having a CAAC structure, in which the c-axis is aligned substantially parallel to the normal direction of the deposition surface, can be obtained.

FIG. 5A to FIG. 5D and FIG. 6A to FIG. 6C show an example in which the layer 21 is formed as a layer containing indium, the layer 31 is formed thereover as a layer containing the element M, and further the layer 41 is formed thereover as a layer containing zinc; however, this embodiment is not limited thereto. One of the layer 31 and the layer 41 may be formed, the layer 21 may be formed thereover, and further the other of the layer 31 and the layer 41 may be formed thereover. Alternatively, one of the layer 31 and the layer 41 may be formed, the other of the layer 31 and the layer 41 may be formed thereover, and further the layer 21 may be formed thereover.

In the case of forming a metal oxide with an atomic ratio that is different from In:M:Zn=1:1:1 [atomic ratio], the above-described layer 21, layer 31, and layer 41 are formed as appropriate in accordance with the atomic ratio. For example, the formation of the layer 41 is repeated a plurality of times before and after the formation of the layer 31 illustrated in FIG. 6A so that a stack including the layers 31 and the layers 41 and having the desired number of atoms and layers and a desired thickness is formed between two layers 21.

Note that in manufacturing a variety of semiconductor devices, both the metal oxide of one embodiment of the present invention and another metal oxide may be used. For example, the metal oxide of one embodiment of the present invention may be used in combination with a metal oxide containing aluminum and at least one of indium and zinc (the metal oxide may further contain at least one of gallium and tin).

Examples of the metal oxide containing aluminum and at least one of indium and zinc include indium gallium aluminum oxide (In—Ga—Al oxide), aluminum zinc oxide (Al—Zn oxide, also referred to as AZO), indium aluminum zinc oxide (In—Al—Zn oxide, also referred to as IAZO), and indium gallium aluminum zinc oxide (In—Ga—Al—Zn oxide, also referred to as IGAZO, IGZAO, or IAGZO).

Examples of a precursor containing aluminum include trimethylaluminum, triethylaluminum, chlorodimethylaluminum, dichloromethylaluminum, bromodimethylaluminum, iododimethylaluminum, aluminumacetylacetonate, tris(2,2,6,6-tetramethyl-3,5-heptanedione acid)aluminum, dimethylchloroaluminum, diethylchloroaluminum, aluminum (III) chloride, aluminum (III) bromide, and aluminum (III) iodide.

### <Deposition Apparatus>

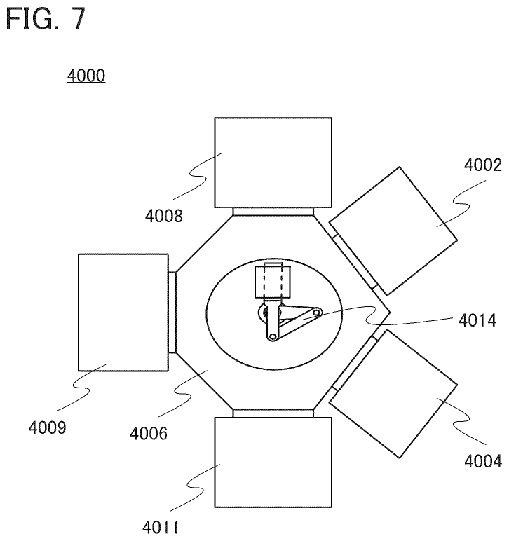

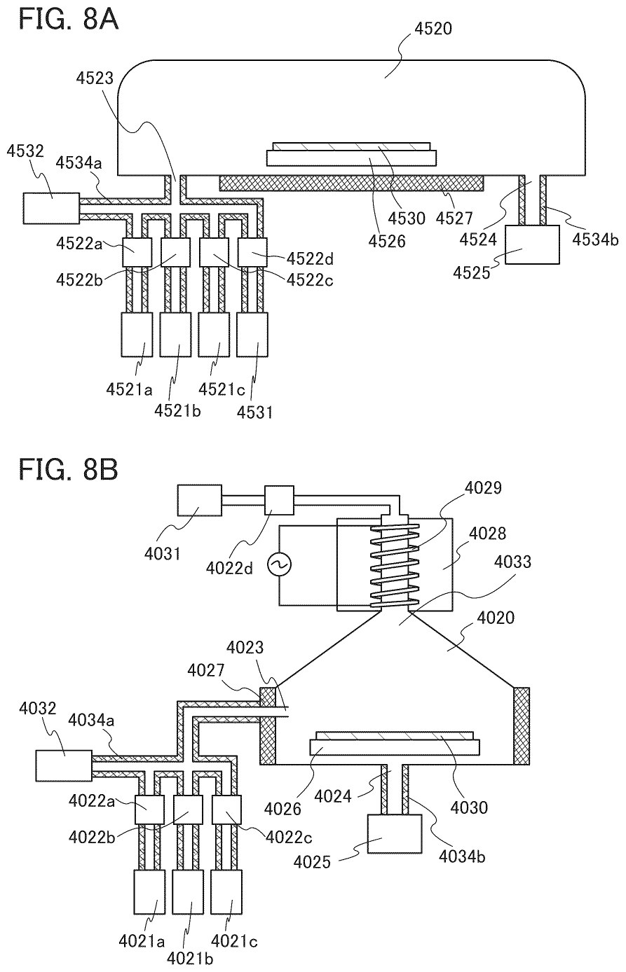

The structure of a deposition apparatus 4000 is described with reference to FIG. 7 to FIG. 10 as an example of an apparatus with which deposition can be performed by an ALD method. FIG. 7 is a schematic view of the multi-chamber type deposition apparatus 4000, and FIG. 8 to FIG. 10 are cross-sectional views of ALD apparatuses that can be used for the deposition apparatus 4000.

The deposition apparatus 4000 illustrated in FIG. 7 includes a carrying-in/out chamber 4002, a carrying-in/out chamber 4004, a transfer chamber 4006, a deposition chamber 4008, a deposition chamber 4009, a treatment chamber 4011, and a transfer arm 4014. Here, the carrying-in/out chamber 4002, the carrying-in/out chamber 4004, the deposition chamber 4008, the deposition chamber 4009, and the treatment chamber 4011 are each independently connected to the transfer chamber 4006 through a gate valve. Thus, successive treatment can be performed in the deposition chamber 4008, the deposition chamber 4009, and the treatment chamber 4011 without exposure to the air, whereby entry of impurities into a film can be prevented. Moreover, contamination of an interface between a substrate and a film and interfaces between films can be reduced, so that clean interfaces can be obtained.

In order to prevent attachment of moisture and the like, the carrying-in/out chamber 4002, the carrying-in/out chamber 4004, the transfer chamber 4006, the deposition chamber 4008, the deposition chamber 4009, and the treatment chamber 4011 are preferably filled with an inert gas (such as a nitrogen gas) whose dew point is controlled, and desirably maintain reduced pressure.

An ALD apparatus can be used in the deposition chamber 4008 and the deposition chamber 4009. A structure using a deposition apparatus other than an ALD apparatus in either of the deposition chamber 4008 and the deposition chamber 4009 may be employed. Examples of the deposition apparatus that can be used in the deposition chamber 4008 and the deposition chamber 4009 include a sputtering apparatus, a plasma CVD (PECVD: Plasma Enhanced CVD) apparatus, a thermal CVD (TCVD) apparatus, a photo CVD apparatus, a metal CVD (MCVD) apparatus, and a metal organic CVD (MOCVD) apparatus.

For the treatment chamber 4011, an apparatus having a function other than that of a deposition apparatus such as a heating apparatus (typically, a vacuum heating apparatus) and a plasma generation apparatus (typically, a microwave treatment apparatus) is preferably used.

For example, in the case where an ALD apparatus is used in the deposition chamber 4008, a sputtering apparatus is used in the deposition chamber 4009, and a heating apparatus is used in the deposition chamber 4011, a base insulating film can be deposited in the deposition chamber 4009, an oxide semiconductor film functioning as an active layer can be deposited in the deposition chamber 4008, and heat treatment after the deposition of the oxide semiconductor film can be performed in the treatment chamber 4011. At that time, the deposition of the base insulating film, the deposition of the oxide semiconductor film, and the heat treatment can be performed successively without exposure to the air. Thus, the heat treatment can be performed after the deposition of the metal oxide without increasing an impurity such as hydrogen or carbon in the film.

Although the deposition apparatus 4000 includes the carrying-in/out chamber 4002, the carrying-in/out chamber 4004, the deposition chamber 4008, the deposition chamber 4009, and the treatment chamber 4011, the present invention is not limited thereto. The number of the deposition chambers in the deposition apparatus 4000 may be one or three or more. The number of the treatment chambers in the deposition apparatus 4000 may be two or more. The deposition apparatus 4000 may be of a single-wafer type or may be of a batch type, in which case deposition is performed on a plurality of substrates at a time.

### <ALD Apparatus>

Next, a structure of a thermal ALD apparatus that can be used as the deposition apparatus 4000 is described with reference to FIG. 8A. The thermal ALD apparatus includes a deposition chamber (a chamber 4520), a source material supply portion 4521 (a source material supply portion 4521a to a source material supply portion 4521c), a source material supply portion 4531, a high-speed valve 4522a to a high-speed valve 4522d that are introduction amount controllers, a gas supply portion 4532, a source material introduction port 4523, a source material exhaust port 4524, and an evacuation unit 4525. The source material introduction port 4523 provided in the chamber 4520 is connected to the source material supply portion 4521a, the source material supply portion 4521b, the source material supply portion 4521c, the source material supply portion 4531, and the gas supply portion 4532 through supply tubes and valves, and the source material exhaust port 4524 is connected to the evacuation unit 4525 through an exhaust tube, a valve, and a pressure controller, for example.

A substrate holder 4526 is located in the chamber 4520, and a substrate 4530 is placed on the substrate holder 4526. The substrate holder 4526 may include a rotation mechanism. A heater 4527, which is provided on an outside wall of the chamber 4520, can control the temperature inside the chamber 4520 and the temperatures of the substrate holder 4526, the surface of the substrate 4530, and the like. The heater 4527 is preferably capable of controlling the temperature of the surface of the substrate 4530 to higher than or equal to 100 °C and lower than or equal to 600 °C, preferably higher than or equal to 300 °C and lower than or equal to 500 °C, further preferably higher than or equal to 400 °C and lower than or equal to 450 °C. The temperature of the heater 4527 itself is preferably set to higher than or equal to 100 °C and lower than or equal to 600 °C, for example. By performing the deposition while the substrate is being heated in such a temperature range, an impurity such as hydrogen or carbon contained in the precursor, the reactant, or the like can be inhibited from remaining in the metal oxide. Furthermore, metal atoms and oxygen atoms are rearranged concurrently with removal of the impurity, so that layers of oxides can be arranged orderly. Thus, a metal oxide having a layered crystal structure with high crystallinity can be formed. In addition, the heat treatment after the deposition of the metal oxide may be performed with the use of the heater 4527.

In the source material supply portion 4521a, the source material supply portion 4521b, the source material supply portion 4521c, and the source material supply portion 4531, a source gas is formed from a solid source material or a liquid source material using a vaporizer, a heating unit, or the like. Alternatively, the source material supply portion 4521a, the source material supply portion 4521b, the source material supply portion 4521c, and the source material supply portion 4531 may supply a source gas.

In the deposition apparatus illustrated in FIG. 8A, a metal oxide can be formed by appropriate selection of source materials (e.g., a volatile organic metal compound) used in the source material supply portion 4521 and the source material supply portion 4531 and introduction of the materials into the chamber 4520. In the case where an In—Ga—Zn oxide, which contains indium, gallium, and zinc, is formed as the metal oxide as described above, it is preferable to use a deposition apparatus provided with at least three source material supply portions 4521a to 4521c and at least one source material supply portion 4531, as illustrated in FIG. 8A.

For example, a precursor containing indium is supplied from the source material supply portion 4521a, a precursor containing gallium is supplied from the source material supply portion 4521b, and a precursor containing zine is supplied from the source material supply portion 4521c. Any of the above-described precursors can be used as the precursor containing indium, the precursor containing gallium, and the precursor containing zinc.

A reactant is supplied from the source material supply portion 4531. An oxidizer containing at least one of ozone, oxygen, and water can be used as the reactant.

A carrier gas is supplied from the gas supply portion 4532. As the carrier gas, an inert gas such as argon (Ar), helium (He), or nitrogen (N₂) can be used. The precursor from the source material supply portion 4521 and the reactant from the source material supply portion 4531 are mixed with the carrier gas and introduced into the chamber 4520.

A pipe heater 4534a is provided to cover the pipe, the valve, and the like between the source material supply portion 4521a, the source material supply portion 4521b, the source material supply portion 4521c, the source material supply portion 4531, and the gas supply portion 4532 and the chamber 4520. A pipe heater 4534b is provided to cover the pipe, the valve, and the like between the evacuation unit 4525 and the chamber 4520. The temperatures of the pipe heater 4534a and the pipe heater 4534b are set as appropriate in a range from room temperature to 300 °C, for example. Provision of such pipe heaters can prevent a precursor or the like supplied from the source material supply portion 4521 from being solidified on inner walls of pipes or the like of the gas introduction system and the gas evacuation system. The temperatures of the pipe heater 4534a, the pipe heater 4534b, and the heater 4527 can be preferably controlled independently. Alternatively, the temperatures of the pipe heater 4534a, the pipe heater 4534b, and the heater 4527 may be controlled collectively.

The high-speed valve 4522a to the high-speed valve 4522d can be precisely controlled based on time. Thus, source gases supplied from the source material supply portion 4521a, the source material supply portion 4521b, the source material supply portion 4521c, and the source material supply portion 4531 can be controlled to be introduced into the chamber 4520.

For example, in the case of supplying a precursor included in any of the source material supply portion 4521a, the source material supply portion 4521b, and the source material supply portion 4521c, a corresponding high-speed valve among the high-speed valve 4522a to the high-speed valve 4522c is opened. In the case of supplying a reactant included in the source material supply portion 4531, the high-speed valve 4522d is opened. In the case of purging the chamber 4520, the high-speed valve 4522a to the high-speed valve 4522d are closed and only a carrier gas included in the gas supply portion 4532 is introduced into the chamber 4520.

Although FIG. 8A shows the example in which three source material supply portions 4521 and one source material supply portion 4531 are provided, this embodiment is not limited thereto. One, two, or four or more source material supply portions 4521 may be provided. In addition, two or more source material supply portions 4531 may be provided.

In FIG. 8A, the heater 4527, the source material introduction port 4523, and the source material exhaust port 4524 are provided on the lower portion of the chamber 4520; however, without limitation to this, their arrangement can be set as appropriate. In FIG. 8A, inlets of the source material supply portion 4521a, the source material supply portion 4521b, the source material supply portion 4521c, the source material supply portion 4531, and the gas supply portion 4532 are combined into the source material introduction port 4523; however, without limitation to this, inlets different from each other may be provided.

Next, a structure of a plasma ALD apparatus that can be used as the deposition apparatus 4000 is described with reference to FIG. 8B. The plasma ALD apparatus includes a deposition chamber (a chamber 4020), a source material supply portion 4021 (a source material supply portion 4021a to a source material supply portion 4021c), a source material supply portion 4031, a high-speed valve 4022a to a high-speed valve 4022d that are introduction amount controllers, a gas supply portion 4032, a source material introduction port 4023, a source material introduction port 4033, a source material exhaust port 4024, and an evacuation unit 4025. The source material introduction port 4023 and the source material introduction port 4033 provided in the chamber 4020 are connected to the source material supply portion 4021a, the source material supply portion 4021b, the source material supply portion 4021c, the source material supply portion 4031, and the gas supply portion 4032 through supply tubes and valves, and the source material exhaust port 4024 is connected to the evacuation unit 4025 through an exhaust tube, a valve, and a pressure controller. A substrate holder 4026 is located in the chamber 4020, and a substrate 4030 is placed on the substrate holder 4026. A heater 4027 is provided on an outside wall of the chamber, and a pipe heater 4034a and a pipe heater 4034b are provided to cover pipes and the like connected to the chamber.

Here, the chamber 4020, the source material supply portion 4021, the source material supply portion 4031, the high-speed valve 4022a to the high-speed valve 4022d, the gas supply portion 4032, the source material introduction port 4023, the source material exhaust port 4024, the evacuation unit 4025, the substrate holder 4026, the substrate 4030, the heater 4027, the pipe heater 4034a, and the pipe heater 4034b correspond to the chamber 4520, the source material supply portion 4521, the source material supply portion 4531, the high-speed valve 4522a to the high-speed valve 4522d, the gas supply portion 4532, the source material introduction port 4523, the source material exhaust port 4524, the evacuation unit 4525, the substrate holder 4526, the substrate 4530, the heater 4527, the pipe heater 4534a, and the pipe heater 4534b, respectively; and detailed structures can be referred to for the above description.

In the plasma ALD apparatus, a plasma generation apparatus 4028 is connected to the chamber 4020 as illustrated in FIG. 8B, whereby deposition can be performed by a plasma ALD method as well as a thermal ALD method. It is preferable that the plasma generation apparatus 4028 be an ICP-type plasma generation apparatus using a coil 4029 connected to a high frequency power source. The high-frequency power source is capable of outputting power with a frequency higher than or equal to 10 kHz and lower than or equal to 100 MHz, preferably higher than or equal to 1 MHz and lower than or equal to 60 MHz, further preferably higher than or equal to 2 MHz and lower than or equal to 60 MHz. For example, power with a frequency of 13.56 MHz can be output. A plasma ALD method enables deposition without decreasing the deposition rate even at low temperatures, and thus is preferably used for a single-wafer type deposition apparatus with low deposition efficiency.

A reactant released from the source material supply portion 4031 passes through the plasma generation apparatus 4028 and turns into a plasma state. The reactant in the plasma state is introduced from the source material introduction port 4033 into the chamber 4020. Although not illustrated in FIG. 8B, a reactant released from the source material supply portion 4031 may be mixed with a carrier gas.

The substrate holder 4526 may be provided with a mechanism to which a constant potential or a high-frequency wave is applied. Alternatively, the substrate holder 4526 may be floating or grounded.

In FIG. 8B, the source material introduction port 4033 is provided on the upper portion of the chamber 4520, the heater 4027 and the source material introduction port 4023 are provided on a side surface of the chamber 4520, and the source material exhaust port 4524 is provided on the lower portion of the chamber 4520; however, without limitation to this, their arrangement can be set as appropriate.

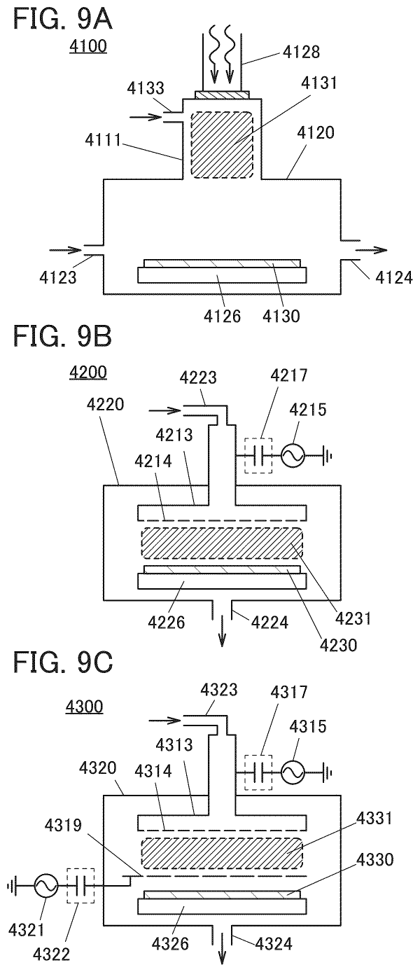

FIG. 9A to FIG. 9C each illustrate a different structure of an ALD apparatus that can be used for the deposition apparatus 4000. Note that detailed description on structures and functions similar to those of the ALD apparatus illustrated in FIG. 8B are omitted in some cases.

FIG. 9A is a schematic view illustrating one embodiment of a plasma ALD apparatus. A plasma ALD apparatus 4100 is provided with a reaction chamber 4120 and a plasma generation chamber 4111 above the reaction chamber 4120. The reaction chamber 4120 can be referred to as a chamber. Alternatively, the reaction chamber 4120 and the plasma generation chamber 4111 can be collectively referred to as a chamber. The reaction chamber 4120 includes a source material introduction port 4123 and a source material exhaust port 4124, and the plasma generation chamber 4111 includes a source material introduction port 4133. Furthermore, a plasma generation apparatus 4128 enables a high-frequency wave such as RF or a microwave to be applied to a gas introduced to the plasma generation chamber 4111, thereby generating plasma 4131 in the plasma generation chamber 4111. In the case where the plasma 4131 is generated using a microwave, a microwave with a frequency of 2.45 GHz is typically used. Such plasma generated by application of the microwave and an electric field is referred to as ECR (Electron Cyclotron Resonance) plasma in some cases.

A substrate holder 4126 is provided in the reaction chamber 4120, and a substrate 4130 is located thereover. A source gas introduced from the source material introduction port 4123 is decomposed by heat from a heater provided in the reaction chamber 4120 and is deposited over the substrate 4130. A source gas introduced from the source material introduction port 4133 turns into a plasma state by the plasma generation apparatus 4128. The source gas in the plasma state is recombined with electrons or other molecules to be in a radical state before it reaches the surface of the substrate 4130, and reaches the substrate 4130. An ALD apparatus that performs deposition using a radical in such a manner may also be referred to as a radical ALD (Radical-Enhanced ALD) apparatus. The structure of the plasma ALD apparatus 4100, in which the plasma generation chamber 4111 is provided above the reaction chamber 4120, is illustrated; however, this embodiment is not limited to this structure. The plasma generation chamber 4111 may be provided adjacent to a side surface of the reaction chamber 4120.

FIG. 9B is a schematic view illustrating one embodiment of a plasma ALD apparatus. A plasma ALD apparatus 4200 includes a chamber 4220. The chamber 4220 includes an electrode 4213, a source material exhaust port 4224, and a substrate holder 4226, and a substrate 4230 is placed on the substrate holder 4226. The electrode 4213 includes a source material introduction port 4223 and a shower head 4214 that supplies the introduced source gas into the chamber 4220. A power source 4215 capable of applying a high-frequency wave through a capacitor 4217 is connected to the electrode 4213. The substrate holder 4226 may be provided with a mechanism to which a constant potential or a high-frequency wave is applied. Alternatively, the substrate holder 4226 may be floating or grounded. The electrode 4213 and the substrate holder 4226 function as an upper electrode and a lower electrode, respectively, for generating plasma 4231. A source gas introduced from the source material introduction port 4223 is decomposed by heat from a heater provided in the chamber 4220 and is deposited over the substrate 4230. Alternatively, the source gas introduced from the source material introduction port 4223 turns into a plasma state between the electrode 4213 and the substrate holder 4226. The source gas in the plasma state enters the substrate 4230 owing to a potential difference (also referred to as an ion sheath) generated between the plasma 4231 and the substrate 4230.

FIG. 9C is a schematic view illustrating one embodiment of a plasma ALD apparatus different from that in FIG. 9B. A plasma ALD apparatus 4300 includes a chamber 4320. The chamber 4320 includes an electrode 4313, a source material exhaust port 4324, and a substrate holder 4326, and a substrate 4330 is placed on the substrate holder 4326. The electrode 4313 includes a source material introduction port 4323 and a shower head 4314 that supplies the introduced source gas into the chamber 4320. A power source 4315 capable of applying a high-frequency wave through a capacitor 4317 is connected to the electrode 4313. The substrate holder 4326 may be provided with a mechanism to which a constant potential or a high-frequency wave is applied. Alternatively, the substrate holder 4326 may be floating or grounded. The electrode 4313 and the substrate holder 4326 function as an upper electrode and a lower electrode, respectively, for generating plasma 4331. The plasma ALD apparatus 4300 is different from the plasma ALD apparatus 4200 in that a mesh 4319 to which a power source 4321 capable of applying a high-frequency wave through a capacitor 4322 is connected is provided between the electrode 4313 and the substrate holder 4326. With the mesh 4319, the plasma 4231 can be away from the substrate 4130. A source gas introduced from the source material introduction port 4323 is decomposed by heat from a heater provided in the chamber 4320 and is deposited over the substrate 4330. Alternatively, the source gas introduced from the source material introduction port 4323 turns into a plasma state between the electrode 4313 and the substrate holder 4326. Charge of the source gas in the plasma state is removed by the mesh 4319 and the source gas reaches the substrate 4130 while being in an electrically neutral state such as a radical. Therefore, it is possible to perform deposition with suppressed damage due to plasma and the entry of ions.

For example, with the plasma ALD apparatus illustrated in FIG. 8B and FIG. 9A to FIG. 9C, plasma treatment or microwave treatment may be performed as the impurity removal treatment. This is preferable because transfer from the deposition chamber to another chamber for the impurity removal treatment is unnecessary.

The plasma treatment or microwave treatment after the deposition of the metal oxide may be performed with the use of the plasma ALD apparatus illustrated in FIG. 8B and FIG. 9A to FIG. 9C.

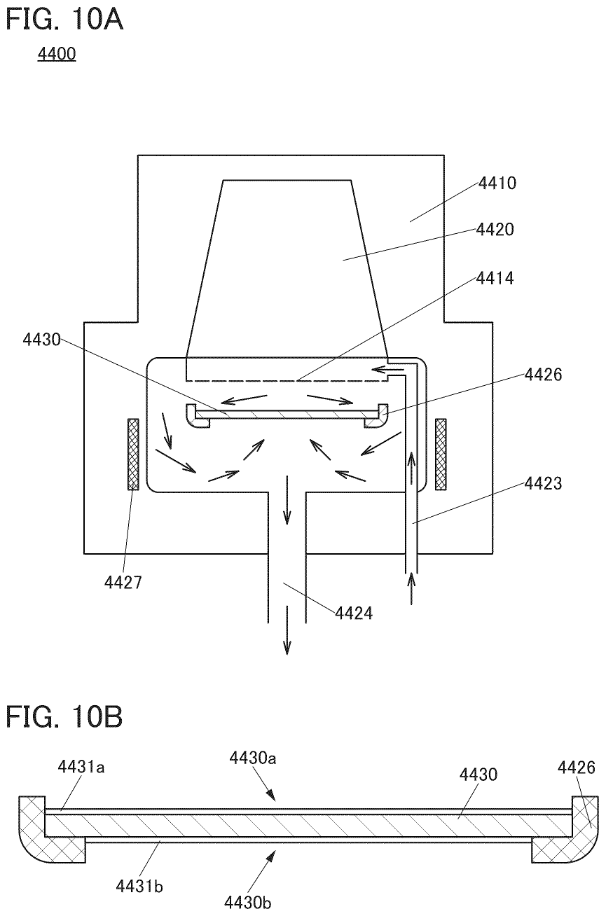

Next, a different structure of an ALD apparatus that can be used for the deposition apparatus 4000 will be described with reference to FIG. 10A and FIG. 10B.

An ALD apparatus 4400 illustrated in FIG. 10A includes a chamber 4420 and a heater 4427 inside an outer chamber 4410, and a substrate holder 4426 is included inside the chamber 4420. A precursor, an oxidizer, and a carrier gas are supplied from a source material introduction port 4423 to the chamber 4420 through a source material supply port 4414. Evacuation is performed from the chamber 4420 through a source material exhaust port 4424.

A substrate 4430 is placed on the substrate holder 4426. As illustrated in FIG. 10A, each of the precursor and the oxidizer is supplied from above the chamber 4420, and a film is formed on the top surface of the substrate 4430. The precursor and the oxidizer are also adsorbed on the bottom surface of the substrate 4430 before evacuation is performed from below the chamber 4420; thus, a film is formed also on the bottom surface of the substrate 4430.

Accordingly, when the ALD apparatus 4400 is used in a face-up mode, a film 4431a is formed on a front surface 4430a of the substrate 4430 and a film 4431b is formed on a rear surface 4430b of the substrate 4430 as illustrated in FIG. 10B. In other words, with the use of the ALD apparatus 4400, the films can be formed on both surfaces of the substrate 4430.

Note that the thicknesses of the film 4431a and the film 4431b are the same or substantially the same. Depending on the kind or the like of the precursor and the oxidizer, the composition of the film 4431a may be the same or substantially the same as that of the film 4431b, or the composition of the film 4431a may be different from that of the film 4431b.

For example, an element that is easily adsorbed may have a higher concentration in the film formed on the front surface than in the film formed on the rear surface. For example, as described later in Example, it is confirmed that the concentration of aluminum, which is contained as an impurity in triethylindium, in the film 4431a deposited on the front surface of the substrate is higher than the concentration of aluminum in the film 4431b deposited on the rear surface of the substrate.

In the case of using the ALD apparatus 4400, deposition may be performed in what is called a face-up mode, in which case deposition is performed in a state where the front surface of the substrate faces upward, or deposition may be performed in what is called a face-down mode, in which case deposition is performed in a state where the front surface of the substrate faces downward (a state where the substrate is inverted). A mode that allows formation of a film with a desired composition can be selected as appropriate.

### <Deposition Sequence>

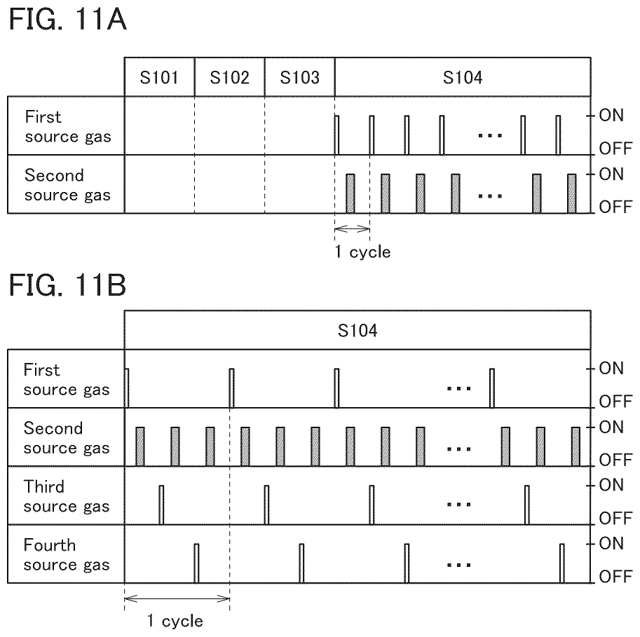

Next, a deposition sequence of a metal oxide using the ALD apparatus illustrated in FIG. 8A is described with reference to FIG. 11 to FIG. 13. In FIG. 11 to FIG. 13, introductions of a first source gas to a fourth source gas are each indicated by ON, and periods during which the source gases are not introduced are each indicated by OFF.

FIG. 11A shows a deposition sequence using the ALD apparatus illustrated in FIG. 8A. First, the substrate 4530 is set on the substrate holder 4526 in the chamber 4520 (Step S101). Next, the temperature of the heater 4527 is adjusted (Step S102). At this time, the temperatures of the pipe heater 4534a and the pipe heater 4534b are also adjusted. Then, the substrate 4530 is held on the substrate holder 4526 so that the temperature of the substrate 4530 becomes uniform in the substrate surface (Step S103). Next, a metal oxide is deposited in accordance with the above first step to fourth step (Step S104). Note that after setting the substrate 4530 (Step S101), Step S102 may be omitted if the temperature of the heater 4527 does not need to be adjusted.

In Step S104, the first source gas (a source gas containing a precursor) and the second source gas (a source gas containing a reactant) are alternately introduced into the chamber 4520, whereby a film is deposited over the substrate 4530. The first source gas and the second source gas are introduced in a pulsed form. In periods during which neither the first source gas nor the second source gas is introduced, the chamber 4520 is purged. In the deposition by an ALD method, introduction of the first source gas (the first step), purge of the first source gas (the second step), introduction of the second source gas (the third step), and purge of the second source gas (the fourth step) are regarded as one cycle, and a film having a desired thickness is formed by repetition of this cycle. Although intermittent impurity removal treatment is not mentioned here, the impurity removal treatment may be performed in the chamber 4520 or another chamber every time the cycle is repeated a plurality of times.

Furthermore, the second source gas containing a reactant may be introduced into the chamber 4020 between Step S103 and Step S104. It is preferable that one or more selected from ozone (O₃), oxygen (O₂), and water (H₂O), which function as oxidizers, be introduced as the second source gas. Introduction of water as the second source gas can form a hydrophilic group on the substrate 4530, so that the precursor can have a much improved adsorption property. Introduction of ozone and oxygen as the second source gas can provide an oxygen atmosphere in the chamber and supply oxygen to the base insulating film or the like formed on the substrate 4530. Accordingly, oxygen can be supplied to the metal oxide film formed over the base insulating film, so that the oxygen concentration in the film can be increased. In that case, the second source gas is preferably introduced in a pulsed form in a manner similar to that in Step S104; however, the present invention is not limited thereto. The second source gas may be successively introduced. In the period during which the second source gas is not introduced, the chamber 4520 is evacuated.

A first oxide layer is formed in one cycle using the above first source gas, a second oxide layer is formed in one cycle using the third source gas different from the first source gas, and a third oxide layer is formed in one cycle using the fourth source gas different from the first source gas, whereby a layered crystalline oxide including different oxide layers can be deposited. Hereinafter, a deposition sequence corresponding to a deposition process of the In—Ga—Zn oxide illustrated in FIG. 5 and FIG. 6 is described as an example with reference to FIG. 11B.

FIG. 11B shows Step S104 of the deposition sequence in an example in which deposition is performed using the first source gas to the third source gas containing different precursors. Note that Steps S101 to S103 are as described above. Here, the first source gas contains a precursor containing indium, the third source gas contains a precursor containing gallium, and the fourth source gas contains a precursor containing zinc.

As shown in FIG. 11B, first, the first source gas is introduced, whereby the precursor containing indium is adsorbed onto the substrate 4530 (corresponding to FIG. 5A). Then, introduction of the first source gas is stopped and an excess first source gas in the chamber is purged.

Next, the second source gas is introduced, whereby the adsorbed precursor containing indium reacts with an oxidizer and a layer of indium oxide is formed (corresponding to FIG. 5B). Then, introduction of the second source gas is stopped and an excess second source gas in the chamber is purged.

Next, the third source gas is introduced, whereby the precursor containing gallium is adsorbed onto the layer of indium oxide (corresponding to FIG. 5C). Then, introduction of the third source gas is stopped and an excess third source gas in the chamber is purged.

Next, the second source gas is introduced, whereby the adsorbed precursor containing gallium reacts with an oxidizer and a layer of gallium oxide is formed (corresponding to FIG. 5D). Then, introduction of the second source gas is stopped and an excess second source gas in the chamber is purged.

Next, the fourth source gas is introduced, whereby the precursor containing zinc is adsorbed onto the layer of gallium oxide (corresponding to FIG. 6A). Then, introduction of the fourth source gas is stopped and an excess fourth source gas in the chamber is purged. Next, the second source gas is introduced, whereby the adsorbed precursor containing zinc reacts with an oxidizer and a layer of zinc oxide is formed (corresponding to FIG. 6B). Then, introduction of the second source gas is stopped and an excess second source gas in the chamber is purged. Furthermore, the precursor containing indium is adsorbed onto the zinc oxide by the above method (corresponding to FIG. 6C).

The above steps of forming indium oxide, gallium oxide, and zinc oxide are regarded as one cycle and the cycle is repeated, whereby an In—Ga—Zn oxide with In:Ga:Zn=1:1:1 [atomic ratio] having a desired thickness can be formed.

Note that the first source gas to the fourth source gas are introduced in a pulsed form. The pulse time of introducing the first source gas, the third source gas, and the fourth source gas into the chamber 4520 is preferably longer than or equal to 0.05 seconds and shorter than or equal to 1 second, further preferably longer than or equal to 0.1 seconds and shorter than or equal to 0.5 seconds. The time for evacuating the first source gas, the third source gas, and the fourth source gas from the chamber 4520 is longer than or equal to 0.1 seconds and shorter than or equal to 15 seconds, preferably longer than or equal to 0.5 seconds and shorter than or equal to 10 seconds. The pulse time of introducing the second source gas into the chamber 4520 is preferably longer than or equal to 0.05 seconds and shorter than or equal to 30 seconds, further preferably longer than or equal to 0.1 seconds and shorter than or equal to 15 seconds. The time for evacuating the second source gas from the chamber 4520 is longer than or equal to 0.1 seconds and shorter than or equal to 15 seconds, preferably longer than or equal to 0.1 seconds and shorter than or equal to 5 seconds.

Note that in the sequence shown in FIG. 11B, the order of introduction of the first source gas, the third source gas, and the fourth source gas is not limited thereto. For example, the fourth gas containing the precursor containing zinc may be introduced first. Since zinc oxide is likely to form a crystal structure as compared to indium oxide and gallium oxide, a stable crystal of zinc oxide can be formed in a bottom layer. Accordingly, layers of indium oxide and gallium oxide can be relatively easily formed over the zinc oxide.

Deposition of an In—Ga—Zn oxide with In:Ga:Zn=1:1:1 [atomic ratio] is described above; however, the present invention is not limited thereto. An In—Ga—Zn oxide with a different atomic ratio can be formed by a similar method. The number of pulses or the pulse time of a source gas containing a precursor in one cycle is preferably set in accordance with the atomic ratio of a desired In—Ga—Zn oxide.

For example, in the sequence shown in FIG. 11B, in order to deposit an In—Ga—Zn oxide with In:Ga:Zn=1:1:1 [atomic ratio], the numbers of pulses of the first source gas containing indium, the third source gas containing gallium, and the fourth source gas containing zinc were each one in one cycle. Here, the pulse times of the precursors are the same.

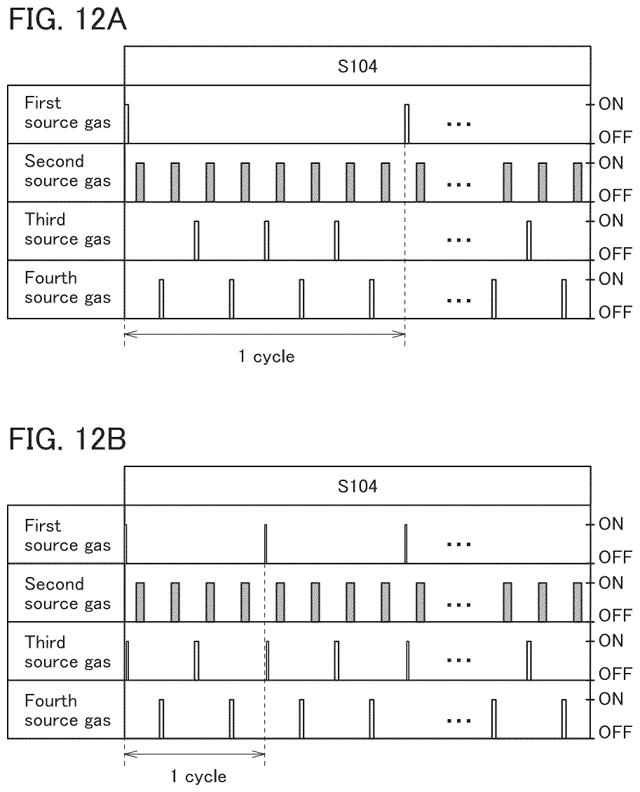

FIG. 12A shows an example of a deposition sequence of an In—Ga—Zn oxide with In:Ga:Zn=1:3:4 [atomic ratio]. In FIG. 12A, in one cycle, the number of pulses of the first source gas containing indium is one, the number of pulses of the third source gas containing gallium is three, and the number of pulses of the fourth source gas containing zinc is four. That is, the numbers of pulses of the source gases containing precursors correspond to In:Ga:Zn=1:3:4 [atomic ratio]. By performing deposition in such a manner, a metal oxide having a layered crystal structure according to FIG. 2D can be formed.

Furthermore, by performing deposition by an ALD method while a substrate is being heated as described above, rearrangement of oxide layers can be promoted. Accordingly, even when deposition is performed in accordance with the sequence shown in FIG. 12A, a layer in which one oxide layer contains two kinds of metal elements (indium and gallium) can be formed like the layer 23 illustrated in FIG. 2D.

Note that in the above, introductions of different kinds of precursors are performed while the source gas containing a reactant is introduced therebetween; however, the present invention is not limited thereto. For example, introductions of source gases containing the same kind of precursor are successively performed while the source gas containing a reactant is introduced therebetween. At this time, the numbers of pulses of the source gases containing the precursors in one cycle is preferably the same as the atomic ratio of a desired In—Ga—Zn oxide.

Moreover, in the above, the structure in which only the source gas containing one kind of precursor is introduced during the interval in which oxidation using the second source gas is performed is shown; however, the present invention is not limited thereto. Two or more kinds of source gases containing precursors may be introduced during the interval in which oxidation using the second source gas is performed. At this time, two or more kinds of source gases containing precursors may be introduced at the same time. Alternatively, the same kind of precursor may be successively introduced twice during the interval in which oxidation using the second source gas is performed.

For example, when an In—Ga—Zn oxide with In:Ga:Zn=1:3:4 [atomic ratio] is deposited, the deposition may be performed in a sequence shown in FIG. 12B. In FIG. 12B, in accordance with the crystal structure illustrated in FIG. 2D in which the layer 23, the layer 41, the layer 31, and the layer 41 are stacked in this order, the first source gas, the third source gas, the fourth source gas, the third source gas, and the fourth source gas are introduced in this order. Note that first introductions of the first source gas and the third source gas are performed without introducing the second source gas therebetween. In other words, the precursor containing indium contained in the first source gas and the precursor containing gallium contained in the third source gas are adsorbed, and then an oxidizer is introduced. Accordingly, like the layer 23 illustrated in FIG. 2D, a layer in which one oxide layer contains two kinds of metal elements (indium and gallium) can be formed. At this time, the pulse time of each of the first source gas and the third source gas is preferably approximately half of the pulse time of the fourth source gas. Accordingly, as shown in FIG. 12B, the ratio of the pulse time of the first source gas containing indium to the pulse time of the third source gas containing gallium and the pulse time of the fourth source gas containing zinc in one cycle can be 1:3:4, which is the same as the atomic ratio.

Deposition of the oxide with a constant atomic ratio is described above; however, the present invention is not limited thereto. Two or more kinds of oxides with different atomic ratios can be successively deposited by a similar method. In this case, for stacked oxides with different atomic ratios, the number of pulses or the pulse time of a source gas containing a precursor in one cycle is preferably set in accordance with the atomic ratios of the oxides. When deposition is performed in such a manner, the stacked oxides with different atomic ratios can be deposited in one chamber. Thus, entry of an impurity such as hydrogen or carbon can be prevented in the interval in which the oxide is deposited.

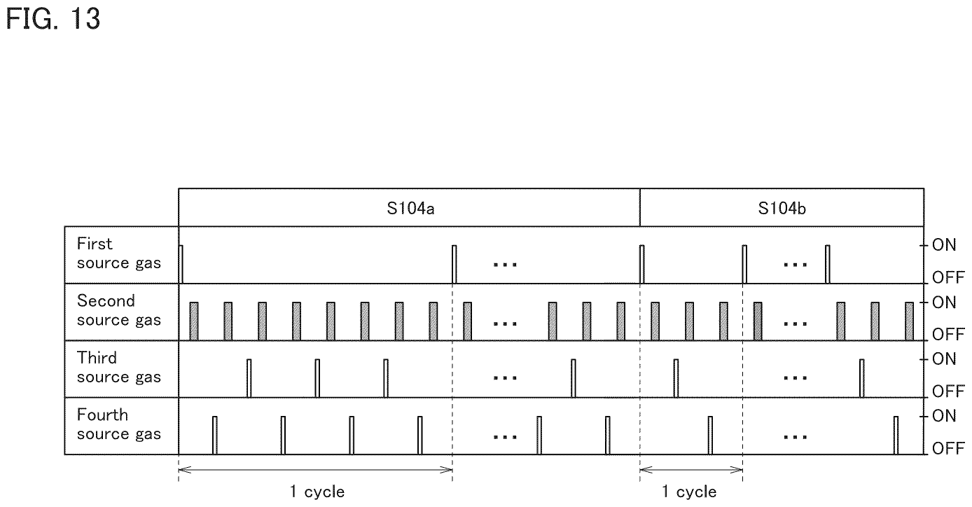

FIG. 13 shows an example of a deposition sequence in the case where an oxide with In:Ga:Zn=1:1:1 [atomic ratio] is stacked over an oxide with In:Ga:Zn=1:3:4 [atomic ratio]. Step 104a corresponds to the oxide with In:Ga:Zn=1:3:4 [atomic ratio] and is similar to the sequence shown in FIG. 12A. Step 104b corresponds to the oxide with In:Ga:Zn=1:1:1 [atomic ratio] and is similar to the sequence shown in FIG. 11B. As described above, the number of pulses in one cycle in the former period is the first source gas:the third source gas:the fourth source gas=1:3:4 and the number of pulses in one cycle in the latter period is the first source gas:the third source gas:the fourth source gas=1:1:1, so that a metal oxide having a stacked-layer structure including the oxide 62 and the oxide 60 illustrated in FIG. 3B can be deposited. In other words, deposition is performed in the former period with the number of pulses corresponding to In:Ga:Zn=1:3:4 [atomic ratio] and deposition is performed in the latter period with the number of pulses corresponding to In:Ga:Zn=1:1:1 [atomic ratio].

In the above, the deposition method is described using an In—Ga—Zn oxide as an example; however, the present invention is not limited thereto. A precursor is set as appropriate in accordance with a metal element contained in a desired metal oxide. In the above, one or three kinds of precursors are used; however, without limitation to this, two or four or more kinds may be used.

In the above, the example in which deposition is performed using a precursor containing one kind of metal element is described; however, the present invention is not limited thereto. A precursor containing two or more kinds of metal elements may be used. For example, a precursor containing indium and gallium or a precursor containing gallium and zinc may be used. In such a case, the number of source material supply portions 4521 illustrated in FIG. 8A and the like can be reduced.

### <Metal Oxide Having CAAC Structure>

The details of a metal oxide having a CAAC structure will be described below.

The CAAC structure includes a plurality of crystals and each of the plurality of crystals has c-axis alignment in a particular direction. Note that the particular direction refers to the thickness direction of a metal oxide having the CAAC structure, the normal direction of the surface where the metal oxide having the CAAC structure is formed, or the normal direction of the surface of the metal oxide having the CAAC structure. In the case where a crystal region is denoted, the crystal region refers to a crystal itself included in the CAAC structure, or a crystal included in the CAAC structure and a region in the vicinity thereof. Thus, a crystal included in the CAAC structure is sometimes referred to as a crystal region included in the CAAC structure.

The crystal region refers to a region having a periodic atomic arrangement. When an atomic arrangement is regarded as a lattice arrangement, the crystal region also refers to a region with a uniform lattice arrangement. The CAAC structure has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, a metal oxide having the CAAC structure is a metal oxide having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one kind or two or more kinds selected from gallium, yttrium, tin, titanium, and the like), the CAAC structure tends to have a layered crystal structure (also referred to as a layered structure) in which a layer containing indium (In) and oxygen and a layer containing the element M, zinc (Zn), and oxygen are stacked. Note that the layer containing indium and oxygen may contain the element M or zinc. The layer containing the element M, zinc, and oxygen may contain indium. Such a layered structure is observed as a lattice image in a high-resolution TEM image, for example.

When a metal oxide having the CAAC structure is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the metal oxide.

For example, a plurality of bright spots are observed in the electron diffraction pattern of a metal oxide having the CAAC structure. Note that one spot and another spot are observed point-symmetrically with a spot of the incident electron beam passing through a sample (also referred to as a direct spot) as the symmetric center.

FFT (Fast Fourier Transform) analysis on a TEM image yields an FFT image having a pattern reflecting reciprocal lattice space information like an electron diffraction pattern. That is, a crystal structure (e.g., CAAC structure) can be observed and evaluated by FFT analysis. For example, in the case of the cross-sectional TEM image of the metal oxide having the CAAC structure taken from the direction perpendicular to the c-axis, two spots having high intensity are observed in the FFT image in some cases. The intensity of the two spots represents the degree of crystallization of the metal oxide having the CAAC structure, and the angle of a line segment obtained by connecting the two spots represents the crystal orientation of the metal oxide having the CAAC structure.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in a metal oxide having the CAAC structure. That is, formation of a grain boundary is inhibited by the distortion of lattice arrangement. This is probably because a metal oxide having the CAAC structure can tolerate distortion owing to a low density of arrangement of oxygen atoms in the a-b plane direction, an interatomic bond distance changed by substitution of a metal atom, and the like.

A metal oxide having the CAAC structure is a metal oxide with high crystallinity in which no clear grain boundary is observed. That is, a reduction in electron mobility due to the grain boundary is less likely to occur in a metal oxide having the CAAC. Thus, a metal oxide having the CAAC structure is physically stable. Therefore, a metal oxide having the CAAC structure is resistant to heat and has high reliability. Thus, a metal oxide having the CAAC structure is one of crystalline oxides having a crystal structure suitable for a semiconductor layer of a transistor.

As described above, the metal oxide that does not contain aluminum as its main component is formed using a precursor having a small aluminum content, whereby an increase in the concentration of aluminum in the formed metal oxide film can be inhibited. When such a metal oxide is used for a semiconductor layer of a transistor, a transistor having a high on-state current can be manufactured. Furthermore, performing impurity removal treatment such as microwave treatment can increase the crystallinity of the metal oxide and improve the reliability of the transistor.

This embodiment can be combined with the other embodiments as appropriate. In this specification, in the case where a plurality of structure examples are shown in one embodiment, the structure examples can be combined as appropriate.

### Embodiment 2

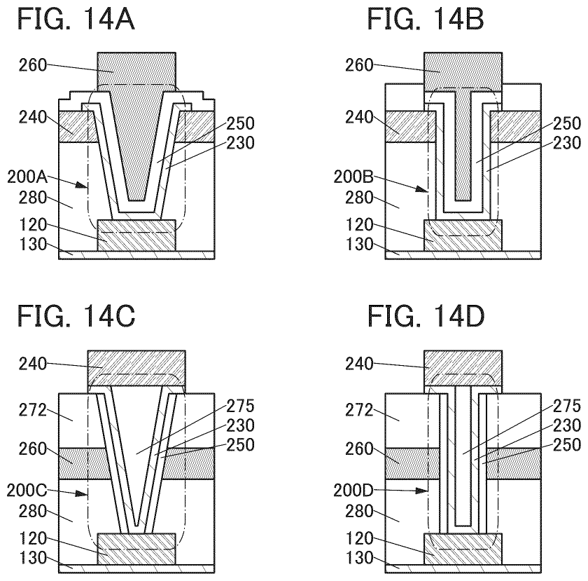

In this embodiment, a transistor, a semiconductor device, and a memory device of one embodiment of the present invention will be described with reference to FIG. 14 to FIG. 32. The semiconductor device of one embodiment of the present invention includes a transistor. The memory device of one embodiment of the present invention includes a memory cell. The memory cell includes a transistor and a capacitor.

### Structure Example 1 of Semiconductor Device

FIG. 14A to FIG. 14D illustrate an example of the semiconductor device of one embodiment of the present invention.

A transistor 200A illustrated in FIG. 14A includes a conductor 120, an oxide semiconductor 230, an insulator 250, a conductor 240, and a conductor 260. The conductor 120, the oxide semiconductor 230, the insulator 250, the conductor 240, and the conductor 260 may each have a single-layer structure or a stacked-layer structure of two or more layers.

The conductor 120 is provided over an insulator 130. The conductor 120 functions as one of a source and a drain.

An insulator 280 is provided over the conductor 120, and the conductor 240 is provided over the insulator 280. An opening reaching the conductor 120 is provided in the insulator 280 and the conductor 240. The conductor 240 functions as the other of the source and the drain.

The oxide semiconductor 230 is provided along the opening provided in the insulator 280 and the conductor 240 and is in contact with the top surface of the conductor 120 inside the opening. The oxide semiconductor 230 is also in contact with the side surface of the insulator 280 inside the opening. Furthermore, the oxide semiconductor 230 includes a portion in contact with the conductor 240. The oxide semiconductor 230 includes a region functioning as a channel formation region.

The oxide semiconductor 230 is in contact with at least one of the top surface, the side surface, and the bottom surface (also referred to as the bottom surface) of the conductor 240. The transistor 200A has what is called a bottom contact structure in which, over the insulator 280, the bottom surface of the oxide semiconductor 230 is in contact with the top surface of the conductor 240. The conductor 240 may be provided over the oxide semiconductor 230 to have what is called a top-contact structure in which the top surface of the oxide semiconductor 230 is in contact with the bottom surface of the conductor 240.

The insulator 250 is provided over the oxide semiconductor 230. The conductor 260 is positioned over the insulator 250 and overlaps with the oxide semiconductor 230 with the insulator 250 therebetween. The conductor 260 functions as a gate.

The transistor 200A has a structure in which the channel formation region surrounds the gate. Thus, the transistor 200A can be referred to as a transistor having a CAA (Channel-All-Around) structure.

In the transistor 200A illustrated in FIG. 14A, the surfaces of the insulator 280 and the conductor 240 in the opening are inclined to the top surface of the conductor 120. That is, it can be said that the sidewall of the opening portion has a tapered shape.

The sidewall of the opening portion preferably has a tapered shape, in which case coverage with the oxide semiconductor 230, the insulator 250, and the like provided along the opening portion is improved. In addition, with the use of the film formation method of the metal oxide of one embodiment of the present invention, the oxide semiconductor 230 can be formed with good coverage.

Meanwhile, in a transistor 200B illustrated in FIG. 14B, the surfaces of the insulator 280 and the conductor 240 in the opening are perpendicular to the top surface of the conductor 120. The transistor 200B has a structure similar to that of the transistor 200A, except for this point.

When the sidewall of the opening portion is perpendicular to the top surface of the conductor 120, the channel length of the transistor can be shorter than that in the case where the transistor has a tapered shape. In addition, with the use of the film formation method of the metal oxide of one embodiment of the present invention, the oxide semiconductor 230 can be formed with good coverage even when the sidewall of the opening portion is perpendicular to the top surface of the conductor 120.

A transistor 200C illustrated in FIG. 14C includes the conductor 120, the oxide semiconductor 230, the insulator 250, the conductor 240, and the conductor 260.

The conductor 120 is provided over the insulator 130. The conductor 120 functions as one of a source and a drain.

The insulator 280 is provided over the conductor 120, the conductor 260 is provided over the insulator 280, and an insulator 272 is provided over the conductor 260. An opening reaching the conductor 120 is provided in the insulator 280, the conductor 260, and the insulator 272. The conductor 260 functions as a gate.

The insulator 250 is provided along the opening provided in the insulator 280, the conductor 260, and the insulator 272 and has the opening reaching the conductor 120. Similarly, the oxide semiconductor 230 is provided along the opening provided in the insulator 280, the conductor 260, and the insulator 272. The oxide semiconductor 230 overlaps with the conductor 260 with the insulator 250 therebetween. The oxide semiconductor 230 is in contact with the top surface of the conductor 120 through the opening provided in the insulator 250.

An insulator 275 is provided to fill the depressed portion that is defined by the oxide semiconductor 230. In the case where the oxide semiconductor 230 does not include a depressed portion, the insulator 275 is not necessarily provided.

The conductor 240 is provided over the oxide semiconductor 230. The conductor 240 functions as the other of the source and the drain.

The transistor 200C has a structure in which the channel formation region is surrounded by the gate. Thus, the transistor 200C can be referred to as a transistor having a GAA (Gate-All-Around) structure.

In the transistor 200C illustrated in FIG. 14C, the surfaces of the insulator 280, the conductor 260, and the insulator 272 in the opening are inclined to the top surface of the conductor 120. That is, it can be said that the sidewall of the opening portion has a tapered shape.

The sidewall of the opening portion preferably has a tapered shape, in which case coverage with the insulator 250, the oxide semiconductor 230, and the like provided along the opening portion is improved. In addition, with the use of the film formation method of the metal oxide of one embodiment of the present invention, the oxide semiconductor 230 can be formed with good coverage.

Meanwhile, in a transistor 200D illustrated in FIG. 14D, the surfaces of the insulator 280, the conductor 260, and the insulator 272 in the opening are perpendicular to the top surface of the conductor 120. The transistor 200D has a structure similar to that of the transistor 200C, except for this point.

When the sidewall of the opening portion is perpendicular to the top surface of the conductor 120, the channel length of the transistor can be shorter than that in the case where the transistor bas a tapered shape. In addition, with the use of the film formation method of the metal oxide of one embodiment of the present invention, the oxide semiconductor 230 can be formed with good coverage even when the sidewall of the opening portion is perpendicular to the top surface of the conductor 120.

In each of the transistors illustrated in FIG. 14A to FIG. 14D, the oxide semiconductor 230 includes a first portion in contact with the top surface of the conductor 120, a second portion in contact with the side surface of the insulator 280, and a third portion in contact with the conductor 240.

The first portion and the second portion are positioned inside the opening provided in the insulator 280.

The oxide semiconductor 230 can be in contact with any one or more of the top surface, the side surface, and the bottom surface (also referred to as the bottom surface) of the conductor 240. FIG. 14A and FIG. 14B each illustrate an example in which the oxide semiconductor 230 is in contact with the top surface and the side surface of the conductor 240. FIG. 14C and FIG. 14D each illustrate an example in which the oxide semiconductor 230 is in contact with the bottom surface of the conductor 240.

Here, as a method for forming the oxide semiconductor 230, the film formation method of the metal oxide of one embodiment of the present invention described in Embodiment 1 is suitable.

When the oxide semiconductor 230 is formed by an ALD method, a metal oxide with good coverage can be formed on a top surface, a bottom surface, a side surface, and a surface with a slope of a structure body. In other words, a metal oxide that has a substantially uniform thickness in the normal direction can be formed on each deposition surface. As for the metal oxide that is formed on each of the top surface, the bottom surface, the side surface, and the surface with the slope of the structure body, the ratio of the minimum thickness to the maximum thickness can be greater than or equal to 0.5 and less than or equal to 1, preferably greater than or equal to 0.7 and less than or equal to 1, further preferably greater than or equal to 0.8 and less than or equal to 1, still further preferably greater than or equal to 0.9 and less than or equal to 1.

For example, the ratio of the thickness of the second portion in contact with the side surface of the insulator 280 to the thickness of the first portion in contact with the conductor 120 is preferably greater than or equal to 0.7 and less than or equal to 1.3, further preferably greater than or equal to 0.8 and less than or equal to 1.2, still further preferably greater than or equal to 0.9 and less than or equal to 1.1.

The aluminum concentration in the channel formation region of the oxide semiconductor 230 is preferably higher than or equal to 0.01 atomic % and preferably lower than or equal to 10 atomic %, further preferably lower than or equal to 5 atomic %, still further preferably lower than or equal to 3 atomic %, yet still further preferably lower than or equal to 1 atomic %, yet still further preferably lower than or equal to 0.1 atomic %. Alternatively, the aluminum concentration may be lower than or equal to 0.01 atomic %. As described in detail in Embodiment 1, when the aluminum concentration in the oxide semiconductor is reduced, the transistor can have both favorable electrical characteristics and favorable reliability. Furthermore, when the aluminum concentration is extremely reduced, the on-state current of the transistor can be further increased.

The carbon concentration in the channel formation region of the oxide semiconductor 230 is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³. A reduction in the carbon concentration in the oxide semiconductor 230 can inhibit formation of defect states and improve the reliability of the transistor.

In the transistor illustrated in FIG. 14A to FIG. 14D, the source electrode and the drain electrode are positioned at different heights, so that a current flows downward or upward in the oxide semiconductor 230. In other words, the channel length direction includes a height (vertical) component, so that the transistor of one embodiment of the present invention can also be referred to as a vertical transistor, a vertical-channel transistor, a vertical channel-type transistor, or the like.

In the transistor of one embodiment of the present invention, the source electrode, the semiconductor layer, and the drain electrode can be provided to overlap with each other. Thus, the area occupied by the transistor can be significantly smaller than the area occupied by what is called a planar transistor in which a planar semiconductor layer is placed.

### Structure Example 1 of Memory Device

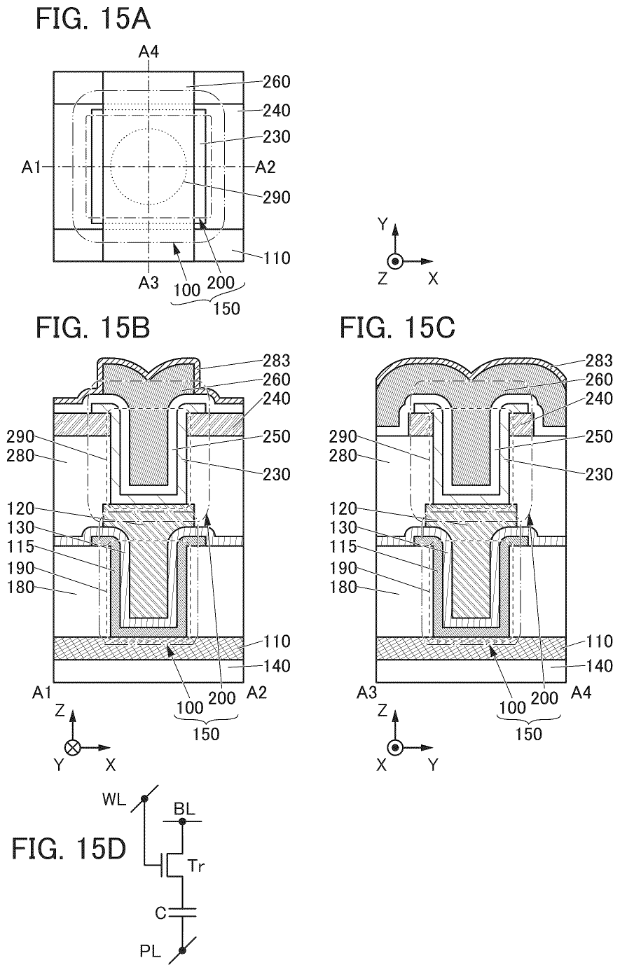

A structure of a memory device including a transistor and a capacitor is described with reference to FIG. 15. FIG. 15A to FIG. 15C are a plan view and cross-sectional views of the memory device including a transistor 200 and a capacitor 100. FIG. 15A is a plan view of the memory device. FIG. 15B and FIG. 15C are cross-sectional views of the memory device. Here, FIG. 15B is a cross-sectional view of a portion indicated by the dashed-dotted line A1-A2 in FIG. 15A. FIG. 15C is a cross-sectional view of a portion indicated by the dashed-dotted line A3-A4 in FIG. 15A. Note that for clarity of the drawing, some components are omitted in the plan view of FIG. 15A.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The memory device illustrated in FIG. 15A to FIG. 15C includes an insulator 140 over a substrate (not illustrated), a conductor 110 over the insulator 140, a memory cell 150 over the conductor 110, an insulator 180 over the conductor 110, the insulator 280, an insulator 283 over the memory cell 150. The insulator 140, the insulator 180, the insulator 280, and the insulator 283 each function as an interlayer film. The conductor 110 functions as a wiring.

The memory cell 150 includes the capacitor 100 over the conductor 110 and the transistor 200 over the capacitor 100.

The capacitor 100 includes a conductor 115 over the conductor 110, the insulator 130 over the conductor 115, and the conductor 120 over the insulator 130. The conductor 120 functions as one of a pair of electrodes (sometimes referred to as an upper electrode), the conductor 115 functions as the other of the pair of electrodes (sometimes referred to as a lower electrode), and the insulator 130 functions as a dielectric. That is, the capacitor 100 forms a MIM (Metal-Insulator-Metal) capacitor.

As illustrated in FIG. 15B and FIG. 15C, the opening portion 190 reaching the conductor 110 is provided in the insulator 180. At least part of the conductor 115 is placed in the opening portion 190. Note that the conductor 115 includes a region in contact with the top surface of the conductor 110 in the opening portion 190, a region in contact with the side surface of the insulator 180 in the opening portion 190, and a region in contact with at least part of the top surface of the insulator 180. The insulator 130 is placed so that at least part of the insulator 130 is positioned in the opening portion 190. The conductor 120 is placed so that at least part of the conductor 120 is positioned in the opening portion 190. Note that the conductor 120 is preferably provided to fill the opening portion 190 as illustrated in FIG. 15B and FIG. 15C. Note that the films provided in the opening portion 190 are preferably formed by an ALD method. Thus, the coverage with the films can be favorable. For example, the conductor 115, the insulator 130, and the conductor 120 are preferably formed by an ALD method.

The upper electrode and the lower electrode of the capacitor 100 face each other with the dielectric therebetween, along the side surface of the opening portion 190 as well as the bottom surface thereof; thus, the capacitance per unit area can be larger. Thus, the deeper the opening portion 190 is, the larger the capacitance of the capacitor 100 can be. Increasing the capacitance per unit area of the capacitor 100 in this manner can stabilize the reading operation of the memory device. This also allows further miniaturization or high integration of the memory device. FIG. 15B and FIG. 15C illustrate an example in which the sidewall of the opening portion 190 is perpendicular to the top surface of the conductor 110. In that case, the opening portion 190 has a cylindrical shape. Such a structure enables the memory device to be miniaturized or highly integrated.

The conductor 115 and the insulator 130 are stacked along the sidewall of the opening portion 190 and the top surface of the conductor 110. The conductor 120 is provided over the insulator 130 to fill the opening portion 190. The capacitor 100 having such a structure may be referred to as a trench-type capacitor or a trench capacitor.

The insulator 280 is placed over the capacitor 100. That is, the insulator 280 is placed over the conductor 115, the insulator 130, and the conductor 120. In other words, the conductor 120 is placed under the insulator 280.

The transistor 200 includes the conductor 120, the conductor 240 over the insulator 280, the oxide semiconductor 230, the insulator 250 over the oxide semiconductor 230, and the conductor 260 over the insulator 250. The oxide semiconductor 230 functions as a semiconductor layer, the conductor 260 functions as a gate electrode, the insulator 250 functions as a gate insulator, the conductor 120 functions as one of a source electrode and a drain electrode, and the conductor 240 functions as the other of the source electrode and the drain electrode. Note that the transistors 200A to 200D illustrated in FIG. 14A to FIG. 14D, respectively, may be used instead of the transistor 20.

As illustrated in FIG. 15B and FIG. 15C, an opening portion 290 reaching the conductor 120 is formed in the insulator 280 and the conductor 240. At least part of the oxide semiconductor 230 is placed in the opening portion 290. The oxide semiconductor 230 includes a region in contact with the top surface of the conductor 120 in the opening portion 290, a region in contact with the side surface of the conductor 240 in the opening portion 290, and a region in contact with at least part of the top surface of the conductor 240. The insulator 250 is placed in such a manner that at least part of the insulator 250 is positioned in the opening portion 290. The conductor 260 is placed in such a manner that at least part of the conductor 260 is positioned in the opening portion 290. In addition, the conductor 260 is preferably provided to fill the opening portion 290 as illustrated in FIG. 15B and FIG. 15C. Note that the films provided in the opening portion 290 are preferably formed by an ALD method. Thus, the coverage with the films can be favorable. For example, the oxide semiconductor 230, the insulator 250, and the conductor 260 are each preferably formed by an ALD method. With the use of the film formation method of the metal oxide of one embodiment of the present invention, the oxide semiconductor 230 can be formed with good coverage.

The oxide semiconductor 230 includes the region in contact with the side surface of the conductor 240 in the opening portion 290 and the region in contact with part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased.

As illustrated in FIG. 15A to FIG. 15C, the transistor 200 is provided to overlap with the capacitor 100. The opening portion 290 where part of the components of the transistor 200 is provided includes a region overlapping with the opening portion 190 where part of the components of the capacitor 100 is provided. In particular, since the conductor 120 has a function of one of the source electrode and the drain electrode of the transistor 200 and a function of the upper electrode of the capacitor 100, the transistor 200 and the capacitor 100 partly share the structure. With such a structure, the transistor 200 and the capacitor 100 can be provided without a great increase in the occupation area in the plan view. Thus, the area of the memory cell 150 can be reduced, so that the memory cells 150 can be arranged densely and the memory capacity of the memory device can be increased. In other words, the memory device can be highly integrated.

FIG. 15D is a circuit diagram of the memory device described in this embodiment. As illustrated in FIG. 15D, the structure illustrated in FIG. 15A to FIG. 15C functions as a memory cell of a memory device. The memory cell includes a transistor Tr and a capacitor C. In this case, the transistor Tr and the capacitor C correspond to the transistor 200 and the capacitor 100, respectively.

One of a source and a drain of the transistor Tr is connected to one of a pair of electrodes of the capacitor C. The other of the source and the drain of the transistor Tr is connected to a wiring BL. A gate of the transistor Tr is connected to a wiring WL. The other of the pair of electrodes of the capacitor C is connected to a wiring PL.

Here, the wiring BL corresponds to the conductor 240, the wiring WL corresponds to the conductor 260, and the wiring PL corresponds to the conductor 110. As illustrated in FIG. 15A to FIG. 15C, it is preferable that the conductor 260 be provided to extend in the Y direction and the conductor 240 be provided to extend in the X direction. In this structure, the wiring BL and the wiring WL are provided to intersect with each other. Although the wiring PL (conductor 110) is provided in a planar shape in FIG. 15A, the present invention is not limited thereto. For example, the wiring PL may be provided in parallel to the wiring WL (conductor 260) or the wiring BL (conductor 240).

The memory cell will be described in detail in a later embodiment.

### [Capacitor 100]

The capacitor 100 includes the conductor 115, the insulator 130, and the conductor 120. The conductor 110 is provided below the conductor 115. The conductor 115 includes a region in contact with the conductor 110.

The conductor 110 is provided over the insulator 140. The conductor 110 functions as the wiring PL and can be provided in a planar shape. As the conductor 110, a single layer or stacked layers of any of the conductors described in the section [Conductor] below can be used. For example, a conductive material with high conductivity such as tungsten can be used for the conductor 110. With the use of a conductive material with high conductivity, the conductivity of the conductor 110 can be improved and the wiring PL can function sufficiently.

A single layer or stacked-layer including a conductive material that is less likely to be oxidized, a conductive material having a function of inhibiting diffusion of oxygen, or the like is preferably used for the conductor 115. For example, titanium nitride, indium tin oxide to which silicon is added, or the like may be used. Alternatively, for example, a structure in which titanium nitride is stacked over tungsten may be used. Alternatively, for example, a structure in which tungsten is stacked over a first titanium nitride and a second titanium nitride is stacked over the tungsten may be used. With such a structure, when an oxide insulator is used for the insulator 130, oxidation of the conductor 110 due to the insulator 130 can be inhibited. In the case of using an oxide insulator for the insulator 180, oxidation of the conductor 110 due to the insulator 180 can be inhibited.

The insulator 130 is provided over the conductor 115. The insulator 130 can be provided to be in contact with the top surface and the side surface of the conductor 115. That is, the insulator 130 preferably covers a side end portion of the conductor 110. This can prevent a short circuit between the conductor 115 and the conductor 120.

In addition, a structure may be employed in which a side end portion of the insulator 130 and a side end portion of the conductor 115 are substantially aligned with each other. This structure enables the insulator 130 and the conductor 115 to be formed using the same mask, so that the manufacturing process of the memory device can be simplified.

For the insulator 130, any of materials with high relative permittivity, that is, high-k materials, described in a later-described section [Insulator] is preferably used. Using such a high-k material for the insulator 130 allows the insulator 130 to be thick enough to inhibit a leakage current and the capacitor 100 to have a sufficiently high capacitance.

It is preferable to use, as the insulator 130, stacked insulators formed of any of the high-k materials; it is preferable to use a stacked-layer structure of a high relative permittivity (high-k) material and a material having a higher dielectric strength than the high-k material. As the insulator 130, an insulating film in which zirconium oxide, aluminum oxide, and zirconium oxide are stacked in this order can be used, for example. An insulating film in which zirconium oxide, aluminum oxide, zirconium oxide, and aluminum oxide are stacked in this order can be used, for example. As another example, an insulating film in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength and inhibit electrostatic breakdown of the capacitor 100.

A material that can have ferroelectricity may be used for the insulator 130. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a k-alumina-type structure, and the like.

In the above description, metal oxides and metal nitrides are presented as non-limiting examples. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 130 can have a stacked-layer structure of a plurality of materials selected from the above-listed materials. Note that the crystal structures (properties) of the above-listed materials and the like can be changed depending on the processes as well as the deposition conditions; thus, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being processed into a thin film of several nanometers. Here, the thickness of the insulator 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The film thickness is preferably greater than or equal to 8 nm and less than or equal to 12 nm, for example. When a ferroelectric layer that can be thinned is used, the capacitor 100 can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupation area) in the plan view less than or equal to 100 μm², less than or equal to 10 μm², less than or equal to 1 μm², or less than or equal to 0.1 μm². Furthermore, even a ferroelectric layer with an area of less than or equal to 10000 nm² or less than or equal to 1000 nm² can have ferroelectricity in some cases. With a small-area ferroelectric layer, the occupation area of the capacitor 100 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 130 can exhibit ferroelectricity, the insulator 130 needs to include a crystal. It is particularly preferable for the insulator 130 to include a crystal having an orthorhombic crystal structure to exhibit ferroelectricity. Note that a crystal included in the insulator 130 may have one or more selected from cubic, tetragonal, orthorhombic, monoclinic, hexagonal crystal structures. Alternatively, the insulator 130 may include an amorphous structure. In that case, the insulator 130 may have a composite structure including an amorphous structure and a crystal structure.

The conductor 120 is provided in contact with part of the top surface of the insulator 130 A side end portion of the conductor 120 is preferably positioned inward from the side end portion of the conductor 115 in both the X direction and the Y direction. In addition, in the structure where the insulator 130 covers the side end portion of the conductor 115, the side end portion of the conductor 120 may be positioned outward from the side end portion of the conductor 115.

As the conductor 120, a single layer or stacked layers of any of the conductors described in the later-described section [Conductor] can be used. In addition, a conductive material that is less likely to be oxidized, a conductive material having a function of inhibiting diffusion of oxygen, or the like is preferably used for the conductor 120. For example, titanium nitride, tantalum nitride, or the like can be used. For example, a structure in which tantalum nitride is stacked over titanium nitride may be used. In that case, titanium nitride is in contact with the insulator 130 and tantalum nitride is in contact with the oxide semiconductor 230. This structure can inhibit excessive oxidation of the conductor 120 due to the oxide semiconductor 230. In the case of using an oxide insulator for the insulator 130, excessive oxidation of the conductor 120 due to the insulator 130 can be inhibited. Alternatively, a structure in which tungsten is stacked over titanium nitride may be used as the conductor 120, for example.

The conductor 120 includes a region in contact with the oxide semiconductor 230 and thus is preferably formed using a conductive material containing oxygen described in the later-described section [Conductor]. When a conductive material containing oxygen is used for the conductor 120, the conductor 120 can maintain its conductivity even when absorbing oxygen. In addition, also in the case of using an insulator containing oxygen, e.g., zirconium oxide, as the insulator 130, the conductor 120 can maintain its conductivity, which is preferable. As the conductor 120, a single layer or stacked layers of indium tin oxide (also referred to as ITO), indium tin oxide to which silicon is added (also referred to as ITSO), indium zinc oxide (IZO (registered trademark)), or the like can be used, for example.

The insulator 180, which functions as an interlayer film, preferably has a low relative permittivity. When a material with a low relative permittivity is used for the interlayer film, parasitic capacitance generated between wirings can be reduced. As the insulator 180, a single layer or stacked layers of any of the insulators including a material with a low relative permittivity described in the section [Insulator] later can be used. Silicon oxide and silicon oxynitride are preferable because they are thermally stable. In this case, an insulator 180b contains at least silicon and oxygen.

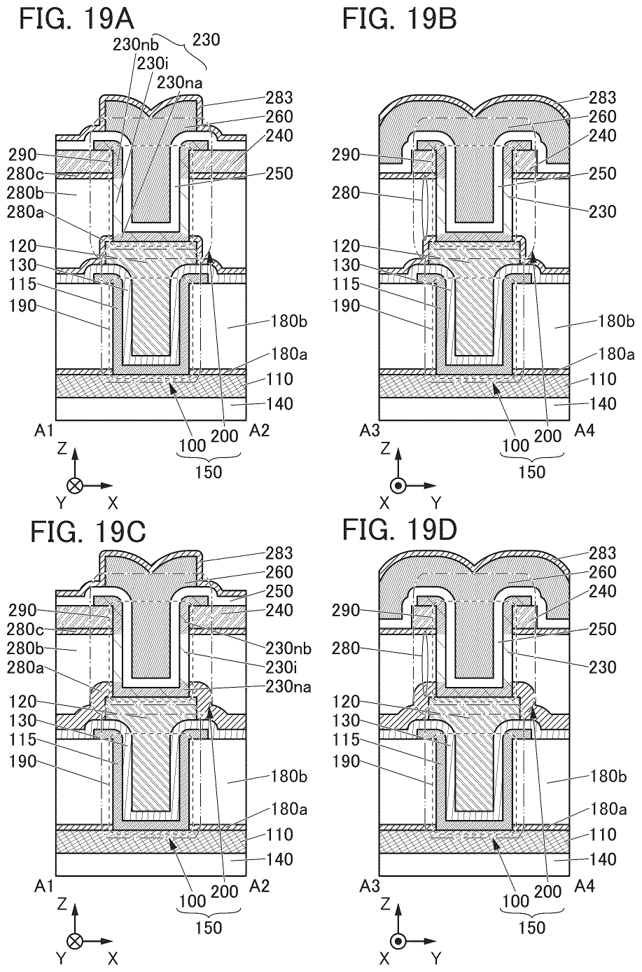

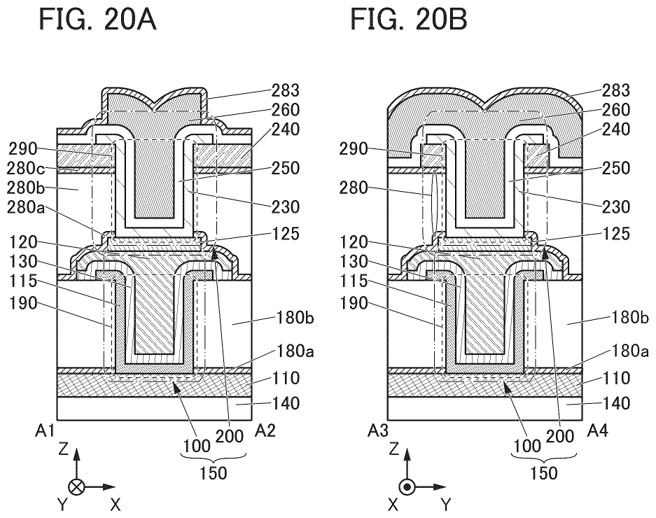

Although FIG. 15B and FIG. 15C show that the insulator 180 is a single layer, the present invention is not limited thereto. The insulator 180 may have a stacked-layer structure of two layers or a stacked-layer structure of three or more layers. For example, as illustrated in FIG. 19A and FIG. 19D and FIG. 20A and FIG. 20B, the insulator 180 may have a stacked-layer structure of an insulator 180a and the insulator 180b over the insulator 180a.

The insulator 180b is preferably formed using an insulating material usable for the insulator 180 described above.

For the insulator 180a, any of the insulators having a barrier property against oxygen described in the later-described section [Insulator] is preferably used. The conductor 110 is oxidized by oxygen contained in the insulator 180b and has high resistance in some cases. Providing the insulator 180a between the insulator 180b and the conductor 110 can inhibit the conductor 110 from being oxidized and having high resistance.

Entry of impurities such as hydrogen into the insulator 130 may increase the leakage current generated between the upper electrode and the lower electrode. In the case where a material that can have ferroelectricity is used for the insulator 130, entry of impurities such as hydrogen into the material capable of having ferroelectricity might reduce the crystallinity of the material capable of having ferroelectricity. Thus, impurities such as hydrogen are preferably inhibited from entering the insulator 130.

In view of the above, any of the insulators having a barrier property against hydrogen described in [Insulator] later is preferably used as the insulator 180a. Thus, diffusion of hydrogen into the insulator 130 through the insulator 180b and the conductor 115 can be inhibited. Silicon nitride and silicon nitride oxide can be suitably used for the insulator 180a because they each release fewer impurities (e.g., water and hydrogen) and are less likely to transmit oxygen and hydrogen. In this case, the insulator 180a contains at least silicon and nitrogen.

For the insulator 180a, any of the insulators having a function of capturing or fixing hydrogen described in the later-described section [Insulator] below is preferably used. With this structure, hydrogen in the insulator 130 can be captured or fixed, whereby the hydrogen concentration in the insulator 130 can be reduced. For the insulator 180a, magnesium oxide, aluminum oxide, hafnium oxide, or the like can be used. Alternatively, for example, a stacked-layer film of aluminum oxide and silicon nitride over the aluminum oxide may be used as the insulator 180a.

In the case where the insulator 180 has a three-layer stacked structure, in addition to the insulator 180a and the insulator 180b, an insulator is preferably provided between the insulator 180b and the conductor 115 and between the insulator 180b and the insulator 130, for example. As the insulator, an insulator that can be used as the insulator 180a can be used. This can inhibit diffusion of hydrogen into the insulator 130 through the insulator 180b.

### [Transistor 200]

As illustrated in FIG. 15A to FIG. 15C, the transistor 200 can have a structure including the conductor 120; the conductor 240 over the insulator 280; the oxide semiconductor 230 provided in contact with the top surface of the conductor 120, which is exposed in the opening portion 290, the side surface of the insulator 280 in the opening portion 290, the side surface of the conductor 240 in the opening portion 290, and at least part of the top surface of the conductor 240; the insulator 250 provided in contact with the top surface of the oxide semiconductor 230; and the conductor 260 provided in contact with the top surface of the insulator 250.

At least part of the components of the transistor 200 is placed in the opening portion 290. Here, the bottom portion of the opening portion 290 is the top surface of the conductor 120, and the sidewall of the opening portion 290 is the side surface of the insulator 280 and the side surface of the conductor 240.

FIG. 15B and FIG. 15C illustrate an example in which the sidewall of the opening portion 290 is perpendicular to the top surface of the conductor 110. In that case, the opening portion 290 has a cylindrical shape. Such a structure enables the memory device to be miniaturized or highly integrated.

Although this embodiment describes the example where the opening portion 290 has a circular shape in the plan view, the present invention is not limited thereto. For example, the opening portion 290 in the plan view may have an almost circular shape such as an elliptical shape, a polygonal shape such as a quadrangular shape, or a polygonal shape such as a quadrangular shape with rounded corners. In that case, the maximum width of the opening portion 290 is preferably calculated as appropriate in accordance with the shape of the uppermost portion of the opening portion 290. For example, in the case where the opening portion 290 is a square in the plan view, the maximum width of the opening portion 290 is preferably the length of a diagonal line of the uppermost portion of the opening portion 290.

Portions of the oxide semiconductor 230, the insulator 250, and the conductor 260 that are placed in the opening portion 290 reflect the shape of the opening portion 290. Therefore, the oxide semiconductor 230 is provided so as to cover the bottom portion and the sidewall of the opening portion 290, the insulator 250 is provided so as to cover the oxide semiconductor 230, and the conductor 260 is provided so as to fill a depressed portion, which reflects the shape of the opening portion 290, of the insulator 250.

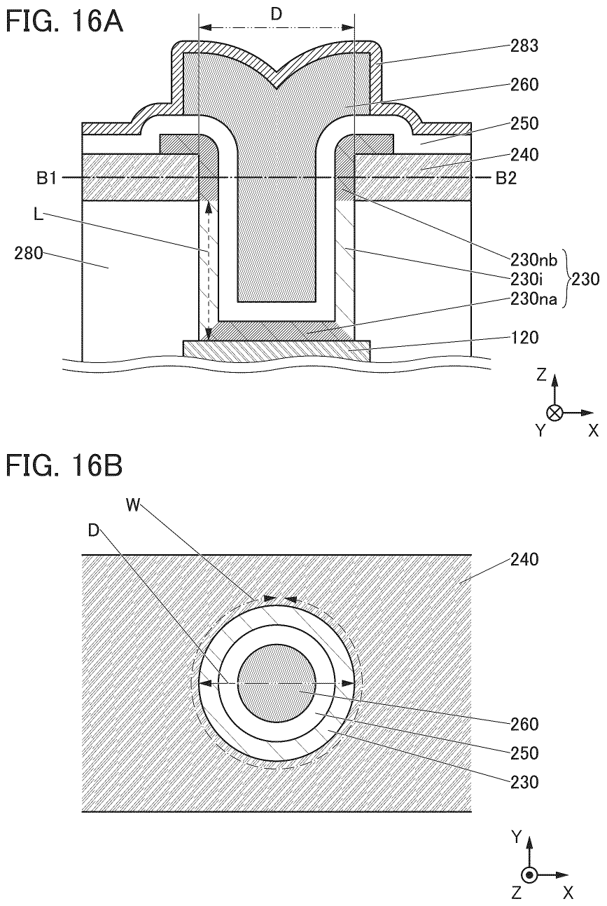

FIG. 16A is an enlarged view of the oxide semiconductor 230 and its vicinity in FIG. 15B. FIG. 16B is a cross-sectional view (also referred to as a cross-sectional view along the dashed-dotted line B1-B2) taken along the XY plane including the conductor 240.

As illustrated in FIG. 16A, the oxide semiconductor 230 includes a region 230i, and a region 230na and a region 230nb provided such that the region 230i is sandwiched therebetween.

The region 230na is a region in contact with the conductor 120 in the oxide semiconductor 230. At least part of the region 230na functions as one of the source region and the drain region of the transistor 200. The region 230nb is a region in contact with the conductor 240 in the oxide semiconductor 230. At least part of the region 230nb functions as the other of the source region and the drain region of the transistor 200. As illustrated in FIG. 16B, the conductor 240 is in contact with all the outer circumference of the oxide semiconductor 230. Thus, the other of the source region and the drain region of the transistor 200 can be formed in all the outer circumference of a portion of the oxide semiconductor 230 that is formed in the same layer as the conductor 240.

The region 230i is a region of the oxide semiconductor 230 between the region 230na and the region 230nb. At least part of the region 230i functions as a channel formation region of the transistor 200. In other words, the channel formation region of the transistor 200 is positioned in a region of the oxide semiconductor 230 between the conductor 120 and the conductor 240. It can be said that the channel formation region of the transistor 200 is positioned in a region in contact with the insulator 280 or a region in the vicinity thereof in the oxide semiconductor 230.

The channel length of the transistor 200 is a distance between the source region and the drain region. In other words, the channel length of the transistor 200 is determined by the thickness of the insulator 280 over the conductor 120. In FIG. 16A, the channel length L of the transistor 200 is indicated by a dashed double-headed arrow. In the cross-sectional view, the channel length L is a distance between an end portion of the region where the oxide semiconductor 230 is in contact with the conductor 120 and an end portion of the region where the oxide semiconductor 230 is in contact with the conductor 240. That is, the channel length L corresponds to the length of the side surface of the insulator 280 on the opening portion 290 side in the cross-sectional view.

In a planar transistor, the channel length is determined by the light exposure limit of photolithography. However, in the present invention, the channel length can be determined by the thickness of the insulator 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200 can have higher on-state current and improved frequency characteristics. Accordingly, the read speed and the write speed of the memory cell 150 can be increased; accordingly, a memory device with a high operation speed can be provided.

In addition, as described above, the channel formation region, the source region, and the drain region can be formed in the opening portion 290. Thus, the occupation area of the transistor 200 can be reduced as compared with a conventional transistor in which a channel formation region, a source region, and a drain region are provided separately on the XY plane. This allows high integration of the memory device; therefore, the memory capacity per unit area can be increased.

Furthermore, in the XY plane including the channel formation region of the oxide semiconductor 230, as in FIG. 16B, the oxide semiconductor 230, the insulator 250, and the conductor 260 are provided concentrically. Therefore, the side surface of the conductor 260 provided at the center faces the side surface of the oxide semiconductor 230 with the insulator 250 therebetween. That is, in the plan view, all the circumference of the oxide semiconductor 230 serves as the channel formation region. In this case, for example, the channel width of the transistor 200 is determined by the length of the outer circumference of the oxide semiconductor 230. In other words, the channel width of the transistor 200 is determined by the maximum width of the opening portion 290 (the maximum diameter in the case where the opening portion 290 is circular in the plan view). In FIG. 16A and FIG. 16B, a maximum width D of the opening portion 290 is indicated by a dashed double-dotted double-headed arrow. In FIG. 16B, the channel width W of the transistor 200 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the film thicknesses of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be “D×π.”.

In the memory device of one embodiment of the present invention, the channel length L of the transistor 200 is preferably shorter than at least the channel width W of the transistor 200. The channel length L of the transistor 200 in one embodiment of the present invention is greater than or equal to 0.1 times and less than or equal to 0.99 times, preferably greater than or equal to 0.5 times and less than or equal to 0.8 times the channel width W of the transistor 200. This structure enables a transistor with favorable electrical characteristics and high reliability.

In the case where the opening portion 290 is formed to be circular in a plan view, the oxide semiconductor 230, the insulator 250, and the conductor 260 are formed concentrically. This makes the distance between the conductor 260 and the oxide semiconductor 230 substantially uniform, so that a gate electric field can be substantially uniformly applied to the oxide semiconductor 230.

It is preferable that the channel formation region of the transistor including oxide semiconductor as a semiconductor layer contain fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as V_{O}H), which generates an electron serving as a carrier. Therefore, it is preferable that V_{O}H be also decreased in the channel formation region. Thus, the channel formation region of the transistor is a high-resistance region having a low carrier concentration. Thus, the channel formation region of the transistor can be regarded as being i-type (intrinsic) or substantially i-type.

Meanwhile, the source region and the drain region of the transistor in which an oxide semiconductor is used for the semiconductor layer include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the transistor is n-type regions that have a higher carrier concentration and a lower resistance than the channel formation region.

Although the opening portion 290 is provided such that the sidewall of the opening portion 290 is perpendicular to the top surface of the conductor 110 in FIG. 15B and FIG. 15C, the present invention is not limited thereto. The sidewall of the opening portion 290 may have a tapered shape, for example. The sidewall of the opening portion 290 preferably has a tapered shape, in which case coverage with the oxide semiconductor 230, the insulator 250, and the like provided along the opening portion 290 is improved.

In a similar manner, the opening portion 190 is provided such that the sidewall of the opening portion 190 is perpendicular to the top surface of the conductor 110 in FIG. 15B and FIG. 15C; however, the present invention is not limited thereto. The sidewall of the opening portion 190 may have a tapered shape or an inverse tapered shape, for example. The sidewall of the opening portion 190 preferably has a tapered shape, in which case coverage with the conductor 115, the insulator 130, and the like provided along the opening portion 190 is improved.

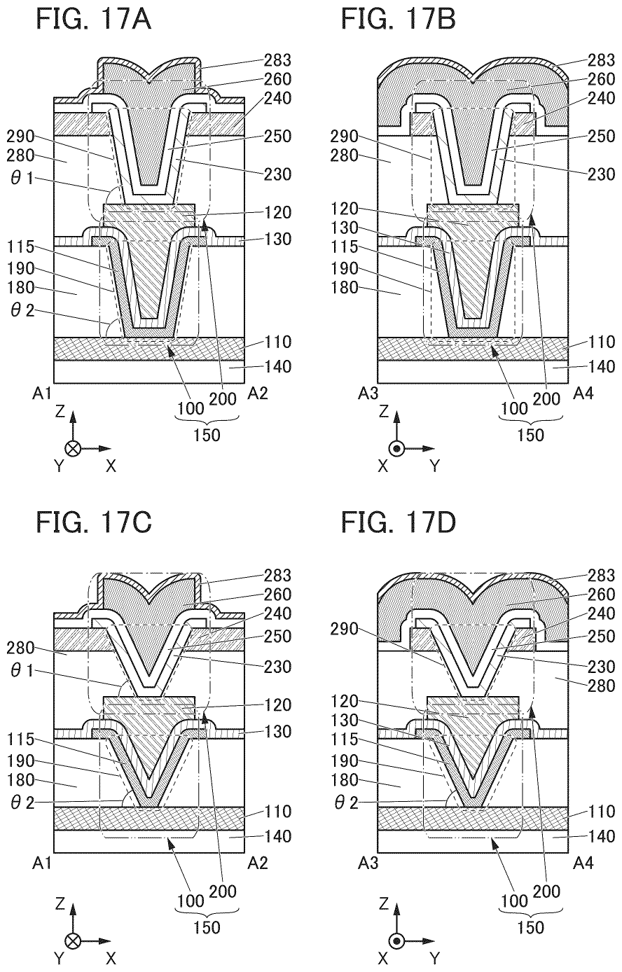

The memory device illustrated in FIG. 17A and FIG. 17B has a structure in which the sidewall of the opening portion 290 has a tapered shape. FIG. 15A can be referred to for the plan view of the memory device illustrated in FIG. 17A and FIG. 17B.

When the sidewall of the opening portion 290 has a tapered shape, the coverage with the oxide semiconductor 230, the insulator 250, and the like can be improved, so that defects such as voids can be reduced. For example, the angle formed by the side surface of the insulator 280 in the opening portion 290 and the top surface of the conductor 110 (the angle θ1 illustrated in FIG. 17A) is preferably greater than or equal to 45° and less than 90°. Alternatively, the angle is preferably greater than or equal to 45° and less than or equal to 75°. Alternatively, the angle is preferably greater than or equal to 45° and less than or equal to 65°.

The opening portion 290 illustrated in FIG. 17A and FIG. 17B has a conical trapezoidal shape. In this case, the opening portion 290 is circular in a plan view and trapezoidal in a cross-sectional view. The area of the upper base surface of the conical trapezoidal shape (e.g., the opening portion provided in the conductor 240) is smaller than the area of the lower base surface of the conical trapezoidal shape (the top surface of the conductor 120 exposed in the opening portion 290). In this case, the maximum diameter of the opening portion 290 is preferably calculated on the basis of the upper base surface having a conical trapezoidal shape.

In the case where the sidewall of the opening portion 290 has a tapered shape, the channel length can be set using the thickness of the insulator 280 and the angle θ1 formed by the side surface of the insulator 280 in the opening portion 290 and the top surface of the conductor 110. The length of the outer perimeter of the oxide semiconductor 230 is preferably obtained at a position in a region facing the conductor 240 or at a position corresponding to the half of the thickness of the insulator 280, for example. Note that the length of the perimeter of the opening portion 290 at an arbitrary position may be regarded as the channel width of the transistor 200, as necessary. For example, the length of the perimeter at the lowest portion of the opening portion 290 may be regarded as the channel width, or the length of the outer perimeter at the uppermost portion of the opening portion 290 may be regarded as the channel width.

Although FIG. 17A and FIG. 17B illustrate a structure in which the side surface of the conductor 240 in the opening portion 290 is aligned with the side surface of the insulator 280 in the opening portion 290, the present invention is not limited thereto. For example, the side surface of the conductor 240 in the opening portion 290 and the side surface of the insulator 280 in the opening portion 290 may be discontinuous. The inclination of the side surface of the conductor 240 in the opening portion 290 and the inclination of the side surface of the insulator 280 in the opening portion 290 may be different from each other. For example, the angle formed by the side surface of the conductor 240 in the opening portion 290 and the top surface of the conductor 110 is preferably smaller than the angle θ1. With such a structure, the coverage of the side surface of the conductor 240 with the oxide semiconductor 230 in the opening portion 290 is improved, so that defects such as voids can be reduced.

As illustrated in FIG. 17A and FIG. 17B, the bottom portion of the conductor 260 positioned in the opening portion 290 includes a flat region. Note that the bottom portion of the conductor 260 positioned in the opening portion 290 does not include a flat region in some cases depending on the maximum width of the opening portion 290 (the maximum diameter in the case where the opening portion 290 is circular in the plan view), the thickness of the insulator 280 (corresponding to the depth of the opening portion 290), the thickness of the oxide semiconductor 230, the thickness of the insulator 250, and the like. For example, as illustrated in FIG. 17C and FIG. 17D, the shape of the bottom portion of the conductor 260 positioned in the opening portion 290 may be acicular. FIG. 15A can be referred to for the plan view of the memory device illustrated in FIG. 17C and FIG. 17D.

Here, an acicular shape refers to a shape that becomes thinner toward the tip (as it becomes closer to the bottom portion of the conductor 260 positioned in the opening portion 290). Note that the acicular tip may have an acute angle or a curved downward-convex shape. Moreover, a shape in which the tip of an acicular shape is an acute angle may be referred to as a V shape.

A region of the conductor 260 that is positioned in the opening portion 290 and faces the oxide semiconductor 230 with the insulator 250 therebetween functions as a gate electrode. Thus, the conductor 260, which is embedded in the opening portion 290 and has an acicular bottom portion, may be referred to as an acicular gate. Moreover, even the conductor 260 whose bottom portion includes a flat region as illustrated in FIG. 17A and FIG. 17B, may be referred to as an acicular gate in some cases.

When the sidewall of the opening portion 190 has a tapered shape, the coverage with the conductor 115, the insulator 130, or the like can be improved, so that defects such as voids can be reduced. For example, the angle subtended between the side surface of the insulator 180 in the opening portion 190 and the top surface of the conductor 110 (the angle θ2 illustrated in FIG. 17A) is preferably greater than or equal to 45° and less than 90°. Alternatively, it is preferably greater than or equal to 45° and less than or equal to 75°. Alternatively, it is preferably greater than or equal to 45° and less than or equal to 65°.

As illustrated in FIG. 17A and FIG. 17B, the bottom portion of the conductor 120 positioned in the opening portion 190 includes a flat region. In some cases, the bottom portion of the conductor 120 positioned in the opening portion 190 does not include a flat region depending on the maximum width of the opening portion 190 (the maximum diameter in the case where the opening portion 190 is circular in the plan view), the thickness of the insulator 180 (corresponding to the depth of the opening portion 190), the thickness of the conductor 115, the thickness of the insulator 130, and the like. For example, as illustrated in FIG. 17C and FIG. 17D, the shape of the bottom portion of the conductor 120 positioned in the opening portion 190 is a needle-like shape in some cases. FIG. 15A can be referred to for a plan view of the memory device illustrated in FIG. 17C and FIG. 17D.

In the case where the same material is used for the insulator 180 and the insulator 280, the angle θ1 and the angle θ2 are the same or substantially the same. Note that the angle θ1 and the angle θ2 may be different from each other depending on materials used for the insulator 180 and the insulator 280, formation methods of the opening portion 190 and the opening portion 290, or the like. For example, the angle θ1 may be larger than or smaller than the angle θ2. One of the angle θ1 and the angle θ2 may be 90° or a value in the neighborhood thereof.

As illustrated in FIG. 15B and FIG. 15C, part of the oxide semiconductor 230 is positioned outside the opening portion 290, that is, over the conductor 240. FIG. 15B and FIG. 15C each illustrate a structure in which a side end portion of the oxide semiconductor 230 is positioned inward from a side end portion of the conductor 240. Note that the present invention is not limited thereto. For example, a structure may be employed in which the side end portion of the oxide semiconductor 230 and the side end portion of the conductor 240 may be substantially aligned with each other in the X direction or the Y direction. Alternatively, the side end portion of the oxide semiconductor 230 may be positioned outward from the side end portion of the conductor 240.

The metal oxide functioning as the oxide semiconductor 230 preferably has a band gap of 2 eV or higher, further preferably 2.5 eV or higher. With the use of a metal oxide having a wide band gap as the oxide semiconductor 230, the off-state current of the transistor can be reduced. Using the transistor having a low off-state current in the memory cell enables long-period retention of stored contents. In other words, such a memory device does not require refresh operation or has extremely low frequency of the refresh operation, which leads to a sufficient reduction in power consumption of the memory device. The frequency of refresh operation in a general DRAM is approximately once per 60 msec, whereas the frequency of refresh operation in the memory device of one embodiment of the present invention can be approximately once per 10 sec, which is greater than or equal to 10 times or greater than or equal to 100 times that of the general DRAM. In the memory device of one embodiment of the present invention, the frequency of refresh operation can be once per period of 1 sec to 100 sec, both inclusive, preferably once per period of 5 sec to 50 sec, both inclusive.

As the oxide semiconductor 230, a single layer or stacked layers including any of the metal oxides described in Embodiment 1 can be used.

As the oxide semiconductor 230, specifically, a metal oxide with a composition of In:M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be used. Note that a composition in the neighborhood includes the range of +30% of an intended atomic ratio. Gallium is preferably used as the element M.

The use of a material with a high content percentage of indium for the oxide semiconductor 230 enables an increase in the on-state current, field-effect mobility, or the like of the transistor. Furthermore, with the element M, generation of oxygen vacancies (V_{O}) can be inhibited. The content percentage of the element M (the proportion of the number of element M atoms in the total number of atoms of all the metal elements contained) is preferably greater than or equal to 0.1% and less than or equal to 10%, further preferably greater than or equal to 0.1% and less than or equal to 3%, still further preferably greater than or equal to 0.1% and less than or equal to 2%. Accordingly, the transistor can have favorable electrical characteristics. For example, a metal oxide having an atomic ratio of In:M:Zn=40:X:10 (X is greater than or equal to 1 and less than or equal to 5) and a composition in the neighborhood thereof is preferably used. The element M is preferably any one or more kinds of the above elements, further preferably one or more kinds selected from gallium, tin, and yttrium. Specifically, a metal oxide with In:Sn:Zn=40:1:10 or a composition in the neighborhood thereof can be suitably used.

When the metal oxide is deposited by a sputtering method, the above atomic ratio is not limited to the atomic ratio of the deposited metal oxide and may be the atomic ratio of a sputtering target used for depositing the metal oxide.

As an analysis method of the composition of a metal oxide used for the oxide semiconductor 230, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, some of the analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

An atomic layer deposition (ALD) method can be suitably used to form the metal oxide.

Alternatively, a sputtering method or a CVD method may be used to form the metal oxide. Note that in the case where the metal oxide is formed by a sputtering method, the composition of the formed metal oxide may be different from the composition of a sputtering target. In particular, the content percentage of the zinc in the formed metal oxide may be reduced to approximately 50% of that of the sputtering target.

The oxide semiconductor 230 preferably has crystallinity (also referred to as “includes a crystal part”). Examples of an oxide semiconductor having crystallinity (also referred to as a crystalline oxide semiconductor) include a CAAC-OS (a c-axis aligned crystalline oxide semiconductor), an nc-OS (a nanocrystalline oxide semiconductor), a polycrystalline oxide semiconductor, and a single-crystal oxide semiconductor. For the oxide semiconductor 230, a CAAC-OS or an nc-OS is preferably used, and a CAAC-OS is particularly preferably used.

CAAC-OS preferably includes a plurality of layered crystal regions and a c-axis is preferably aligned in a normal direction of a surface where the CAAC-OS is formed. For example, the oxide semiconductor 230 preferably includes a layered crystal that is substantially parallel to the sidewall of the opening portion 290, particularly the side surface of the insulator 280. With this structure, the layered crystals of the oxide semiconductor 230 are formed substantially in parallel with the channel length direction of the transistor 200, so that the on-state current of the transistor can be increased.

The CAAC-OS is a metal oxide having a dense structure with high crystallinity and a small number of impurities and defects (e.g., oxygen vacancies). In particular, after the formation of a metal oxide, heat treatment is performed at a temperature at which the metal oxide does not become a polycrystal (e.g., higher than or equal to 400 °C and lower than or equal to 600 °C), whereby a CAAC-OS having a dense structure with higher crystallinity can be obtained. When the density of the CAAC-OS is increased in such a manner, diffusion of impurities or oxygen in the CAAC-OS can be further reduced.

When an oxide having crystallinity, such as CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor 200 is stable with respect to high temperatures in a manufacturing process (what is called thermal budget).

The crystallinity of the oxide semiconductor 230 can be analyzed with X-ray diffraction (XRD), a transmission electron microscope (TEM), or electron diffraction (ED), for example. Alternatively, some of the analysis methods may be performed in combination.

The oxide semiconductor 230 may have a stacked-layer structure of a plurality of oxide layers with different chemical compositions. For example, a structure in which a plurality of kinds of metal oxides selected from the above-described metal oxides are stacked as appropriate may be used.

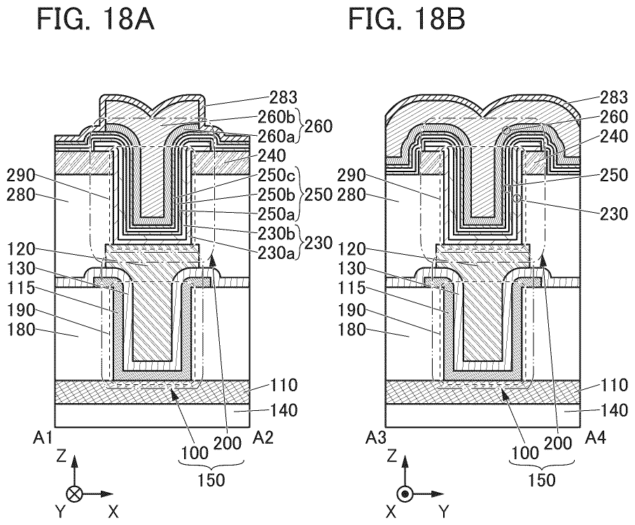

For example, the oxide semiconductor 230 may have a stacked-layer structure of an oxide semiconductor 230a and an oxide semiconductor 230b over the oxide semiconductor 230a, as illustrated in FIG. 18A and FIG. 18B. At least one of the oxide semiconductor 230a and the oxide semiconductor 230b is preferably formed by the film formation method of the metal oxide of one embodiment of the present invention.

The conductivity of a material used for the oxide semiconductor 230a is preferably different from the conductivity of a material used for the oxide semiconductor 230b.

For example, a material having higher conductivity than a material for the oxide semiconductor 230b can be used for the oxide semiconductor 230a. The use of the material having high conductivity for the oxide semiconductor 230a, which is in contact with the conductor 120 and the conductor 240 functioning as the source electrode and the drain electrode, can reduce the contact resistance between the oxide semiconductor 230 and the conductor 120 and the contact resistance between the oxide semiconductor 230 and the conductor 240, and thus the transistor can have high on-state current.

Here, in the case where a material having high conductivity is used for the oxide semiconductor 230b provided on the side of the conductor 260 functioning as the gate electrode, the threshold voltage of the transistor is shifted and a drain current flowing when the gate voltage is 0 V (hereinafter also referred to as cutoff current) becomes large in some cases. Specifically, the threshold voltage may be low when the transistor 200 is an n-channel transistor. Thus, a material having lower conductivity than a material for the oxide semiconductor 230a is preferably used for the oxide semiconductor 230b. Accordingly, the transistor 200 can have high threshold voltage in the case where the transistor 200 is an n-channel transistor, in which case the transistor 200 can have low cut-off current. Note that the low cut-off current is sometimes referred to as normally-off.

When the oxide semiconductor 230 has a stacked-layer structure and the material having higher conductivity than the material for the oxide semiconductor 230b is used for the oxide semiconductor 230a as described above, the transistor can have normally-off characteristics and high on-state current. Consequently, the memory device can have both low power consumption and high performance.

The carrier concentration of the oxide semiconductor 230a is preferably higher than the carrier concentration of the oxide semiconductor 230b. Increasing the carrier concentration of the oxide semiconductor 230a results in higher conductivity thereof, which can reduce the contact resistance between the oxide semiconductor 230 and the conductor 120 and the contact resistance between the oxide semiconductor 230 and the conductor 240, and thus the transistor can have high on-state current. When the carrier concentration of the oxide semiconductor 230b is reduced, the conductivity is reduced, and thus the transistor can have normally-off characteristics.

Although an example in which a material having higher conductivity than the oxide semiconductor 230b is used for the oxide semiconductor 230a is described here, one embodiment of the present invention is not limited thereto. A material having lower conductivity than the oxide semiconductor 230b may be used for the oxide semiconductor 230a. The carrier concentration of the oxide semiconductor 230a can be lower than that of the oxide semiconductor 230b.

The band gap of the first metal oxide used for the oxide semiconductor 230a and the band gap of the second metal oxide used for the oxide semiconductor 230b are preferably different from each other. For example, the difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 230a can be smaller than the band gap of the second metal oxide used for the oxide semiconductor 230b. Thus, the contact resistance between the oxide semiconductor 230 and the conductor 120 and the contact resistance between the oxide semiconductor 230 and the conductor 240 can be reduced, and thus the transistor can have high on-state current. Furthermore, the transistor 200 can have high threshold voltage in the case where the transistor is an n-channel transistor; accordingly, the transistor 200 can be a normally-off transistor.

Although the example in which the band gap of the first metal oxide is smaller than that of the second metal oxide is described here, one embodiment of the present invention is not limited to the example. The band gap of the first metal oxide can be larger than that of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In-M-Zn oxide, the first metal oxide can have an atomic ratio of In:M:Zn=1:1:1 or a composition in the neighborhood thereof, and the second metal oxide can have an atomic ratio of In:M:Zn=1:3:2 or a composition in the neighborhood thereof. It is particularly preferable to use one or both of gallium and tin as the element M.

The first metal oxide may have a composition not including the element M. For example, the first metal oxide used for the oxide semiconductor 230a can be an In—Zn oxide, and the second metal oxide used for the oxide semiconductor 230b can be an In-M-Zn oxide. Specifically, the first metal oxide can be an In—Zn oxide, and the second metal oxide can be an In—Ga—Zn oxide. More specifically, the first metal oxide can have an atomic ratio of In:Zn=1:1 or a composition in the neighborhood thereof or an atomic ratio of In:Zn=4:1 or a composition in the neighborhood thereof and the second metal oxide can have an atomic ratio of In:Ga:Zn=1:1:1 or a composition in the neighborhood thereof.

Although the example in which the content percentage of the element M in the first metal oxide is lower than that of the element M in the second metal oxide is described here, one embodiment of the present invention is not limited to the example. The content percentage of the element M in the first metal oxide may be higher than that of the element M in the second metal oxide. As long as the compositions of the first metal oxide and the second metal oxide are different from each other, the content percentages of elements other than the element M may be different from each other.

The film thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the oxide semiconductor 230 (here, the oxide semiconductor 230a and the oxide semiconductor 230b) are determined so that the thickness of the oxide semiconductor 230 is within the above-described range. The thickness of the oxide semiconductor 230a can be determined so that the contact resistance between the oxide semiconductor 230a and the conductor 120 and the contact resistance between the oxide semiconductor 230a and the conductor 240 are within the required range. The thickness of the oxide semiconductor 230b can be determined so that the threshold voltage of the transistor is within the required range. Note that the thickness of the oxide semiconductor 230a may be the same as or different from the thickness of the oxide semiconductor 230b.

Although FIG. 18A and FIG. 18B illustrate the structure in which the oxide semiconductor 230 has a stacked-layer structure of two layers, the oxide semiconductor 230a and the oxide semiconductor 230b, the present invention is not limited to the structure. The metal oxide semiconductor 230 may have a stacked-layer structure of three or more layers.

In the case where the oxide semiconductor 230 has a three-layer structure, the oxide semiconductor 230 may have a structure in which a metal oxide with a composition of In:Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in order from the conductor 120 side. With this structure, the on-state current of the transistor 200 can be increased, and the transistor can have high reliability with small variations.

As the insulator 250, a single layer or stacked layers of any of the insulators described in the later-described section [Insulator] can be used. For the insulator 250, silicon oxide or silicon oxynitride can be used, for example. In particular, silicon oxide and silicon oxynitride, which are thermally stable, are preferable.

As the insulator 250, any of insulators each having high relative permittivity, that is, high-k materials, described in the later-described section [Insulator] may be used. For example, hafnium oxide, aluminum oxide, or the like may be used.

The thickness of the insulator 250 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 250 preferably has a region with the above-described thickness.

The concentration of impurities such as water and hydrogen in the insulator 250 is preferably reduced. This can inhibit entry of impurities such as water and hydrogen into the channel formation region of the oxide semiconductor 230.

As illustrated in FIG. 15B and FIG. 15C, part of the insulator 250 is positioned outside the opening portion 290, that is, over the conductor 240 and the insulator 280. In this case, the insulator 250 preferably covers the side end portions of the oxide semiconductor 230. This can prevent a short circuit between the conductor 260 and the oxide semiconductor 230. The insulator 250 preferably covers the side end portions of the conductor 240. This can prevent a short circuit between the conductor 260 and the conductor 240.

As illustrated in FIG. 18A and FIG. 18B, the insulator 250 may have a stacked-layer structure of an insulator 250a, an insulator 250b over the insulator 250a, and an insulator 250c over the insulator 250b.

For the insulator 250b, any of materials each having low relative permittivity described in the later-described section [Insulator] is preferably used. In particular, silicon oxide and silicon oxynitride, which are thermally stable, are preferable. The insulator 250b in this case is contains at least oxygen and silicon. With such a structure, parasitic capacitance generated between the conductor 260 and the conductor 240 can be reduced. Furthermore, the concentration of impurities such as water and hydrogen in the insulator 250b is preferably reduced. For the insulator 250a, any of the insulators having a barrier property against oxygen described in the later-described section [Insulator] is preferably used. The insulator 250a includes a region in contact with the oxide semiconductor 230. When the insulator 250a has a barrier property against oxygen, release of oxygen from the oxide semiconductor 230 at the time of performing heat treatment or the like can be inhibited. This can inhibit formation of oxygen vacancies in the oxide semiconductor 230. Accordingly, the transistor 200 can have favorable electrical characteristics and higher reliability. As the insulator 250a, aluminum oxide is preferably used, for instance. In this case, the insulator 250a contains at least oxygen and aluminum.

For the insulator 250c, any of the insulators having a barrier property against hydrogen described in the later-described section [Insulator] is preferably used. In that case, diffusion of impurities contained in the conductor 260 into the oxide semiconductor 230 can be inhibited. In particular, silicon nitride is suitably used for the insulator 250c because of its high hydrogen barrier property. In this case, the insulator 250c contains at least nitrogen and silicon.

The insulator 250c may further have a barrier property against oxygen. The insulator 250c is provided between the insulator 250b and the conductor 260. Thus, diffusion of oxygen contained in the insulator 250b into the conductor 260 can be prevented, so that oxidation of the conductor 260 can be inhibited. A reduction in the amount of oxygen supplied to the region 230i can be inhibited.

An insulator may be provided between the insulator 250b and the insulator 250c. For the insulator, any of the insulators having a function of capturing or fixing hydrogen described in the later-described section [Insulator] is preferably used. In this case, hydrogen contained in the oxide semiconductor 230 can be captured or fixed more effectively by providing the insulator.

Thus, the hydrogen concentration in the oxide semiconductor 230 can be lowered. As the insulator, for example, hafnium oxide is preferably used. In this case, the above insulator contains at least oxygen and hafnium. Alternatively, the insulator may have an amorphous structure.

The thicknesses of the insulator 250a to the insulator 250c are preferably small and preferably within the above range for miniaturization of the transistor 200. Typically, the thicknesses of the insulator 250a, the insulator 250b, the insulator that has a function of capturing or fixing hydrogen, and the insulator 250c are 1 nm, 2 nm, 2 nm, and 1 nm, respectively. Such a structure enables the transistor 200 to have favorable electrical characteristics even when the transistor is miniaturized or highly integrated.

Although FIG. 18A and FIG. 18B illustrate the structure in which the insulator 250 has a stacked structure of three layers, the insulator 250a to the insulator 250c, the present invention is not limited thereto. The insulator 250 may have a stacked-layer structure of two layers or four or more layers. In that case, the layers included in the insulator 250 are preferably selected as appropriate from the insulator 250a to the insulator 250c and the insulator having a function of capturing or fixing hydrogen.

As the conductor 260, a single layer or stacked layers of any of the conductors described in the later-described section [Conductor] can be used. For example, a conductive material with high conductivity such as tungsten can be used for the conductor 260, for example.

In addition, a conductive material that is less likely to be oxidized, a conductive material having a function of inhibiting diffusion of oxygen, or the like is preferably used as the conductor 260. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 260.

As illustrated in FIG. 18A and FIG. 18B, the conductor 260 may have a stacked-layer structure of a conductor 260a and a conductor 260b over the conductor 260a. In this case, titanium nitride may be used as the conductor 260a, and tungsten may be used as the conductor 260b, for example. When tungsten is stacked in this manner, the conductivity of the conductor 260 can be improved and can serve well as the wiring WL.

Although the conductor 260 is provided to fill the opening portion 290 in FIG. 15B and FIG. 15C, the present invention is not limited thereto. For example, a depressed portion reflecting the shape of the opening portion 290 is formed in a center portion of the conductor 260 and part of the depressed portion is positioned in the opening portion 290 in some cases. In this case, the depressed portion may be filled with an inorganic insulating material or the like.

As illustrated in FIG. 15B and FIG. 15C, part of the conductor 260 is positioned outside the opening portion 290, that is, over the conductor 240 and the insulator 280. In this case, a side end portion of the conductor 260 is preferably positioned inward from the side end portion of the oxide semiconductor 230 as illustrated in FIG. 15B. This can prevent a short circuit between the conductor 260 and the oxide semiconductor 230. The side end portion of the conductor 260 may be aligned with the side end portion of the oxide semiconductor 230 or positioned outward from the side end portion of the oxide semiconductor 230.

The conductor 120 can be provided as described in the section [Capacitor 100].

Although FIG. 15B and FIG. 15C illustrate a structure in which the top surface of the conductor 120 is flat, the present invention is not limited to the structure. For example, a depressed portion overlapping with the opening portion 290 may be formed on the top surface of the conductor 120. When at least parts of the oxide semiconductor 230, the insulator 250, and the conductor 260 are formed to fill the depressed portion, the gate electric field of the conductor 260 can be easily applied to a portion of the oxide semiconductor 230 close to the conductor 120.

As the conductor 240, a single layer or stacked layers of any of the conductors described in the later-described section [Conductor] can be used. Moreover, a conductive material with high conductivity such as tungsten can be used for the conductor 240, for example.

A conductive material that is less likely to be oxidized, a conductive material having a function of inhibiting diffusion of oxygen, or the like is preferably used for the conductor 240 like the conductor 260. For example, titanium nitride, tantalum nitride, or the like can be used. Such a structure can reduce excessive oxidation of the conductor 240 due to the oxide semiconductor 230.

In addition, a structure in which tungsten is stacked over titanium nitride may be used, for example. When tungsten is stacked in this manner, the conductivity of the conductor 240 can be improved and can serve well as the wiring BL.

In the case where the conductor 240 has a structure where a first conductor and a second conductor are stacked, the first conductor may be formed using a conductive material with high conductivity and the second conductor may be formed using a conductive material containing oxygen, for example. When a conductive material containing oxygen is used as the second conductor of the conductor 240 that is in contact with the insulator 250, oxygen in the insulator 250 can be prevented from diffusing into the first conductor of the conductor 240. For example, tungsten is preferably used as the first conductor of the conductor 240, and indium tin oxide to which silicon is added is preferably used as the second conductor of the conductor 240.

When the oxide semiconductor 230 and the conductor 120 are in contact with each other, a metal compound is formed or oxygen vacancies are formed, so that the resistance of the region 230na in the oxide semiconductor 230 is reduced. The reduction in the resistance of the oxide semiconductor 230 in contact with the conductor 120 can reduce the contact resistance between the oxide semiconductor 230 and the conductor 120. Similarly, when the oxide semiconductor 230 and the conductor 240 are in contact with each other, the resistance of the region 230nb in the oxide semiconductor 230 is reduced. Accordingly, the contact resistance between the oxide semiconductor 230 and the conductor 240 can be reduced.

The insulator 140 and the insulator 280 function as interlayer films and thus preferably have low relative permittivity. When a material with low relative permittivity is used for an interlayer film, parasitic capacitance generated between wirings can be reduced. As the insulator 140 and the insulator 280, a single layer or stacked layers of any of insulators each containing a material with low relative permittivity described in the later-described section [Insulator] can be used. Silicon oxide and silicon oxynitride are preferable because they are thermally stable.

The concentration of impurities such as water and hydrogen in the insulator 140 and the insulator 280 is preferably reduced. This can inhibit entry of impurities such as water and hydrogen into the channel formation region of the oxide semiconductor 230.

As the insulator 280 placed in the vicinity of the channel formation region, an insulator containing oxygen that is released by heating (hereinafter, sometimes referred to as excess oxygen) is preferably used. By performing heat treatment on the insulator 280 containing excess oxygen, oxygen can be supplied from the insulator 280 to the channel formation region of the oxide semiconductor 230 and oxygen vacancies and V_{O}H can be reduced. Thus, the transistor 200 can have stable electrical characteristics and increased reliability.

As the insulator 280, any of the insulators having a function of capturing or fixing hydrogen described in the later-described [Insulator] may be used. With this structure, hydrogen in the oxide semiconductor 230 can be captured or fixed, so that the hydrogen concentration in the oxide semiconductor 230 can be reduced. For the insulator 280, magnesium oxide, aluminum oxide, or the like can be used for example.

The insulator 280 may have a single-layer structure or a stacked-layer structure of two or more layers. For example, as illustrated in FIG. 19A and FIG. 19B, the insulator 280 may have a stacked-layer structure of an insulator 280a, an insulator 280b over the insulator 280a, and an insulator 280c over the insulator 280b.

As the insulator 280b, an insulator containing oxygen is preferably used. The insulator 280b preferably includes a region having a higher oxygen content than at least one of the insulator 280a and the insulator 280c. In particular, the insulator 280b preferably includes a region having a higher oxygen content than each of the insulator 280a and the insulator 280c. When the insulator 280b has a high oxygen content, an i-type region can be easily formed in a region of the oxide semiconductor 230 that is in contact with the insulator 280b and in the vicinity of the region.

It is further preferable that a film from which oxygen is released by heating be used as the insulator 280b. When the insulator 280b releases oxygen by being heated during the manufacturing process of the transistor 200, the oxygen can be supplied to the oxide semiconductor 230. Supply of oxygen from the insulator 280b to the oxide semiconductor 230, particularly to the channel formation region of the oxide semiconductor 230, can reduce oxygen vacancies and V_{O}H in the oxide semiconductor 230, so that the transistor can have favorable electrical characteristics and high reliability.

For example, the insulator 280b can be supplied with oxygen when heat treatment in an oxygen-containing atmosphere or plasma treatment in an oxygen-containing atmosphere is performed. Alternatively, an oxide film may be formed over the top surface of the insulator 280b by a sputtering method in an oxygen atmosphere to supply oxygen. After that, the oxide film may be removed.

The insulator 280b is preferably formed by a film formation method such as a sputtering method or a plasma-enhanced chemical vapor deposition (PECVD) method. It is particularly preferable to employ a sputtering method, in which a hydrogen gas does not need to be used as a film formation gas, to form a film having an extremely low hydrogen content. Thus, supply of hydrogen to the oxide semiconductor 230 is inhibited and the electrical characteristics of the transistor 200 can be stabilized.

Particularly in the case where the channel length of the transistor 200 is short, oxygen vacancies and V_{O}H in the channel formation region significantly affect electrical characteristics and reliability. Supplying oxygen from the insulator 280b to the oxide semiconductor 230 can inhibit increases in oxygen vacancies and V_{O}H at least in the region of the oxide semiconductor 230 that is in contact with the insulator 280b. Thus, the transistor with a short channel length can have favorable electrical characteristics and high reliability.

For each of the insulator 280a and the insulator 280c, the insulator having a barrier property against oxygen described in [Insulator] later is preferably used. This can inhibit heating from causing diffusion of oxygen contained in the insulator 280b to the substrate side through the insulator 280a and diffusion of the oxygen to the insulator 250 side through the insulator 280c. In other words, the upper and lower sides of the insulator 280b are sandwiched between the insulator 280a and the insulator 280c through which oxygen is less likely to be diffused, whereby oxygen contained in the insulator 280b can be enclosed. Consequently, oxygen can be effectively supplied to the oxide semiconductor 230.

The conductor 120 and the conductor 240 are oxidized by oxygen contained in the insulator 280b and have high resistance in some cases. Providing the insulator 280a between the insulator 280b and the conductor 120 can inhibit the conductor 120 from being oxidized and having high resistance. Furthermore, the insulator 280c provided between the insulator 280b and the conductor 240 can inhibit the conductor 240 from being oxidized and having high resistance. In addition, the amount of oxygen supplied from the insulator 280b to the oxide semiconductor 230 is increased, so that oxygen vacancies in the oxide semiconductor 230 can be reduced.

The contact region between the oxide semiconductor 230 and the insulator 280a and the contact region between the oxide semiconductor 230 and the insulator 280c are supplied with a smaller amount of oxygen than the contact region between the oxide semiconductor 230 and the insulator 280b. Thus, the contact region between the oxide semiconductor 230 and the insulator 280a and the contact region between the oxide semiconductor 230 and the insulator 280c each have a low resistance in some cases. That is, by adjusting the thickness of the insulator 280a, the range of the region 230na functioning as one of the source region and the drain region can be controlled. Similarly, by adjusting the thickness of the insulator 280c, the range of the region 230nb functioning as the other of the source region and the drain region can be controlled.

Since the source region and the drain region can be controlled by the thicknesses of the insulator 280a and the insulator 280c as described above, the thicknesses of the insulator 280a and the insulator 280c can be set as appropriate in accordance with the characteristics required for the transistor 200.

For example, as illustrated in FIG. 19A and FIG. 19B, the thickness of the insulator 280c and the thickness of the insulator 280a may be substantially the same. Alternatively, as illustrated in FIG. 19C and FIG. 19D, the thickness of the insulator 280c may be smaller than the thickness of the insulator 280a, for example. With the structure illustrated in FIG. 19C and FIG. 19D, the region 230na can be brought close to the bottom portion of the conductor 260 in the opening portion 290. In this case, the area of the region 230i can be regarded as being narrowed. This leads to an improvement of the on-state characteristics of the transistor 200.

Although FIG. 19C and FIG. 19D each illustrate a structure in which the insulator 280c is provided over the planarized insulator 280b, the present invention is not limited thereto. For example, a film of the insulator 280c may be formed without planarization treatment of the insulator 280b. By not performing planarization treatment, manufacturing cost can be reduced and production yield can be increased. In addition, film formation of the insulator 280a, the insulator 280b, and the insulator 280c can be successively performed without exposure to the air. By the film formation without exposure to the air, impurities or moisture from the atmospheric environment can be prevented from being attached onto the insulator 280a to the insulator 280c, so that the vicinity of the interface between the insulator 280a and the insulator 280b and the vicinity of the interface between the insulator 280b and the insulator 280c can be kept clean.

For each of the insulator 280a and the insulator 280c, any of the insulators having a barrier property against hydrogen described in the later-described section [Insulator] is preferably used. Thus, hydrogen can be inhibited from diffusing from outside the transistor to the oxide semiconductor 230 through the insulator 280a or the insulator 280c. A silicon nitride film and a silicon nitride oxide film can be suitably used for the insulator 280a and the insulator 280c because the silicon nitride film and the silicon nitride oxide film release fewer impurities (e.g., water and hydrogen) and are less likely to transmit oxygen and hydrogen. For the insulator 280a and the insulator 280c, the same material or different materials may be used.

As the insulator 280a, any of the insulators having a function of capturing or fixing hydrogen described in [Insulator] later is preferably used. With such a structure, diffusion of hydrogen from below the insulator 280a into the oxide semiconductor 230 can be inhibited, and hydrogen in the oxide semiconductor 230 can be captured or fixed, whereby the hydrogen concentration in the oxide semiconductor 230 can be reduced. Furthermore, diffusion of hydrogen from above the insulator 280a into the insulator 130 can be inhibited, and hydrogen in the insulator 130 can be captured or fixed, whereby the hydrogen concentration in the insulator 130 can be reduced. For the insulator 280a, magnesium oxide, aluminum oxide, hafnium oxide, or the like can be used. Alternatively, for example, a stacked-layer film of aluminum oxide and silicon nitride over the aluminum oxide may be used as the insulator 280a.

The thickness of the insulator 280a is preferably smaller than the thickness of the insulator 280b. The thickness of the insulator 280c is preferably smaller than the thickness of the insulator 280b. The thickness of each of the insulator 280a and the insulator 280c is preferably greater than or equal to 1 nm and less than or equal to 15 nm, further preferably greater than or equal to 2 nm and less than or equal to 10 nm, still further preferably greater than or equal to 3 nm and less than or equal to 7 nm, yet still further preferably greater than or equal to 3 nm and less than or equal to 5 nm. The thickness of the insulator 280b is preferably greater than or equal to 3 nm and less than or equal to 30 nm, further preferably greater than or equal to 5 nm and less than or equal to 20 nm, still further preferably greater than or equal to 7 nm and less than or equal to 15 nm. When the thicknesses of the insulator 280a to the insulator 280c are in the above range, oxygen vacancies in the oxide semiconductor 230, particularly in the channel formation region, can be reduced.

For example, it is preferable that silicon nitride be used for the insulator 280a and the insulator 280c, and silicon oxide be used for the insulator 280b. In that case, each of the insulator 280a and the insulator 280c contains at least silicon and nitrogen. The insulator 280b contains at least silicon and oxygen.

Although FIG. 20A and FIG. 20B illustrate the structure in which the insulator 280 has a stacked-layer structure of three layers, one embodiment of the present invention is not limited to the structure. The insulator 280 may have a stacked-layer structure of two layers or four or more layers.

As the insulator 283, any of the insulators having a barrier property against hydrogen described in the later-described section [Insulator] is preferably used. In that case, hydrogen can be inhibited from being diffused from outside of the transistor to the oxide semiconductor 230 through the insulator 250. A silicon nitride film and a silicon nitride oxide film can be suitably used for the insulator 283 because the silicon nitride film and the silicon nitride oxide film release fewer impurities (e.g., water and hydrogen) and are less likely to transmit oxygen and hydrogen.

For the insulator 283, any of the insulators having a function of capturing or fixing hydrogen described in the later-described [Insulator] is preferably used. With this structure, diffusion of hydrogen into the oxide semiconductor 230 from above the insulator 283 can be inhibited, and hydrogen in the oxide semiconductor 230 can be captured or fixed, whereby the hydrogen concentration in the oxide semiconductor 230 can be reduced. As the insulator 283, magnesium oxide, aluminum oxide, hafnium oxide, or the like can be used. Alternatively, for example, a stacked-layer film of aluminum oxide and silicon nitride over the aluminum oxide may be used as the insulator 283.

Although FIG. 15B and FIG. 15C each illustrate a structure in which the top surface of the conductor 120 and the bottom surface of the oxide semiconductor 230 are in contact with each other, the present invention is not limited thereto. For example, a conductor may be provided between the conductor 120 and the oxide semiconductor 230.

For example, as illustrated in FIG. 20A and FIG. 20B, the conductor 125 may be provided between the conductor 120 and the oxide semiconductor 230. For the conductor 125, a conductive material containing oxygen described in the section [Conductor] below is preferably used. When a conductive material containing oxygen is used for the conductor 125, the conductor 125 can maintain its conductivity even when absorbing oxygen. Furthermore, diffusion of oxygen from the oxide semiconductor 230 into the conductor 120 can be inhibited. As the conductor 125, a single layer or stacked layers of indium tin oxide, indium tin oxide to which silicon is added, indium zinc oxide, and the like can be used, for example.

FIG. 15B and FIG. 15C illustrate a structure in which the conductor 240 is provided over the insulator 280. Furthermore, a region of the insulator 250 that does not overlap with the conductor 240 includes a region in contact with the top surface of the insulator 280. Note that the present invention is not limited thereto.

The conductor 240 may be provided to be embedded in the insulator, for example. In that case, the top surface of the conductor 240 is preferably level with the top surface of the insulator. With such a structure, the physical distance from the conductor 260 to the conductor 240 (particularly the side end portion of the conductor 240) can be increased, so that a short circuit between the conductor 260 and the conductor 240 can be prevented.

An example of a method for manufacturing the memory cell 150 illustrated in FIG. 15A to FIG. 15C is described. First, the insulator 180 is formed over the conductor 110 and processed, whereby the opening portion 190 reaching the conductor 110 is formed. Next, the conductor 115 in contact with the side surface of the insulator 180 in the opening portion 190 is formed, the insulator 130 is formed over the conductor 115, the conductor 120 is formed over the insulator 130, the insulator 280 is formed over the conductor 120, and the conductor 240 is formed over the insulator 280. Then, each of the conductor 240 and the insulator 280 is processed to form the opening portion 290 reaching the conductor 120. Next, the oxide semiconductor 230 in contact with the top surface of the conductor 120, the side surface of the insulator 280, and the top surface and the side surface of the conductor 240 in the opening portion 290 is formed, the insulator 250 is formed over the oxide semiconductor 230, and the conductor 260 is formed over the insulator 250. In the above manner, the memory cell 150 can be formed. For the formation of the oxide semiconductor 230, the film formation method of a metal oxide described in Embodiment 1 is preferably used.

### <Component Materials of Semiconductor Device and Memory Device>

Component materials that can be used for the semiconductor device and the memory device will be described below. The description in Embodiment 1 can be referred to for the metal oxide that can be used for the oxide semiconductor 230.

### [Substrate]

As a substrate where the transistor 200 and the capacitor 100 are formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is the above-described semiconductor substrate including an insulator region, e.g., an SOI (Silicon On Insulator) substrate. Examples of the conductor substrate include a graphite substrate, a metal substrate, an alloy substrate, and a conductive resin substrate. Other examples of substrates include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, any of these substrates where one or more elements are provided may be used. Examples of the element provided for the substrate include a capacitor, a resistor, a switching element, a light-emitting element, and a memory element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. By contrast, when a material with low relative permittivity is used for the insulator functioning as an interlayer film, parasitic capacitance generated between wirings can be reduced. Thus, a material is preferably selected in accordance with the function of the insulator. Note that the material with low relative permittivity is a material with high dielectric strength.

Examples of the material with high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with low relative permittivity include silicon oxide to which fluorine is added, silicon oxide to which carbon is added, and silicon oxide to which carbon and nitrogen are added, and porous silicon oxide. These silicon oxides may contain nitrogen.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used. Specific examples of the insulator having a function of inhibiting passage of oxygen and impurities such as hydrogen include a metal oxide such as aluminum oxide, magnesium oxide, gallium oxide, germanium oxide, yttrium oxide, zirconium oxide, lanthanum oxide, neodymium oxide, hafnium oxide, or tantalum oxide and a metal nitride such as aluminum nitride, silicon nitride oxide, or silicon nitride.

An insulator that is in contact with a semiconductor layer or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of the barrier insulator against oxygen include an oxide containing one or both of aluminum and hafnium, an oxide containing hafnium and silicon (hafnium silicate), magnesium oxide, gallium oxide, gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, indium gallium zinc oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond and sometimes has a property of capturing or fixing hydrogen with the dangling bond. Note that such a metal oxide preferably has an amorphous structure, but may include a crystal region that is partly formed.

In this specification and the like, a barrier property refers to a property that does not easily allow diffusion of a target substance (also referred to as a property that does not easily allow passage of a target substance, a property with low permeability to a target substance, or a function of inhibiting diffusion of a target substance). Moreover, a function of capturing or fixing (also referred to as gettering) a target substance can be rephrased as a barrier property. In addition, hydrogen described as a target substance refers to at least one of a hydrogen atom, a hydrogen molecule, and a substance bonded to hydrogen, such as a water molecule or OH″, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductors formed of the above-described materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Other Semiconductor Materials]

The oxide semiconductor 230 can be rephrased as a semiconductor layer including a channel formation region of the transistor. A semiconductor material that can be used for the semiconductor layer is not limited to the above metal oxides. The semiconductor material that has a band gap (a semiconductor material that is not a zero-gap semiconductor) may be used as the semiconductor. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS). Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a memory device with a high on-state current to be provided.

### Structure Example 2 of Semiconductor Device

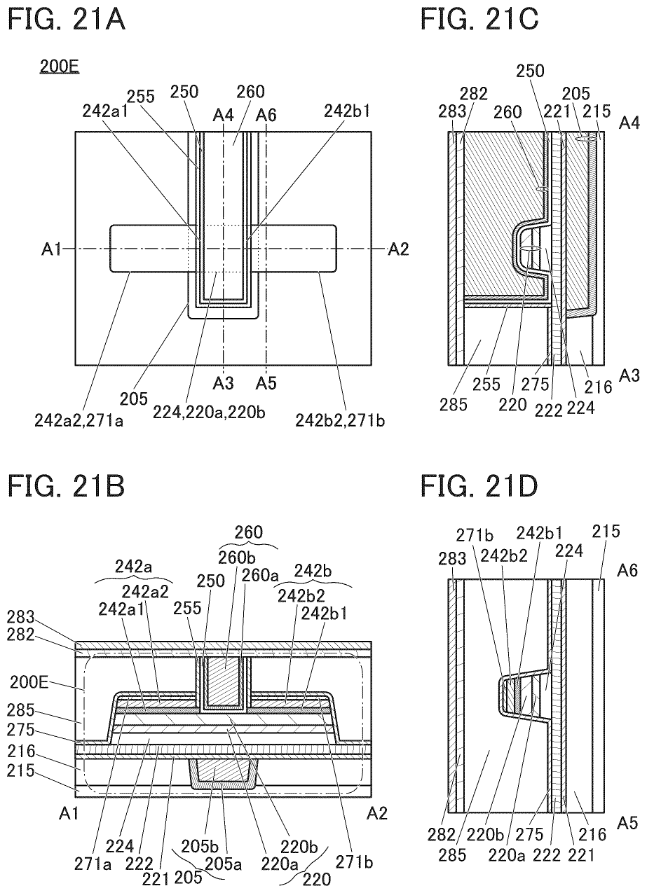

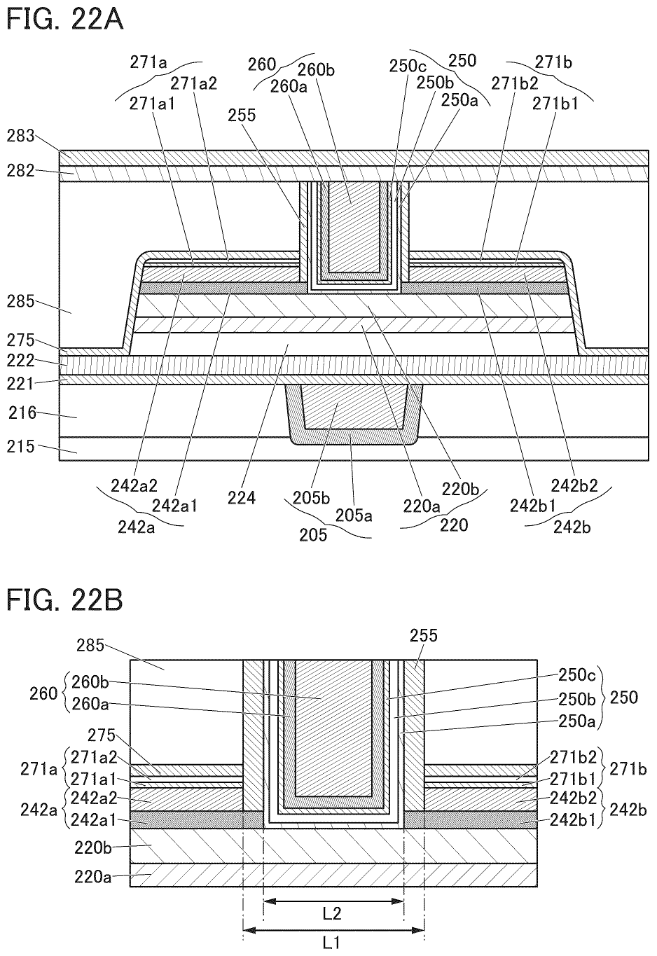

Next, an example of the semiconductor device of one embodiment of the present invention is described with reference to FIG. 21 and FIG. 22. The semiconductor device illustrated in FIG. 21 and FIG. 22 includes a transistor 200E having a structure different from those of the above-described transistors 200 and 200A to 200D.

FIG. 21A is a plan view of the semiconductor device of one embodiment of the present invention. FIG. 21B is a cross-sectional view taken along the dashed-dotted line A1-A2 in FIG. 21A. FIG. 21B is also a cross-sectional view of the transistor 200E in the channel length direction. FIG. 21C is a cross-sectional view taken along the dashed-dotted line A3-A4 in FIG. 21A. FIG. 21C is also a cross-sectional view of the transistor 200E in the channel width direction. FIG. 21D is a cross-sectional view taken along the dashed-dotted line A5-A6 in FIG. 21A. FIG. 21D is also a cross-sectional view of the transistor 200E in the channel width direction. Note that for the sake of clarity of the drawing, some components are omitted in the plan view of FIG. 21A. FIG. 22A and FIG. 22B are enlarged cross-sectional views of the transistor 200E in the channel length direction.

The transistor 200E includes a conductor 205 (a conductor 205a and a conductor 205b) provided to be embedded in an insulator 216; an insulator 221 over the insulator 216 and the conductor 205; an insulator 222 over the insulator 221; an insulator 224 over the insulator 222; an oxide 220 (an oxide 220a and an oxide 220b) over the insulator 224; a conductor 242a (a conductor 242al and a conductor 242a2) and a conductor 242b (a conductor 242b1 and a conductor 242b2) over the oxide 220; an insulator 271a over the conductor 242a; an insulator 271b over the conductor 242b; the insulator 250 over the oxide 220; and the conductor 260 (the conductor 260a and the conductor 260b) over the insulator 250.

The insulator 275 is provided over the insulators 271a and 271b, and an insulator 285 is provided over the insulator 275. An insulator 255, the insulator 250, and the conductor 260 are placed in an opening provided in the insulator 285 and the insulator 275. An insulator 282 is provided over the insulator 285 and the conductor 260. The insulator 283 is provided over the insulator 282. An insulator 215 is provided below the insulator 216 and the conductor 205. The insulator 255 is provided between the insulator 250 and the conductor 242a2, the conductor 242b2, the insulator 271a, the insulator 271b, the insulator 275, and the insulator 285.

Note that the insulator 215, the insulator 216, the conductor 205, the insulator 221, the insulator 222, the insulator 224, the oxide 220, the conductor 242a, the conductor 242b, the insulator 271a, the insulator 271b, the insulator 275, the insulator 285, the insulator 255, the insulator 250, the conductor 260, the insulator 282, and the insulator 283 may each have a single-layer structure or a stacked-layer structure.

The oxide 220 includes a region functioning as the channel formation region of the transistor 200E. The conductor 260 includes a region functioning as a first gate electrode (an upper gate electrode) of the transistor 200E. The insulator 250 includes a region functioning as a first gate insulator of the transistor 200E. The conductor 205 includes a region functioning as a second gate electrode (a lower gate electrode) of the transistor 200E. The insulator 224, the insulator 222, and the insulator 221 each include a region functioning as a second gate insulator of the transistor 200E.

The conductor 242a includes a region functioning as one of a source electrode and a drain electrode of the transistor 200E. The conductor 242b includes a region functioning as the other of the source electrode and the drain electrode of the transistor 200E.

The oxide 220 preferably includes the oxide 220a over the insulator 224 and the oxide 220b over the oxide 220a. Including the oxide 220a under the oxide 220b makes it possible to inhibit diffusion of impurities into the oxide 220b from components formed below the oxide 220a.

Note that the oxide 220 is not limited to having a two-layer structure of the oxide 220a and the oxide 220b. The oxide 220 may have a single-layer structure of the oxide 220b or a stacked-layer structure of three or more layers, for example.

The oxide 220b includes a channel formation region of the transistor 200E and a source region and a drain region provided to sandwich the channel formation region. At least part of the channel formation region overlaps with the conductor 260. The source region overlaps with the conductor 242a, and the drain region overlaps with the conductor 242b. Note that the source region and the drain region can be interchanged with each other.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the channel formation region, the source region, and the drain region may each be formed not only in the oxide 220b but also in the oxide 220a.

In the oxide 220, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter also referred to as an oxide semiconductor) is preferably used for the oxide 220 (the oxide 220a and the oxide 220b).

At least one layer of the oxide 220 is preferably formed by the film formation method of the metal oxide of one embodiment of the present invention. In particular, the oxide 220b including the channel formation region is preferably formed by the film formation method of the metal oxide of one embodiment of the present invention.

For example, both the oxide 220a and the oxide 220b are preferably formed by an ALD method. Alternatively, it is preferable that the oxide 220a be formed by a sputtering method and the oxide 220b be formed by an ALD method.

The preferable range of the aluminum concentration and the preferable range of the carbon concentration in the channel formation region of the oxide 220 are similar to those of the oxide semiconductor 230.

The oxide 220 preferably has a stacked-layer structure of a plurality of oxide layers with different chemical compositions. For example, the atomic ratio of the element M to a metal element that is a main component in the metal oxide used for the oxide 220a is preferably greater than the atomic ratio of the element M to a metal element that is a main component in the metal oxide used for the oxide 220b. Moreover, the atomic ratio of the element M to In in the metal oxide used for the oxide 220a is preferably greater than the atomic ratio of the element M to In in the metal oxide used for the oxide 220b. With this structure, impurities and oxygen can be inhibited from diffusing into the oxide 220b from the components formed below the oxide 220a.

Furthermore, the atomic ratio of In to the element M in the metal oxide used for the oxide 220b is preferably greater than the atomic ratio of In to the element M in the metal oxide used for the oxide 220a. With this structure, the transistor 200E can have a high on-state current and excellent frequency characteristics.

When the oxide 220a and the oxide 220b include a common element as the main component besides oxygen, the density of defect states at the interface between the oxide 220a and the oxide 220b can be decreased. The density of defect states at the interface between the oxide 220a and the oxide 220b can be decreased. Thus, the influence of interface scattering on carrier conduction is reduced, and the transistor 200E can have a high on-state current and high frequency characteristics.

Specifically, for the oxide 220a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used. For the oxide 220b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of +30% of an intended atomic ratio. Gallium is preferably used as the element M. In the case where a single layer of the oxide 220b is provided as the oxide 220, a metal oxide that can be used for the oxide 220a may be used for the oxide 220b. The compositions of the metal oxides that can be used for the oxide 220a and the oxide 220b are not limited to the above. For example, the composition of the metal oxide that can be used for the oxide 220a may be applied to the oxide 220b. Similarly, the composition of the metal oxide that can be used for the oxide 220b may be applied to the oxide 220a.

When the metal oxide is deposited by a sputtering method, the above atomic ratio is not limited to the atomic ratio of the deposited metal oxide and may be the atomic ratio of a sputtering target used for depositing the metal oxide.

The oxide 220b preferably has crystallinity. It is particularly preferable to use a CAAC-OS for the oxide 220b.

When an oxide having crystallinity, such as a CAAC-OS, is used for the oxide 220b, oxygen extraction from the oxide 220b by the source electrode or the drain electrode can be inhibited. This can reduce oxygen extraction from the oxide 220b even when heat treatment is performed; thus, the transistor 200E is stable with respect to high temperatures in the manufacturing process (what is called thermal budget).

As materials that can be used for each of the insulators and each of the conductors included in the semiconductor device illustrated in FIG. 21A to FIG. 21D, the materials given in sections [Insulator] and [Conductor] can be given. A typical example is described below.

The conductor 242a has a stacked structure of the conductor 242al and the conductor 242a2 over the conductor 242al, and the conductor 242b has a stacked structure of the conductor 242b1 and the conductor 242b2 over the conductor 242bl. The conductor 242al and the conductor 242b1 in contact with the oxide 220b are preferably conductors that are not easily oxidized, such as metal nitride. Thus, the conductor 242a and the conductor 242b can be prevented from being oxidized excessively by oxygen contained in the oxide 220b. The conductor 242a2 and the conductor 242b2 are preferably conductors having higher conductivity than the conductor 242al and the conductor 242b1, such as a metal layer. Accordingly, the conductor 242a and the conductor 242b can each function as a wiring or an electrode with high conductivity.

For example, tantalum nitride or titanium nitride can be used for the conductor 242al and the conductor 242b1, and tungsten can be used for the conductor 242a2 and the conductor 242b2.

As illustrated in FIG. 22B, in a cross-sectional view of the transistor 200E in the channel length direction, a distance L2 between the conductor 242al and the conductor 242b1 is preferably smaller than a distance L1 between the conductor 242a2 and the conductor 242b2. Specifically, the difference between L1 and L2 is equal to or substantially equal to twice the thickness of the insulator 255. Here, the thickness of the insulator 255 corresponds to the thickness in the A1-A2 direction of at least part of the insulator 255.

The distance L2 between the conductor 242al and the conductor 242b1 is preferably short because the distance L2 reflects the channel length of the transistor 200E. For example, the distance L2 is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm. For example, it is further preferable that the distance L2 be approximately greater than or equal to 2 nm and less than or equal to 20 nm. With such a structure, the distance between the source and the drain can be shortened, and the channel length can be accordingly shortened. Thus, the frequency characteristics of the transistor 200E can be improved. In this manner, miniaturization of the semiconductor device enables the semiconductor device to have a higher operating speed.

The opening formed in the insulator 285 and the insulator 275 overlap with a region between the conductor 242a2 and the conductor 242b2. In a top view, the side surface of the opening in the insulator 285 is aligned or substantially aligned with the side surface of the conductor 242a2 and the side surface of the conductor 242b2. The conductor 242al and the conductor 242b1 are formed to partly extend toward the inside of the opening. A part of the top surface of the conductor 242al is in contact with the conductor 242a2, and a part of the top surface of the conductor 242b1 is in contact with the conductor 242b2. Thus, the insulator 255 is in contact with another part of the top surface of the conductor 242al, another part of the top surface of the conductor 242b1, and the side surface of the conductor 242a2, and the side surface of the conductor 242b2 in the opening. The insulator 250 is in contact with the top surface of the oxide 220, the side surface of the conductor 242a1, the side surface of the conductor 242b1, and the side surface of the insulator 255.

The insulator 255 is preferably an insulator that is not easily oxidized, such as nitride. By anisotropic etching, the insulator 255 is formed in a sidewall shape to be in contact with the sidewall of the opening formed in the insulator 285 and the like (here, the sidewall of the opening corresponds to, for example, the side surface of the insulator 285 or the like). The insulator 255 is formed in contact with the side surface of the conductor 242a2 and the side surface of the conductor 242b2 and bas a function of protecting the conductor 242a2 and the conductor 242b2. In order to supply oxygen to the oxide 220b, heat treatment in an atmosphere containing oxygen is preferably performed after the separation into the conductor 242al and the conductor 242b1 and before the formation of the insulator 250. At this time, since the insulator 255 is formed in contact with the side surface of the conductor 242a2 and the side surface of the conductor 242b2, excessive oxidation of the conductor 242a2 and the conductor 242b2 can be prevented. The insulator 255 can be formed using silicon nitride, for example.

An insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 200E. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and V_{O}H in the channel formation region of the oxide semiconductor are preferably reduced. Supply of an excess amount of oxygen to the source region and the drain region and excessive reduction in the amount of V_{O}H in the source region and the drain region are preferably inhibited. In addition, a structure in which conductivity of the conductor 260, the conductor 242a, the conductor 242b, and the like is less likely to be reduced is preferably employed. For example, oxidation of the conductor 260, the conductor 242a, the conductor 242b, and the like is preferably inhibited. Note that hydrogen in the oxide semiconductor can form V_{O}H; thus, the hydrogen concentration needs to be reduced in order to reduce the amount of V_{O}H.

The transistor 200E has a structure in which the hydrogen concentration in the channel formation region is reduced, oxidation of the conductor 242a, the conductor 242b, and the conductor 260 is inhibited, and a reduction in the hydrogen concentration in the source region and the drain region is inhibited.

The insulator 250 in contact with the channel formation region of the oxide 220b preferably has a function of capturing or fixing hydrogen. Thus, the hydrogen concentration in the channel formation region of the oxide 220b can be reduced. Accordingly, V_{O}H in the channel formation region can be reduced, so that the channel formation region can be an i-type or substantially i-type region.

Here, as illustrated in FIG. 22A, the insulator 250 preferably has a stacked-layer structure of the insulator 250a in contact with the oxide 220, the insulator 250b over the insulator 250a, and the insulator 250c over the insulator 250b.

The insulator 250a preferably has a function of capturing or fixing hydrogen. A high permittivity (high-k) material is preferably used for the insulator 250a. For the insulator 250a, an oxide containing one or both of aluminum and hafnium is preferably used, and an oxide that has an amorphous structure and contains one or both of aluminum and hafnium is further preferably used, for example. In this embodiment, an aluminum oxide film having an amorphous structure is used for the insulator 250a. An aluminum oxide film can be formed as an amorphous film relatively easily by an ALD method.

An insulator having a thermally stable structure, such as silicon oxide or silicon oxynitride, is preferably used for the insulator 250b.

In order to inhibit oxidation of the conductor 242a, the conductor 242b, and the conductor 260, an insulator having a barrier property against oxygen is preferably provided in the vicinity of each of the conductor 242a, the conductor 242b, and the conductor 260. The insulator corresponds to, for example, the insulator 250a, the insulator 250c, the insulator 255, and the insulator 275.

The insulator 250a and the insulator 255 each preferably have a barrier property against oxygen. It is preferable that oxygen be less likely to pass through the insulator 250a and the insulator 255 than at least through the insulator 285. The insulator 250a includes a region in contact with the side surface of the conductor 242al and a region in contact with the side surface of the conductor 242b1. The insulator 255 includes a region in contact with the top surface of the conductor 242al, the top surface of the conductor 242b1, the side surface of the conductor 242a2, and the side surface of the conductor 242b2. The insulator 250a is in contact with the side surface of the insulator 255. When the insulator 250a and the insulator 255 each have a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 200E can be inhibited.

The insulator 250a is provided in contact with the top surface and the side surface of the oxide 220b, the side surface of the oxide 220a, the side surface of the insulator 224, and the top surface of the insulator 222. When the insulator 250a has a barrier property against oxygen, release of oxygen from the channel formation region of the oxide 220b caused by heat treatment or the like can be inhibited. This can reduce formation of oxygen vacancies in the oxide 220a and the oxide 220b.

By providing the insulator 250a and the insulator 255, even when the insulator 285 contains an excess amount of oxygen, excessive supply of oxygen to the oxide 220a and the oxide 220b can be inhibited and an appropriate amount of oxygen can be supplied to the oxide 220a and the oxide 220b. Thus, it is possible to inhibit excessive oxidation of the source region and the drain region and a decrease in the on-state current or field-effect mobility of the transistor 200E.

The insulator 255 preferably has a barrier property against hydrogen. Accordingly, diffusion of impurities contained in the conductors 242a2 and 242b2, such as hydrogen, into the oxide 220b can be prevented.

The insulator 250c also preferably has a barrier property against oxygen. The insulator 250c is provided between the conductor 260 and the channel formation region of the oxide 220 and between the insulator 285 and the conductor 260. Such a structure can inhibit diffusion of oxygen contained in the channel formation region of the oxide 220 into the conductor 260 and formation of oxygen vacancies in the channel formation region of the oxide 220. Moreover, oxygen contained in the oxide 220 and oxygen contained in the insulator 285 can be inhibited from diffusing into the conductor 260 and oxidizing the conductor 260. It is preferable that oxygen be less likely to pass through the insulator 250c than at least through the insulator 285. For example, a silicon nitride film is preferably used for the insulator 250c.

The insulator 250c preferably has a barrier property against hydrogen. Accordingly, diffusion of impurities contained in the conductor 260, such as hydrogen, into the oxide 220b can be prevented.

The insulator 275 also preferably has a barrier property against oxygen. The insulator 275 is provided between the insulator 285 and the conductor 242a and between the insulator 285 and the conductor 242b. With this structure, oxygen contained in the insulator 285 can be inhibited from diffusing into the conductor 242a and the conductor 242b. Thus, the conductor 242a and the conductor 242b can be inhibited from being oxidized by oxygen contained in the insulator 285, so that an increase in resistivity and a reduction in on-state current can be inhibited. It is preferable that oxygen be less likely to pass through the insulator 275 than at least through the insulator 285. For example, silicon nitride is preferably used for the insulator 275.

The insulator 275 preferably has a barrier property against hydrogen. Providing the insulator having a barrier property against hydrogen in the vicinity of each of the source region and the drain region in the oxide 220 can reduce the amount hydrogen diffusing from the source region and the drain region to the outside, so that a reduction in the hydrogen concentrations of the source region and the drain region can be inhibited. Thus, the source region and the drain region can be n-type regions.

With the above structure, the channel formation region can be an i-type or substantially i-type region, and the source region and the drain region can be n-type regions. Thus, a semiconductor device with favorable electrical characteristics can be provided. The semiconductor device with the above structure can have favorable electrical characteristics even when miniaturized or highly integrated. Miniaturization of the transistor 200E can improve the high frequency characteristics. Specifically, the cutoff frequency can be improved.

The insulator 250 functions as a gate insulator. The insulator 250 is provided in the opening formed in the insulator 285, together with the insulator 255 and the conductor 260. The thickness of the insulator 250 is preferably small for miniaturization of the transistor 200E. The thickness of each layer included in the insulator 250 is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm. Each of the layers included in the insulator 250 at least partly includes a region with the above-described thickness.

To form the insulator 250 having a small thickness, an ALD method is preferably used for deposition. Furthermore, in the case where the insulator 250 and the insulator 255 are provided in the opening in the insulator 285 and the like, an ALD method is preferably employed. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables deposition at a lower temperature.

The thickness of the insulator 255 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 255 has a thickness in the above range, excessive oxidation of the conductor 242a2 and the conductor 242b2 can be inhibited. In this case, at least part of the insulator 255 may have a region with the above-described thickness. When the thickness of the insulator 255 is set excessively large, the time for depositing the insulator 255 by an ALD method is long, which decreases the productivity; for this reason, the thickness of the insulator 255 is preferably in the above range.

A structure in which hydrogen is inhibited from entering the transistor 200E and the like is preferably employed for the semiconductor device illustrated in FIG. 21A and the like. For example, one or both of upper and lower insulators having a function of inhibiting diffusion of hydrogen is/are preferably provided to cover the transistor 200E and the like. Accordingly, each of the insulator 215, the insulator 221, the insulator 222, the insulator 282, and the insulator 283 preferably includes an insulator having a function of inhibiting diffusion of oxygen and impurities such as water and hydrogen. Examples of the insulator include aluminum oxide, magnesium oxide, hafnium oxide, zirconium oxide, oxide containing aluminum and hafnium (hafnium aluminate), oxide containing hafnium and zirconium (hafnium zirconium oxide), gallium oxide, silicon nitride, and silicon nitride oxide. For example, silicon nitride, which has a higher hydrogen barrier property, is preferably used for the insulator 283 and the insulator 221. For example, the insulator 282 preferably includes aluminum oxide or the like, which has a function of capturing or fixing hydrogen well. For example, hafnium oxide, which has high capability of capturing or fixing hydrogen and is a high permittivity (high-k) material, is preferably used for the insulator 222. With such a structure where the transistor 200E is surrounded by upper and lower insulators having a function of inhibiting diffusion of oxygen and impurities such as water and hydrogen, excess oxygen and hydrogen can be prevented from diffusing into the oxide semiconductor. Thus, the semiconductor device can have improved electrical characteristics and reliability.

Here, it is preferable that a region of the insulator 275 not overlapping with the oxide 220 be in contact with the insulator 222, a side end portion of the insulator 275 be in contact with the insulator 255, and an upper end portion of the insulator 255 and upper end portions of the insulator 250a to the insulator 250c be in contact with the insulator 282. With the above structure, in a region sandwiched between the insulator 283 and the insulator 221, the insulator 285 is separated from the oxide 220 by the insulator 275, the insulator 285 is separated from the insulator 250b by the insulator 255 and the insulator 250a, the conductor 260 is separated from the insulator 250b by the insulator 250c, and the conductor 242a2 and the conductor 242b2 are separated from the insulator 250b by the insulator 255 and the insulator 250a.

Accordingly, diffusion of impurities contained in the insulator 285, such as water and hydrogen, into the oxide 220 and the insulator 250b can be inhibited. Impurities such as water and hydrogen contained in the conductor 260 can be inhibited from diffusing into the oxide 220 through the insulator 250b. Impurities such as water and hydrogen contained in the conductor 242a2 and the conductor 242b2 can be inhibited from diffusing into the oxide 220 through the insulator 250b. For example, even when a contact plug is formed in contact with top surfaces of the conductor 242a2 and the conductor 242b2 and impurities such as water and hydrogen diffuse into the conductor 242a2 and the conductor 242b2 through the contact plug, the amount of impurities such as water and hydrogen diffusing into the oxide 220 can be reduced. Hydrogen contained in the insulator 250a and the insulator 250b can be captured and fixed in the insulator 282. With such a structure, the amount of hydrogen diffusing into the oxide semiconductor can be further reduced. Thus, the semiconductor device can have improved electrical characteristics and reliability.

In the transistor 200E, the conductor 205 is placed to overlap with the oxide 220 and the conductor 260. Here, the conductor 205 is preferably provided to be embedded in an opening portion formed in the insulator 216. Moreover, the conductor 205 is preferably provided to extend in the channel width direction as illustrated in FIG. 21A and FIG. 21C. With such a structure, the conductor 205 functions as a wiring when a plurality of transistors are provided.

As illustrated in FIG. 21B and FIG. 21C, the conductor 205 preferably includes the conductor 205a and the conductor 205b. The conductor 205a is provided in contact with the bottom surface and the sidewall of the opening portion. The conductor 205b is provided to fill a depressed portion that is defined by the conductor 205a and formed along the opening portion. Here, the top surface of the conductor 205 is level or substantially level with the top surface of the insulator 216.

When the conductor 205a is formed using a conductive material having a function of inhibiting diffusion of hydrogen, impurities such as hydrogen contained in the conductor 205b can be prevented from diffusing into the oxide 220 through the insulator 216 and the like. When a conductive material having a function of inhibiting diffusion of oxygen is used for the conductor 205a, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably contains titanium nitride. The conductor 205b is preferably formed using a conductive material containing tungsten, copper, or aluminum as its main component. For example, the conductor 205b preferably contains tungsten.

The conductor 205 can function as the second gate electrode. In that case, by changing a potential applied to the conductor 205 not in conjunction with but independently of a potential applied to the conductor 260, the threshold voltage (Vt) of the transistor 200E can be controlled. In particular, by applying a negative potential to the conductor 205, Vₜₕ of the transistor 200E can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is set in accordance with the electrical resistivity. The thickness of the insulator 216 is substantially equal to that of the conductor 205. Here, the conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, inhibiting diffusion of the impurities into the oxide 220.

The insulator 224 that is in contact with the oxide 220 preferably includes silicon oxide or silicon oxynitride, for example. Accordingly, oxygen can be supplied from the insulator 224 to the oxide 220, so that oxygen vacancies can be reduced.

The insulator 224 is preferably processed into an island shape in the same manner as the oxide 220. Thus, in the case where a plurality of the transistors 200E are provided, the insulators 224 in the transistors 200E have substantially the same size as each other. Accordingly, among the transistors 200E, the amount of oxygen supplied from the insulator 224 to the oxide 220 is substantially the same. This can reduce variations in electrical characteristics of the transistors 200E in the substrate plane. Note that the structure is not limited to this, and it is possible not to pattern the insulator 224 as in the case of the insulator 222.

A conductive material that is less likely to be oxidized or a conductive material having a function of inhibiting diffusion of oxygen is preferably used for each of the conductor 242a, the conductor 242b, and the conductor 260. Examples of the conductive material include a conductive material containing nitrogen and a conductive material containing oxygen. Thus, a decrease in the conductivity of the conductor 242a, the conductor 242b, and the conductor 260 can be inhibited.

The insulator 271a and the insulator 271b are inorganic insulators functioning as etching stoppers in the processing into the conductor 242a2 and the conductor 242b2 and protecting the conductor 242a2 and the conductor 242b2. Since the insulator 271a and the insulator 271b are respectively in contact with the conductor 242a and the conductor 242b, the insulator 271a and the insulator 271b are preferably inorganic insulators that are less likely to oxidize the conductors 242a and 242b. Thus, as illustrated in FIG. 22A, the insulator 271a preferably has a stacked-layer structure of an insulator 271al and an insulator 271a2 over the insulator 271al, and the insulator 271b preferably has a stacked-layer structure of an insulator 271b1 and an insulator 271b2 over the insulator 271b1. Here, the insulators 271a1 and 271b1 are preferably formed using the nitride insulator that can be used for the insulator 250c, so as not to easily oxidize the conductors 242a2 and 242b2. The insulators 271a2 and 271b2 are preferably formed using the oxide insulator that can be used for the insulator 250b, so as to function as etching stoppers. For example, silicon nitride can be used for the insulator 271al and the insulator 271b1, and silicon oxide can be used for the insulator 271a2 and the insulator 271b2.

Note that in this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor 200E has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 200E has the S-channel structure, the GAA structure, or the LGAA structure, the channel formation region that is formed at the interface between the oxide 220 and the gate insulator or in the vicinity of the interface can correspond to the entire bulk of the oxide 220. Accordingly, the density of current flowing through the transistor can be increased, which can be expected to increase the on-state current of the transistor or increase the field-effect mobility of the transistor.

In this embodiment, the insulator 224 with an island shape is provided as described above. Accordingly, as illustrated in FIG. 21C, at least part of the bottom surface of the conductor 260 can be positioned lower than the bottom surface of the oxide 220b. Thus, the conductor 260 can be provided to face the top surface and the side surface of the oxide 220b, so that an electric field of the conductor 260 can be applied to the top surface and the side surface of the oxide 220b. When the insulator 224 with an island shape is provided in this manner, the transistor 200E can have the S-channel structure.

The conductor 260 preferably includes the conductor 260a and the conductor 260b placed over the conductor 260a. For example, the conductor 260a is preferably placed to cover the bottom surface and the side surface of the conductor 260b. In this case, the conductor 260a is preferably formed using a conductive material that is less likely to be oxidized or a conductive material having a function of inhibiting diffusion of oxygen. When the conductor 260a has a function of inhibiting diffusion of oxygen, the conductivity of the conductor 260b can be inhibited from being lowered because of oxidation due to oxygen contained in the insulator 285 or the like. As the conductive material having a function of inhibiting diffusion of oxygen, titanium, titanium nitride, tantalum, tantalum nitride, ruthenium, or ruthenium oxide is preferably used, for example.

As the conductor 260b, a conductor having high conductivity is preferably used. For example, the conductor 260b can be formed using a conductive material containing tungsten, copper, or aluminum as its main component. The conductor 260b may have a stacked-layer structure; for example, a stacked-layer structure of titanium or titanium nitride and the above conductive material may be employed.

The insulator 216 and the insulator 285 each preferably have a lower permittivity than the insulator 222. When a material with a low permittivity is used for an interlayer film, parasitic capacitance generated between wirings can be reduced.

### Structure Example 3 of Semiconductor Device

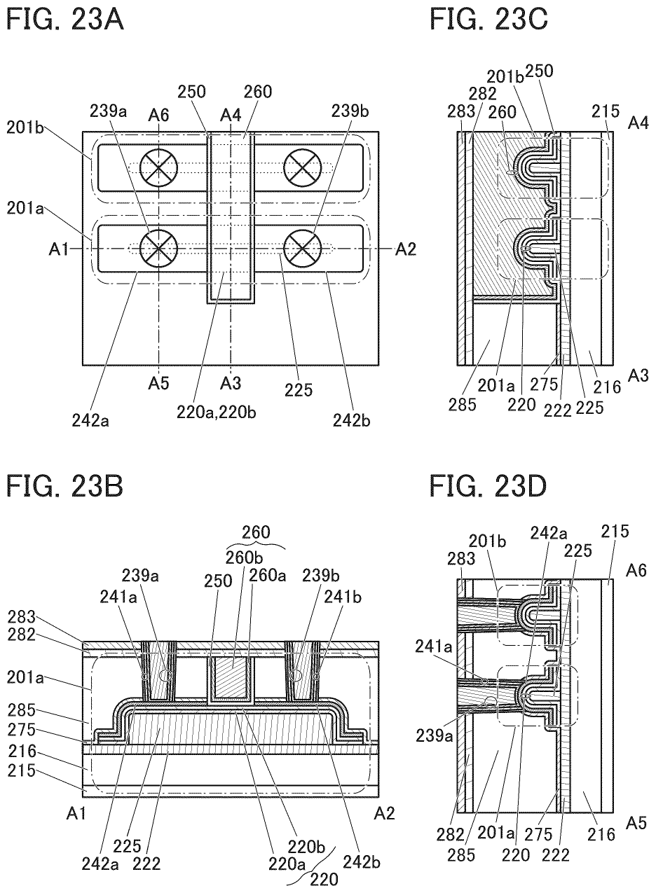

Next, an example of the semiconductor device of one embodiment of the present invention is described with reference to FIG. 23 to FIG. 25. The semiconductor device illustrated in FIG. 23 to FIG. 25 includes transistors 201a and 201b having structures different from those of the above-described transistors 200 and 200A to 200E.

Note that as for the transistors 201a and 201b, the above description can be referred to for components similar to those of the transistor 200E.

FIG. 23A to FIG. 23D are a plan view and cross-sectional views of the semiconductor device including the transistor 201a and the transistor 201b over a substrate (not illustrated). Note that since the transistor 201b has a structure similar to that of the transistor 201a, the components are shown with the same hatching patterns as those of the transistor 201a and are not especially denoted by reference numerals. Hereinafter, the transistor 201a and the transistor 201b are collectively referred to as a transistor 201, in some cases. Note that when a capacitor electrically connected to the transistor 201a and a capacitor electrically connected to the transistor 201b are provided in the semiconductor device described in this embodiment, the semiconductor device can function as two 1T (transistor) 1C (capacitor) memory cells and can also be used in a memory device.

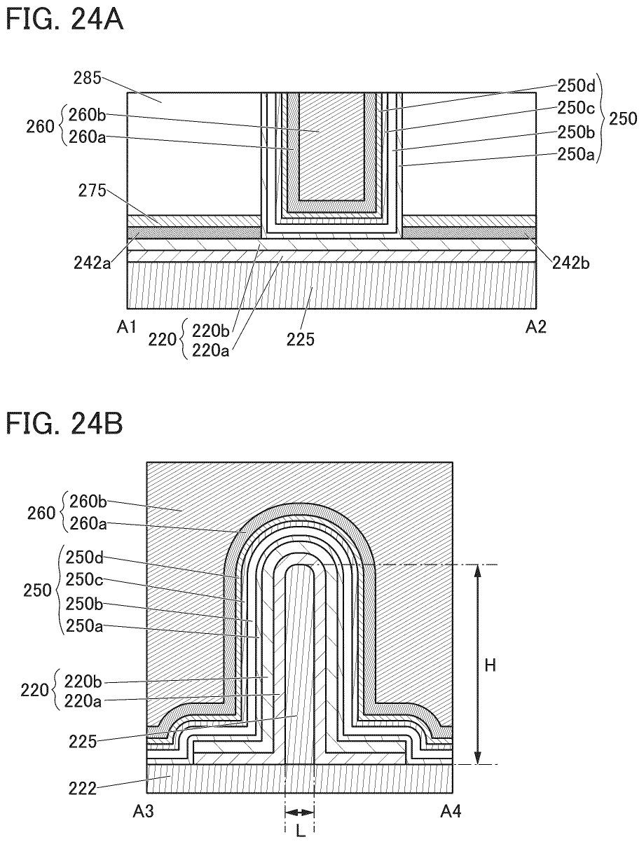

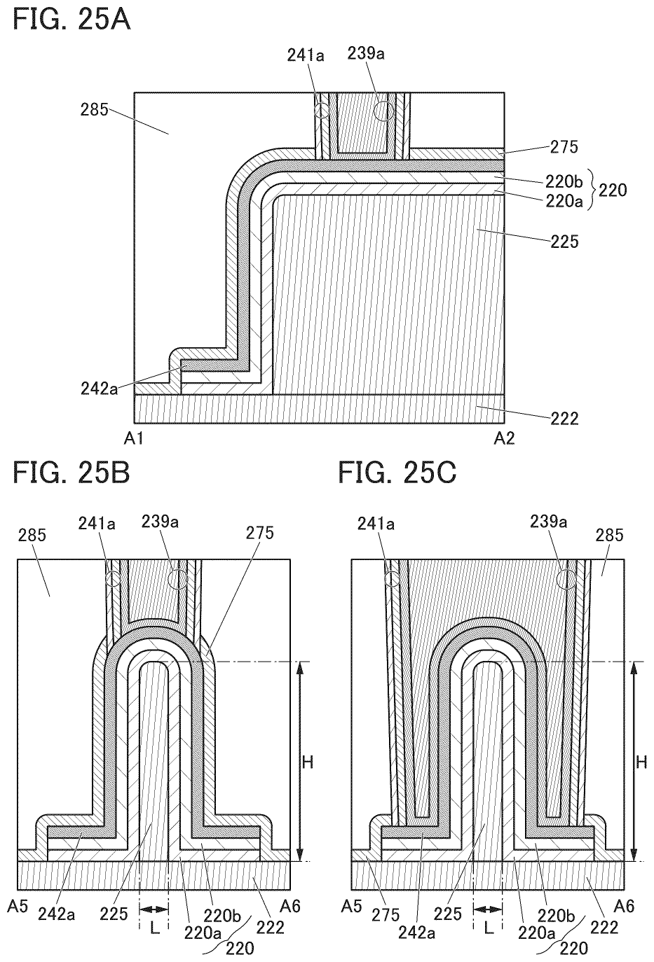

FIG. 23A is a plan view of the semiconductor device. FIG. 23B to FIG. 23D are cross-sectional views of the semiconductor device. Here, FIG. 23B is a cross-sectional view taken along the dashed-dotted line A1-A2 in FIG. 23A, and is also a cross-sectional view of the transistor 201a in the channel length direction. FIG. 23C is a cross-sectional view taken along the dashed-dotted line A3-A4 in FIG. 23A, and is also a cross-sectional view of the transistor 201a and the transistor 201b in the channel width direction. FIG. 23D is a cross-sectional view taken along the dashed-dotted line A5-A6 in FIG. 23A, and is also a cross-sectional view of the transistor 201a and the transistor 201b in the channel width direction. Here, the dashed-dotted line A1-A2 is orthogonal to the dashed-dotted line A3-A4 and the dashed-dotted line A5-A6, and the dashed-dotted line A3-A4 and the dashed-dotted line A5-A6 are parallel to each other. For the sake of clarity of the drawing, some components are omitted in the plan view of FIG. 23A. FIG. 24A is an enlarged view of the conductor 260 and the vicinity thereof in FIG. 23B. FIG. 24B is an enlarged view of an insulator 225 and the vicinity thereof in FIG. 23C. FIG. 25A is an enlarged view of the conductor 242a and the vicinity thereof in FIG. 23B. FIG. 25B is an enlarged view of the insulator 225 and the vicinity thereof in FIG. 23D.

The semiconductor device illustrated in FIG. 23A to FIG. 23D includes the insulator 215, the insulator 216, and the insulator 222 that are stacked, and further includes the insulator 225 over the insulator 222, the oxide 220 (the oxide 220a and the oxide 220b) over the insulator 225 and the insulator 222, a conductor 242 (the conductor 242a and the conductor 242b) over the oxide 220, the insulator 250 over the oxide 220, and the conductor 260 (the conductor 260a and the conductor 260b) over the insulator 250.

The insulator 275 is provided over the conductor 242, and the insulator 285 is provided over the insulator 275. The insulator 250 and the conductor 260 are placed in the opening provided in the insulator 285 and the insulator 275. The insulator 282 is provided over the insulator 285 and the conductor 260. The insulator 283 is provided over the insulator 282.

An insulator 241a is provided in contact with an inner wall of the opening in the insulator 285 and the like, and a conductor 239a is provided in contact with the insulator 241a. The conductor 239a is in contact with the conductor 242a. An insulator 241b is provided in contact with an inner wall of the opening in the insulator 285 and the like, and a conductor 239b is provided in contact with the insulator 241b. The conductor 239b is in contact with the conductor 242b. Hereinafter, the conductor 239a and the conductor 239b might be collectively referred to as a conductor 239. The insulator 241a and the insulator 241b are sometimes collectively referred to as an insulator 241.

Note that the insulator 215, the insulator 216, the insulator 222, the insulator 225, the oxide 220, the conductor 242a, the conductor 242b, the insulator 275, the insulator 285, the insulator 250, the conductor 260, the insulator 241, the conductor 239, the insulator 282, and the insulator 283 may each have a single-layer structure or a stacked-layer structure.

The oxide 220 includes a region functioning as the channel formation region of the transistor 201. The conductor 260 includes a region functioning as the first gate electrode (the upper gate electrode) of the transistor 201. The insulator 250 includes a region functioning as the first gate insulator of the transistor 201.

Although the transistors 201a and 201b each having a single-gate structure not including a back gate are described as an example in this embodiment, the present invention is not limited thereto. Each of the transistors 200a and 200b may be a dual-gate transistor including a back gate. For example, like the transistor 200E described above, the transistor 201 may include the conductor 205 (the conductor 205a and the conductor 205b) provided to be embedded in the insulator 216. The insulator 221 may be further included. In that case, the conductor 205 includes a region functioning as the second gate electrode (the lower gate electrode) of the transistor 201. The insulator 222 and the insulator 221 each include a region functioning as the second gate insulator of the transistor 201.

Here, as illustrated in FIG. 24B, the oxide 220 in the transistor 201 has a half-folded structure with the insulator 225 therebetween. Thus, a portion of the conductor 260 at a position that faces the oxide 220 with the insulator 225 in between functions as the second gate electrode in some cases.

The conductor 242a includes a region functioning as one of a source electrode and a drain electrode of the transistor 201. The conductor 242b includes a region functioning as the other of the source electrode and the drain electrode of the transistor 201. The conductor 239a functions as a plug connected to the conductor 242a. The conductor 239b functions as a plug connected to the conductor 242b.

The oxide 220 preferably includes the oxide 220a covering the insulator 225 and the oxide 220b over the oxide 220a. Here, the oxide 220a is in contact with the top surface and the side surface of the insulator 225 and the top surface of the insulator 222. The oxide 220a and the oxide 220b are provided to cover the insulator 225 having a high aspect ratio, as illustrated in FIG. 24B and the like. Thus, the oxide 220a and the oxide 220b are preferably formed by a film formation method that offers favorable coverage, such as an ALD method. Here, as illustrated in FIG. 24B, the oxide 220a and the oxide 220b are formed to be folded in half so as to sandwich the insulator 225 in the cross section in the channel width direction. With such a structure, the channel formation region of the transistor 201 can be formed in an upper portion, the side surface on the A3 side, and the side surface on the A4 side of the insulator 225; thus, the channel width per unit area can be increased.

Including the oxide 220a under the oxide 220b makes it possible to inhibit diffusion of impurities into the oxide 220b from components formed below the oxide 220a.

Note that the oxide 220 is not limited to having a two-layer structure of the oxide 220a and the oxide 220b. The oxide 220 may have a single-layer structure of the oxide 220b or a stacked-layer structure of three or more layers, for example.

The oxide 220b includes a channel formation region of the transistor 201 and a source region and a drain region provided to sandwich the channel formation region. At least part of the channel formation region overlaps with the conductor 260. The source region overlaps with the conductor 242a, and the drain region overlaps with the conductor 242b. Note that the source region and the drain region can be interchanged with each other.

A metal oxide functioning as a semiconductor (hereinafter also referred to as an oxide semiconductor) is preferably used for the oxide 220 (the oxide 220a and the oxide 220b).

At least one layer of the oxide 220 is preferably formed by the film formation method of the metal oxide of one embodiment of the present invention. In particular, the oxide 220b including the channel formation region is preferably formed by the film formation method of the metal oxide of one embodiment of the present invention.

When at least one layer of the oxide 220 is formed by an ALD method, a metal oxide with good coverage can be formed on a top surface, a bottom surface, a side surface, and a surface with a slope of a structure body. In other words, a metal oxide that has a substantially uniform thickness in the normal direction can be formed on each deposition surface. As for the metal oxide that is formed on each of the top surface, the bottom surface, the side surface, and the surface with the slope of the structure body, the ratio of the minimum thickness to the maximum thickness can be greater than or equal to 0.5 and less than or equal to 1, preferably greater than or equal to 0.7 and less than or equal to 1, further preferably greater than or equal to 0.8 and less than or equal to 1, still further preferably greater than or equal to 0.9 and less than or equal to 1.

For example, in the oxide 220 illustrated in FIG. 24B, the ratio of the thickness of the second portion provided along the side surface of the insulator 225 to the thickness of the first portion provided along the top surface of the insulator 222 is preferably greater than or equal to 0.7 and less than or equal to 1.3, further preferably greater than or equal to 0.8 and less than or equal to 1.2, still further preferably greater than or equal to 0.9 and less than or equal to 1.1.

The preferable range of the aluminum concentration and the preferable range of the carbon concentration in the channel formation region of the oxide 220 are as described above.

For example, both the oxide 220a and the oxide 220b are preferably formed by an ALD method. Alternatively, it is preferable that the oxide 220a be formed by a sputtering method and the oxide 220b be formed by an ALD method.

As materials that can be used for each of the insulators and each of the conductors included in the semiconductor device illustrated in FIG. 23A to FIG. 23D, the materials given in sections [Insulator] and [Conductor] can be given. The above description of <Structure example 2 of semiconductor device> can also be referred to. Differences from the above-described structures are mainly described below.

As illustrated in FIG. 24A, the insulator 250 may have a four-layer structure. The insulator 250 illustrated in FIG. 24A preferably has a stacked-layer structure of the insulator 250a in contact with the oxide 220, the insulator 250b over the insulator 250a, the insulator 250c over the insulator 250b, and an insulator 250d over the insulator 250c. In this case, each of the insulator 250a and the insulator 250c preferably has a function of capturing or fixing hydrogen.

For the insulator 250a and the insulator 250c, for example, a metal oxide such as magnesium oxide or an oxide containing one or both of aluminum and hafnium is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high permittivity (high-k) material is preferably used for the insulator 250a and the insulator 250c. An example of the high-k material is an oxide containing one or both of aluminum and hafnium. With use of the high-k material for the insulator 250a and the insulator 250c, a gate potential applied during the operation of the transistor can be reduced while the physical thickness of the gate insulator is maintained. In addition, the equivalent oxide thickness (EOT) of the insulator functioning as the gate insulator can be reduced.

For the insulator 250a and the insulator 250c, an oxide containing one or both of aluminum and hafnium is preferably used, and an oxide that has an amorphous structure and contains one or both of aluminum and hafnium is further preferably used.

In this embodiment, aluminum oxide is used for the insulator 250a illustrated in FIG. 24A. The aluminum oxide preferably has an amorphous structure. Here, when the insulator 250a is provided in contact with the oxide 220b, hydrogen contained in the oxide 220b and the like can be captured or fixed more effectively.

In this embodiment, hafnium oxide is used for the insulator 250c illustrated in FIG. 24A. Here, when the insulator 250c is provided between the insulator 250b and the insulator 250d, hydrogen contained in the insulator 250b and the like can be captured or fixed more effectively.

An insulator having a thermally stable structure, such as silicon oxide or silicon oxynitride, is preferably used for the insulator 250b.

In order to inhibit oxidation of the conductor 242a, the conductor 242b, and the conductor 260, a barrier insulator against oxygen is preferably provided in the vicinity of each of the conductor 242a, the conductor 242b, and the conductor 260. The insulator corresponds to, for example, the insulator 250a, the insulator 250d, the insulator 250c, and the insulator 275.

The insulator 250d also preferably has a barrier property against oxygen. The insulator 250d is provided between the conductor 260 and the channel formation region of the oxide 220 and between the insulator 285 and the conductor 260. Such a structure can inhibit diffusion of oxygen contained in the channel formation region of the oxide 220 into the conductor 260 and formation of oxygen vacancies in the channel formation region of the oxide 220. Moreover, oxygen contained in the oxide 220 and oxygen contained in the insulator 285 can be inhibited from diffusing into the conductor 260 and oxidizing the conductor 260. It is preferable that oxygen be less likely to pass through the insulator 250d than at least through the insulator 285. For example, a silicon nitride film is preferably used for the insulator 250d. In this case, the insulator 250d is an insulator that contains at least nitrogen and silicon.

The insulator 250d preferably has a barrier property against hydrogen. Accordingly, diffusion of impurities contained in the conductor 260, such as hydrogen, into the oxide 220b can be prevented.

The insulator 250a to the insulator 250d function as part of the gate insulator. The insulator 250a to the insulator 250d are provided in the opening formed in the insulator 285 and the like, together with the conductor 260. The thicknesses of the insulator 250a to the insulator 250d are preferably small for miniaturization of the transistor 201. The thickness of each of the insulator 250a to the insulator 250d is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm. Note that at least part of each of the insulator 250a to the insulator 250d includes a region having the above-described thickness.

Although the case where the insulator 250 has a four-layer structure of the insulator 250a to the insulator 250d is described above, the present invention is not limited thereto. The insulator 250 can have a structure including at least one of the insulator 250a to the insulator 250d. When the insulator 250 is formed of one, two, or three layer(s) of the insulator 250a to the insulator 250d, the fabrication process of the semiconductor device can be simplified and the productivity can be increased.

The insulator 225 is formed over and in contact with the insulator 222. The insulator 225 has a shape with a high aspect ratio in a cross-sectional view in the channel width direction, as illustrated in FIG. 24B and FIG. 25B. Here, the aspect ratio of the insulator 225 in the cross-sectional view in the channel width direction refers to the ratio between a length L of the insulator 225 in the A3-A4 direction (also referred to as a width L of the insulator 225) and a length H of the insulator 225 in a direction perpendicular to the formation surface (e.g., the insulator 222) of the insulator 225 (also referred to as a height H of the insulator 225). In the insulator 225, the height H of the insulator 225 is at least longer than the width L of the insulator 225. The height H of the insulator 225 is greater than 1 time, preferably greater than or equal to 2 times, further preferably greater than or equal to 5 times, still further preferably greater than or equal to 10 times the width L of the insulator 225. The height H of the insulator 225 is preferably less than or equal to 20 times the width L of the insulator 225.

The oxide 220a, the oxide 220b, and the conductor 242 are provided to cover the insulator 225 having such a high aspect ratio. In the transistor 201, as illustrated in FIG. 24B, the oxide 220a and the oxide 220b are provided to be folded in half to sandwich the insulator 225, and the insulator 250 and the conductor 260 are provided to cover the oxide 220b. Thus, in the cross-sectional view in the channel width direction, the oxide 220 and the conductor 260 face each other with the insulator 250 therebetween in the upper portion, the side surface on the A3 side, and the side surface on the A4 side of the insulator 225. That is, the upper portion, the side surface on the A3 side, and the side surface on the A4 side of the insulator 225 each function as a channel formation region. Thus, the channel width of the transistor 201 is greater by the side surface on the A3 side and the side surface on the A4 side of the insulator 225 than that of the case where the insulator 225 is not provided.

The transistor 201 can have a favorable on-state current, favorable field-effect mobility, favorable frequency characteristics, and the like when the channel width is increased as described above. Thus, a semiconductor device with a high operation speed can be provided. In addition, the operation speed of a memory device including the semiconductor device can be increased. In the above structure, providing the insulator 225 enables the channel width to be increased without an increase in the area occupied by the transistor 201. Accordingly, miniaturization and high integration of the semiconductor device can be achieved. It is also possible to increase the memory capacity of the memory device including the semiconductor device.

For the insulator 225, an insulating material that can be used for the insulator 222, the insulator 285, the insulator 250, or the like can be used. Since the insulator 225 has a shape with a high aspect ratio, the insulator 225 is preferably formed in a sidewall shape on the side surface of a sacrificial layer (a structure body used in the manufacturing process). Thus, the insulator 225 is preferably deposited by an ALD method that provides favorable coverage. For example, hafnium oxide deposited by a thermal ALD method can be used for the insulator 225.

When the insulator 225 is formed to have a sidewall shape in contact with the side surface of the sacrificial layer in this manner, the insulator 225 of the transistor 201a and the insulator 225 of the transistor 201b can be formed at the same time as illustrated in FIG. 23A and the like. When the two insulators 225 are formed in this manner, the distance between the two insulators 225 can be determined by the size of the sacrificial layer. Thus, the distance between the insulators 225 can be reduced and the area occupied by the transistor 201a and the transistor 201b can be reduced, in which case high integration of the semiconductor device can be achieved.

Note that the insulator 225 is not limited to only an insulating material in a strict sense. For example, a metal oxide with a relatively high insulating property can also be used. For example, a metal oxide that can be used as the oxide 220a may be used.

The upper portion of the insulator 225 may have a curved shape. Such a curved shape can prevent formation of defects such as voids in the oxide 220a, the oxide 220b, and the conductor 242 in the vicinity of the upper portion of the insulator 225. Although the upper portion of the insulator 225 has a symmetrical structure with a curved shape on both the A3 side (the A5 side) and the A4 side (the A6 side) in FIG. 24B, FIG. 25B, and the like, the present invention is not limited thereto. For example, the upper portion of the insulator 225 may have an asymmetrical structure with a curved shape only on the A3 side (the A5 side).

The conductor 242a and the conductor 242b are placed apart from each other and over and in contact with the oxide 220b. As illustrated in FIG. 25A, FIG. 25B, and the like, the conductor 242 is provided to cover the insulator 225 having a high aspect ratio. Thus, the conductor 242 is preferably formed by a film formation method that offers favorable coverage, such as an ALD method or a CVD method.

Here, the oxide 220a, the oxide 220b, and the conductor 242a are provided to be folded in half to sandwich the insulator 225 in the vicinity of the source or the drain of the transistor 201a as illustrated in FIG. 25B. Accordingly, the conductor 242a is in contact with the oxide 220b in the upper portion, the side surface on the A5 side, and the side surface on the A6 side of the insulator 225 in a cross-sectional view in the channel width direction. Thus, the contact area between the conductor 242a and the oxide 220b is larger by the side surface on the A5 side and the side surface on the A6 side of the insulator 225 than that of the case where the insulator 225 is not provided. Although FIG. 25B illustrates the conductor 242a and its vicinity, the same applies to the conductor 242b. That is, the contact area between the conductor 242b and the oxide 220b increases like that between the conductor 242a and the oxide 220b.

The increase in the contact area between the conductor 242 and the oxide 220b as described above enables the transistor 201 to have a favorable on-state current, favorable frequency characteristics, and the like without an increase in the area occupied by the transistor 201. Thus, a semiconductor device with a high operation speed can be provided. In addition, the operation speed of a memory device including the semiconductor device can be increased. Accordingly, miniaturization and high integration of the semiconductor device can be achieved. It is also possible to increase the memory capacity of the memory device including the semiconductor device.

As illustrated in FIG. 23B and FIG. 23C, the conductor 260 is placed in the opening formed in the insulator 285, the insulator 275, the conductor 242a, and the conductor 242b. The conductor 260 is provided in the opening to cover the top surface of the insulator 222, the side surface of the oxide 220a, the side surface of the oxide 220b, and the top surface of the oxide 220b, with the insulator 250 therebetween. The top surface of the conductor 260 is placed to be level with or substantially level with the uppermost portion of the insulator 250 and the top surface of the insulator 285.

Note that the sidewall of the opening in which the conductor 260 and the insulator 250 are placed may be perpendicular or substantially perpendicular to the top surface of the insulator 222 or may have a tapered shape. The tapered shape of the sidewall can improve the coverage with the insulator 250 and the like provided in the opening in the insulator 285, whereby defects such as voids can be reduced.

The conductor 260 functions as the first gate electrode of the transistor 201. Here, the conductor 260 is preferably provided to extend in the channel width direction as illustrated in FIG. 23A and FIG. 23C. With such a structure, the conductor 260 functions as a wiring when a plurality of transistors are provided.

FIG. 23B and the like illustrate the conductor 260 having a two-layer structure. Here, the conductor 260 preferably includes the conductor 260a and the conductor 260b placed over the conductor 260a. For example, the conductor 260a is preferably placed to cover the bottom surface and the side surface of the conductor 260b. In this case, a conductive material that is less likely to be oxidized or a conductive material having a function of inhibiting diffusion of oxygen is preferably used for the conductor 260a.

In the transistor 201, the conductor 260 is formed in a self-aligned manner to fill the opening formed in the insulator 285 and the like. Here, the side surface of the insulator 285 in the opening is aligned or substantially aligned with the side surface of the conductor 242a and the side surface of the conductor 242b. Thus, the conductor 260 can be placed to overlap with a region between the conductor 242a and the conductor 242b without alignment.

Each of the conductor 239a and the conductor 239b is formed in an opening in the insulator 275, the insulator 285, the insulator 282, and the insulator 283. The bottom surface of the conductor 239a is in contact with the top surface of the conductor 242a, and the bottom surface of the conductor 239b is in contact with the top surface of the conductor 242b. Here, the level of the top surface of the conductor 239 and the level of the top surface of the insulator 283 are substantially the same.

For the conductor 239, a conductive material including tungsten, copper, or aluminum as its main component is preferably used. The conductor 239, the conductor 239 may have a stacked-layer structure in which the first conductor is provided in contact with the side surface of the insulator 241 and the second conductor is provided on the inner side of the first conductor. In that case, the above-described material can be used for the second conductor.

In the case where the conductor 239 has a stacked-layer structure, a conductive material having a function of inhibiting passage of impurities such as water and hydrogen is preferably used for the first conductor placed in the vicinity of the insulator 283, the insulator 282, the insulator 285, and the insulator 275. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. With such a structure, impurities such as water and hydrogen included in a layer above the insulator 283 can be inhibited from entering the oxide 220 through the conductor 239a and the conductor 239b.

Each of the insulator 241a and the insulator 241b is formed in contact with an inner wall of the opening in the insulator 275, the insulator 285, the insulator 282, and the insulator 283. The inner side surface of the insulator 241a is in contact with the conductor 239a, and the inner side surface of the insulator 241b is in contact with the conductor 239b.

For the insulator 241, a barrier insulating film that can be used for the insulator 275 or the like may be used. For the insulator 241, for example, an insulator such as silicon nitride, aluminum oxide, or silicon nitride oxide may be used. With the provision of the insulator 241, impurities such as water and hydrogen included in the insulator 285 or the like can be inhibited from entering the oxide 220 through the conductor 239a and the conductor 239b. In particular, silicon nitride is suitable because of its high blocking property against hydrogen. Furthermore, oxygen included in the insulator 285 can be prevented from being absorbed by the conductor 239a and the conductor 239b.

When the insulator 241 has a stacked-layer structure illustrated in FIG. 23B, a first insulator in contact with an inner wall of the opening formed in the insulator 285 and the like and a second insulator on the inner side of the first insulator are preferably formed using a combination of an oxygen-barrier insulating film and a hydrogen-barrier insulating film.

For example, aluminum oxide deposited by a thermal ALD method is used for the first insulator and silicon nitride deposited by a PEALD method is used for the second insulator. With this structure, oxidation of the conductor 239 can be inhibited, and hydrogen can be inhibited from entering the conductor 239.

Although the structure in which the insulator 241 has a stacked-layer structure of two layers is described above, the present invention is not limited thereto. For example, the insulator 241 may have a single-layer structure or a stacked-layer structure of three or more layers. Although the structure in which the conductor 239 has a stacked-layer structure of two layers is described above, the present invention is not limited thereto. For example, the conductor 239 may have a single-layer structure or a stacked-layer structure of three or more layers.

Although FIG. 25B and the like illustrate a structure in which the conductor 239a is in contact with the conductor 242a only above an upper end portion of the insulator 225, the present invention is not limited thereto. For example, as illustrated in FIG. 25C, a structure may be employed in which the conductor 239a covers the insulator 225 and the oxide 220a, the oxide 220b, and the conductor 242a that are folded in half to sandwich the insulator 225. Accordingly, the conductor 239a is in contact with the conductor 242a in the upper portion, the side surface on the A5 side, and the side surface on the A6 side of the insulator 225 in a cross-sectional view in the channel width direction. Thus, the contact area between the conductor 239a and the conductor 242a is larger by the side surface on the A5 side and the side surface on the A6 side of the insulator 225 than that of the case where the insulator 225 is not provided. Although FIG. 25C illustrates the conductor 239a, the conductor 242a, and their vicinities, the same applies to the conductor 239b and the conductor 242b. That is, the contact area between the conductor 239b and the conductor 242b increases like that between the conductor 239a and the conductor 242a.

The increase in the contact area between the conductor 239 and the conductor 242 as described above enables the transistor 201 to have a favorable on-state current, favorable frequency characteristics, and the like without a significant increase in the area occupied by the transistor 201. Thus, a semiconductor device with a high operation speed can be provided. In addition, the operation speed of a memory device including the semiconductor device can be increased. Accordingly, miniaturization and high integration of the semiconductor device can be achieved. It is also possible to increase the memory capacity of the memory device including the semiconductor device.

### Structure Example 2 of Memory Device

Also in the case where a planar transistor such as the transistor 200E is used in the memory device, a structure in which a transistor and a capacitor overlap with each other can be employed.

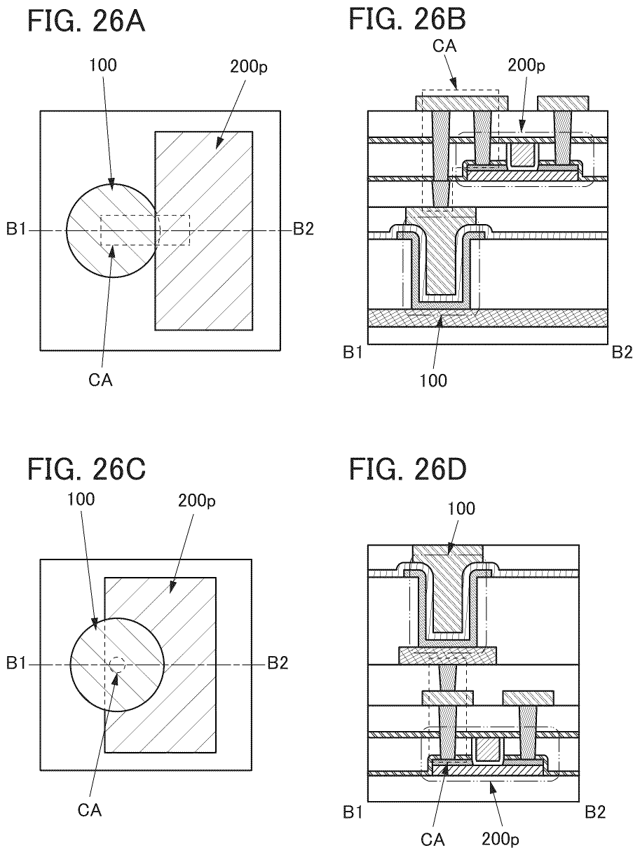

FIG. 26A to FIG. 26D illustrate examples of memory cells each including a planar transistor and a capacitor.

FIG. 26A is a plan view schematically illustrating the arrangement of a transistor 200p in the case of using a planar transistor and the capacitor 100 provided below the transistor 200p in a cell. FIG. 26B is a cross-sectional view taken along the dashed-dotted line B1-B2 in FIG. 26A.

In the case where the capacitor 100 is provided below the transistor 200p as illustrated in FIG. 26A and FIG. 26B, a component CA such as a wiring or a plug that connects a source electrode or a drain electrode of the transistor 200p and one electrode (an upper electrode) of the capacitor 100 is provided.

FIG. 26C is a plan view schematically illustrating the arrangement of the transistor 200p and the capacitor 100 provided above the transistor 200p in the memory cell. FIG. 26C is a cross-sectional view taken along the dashed-dotted line B1-B2 in FIG. 26D.

In the case where the capacitor 100 is provided above the transistor 200p as illustrated in FIG. 26C and FIG. 26D, the component CA such as a wiring or a plug that connects the source electrode or the drain electrode of the transistor 200p and one electrode (a lower electrode) of the capacitor 100 is provided. In FIG. 26C and FIG. 26D, the component CA can be placed in a region where the transistor 200p and the capacitor 100 overlap with each other. Such a structure is more advantageous for miniaturization than that in the case where the capacitor 100 is provided below the transistor 200p.

### Structure Example 3 of Memory Device

The memory cell 150 including the transistor 200 and the capacitor 100 described in this embodiment can be used as a memory cell of the memory device. The transistor 200 is a transistor in which a channel is formed in a semiconductor layer including an oxide semiconductor. Since the transistor 200 has a low off-state current, a memory device that uses the transistor 200 can retain stored contents for a long time. In other words, such a memory device does not require refresh operation or has extremely low frequency of the refresh operation, which leads to a sufficient reduction in power consumption of the memory device. The transistor 200 also has high frequency characteristics and thus enables high-speed reading and writing of the memory device.

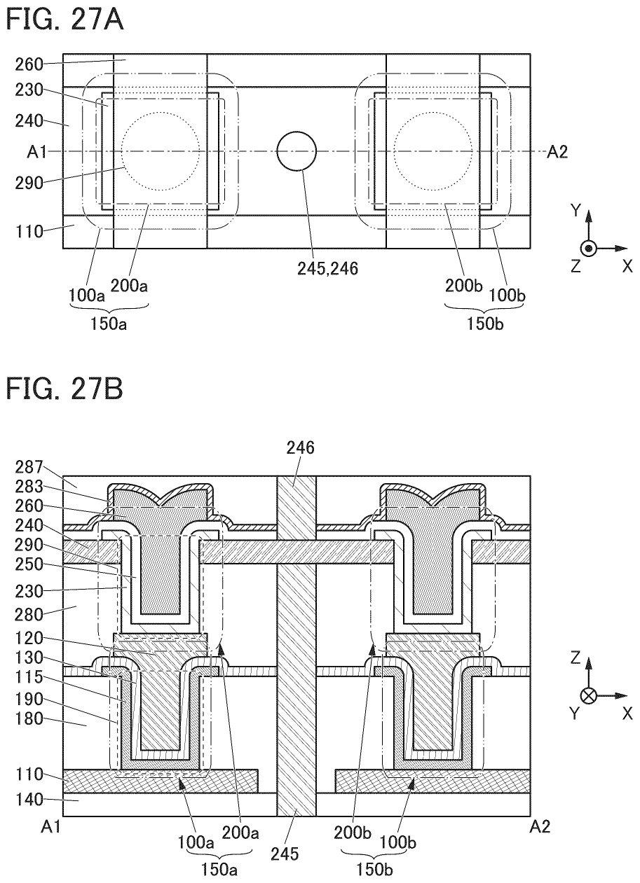

An example of a memory device in which two memory cells 150 (hereinafter referred to as a memory cell 150a and a memory cell 150b) are connected to a common wiring is described with reference to FIG. 27A and FIG. 27B. FIG. 27A is a plan view of the memory device. FIG. 27B is a cross-sectional view of a portion indicated by the dashed-dotted line A1-A2 in FIG. 27A. For the sake of clarity of the drawing, some components are omitted in the plan view of FIG. 27A.

Here, the memory cell 150a and the memory cell 150b illustrated in FIG. 27A and FIG. 27B each have a structure similar to that of the memory cell 150. The memory cell 150a includes a capacitor 100a and a transistor 200a, and the memory cell 150b includes a capacitor 100b and a transistor 200b. Thus, in the memory device illustrated in FIG. 27A and FIG. 27B, components having the same functions as the components of the memory device illustrated in FIG. 15 are denoted by the same reference numerals. In addition, the materials described in detail in <Structure example of memory device> can be used as component materials of the memory devices also in this section.

As illustrated in FIG. 27A and FIG. 27B, the conductor 260 functioning as the wiring WL is provided in each of the memory cell 150a and the memory cell 150b. The conductor 240 functioning as part of the wiring BL is provided to be shared by the memory cell 150a and the memory cell 150b. That is, the conductor 240 is in contact with the oxide semiconductor 230 of the memory cell 150a and the oxide semiconductor 230 of the memory cell 150b.

Here, the memory device illustrated in FIG. 27A and FIG. 27B includes a conductor 245 and a conductor 246 functioning as plugs (also can be referred to as connection electrodes) electrically connected to the memory cell 150a and the memory cell 150b. The conductor 245 is placed in an opening formed in the insulator 180, the insulator 280, and the insulator 140 and is in contact with the bottom surface of the conductor 240. The conductor 246 is placed in an opening portion formed in the insulator 287, the insulator 283, and the insulator 250 and is in contact with the top surface of the conductor 240. In addition, a conductive material or the like usable for the conductor 240 can be used for the conductor 245 and the conductor 246.

The insulator 287 functions as an interlayer film and thus preferably has low relative permittivity. When a material with low relative permittivity is used for an interlayer film, parasitic capacitance generated between wirings can be reduced. As the insulator 287, a single layer or stacked layers of insulators containing any of the materials with low relative permittivity described in the above-described section [Insulator] can be used.

The concentration of impurities such as water and hydrogen in the insulator 287 is preferably reduced. This can inhibit entry of impurities such as water and hydrogen into the channel formation region of the oxide semiconductor 230.

Here, the conductor 245 and the conductor 246 function as plugs or wirings for electrically connecting the memory cell 150a and the memory cell 150b to a circuit element such as a switch, a transistor, a capacitor, an inductor, a resistor, or a diode, a wiring, an electrode, or a terminal. For example, the conductor 245 can be electrically connected to a sense amplifier (not illustrated) provided below the memory device illustrated in FIG. 27, and the conductor 246 can be electrically connected to a similar memory device (not illustrated) provided above the memory device illustrated in FIG. 27. In that case, the conductor 245 and the conductor 246 function as part of the wiring BL. When the memory device or the like is provided above or below the memory device illustrated in FIG. 27 in this manner, the memory capacity per unit area can be increased.

The memory cell 150a and the memory cell 150b have a line-symmetric structure with a perpendicular bisector of the dashed-dotted line A1-A2 as the symmetric axis. Thus, the transistor 200a and the transistor 200b are also placed symmetrically with the conductor 245 and the conductor 246 therebetween. Here, the conductor 240 has a function of the other of the source electrode and the drain electrode of the transistor 200a and a function of one of a source electrode and a drain electrode of the transistor 200b. The transistor 200a and the transistor 200b share the conductor 245 and the conductor 246 functioning as plugs. Accordingly, when the two transistors and the plug are connected as described above, a memory device that can be miniaturized or highly integrated can be provided.

Note that the conductor 110 functioning as the wiring PL may be provided in each of the memory cell 150a and the memory cell 150b or may be provided to be shared by the memory cell 150a and the memory cell 150b. However, as illustrated in FIG. 27B, the conductor 110 is provided to be apart from the conductor 245 so that the conductor 110 and the conductor 245 are not short-circuited.

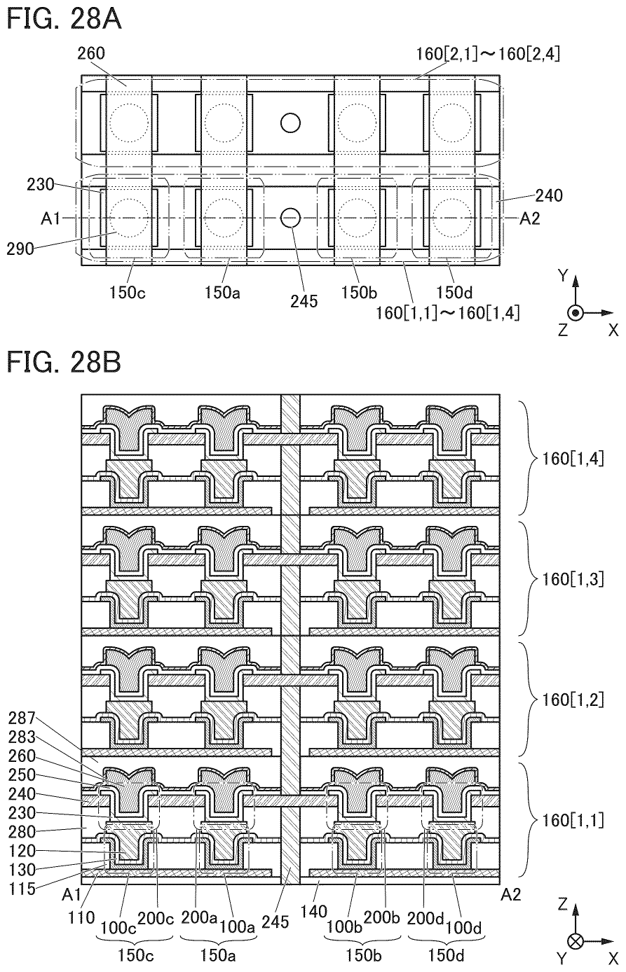

Note that the memory cells 150 can be three-dimensionally arranged in a matrix to form a memory cell array. As an example of the memory cell array, FIG. 28A and FIG. 28B illustrate an example of a memory device in which 4×2×4 memory cells 150 are arranged in the X direction, the Y direction, and the Z direction. FIG. 28A is a plan view of the memory device. In addition, FIG. 28B is a cross-sectional view of a portion indicated by the dashed-dotted line A1-A2 in FIG. 28A. For the sake of clarity of the drawing, some components are omitted in the plan view in FIG. 28A.

Here, the memory cell 150a to the memory cell 150d illustrated in FIG. 28A and FIG. 28B each have a structure similar to that of the memory cell 150. The memory cell 150a includes the capacitor 100a and the transistor 200a, the memory cell 150b includes the capacitor 100b and the transistor 200b, the memory cell 150c includes a capacitor 100c and a transistor 200c, and the memory cell 150d includes a capacitor 100d and a transistor 200d. Thus, in the memory device illustrated in FIG. 28A and FIG. 28B, components having the same functions as the components of the memory device illustrated in FIG. 15 are denoted by the same reference numerals. Note that the materials described in detail in <Structure example of memory device> can be used as component materials of the memory devices also in this section.

Hereinafter, a memory device including the memory cell 150a to the memory cell 150d is referred to as a memory unit. The memory device illustrated in FIG. 28A and FIG. 28B include a memory unit 160[1,1] to a memory unit 160[2,4]. Hereinafter, the memory unit 160[1,1] t to the memory unit 160[2,4] are collectively referred to as a memory unit 160 in some cases. The memory unit 160[1,2] is provided over the memory unit 160[1,1], the memory unit 160[1,3] is provided over the memory unit 160[1,2], and the memory unit 160[1,4] is provided over the memory unit 160[1,3]. The memory unit 160[2,1] is provided adjacent to the memory unit 160[1,1] in the Y direction. The memory unit 160[2,2] is provided over the memory unit 160[2,1], the memory unit 160[2,3] is provided over the memory unit 160[2,2], and the memory unit 160[2,4] is provided over the memory unit 160[2,3].

In the memory unit 160, as illustrated in FIG. 28B, the memory cell 150c is placed outside the memory cell 150a with the conductor 245 as the center, and the memory cell 150d is placed outside the memory cell 150b. In other words, the memory unit 160 can be regarded as a memory device in which the memory cell 150c is provided adjacent to the memory cell 150a and the memory cell 150d is provided adjacent to the memory cell 150b in the memory device illustrated in FIG. 27.

As illustrated in FIG. 28A and FIG. 28B, the conductor 260 functioning as the wiring WL is shared by the memory cells 150 adjacent to each other in the Y direction. The conductor 240 functioning as part of the wiring BL is shared in the same memory unit. That is, the conductor 240 is in contact with the oxide semiconductor 230 of each of the memory cell 150a to the memory cell 150d.

The conductor 245 is provided between the conductors 240 included in the memory units adjacent to each other in the Z direction. For example, as illustrated in FIG. 28B, the conductor 245 is provided in contact with the top surface of the conductor 240 of the memory unit 160[1,1] and the bottom surface of the conductor 240 of the memory unit 160[1,2]. In this manner, the conductor 240 and the conductor 245 provided in the memory unit 160 form the wiring BL. The conductor 245 is electrically connected to a sense amplifier (not illustrated) provided below the memory device illustrated in FIG. 28. As described above, when a plurality of memory units are stacked in the memory device illustrated in FIG. 28, the memory capacity per unit area can be increased.

The memory cell 150a and the memory cell 150c are line-symmetrical to the memory cell 150b and the memory cell 150d with a perpendicular bisector of the dashed-dotted line A1-A2 as the symmetric axis. Thus, the transistor 200a and the transistor 200c are also arranged symmetrically to the transistor 200b and the transistor 200d with the conductor 245 therebetween. The conductor 240 has a function of the other of the source electrode and the drain electrode of each of the transistor 200a to the transistor 200d. The transistor 200a to the transistor 200d share the conductor 245 functioning as a plug. Accordingly, when the four transistors are connected to the plug as described above, a memory device that can be miniaturized or highly integrated can be provided.

When a plurality of memory cells are stacked as illustrated in FIG. 28, cells can be integrally arranged without increasing the area occupied by the memory cell array. In other words, a 3D memory cell array can be formed. Although FIG. 28 illustrates the structure in which four layers each including two memory units are stacked, the present invention is not limited thereto. The memory device may include one layer including at least one memory cell 150, or two or more layers may be stacked.

FIG. 28 illustrates a structure in which the conductor 245 functioning as a plug is placed between the memory cells 150. In other words, the conductor 245 functioning as a plug is placed in the memory unit 160. Note that the present invention is not limited thereto. The conductor 245 may be placed outside the memory unit.

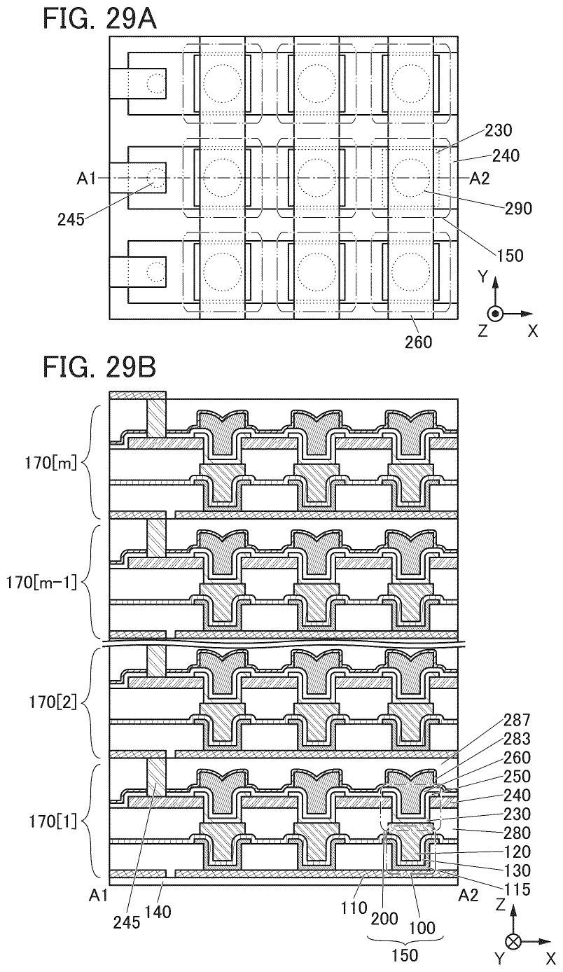

As an example of the memory cell array, FIG. 29A and FIG. 29B illustrate an example of a memory device in which 3×3×4 memory cells 150 are arranged in the X direction, the Y direction, and the Z direction. FIG. 29A is a plan view of the memory device. In addition, FIG. 29B is a cross-sectional view of a portion indicated by the dashed-dotted line A1-A2 in FIG. 29A. For the sake of clarity of the drawing, some components are omitted in the plan view in FIG. 29A.

In the memory device illustrated in FIG. 29A and FIG. 29B, m (m is an integer greater than or equal to 2) layers each including the memory cell 150 are stacked. Here, FIG. 29B illustrates a layer 170[1] as the layer provided in the first layer (the lowermost layer), a layer 170[2] as the layer provided in the second layer, a layer 170[m−1] as the layer provided in the [m−1]-th layer, and a layer 170[m] as the layer provided in the m-th layer (the uppermost layer). In other words, the memory device of one embodiment of the present invention may include a plurality of layers including memory cells 150 and have a structure in which the plurality of layers are stacked.

As illustrated in FIG. 29A and FIG. 29B, the conductor 245 may be provided outside the memory unit. The conductor 245 may also be electrically connected to a wiring provided in a layer above the layer including the conductor 245. For example, the conductor 245 provided in the layer 170[1] is electrically connected to a wiring provided in the layer 170[2]. Note that the wiring provided in the layer 170[2] is provided in the same layer as the lower electrode (conductor 110) of the memory cell 150 included in the layer 170[2]. That is, the wiring can be formed in the same step as the conductor 110.

Although FIG. 29 illustrates a structure in which the conductor 245 is electrically connected to a wiring provided in the layer above the layer including the conductor 245, the present invention is not limited thereto. For example, the conductor 245 may be electrically connected to a wiring provided in the layer including the conductor 245. The conductor 245 provided in the layer 170[1] may be electrically connected to a wiring provided in the layer 170[1], for example. Note that the wiring provided in the layer 170[1] is provided in the same layer as the lower electrode (conductor 110) of the memory cell 150 included in the layer 170[1]. That is, the wiring can be formed in the same step as the conductor 110.

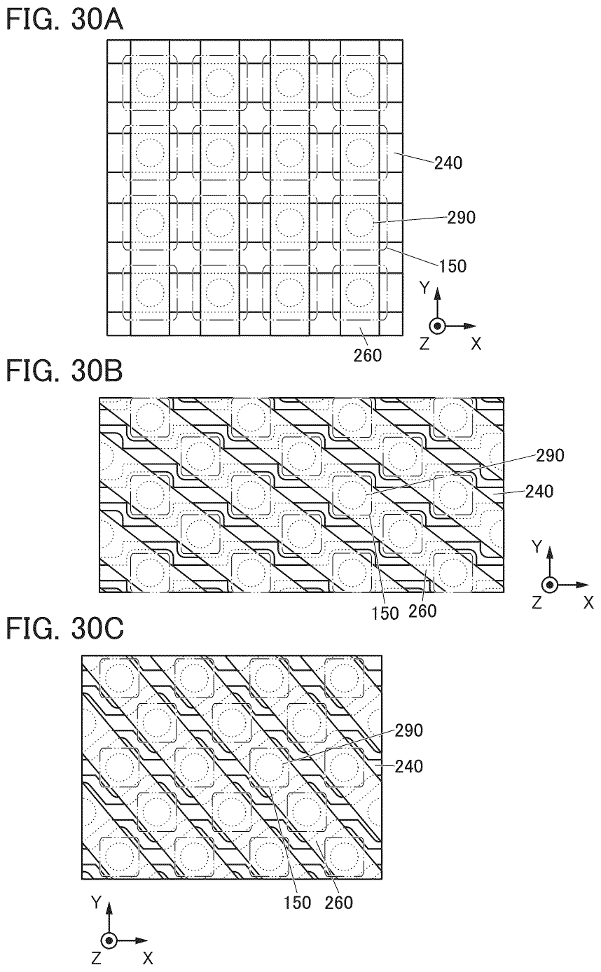

FIG. 30A illustrates a planar layout of the memory device illustrated in FIG. 29A. Specifically, the planar layout in FIG. 30A illustrates a region including a 4×4 array of memory cells 150. In addition, the conductor 260 functioning as the wiring WL, the conductor 240 functioning as the wiring BL, and the opening portion 290 are illustrated. Note that the memory cell 150 is provided in a region where the conductor 260, the conductor 240, and the opening portion 290 overlap with each other. In other words, the opening portion 290 is provided in a region of the conductor 240 where the conductor 240 and the conductor 260 intersect with each other.

FIG. 30A illustrates a structure in which the memory cells 150 are arranged in a matrix. In the structure, the opening portions 290 are also arranged in a matrix. In the structure, the conductor 260 is provided to extend in the Y direction (also referred to as a column direction), and the conductor 240 is provided to extend in the X direction (also referred to as a row direction). In other words, the conductor 260 and the conductor 240 are orthogonal to each other in the structure. In the structure, the width of the conductor 260 in the direction (X direction) perpendicular to the direction in which the conductor 260 extends is uniform, and the width of the conductor 240 in the direction (Y direction) perpendicular to the direction in which the conductor 240 extends is uniform. Note that the present invention is not limited thereto.

FIG. 30B is another example of a planar layout of the memory device. In the planar layout of FIG. 30B, the conductor 260, the conductor 240, the memory cells 150, and the opening portions 290 are illustrated as in FIG. 30A. The memory device illustrated in FIG. 30B is different from the memory device illustrated in FIG. 30A mainly in the arrangement of the memory cells 150, the arrangement of the opening portions 290, the shape of the conductor 240, and the direction in which the conductor 260 extends.

As illustrated in FIG. 30B, the memory cells 150 are arranged to shift by half a repeating unit of the memory cells 150 between the odd-numbered rows and the even-numbered rows. In addition, the memory cells 150 are arranged to shift by half the repeating unit between the odd-numbered columns and the even-numbered columns. Similarly, the opening portions 290 illustrated in FIG. 30B are arranged to shift by half a repeating unit of the opening portions 290 between the odd-numbered rows and the even-numbered rows. Moreover, the opening portions 290 are arranged to shift by half the repeating unit between the odd-numbered columns and the even-numbered columns.

In FIG. 30B, a memory cell adjacent to a first memory cell in the X direction is referred to as a second memory cell, and of memory cells adjacent to the first memory cell in the direction where the conductor 260 extends, a memory cell closer to the second memory cell is referred to as a third memory cell. In this case, it is preferable that the center of the third memory cell be positioned on a straight line parallel to the Y direction that passes through the middle of the first memory cell and the second memory cell. It can be said that the third memory cell is located in a position shifted in the X direction by half a repeating unit from each of the first memory cell and the second memory cell.

In FIG. 30B, the direction in which the conductor 260 extends is inclined to the Y direction. Meanwhile, the conductor 240 is provided to extend in the X direction. This indicates that, in some cases, the direction in which the conductor 260 extends is not orthogonal to the direction in which the conductor 240 extends depending on the arrangement of the memory cells 150 (or the opening portions 290). In other words, the conductor 260 is not necessarily orthogonal to the conductor 240 and is placed to intersect with the conductor 240.

As illustrated in FIG. 30B, the conductor 240 includes a first region and a second region. The first region is a region that includes the opening portion 290 and the vicinity thereof, and the width of the first region in the Y direction is a first width. In the plan view, the first region can be regarded as having a quadrangular shape with rounded corners. The second region is a region located between the adjacent opening portions 290 (also referred to as a region located between two adjacent first regions) in one conductor 240, and the width of the second region in the Y direction is referred to as a second width. In that case, the second width is preferably smaller than the first width. Such a structure enables the physical distance between the conductors 240 to be reduced when the memory cells 150 (or the opening portions 290) are arranged to shift by half a repeating unit in every row and every column. Accordingly, miniaturization and high integration of the memory device can be achieved.

FIG. 30C is another example of a planar layout of the memory device. In the planar layout in FIG. 30C, the conductor 260, the conductor 240, the memory cells 150, and the opening portions 290 are illustrated as in FIG. 30B. The memory device illustrated in FIG. 30C is different from the memory device illustrated in FIG. 30B mainly in the shape of the first region of the conductor 240.

The first region of the conductor 240 illustrated in FIG. 30B has a quadrangular shape with rounded corners in a plan view, and one side of the quadrangular shape is parallel to the X direction or the Y direction. Meanwhile, the first region of the conductor 240 illustrated in FIG. 30C has a quadrangular shape with rounded corners in a plan view, and the diagonal of the quadrangular shape is parallel to the X direction or the Y direction. Even such a structure enables the physical distance between the conductors 240 to be reduced when the memory cells 150 (or the opening portions 290) are arranged to shift by half a repeating unit for every row and every column. Accordingly, miniaturization and high integration of the memory device can be achieved.

Although FIG. 30B and FIG. 30C each illustrate an example in which the first region of the conductor 240 has a shape of a quadrangle with rounded corners in the plan view, the present invention is not limited thereto.

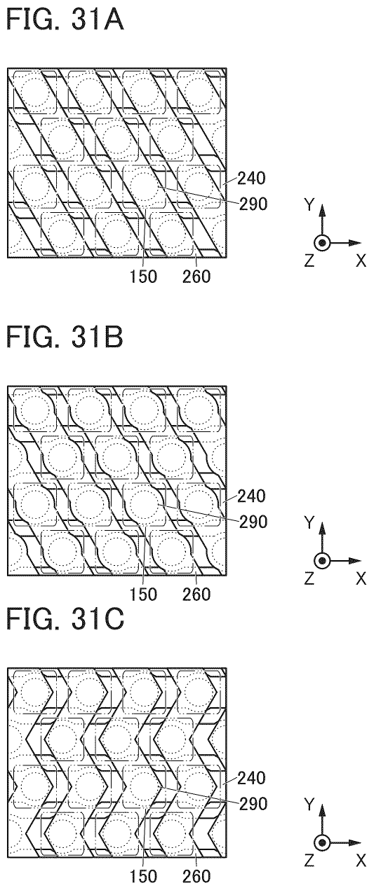

FIG. 31A is another example of a planar layout of the memory device. In the planar layout in FIG. 31A, the conductor 260, the conductor 240, the memory cell 150, and the opening portion 290 are illustrated as in FIG. 30B. The memory device illustrated in FIG. 31A is different from the memory device illustrated in FIG. 30B or FIG. 30C mainly in the shape of the first region of the conductor 240.

The first region of the conductor 240 illustrated in FIG. 31B has a circular shape in a plan view. Even such a structure enables the physical distance between the conductors 240 to be reduced when the memory cells 150 (or the opening portions 290) are arranged to shift by half a repeating unit for every row and every column. Accordingly, miniaturization and high integration of the memory device can be achieved.

The first region of the conductor 240 in the plan view is not limited to the above-described shapes. For example, the first region of the conductor 240 in the plan view may have an almost circular shape such as an elliptical shape, a polygonal shape such as a quadrangular shape, or a shape of a polygon such as a quadrangle with rounded corners.

Although FIG. 31A illustrates the structure in which the width of the conductor 260 is uniform in the direction perpendicular to the direction in which the conductor 260 extends, the present invention is not limited thereto.

FIG. 31B is another example of a planar layout of the memory device. In the planar layout in FIG. 31B, the conductor 260, the conductor 240, the memory cells 150, and the opening portions 290 are illustrated as in FIG. 31A. The memory device illustrated in FIG. 31B is different from the memory device illustrated in FIG. 31A mainly in the shape of the conductor 260.

The conductor 260 illustrated in FIG. 31B includes a first region and a second region, like the conductor 240. The first region is a region that includes the opening portion 290 and the vicinity thereof, and has a circular shape in a plan view. The second region is a region located between the adjacent opening portions 290 (also referred to as a region located between two adjacent first regions) in one conductor 260. Note that the first region of the conductor 260 overlaps with the first region of the conductor 240. Such a structure enables the physical distance between the conductors 260 to be reduced when the memory cells 150 (or the opening portions 290) are arranged to shift by half a repeating unit for every row and every column. Accordingly, miniaturization and high integration of the memory device can be achieved.

FIG. 31C is another example of a planar layout of the memory device. In the planar layout in FIG. 31C, the conductor 260, the conductor 240, the memory cells 150, and the opening portions 290 are illustrated as in FIG. 31A. The memory device illustrated in FIG. 31C is different from the memory device illustrated in FIG. 31A mainly in the shape and extending direction of the conductor 260.

The conductor 260 illustrated in FIG. 31C has a serpentine shape like a triangular wave in a plan view and is provided to extend in the Y direction. Such a structure enables the physical distance between the conductors 260 to reduced when the memory cells 150 (or the opening portions 290) are arranged to shift by half a repeating unit for every row and every column. Accordingly, miniaturization and high integration of the memory device can be achieved. Note that the shape of the conductor 260 in the plan view is not limited to the above, and may have a meandering shape or the like.

With the above structure, one or both of the physical distance between the conductors 260 and the physical distance between the conductors 240 can be reduced, whereby the memory device can be miniaturized and highly integrated.

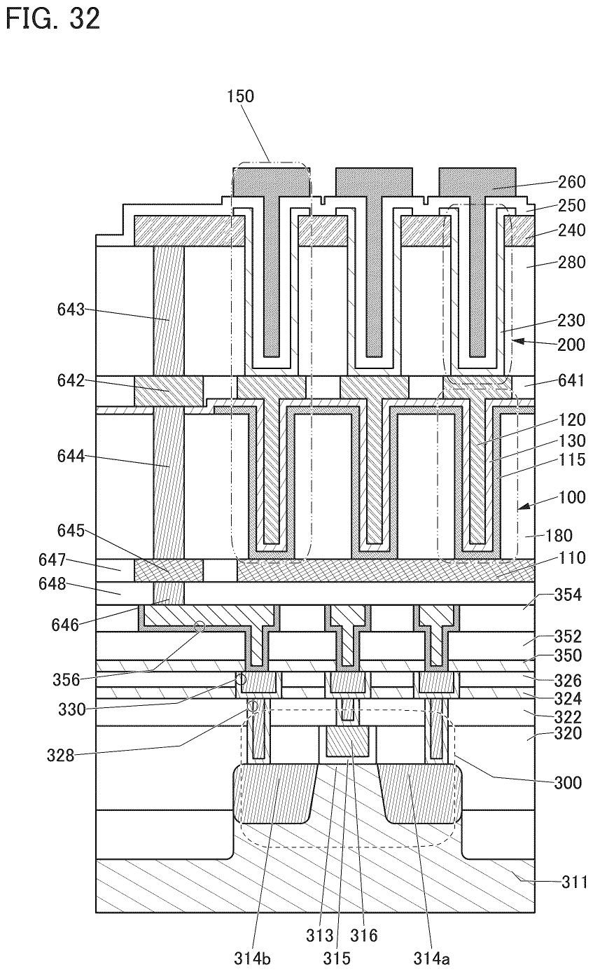

FIG. 32 illustrates a cross-sectional structure example of a memory device where a layer including a memory cell is stacked over a layer including a driver circuit provided with a sense amplifier.

In FIG. 32, the capacitor 100 is provided above a transistor 300, and the transistor 200 is provided above the transistor 300 and the capacitor 100.

The transistor 300 is one of the transistors included in the sense amplifier.

The structure of the memory cells 150 (the transistor 200 and the capacitor 100) illustrated in FIG. 32 is as described above.

When the sense amplifier is provided to overlap with the memory cell 150 as illustrated in FIG. 32, the bit line can be shortened. Accordingly, the bit line capacitance can be reduced and the memory device can be driven at high speed.

When the transistor 200 is provided above the capacitor 100, the transistor 200 is not affected by thermal budget in fabricating the capacitor 100. Thus, in the transistor 200, degradation of the electrical characteristics such as variation in threshold voltage or an increase in parasitic resistance, and an increase in variation in electrical characteristics due to the degradation of the electrical characteristics can be inhibited.

The memory device illustrated in FIG. 32 can correspond to a memory device 80 described in Embodiment 3. Specifically, the transistor 300 corresponds to a transistor included in a sense amplifier 46 in the memory device 80. The memory cell 150 corresponds to a memory cell 32, the transistor 200 corresponds to a transistor 37, and the capacitor 100 corresponds to a capacitor 38.

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

In the transistor 300 illustrated in FIG. 32, the semiconductor region 313 (part of the substrate 311) where a channel is formed has a protruding shape. Furthermore, the conductor 316 is provided to cover the side and top surfaces of the semiconductor region 313 with the insulator 315 therebetween. The conductor 316 may be formed using a material for adjusting the work function. Such a transistor 300 is also referred to as a FIN-type transistor because it utilizes the protruding portion of the semiconductor substrate. Note that an insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI substrate.

Note that the transistor 300 illustrated in FIG. 32 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Here, a plurality of conductors functioning as a plug or a wiring are collectively denoted by the same reference numeral in some cases. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 300 as an interlayer film. A conductor 328 is embedded in the insulator 320 and the insulator 322, and a conductor 330 is embedded in the insulator 324 and the insulator 326. Note that the conductor 328 and the conductor 330 function as a plug or a wiring.

The insulator functioning as an interlayer film may also function as a planarization film that covers an uneven shape thereunder. For example, the top surface of the insulator 322 may be planarized through planarization treatment using a CMP method or the like to increase the level of planarity.

A wiring layer may be provided over the insulator 326 and the conductor 330. For example, in FIG. 32, an insulator 350, an insulator 352, and an insulator 354 are stacked sequentially. Furthermore, a conductor 356 is formed in the insulator 350, the insulator 352, and the insulator 354. The conductor 356 functions as a plug or a wiring.

As the insulator 352, the insulator 354, and the like functioning as interlayer films, the above-described insulator that can be used for the semiconductor device or the memory device can be used.

As the conductor functioning as a plug or a wiring, such as the conductor 328, the conductor 330, and the conductor 356, a conductor described above in [Conductor] can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

The conductor 240 included in the transistor 200 is electrically connected to the low-resistance region 314b functioning as the source region or the drain region of the transistor 300 through a conductor 643, a conductor 642, a conductor 644, a conductor 645, a conductor 646, the conductor 356, the conductor 330, and the conductor 328.

The conductor 643 is embedded in the insulator 280. The conductor 642 is provided over the insulator 130 and is embedded in an insulator 641. The conductor 642 and the conductor 120 can be formed using the same material in the same step. The conductor 644 is embedded in the insulator 180 and the insulator 130. The conductor 645 is embedded in an insulator 647. The conductor 645 and the conductor 110 can be formed using the same material in the same step. The conductor 646 is embedded in an insulator 648. The transistor 300 and the conductor 110 are electrically insulated from each other by the insulator 648.

According to one embodiment of the present invention, a novel transistor, a novel semiconductor device, and a novel memory device can be provided. Alternatively, a transistor, a semiconductor device, and a memory device that can be miniaturized or highly integrated can be provided. Alternatively, a transistor, a semiconductor device, and a memory device each having high reliability can be provided. Alternatively, a transistor having a high on-state current and a semiconductor device and a memory device each including the transistor can be provided.

Alternatively, a semiconductor device and a memory device each having a small variation in transistor characteristics can be provided. Alternatively, a transistor with favorable electrical characteristics and a semiconductor device and a memory device that include the transistor can be provided. Alternatively, a semiconductor device and a memory device each having low power consumption can be provided. Alternatively, a memory device with favorable frequency characteristics can be provided. Alternatively, a memory device with a high operation speed can be provided.

This embodiment can be combined with the other embodiments and the example as appropriate.

### Embodiment 3

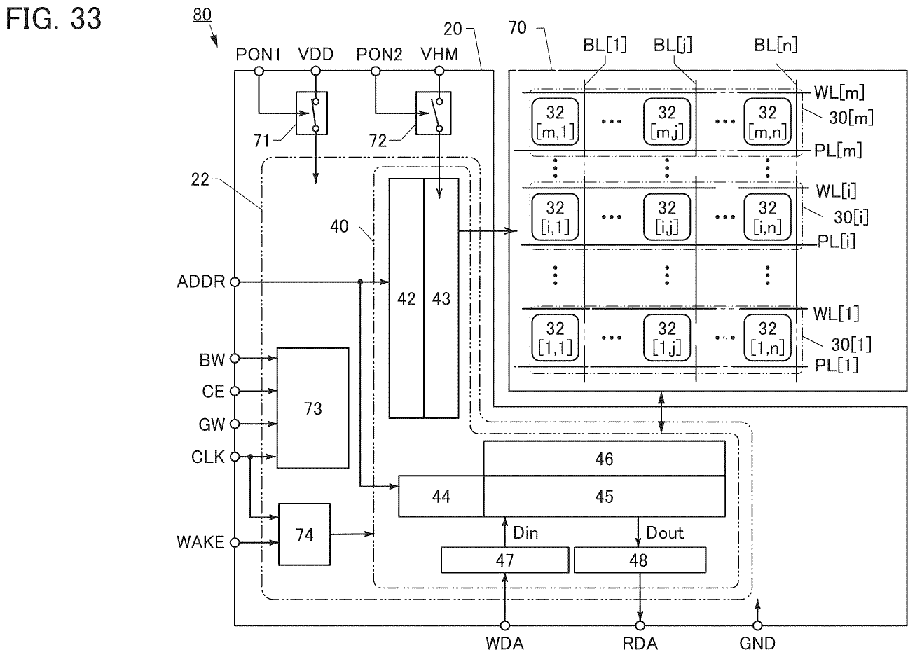

In this embodiment, memory device of one embodiment of the present invention will be described with reference to FIG. 33 to FIG. 36. This embodiment describes a cross-sectional structure example of a memory device in which a layer including a memory cell is stacked over a layer including a driver circuit including a sense amplifier.

### Structure Example 4 of Memory Device

FIG. 33 is a block diagram illustrating a structure example of the memory device 80 of one embodiment of the present invention. The memory device 80 illustrated in FIG. 33 includes a layer 20 and a stacked layer 70.

The layer 20 is a layer including Si transistors. In the stacked layer 70, element layers 30[1] to 30[m] (m is an integer greater than or equal to 2) are stacked. The element layers 30[1] to 30[m] each include an OS transistor. The layer 70 in which the layers including OS transistors are stacked can be stacked over the layer 20.

Elements such as the OS transistor and the capacitor included in each of the element layers 30[1] to 30[m] form a memory cell. FIG. 33 illustrates an example in which the element layers 30[1] to 30[m] include a plurality of the memory cells 32 arranged in a matrix of m rows and n columns (n is an integer greater than or equal to 2).

In FIG. 33, the memory cell 32 in the first row and the first column is referred to as a memory cell 32[1,1], and the memory cell 32 in the m-th row and the n-th column is referred to as a memory cell 32[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 32 in the i-th row and the j-th column is referred to as a memory cell 32[i,j]. In this embodiment and the like, “i+a” (a is a positive or negative integer) is not below 1 and does not exceed m. Similarly, “+a” is not below 1 and does not exceed n.

FIG. 33 illustrates m wirings WL extending in the row direction, m wirings PL extending in the row direction, and n wirings BL extending in the column direction, for example. In this embodiment and the like, a first (first row) wiring WL is referred to as a wiring WL[1] and an m-th (m-th row) wiring WL is referred to as a wiring WL[m]. Similarly, a first (first row) wiring PL is referred to as a wiring PL[1] and an m-th (m-th row) wiring PL is referred to as a wiring PL[m]. Similarly, a first (first column) wiring BL is referred to as a wiring BL[1] and an n-th (n-th column) wiring BL is referred to as a wiring BL[n]. Note that the number of the element layers 30[1] to 30[m] is not necessarily the same as the number of the wirings WL (and the wirings PL).

A plurality of memory cells 32 provided in the i-th row are electrically connected to the wiring WL in the i-th row (wiring WL[i]) and the wiring PL in the i-th row (wiring PL[i]). A plurality of memory cells 32 provided in the j-th column are electrically connected to the wiring BL in the j-th column (wiring BL[/]).

The wiring BL functions as a bit line for writing and reading data. The wiring WL functions as a word line for controlling on and off states (conduction and non-conduction states) of the access transistor serving as a switch. The wiring PL has a function of a constant potential line connected to a capacitor. Note that a wiring CL (not illustrated) can be separately provided as a wiring for transmitting the back gate potential.

The memory cell 32 included in each of the element layers 30[1] to 30[m] is connected to the sense amplifier 46 through the wiring BL. The wirings BL can be provided in the direction horizontal and the direction perpendicular to the surface of the substrate provided with the layer 20. When the wirings BL provided to extend from the memory cells 32 included in the element layers 30[1] to 30[m] are formed of the wiring provided in the direction perpendicular to the substrate surface in addition to the wiring provided in the direction horizontal to the substrate surface, the length of the wiring between the element layer 30 and the sense amplifier 46 can be reduced. The signal transmission distance between the memory cell and the sense amplifier can be reduced, and the resistance and parasitic capacitance of the bit line can be significantly reduced, so that power consumption and signal delays can be reduced. Accordingly, power consumption and signal delays of the memory device 80 can be reduced. Moreover, operation is possible even when the capacitance of the capacitors included in the memory cells 32 is reduced. Accordingly, the memory device 80 can be downsized.

The layer 20 includes a power switch 71 (PSW), a power switch 72, and a peripheral circuit 22. The peripheral circuit 22 includes a driver circuit 40, a control circuit 73, and a voltage generation circuit 74. Each of the circuits included in the layer 20 is a circuit including a Si transistor.

In the memory device 80, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 73.

The control circuit 73 is a logic circuit having a function of controlling the entire operation of the memory device 80. For example, the control circuit performs a logical operation on the signal CE, the signal GW, and the signal BW to determine an operation mode (e.g., a writing operation or a reading operation) of the memory device 80. Alternatively, the control circuit 73 generates a control signal for the driver circuit 40 so that the operation mode is executed.

The voltage generation circuit 74 has a function of generating a negative voltage. The signal WAKE has a function of controlling the input of the signal CLK to the voltage generation circuit 74. For example, when an H-level signal is supplied as the signal WAKE, the signal CLK is input to the voltage generation circuit 74, and the voltage generation circuit 74 generates a negative voltage.

The driver circuit 40 a circuit for writing and reading data to/from the memory cells 32. The driver circuit 40 includes the above-described sense amplifier 46 in addition to a row decoder 42, a column decoder 44, a row driver 43, a column driver 45, an input circuit 47, and an output circuit 48.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 32, a function of reading data from the memory cells 32, a function of retaining the read data, and the like.

The input circuit 47 has a function of retaining the signal WDA. Data retained by the input circuit 47 is output to the column driver 45. Data output from the input circuit 47 is data (Din) to be written to the memory cells 32. Data (Dout) read from the memory cells 32 by the column driver 45 is output to the output circuit 48. The output circuit 48 has a function of retaining Dout. In addition, the output circuit 48 has a function of outputting Dout to the outside of the memory device 80. Data output from the output circuit 48 is the signal RDA.

The power switch 71 has a function of controlling supply of VDD to the peripheral circuit 22. The power switch 72 has a function of controlling supply of VHM to the row driver 43. Here, in the memory device 80, a high power supply voltage is VDD and a low power supply voltage is GND (a ground potential). In addition, VHM is a high power supply voltage used to set a word line at a high level and is higher than VDD. The on/off of the power switch 71 is controlled by the signal PON1, and the on/off of the power switch 72 is controlled by the signal PON2. In the peripheral circuit 22 in FIG. 33, the number of power domains to which VDD is supplied is one but can be more than one. In that case, a power switch may be provided for each power domain.

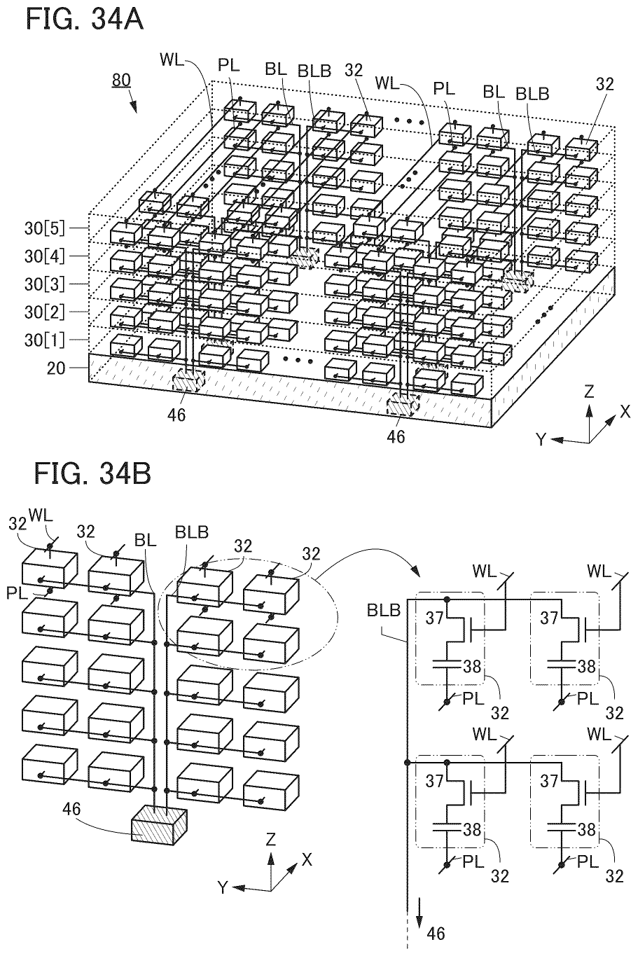

The element layers 30[1] to 30[m] can be provided over the layer 20 to overlap with the layer 20. FIG. 34A is a perspective view of the memory device 80 in which five element layers 30[1] to 30[5] (m=5) are provided over the layer 20 to overlap with the layer 20.

In FIG. 34A, the element layer 30 provided in the first layer is denoted as the element layer 30[1], the element layer 30 provided in the second layer is denoted as the element layer 30[2], and the element layer 30 provided in the fifth layer is denoted as the element layer 30[5]. FIG. 34A also illustrates the wiring WL and the wiring PL provided to extend in the X direction and the wiring BL and the wiring BLB provided to extend in the Y direction and the Z direction (the directions perpendicular to the surface of the substrate provided with the driver circuit). The wiring BLB is an inverted bit line. For easy viewing of the drawing, some of the wirings WL and the wirings PL included in the element layers 30 are not illustrated.

FIG. 34B is a schematic view showing a structure example of the sense amplifier 46 connected to the wiring BL and the wiring BLB illustrated in FIG. 34A, and the memory cells 32 included in the element layers 30[1] to 30[5], which are connected to the wiring BL and the wiring BLB. A structure in which a plurality of memory cells (the memory cells 32) are electrically connected to the wiring BL and the wiring BLB is referred to as a “memory string”.

FIG. 34B illustrates an example of a circuit structure of the memory cells 32 connected to the wiring BLB. The memory cell 32 includes the transistor 37 and the capacitor 38. As for the transistor 37, the capacitor 38, and the wirings (BL, WL, and the like), for example, the wiring BL[1] and the wiring WL[1] are referred to as the wiring BL and the wiring WL in some cases. As the memory cell 32, the memory cell 150 described in the above embodiment can be used, for example. That is, the transistor 200 can be used as the transistor 37, and the capacitor 100 can be used as the capacitor 38. As the transistor included in the sense amplifier 46, the transistor 300 (see FIG. 32) can be used.

In the memory cell 32, one of a source and a drain of the transistor 37 is connected to the wiring BL. The other of the source and the drain of the transistor 37 is connected to one electrode of the capacitor 38. The other electrode of the capacitor 38 is connected to the wiring PL. A gate of the transistor 37 is connected to the wiring WL.

The wiring PL is a wiring supplying a fixed potential for retaining a potential of the capacitor 38. When a plurality of wirings PL are connected to each other as one wiring, the number of wirings can be reduced.

In one embodiment of the present invention, OS transistors are provided in stacked layers and a wiring functioning as a bit line is provided in the direction perpendicular to the surface of the substrate provided with the layer 20. In addition, the transistor 37 and the capacitor 38 included in the memory cell 32 are arranged in the direction perpendicular to the surface of the substrate provided with the layer 20. When the elements and the wirings are provided in the direction perpendicular to the substrate surface, the length of the wirings between the element layers can be shortened and the density of the elements provided per unit area can be increased. Accordingly, the memory device can have high memory capacity and low power consumption.

### Structure Example of Memory Cell 32 and Sense Amplifier 46

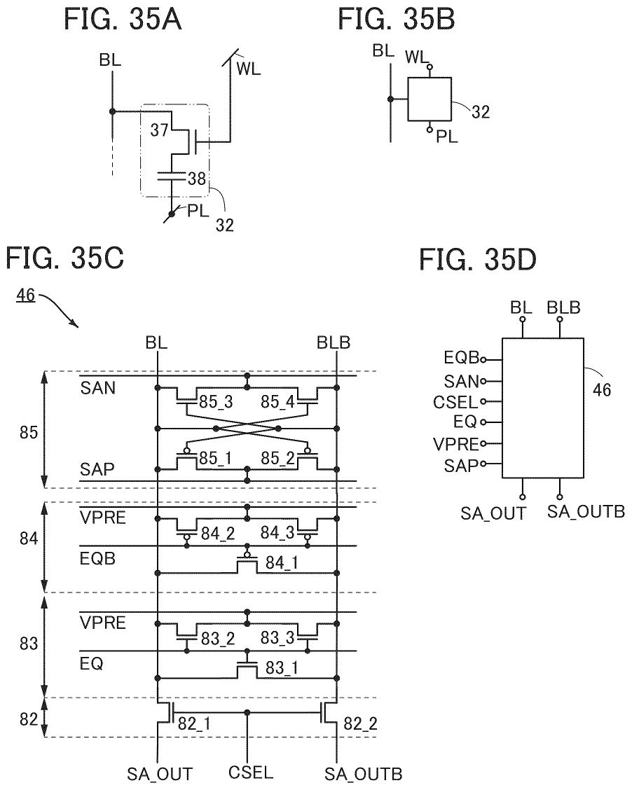

FIG. 35A and FIG. 35B show respectively a circuit diagram corresponding to the memory cell 32 and a diagram illustrating a circuit block corresponding to the circuit diagram. As illustrated in FIG. 35A and FIG. 35B, the memory cell 32 is sometimes illustrated as a block in a drawing or the like. Note that the wiring BL illustrated in FIG. 35A and FIG. 35B can be replaced with the wiring BLB.

FIG. 35C and FIG. 35D show respectively a circuit diagram corresponding to the above-described sense amplifier 46 and a diagram illustrating a circuit block corresponding to the circuit diagram. As the sense amplifier 46, a switch circuit 82, a precharge circuit 83, a precharge circuit 84, and an amplifier circuit 85 are illustrated. In addition, a wiring SA_OUT and a wiring SA_OUTB each of which outputs a read signal are illustrated in addition to the wiring BL and the wiring BLB.

The switch circuit 82 includes, for example, n-channel transistors 82_1 and 82_2, as illustrated in FIG. 35C. The transistors 82_1 and 82_2 switch electrical continuity between the wiring SA_OUT and the wiring BL and between the wiring SA_OUTB and the wiring BLB in response to a signal CSEL; the wiring SA_OUT and the wiring SA_OUTB form a wiring pair and the wiring BL and the wiring BLB form a wiring pair.

The precharge circuit 83 is composed of n-channel transistors 83_1 to 83_3 as illustrated in FIG. 35C. The precharge circuit 83 is a circuit for precharging the wiring BL and the wiring BLB to an intermediate potential VPRE corresponding to half of the potential VDD in response to a signal EQ.

The precharge circuit 84 is composed of p-channel transistors 84_1 to 84_3 as illustrated in FIG. 35C. The precharge circuit 84 is a circuit for precharging the wiring BL and the wiring BLB to the intermediate potential VPRE, which corresponds to half of the potential VDD, in response to a signal EQB.

The amplifier circuit 85 is composed of p-channel transistors 85_1 and 85_2 and n-channel transistors 85_3 and 85_4 that are connected to a wiring SAP or a wiring SAN, as illustrated in FIG. 35C. The wiring SAP or the wiring SAN is a wiring having a function of supplying VDD or VSS. The transistors 85_1 to 85_4 are transistors that form an inverter loop.

FIG. 35D illustrates a circuit block corresponding to the sense amplifier 46 described with reference to FIG. 35C and the like. As illustrated in FIG. 35D, the sense amplifier 46 is expressed as a block in the drawing and the like in some cases.

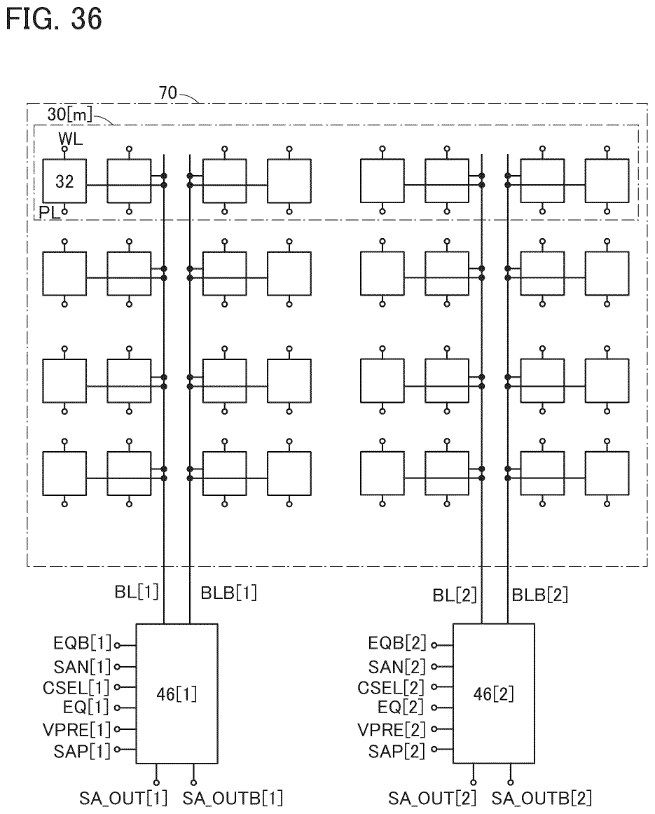

FIG. 36 is a circuit diagram of the memory device 80 in FIG. 33. In FIG. 36, the circuit block illustrated in FIG. 35A to FIG. 35D is used.

As illustrated in FIG. 36, the layer 70 including the element layer 30[m] includes the memory cells 32. The memory cell 32 illustrated in FIG. 36 is connected to a pair of wiring BL[1] and the wiring BLB[1], or a pair of wirings BL[2] and BLB[2], for example. The memory cells 32 connected to the wiring BL are memory cells to/from which data is written or read. The wiring BL[1] and the wiring BLB[1] are connected to a sense amplifier 46 [1], and the wiring BL[2] and the wiring BLB[2] are connected to a sense amplifier 46 [2]. The sense amplifier 46 [1] and the sense amplifier 46 [2] enables reading data in accordance with various kinds of the signals described with reference to FIG. 35C.

This embodiment can be combined with the other embodiments and the examples as appropriate.

### Embodiment 4

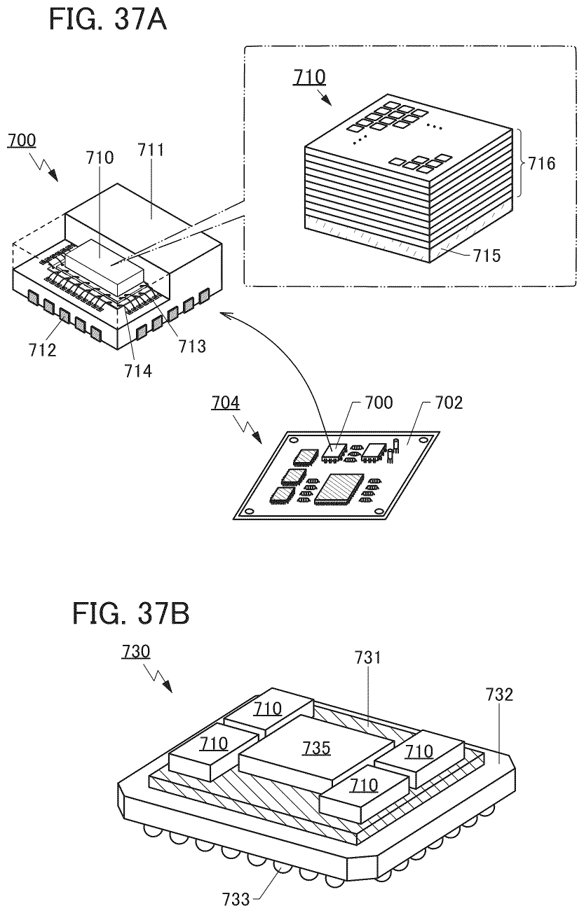

In this embodiment, application examples of the semiconductor device of one embodiment of the present invention will be described with reference to FIG. 37 to FIG. 40. The semiconductor device of one embodiment of the present invention can be used for an electronic component, an electronic appliance, a large computer, space equipment, and a data center (also referred to as DC), for example. An electronic component, an electronic appliance, a large computer, space equipment, and a data center each using the semiconductor device of one embodiment of the present invention are effective in achieving high performance, e.g., reducing power consumption.

### [Electronic Component]

FIG. 37A is a perspective view of a substrate (a mounting board 704) on which an electronic component 700 is mounted. The electronic component 700 illustrated in FIG. 37A includes a semiconductor device 710 in a mold 711. FIG. 37A omits part of the electronic component to illustrate the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the mounting board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via) or a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 37B is a perspective view of an electronic component 730. The electronic component 730 is an example of a SiP (System in Package) or an MCM (Multi Chip Module). In the electronic component 730, an interposer 731 is provided over a package board 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package board 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package board 732. Accordingly, the interposer is sometimes referred to as a “redistribution substrate” or an “intermediate substrate”. A through electrode may be provided in the interposer 731 to be used for electrically connecting the integrated circuit and the package board 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

A heat sink (radiator plate) may be provided to overlap with the electronic component 730. In the case of providing a heat sink, integrated circuits provided on the interposer 731 are preferably level with each other. For example, in the electronic component 730 described in this embodiment, the heights of the semiconductor devices 710 and the semiconductor device 735 are preferably equal to each other.

An electrode 733 may be provided on the bottom portion of the package board 732 to mount the electronic component 730 on another substrate. FIG. 37B illustrates an example where the electrode 733 is formed of a solder ball. Solder balls are provided in a matrix on the bottom portion of the package board 732, whereby a BGA (Ball Grid Array) can be achieved. Alternatively, the electrode 733 may be formed of a conductive pin. When conductive pins are provided in a matrix on the bottom portion of the package board 732, a PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Appliance]

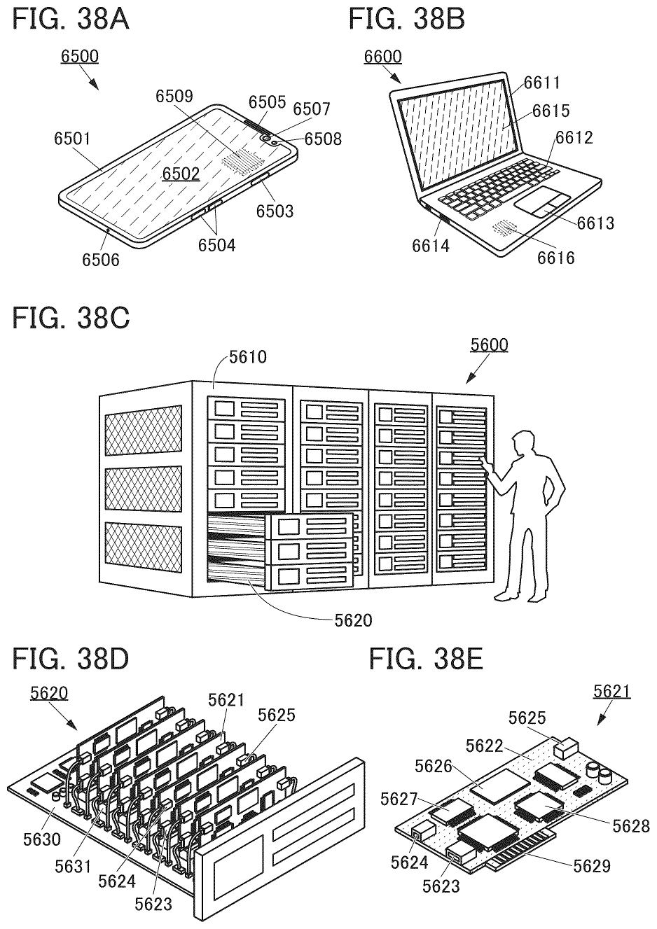

FIG. 38A is a perspective view of an electronic appliance 6500. The electronic appliance 6500 illustrated in FIG. 38A is a portable information terminal that can be used as a smartphone. The electronic appliance 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The semiconductor device of one embodiment of the present invention can be used for the display portion 6502, the control device 6509, and the like.

An electronic appliance 6600 illustrated in FIG. 38B is an information terminal that can be used as a laptop personal computer. The electronic appliance 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is suitably used for the control device 6509 and the control device 6616, in which case power consumption can be reduced.

### [Large Computer]

FIG. 38C is a perspective view of a large computer 5600. In the large computer 5600 illustrated in FIG. 38C, a plurality of rack mount computers 5620 are stored in a rack 5610. Note that the large computer 5600 may be referred to as a supercomputer.

The computer 5620 can have a structure in a perspective view of FIG. 38D, for example. In FIG. 38D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 38E is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 38E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment.

The semiconductor device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, OS transistors can be suitably used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space in this specification may also include one or more of the thermosphere, mesosphere, and stratosphere.

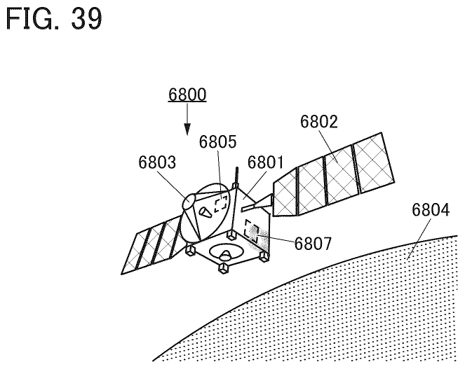

FIG. 39 illustrates an artificial satellite 6800 as an example of space equipment. The artificial satellite 6800 includes a body 6801, a solar panel 6802, an antenna 6803, a secondary battery 6805, and a control device 6807. FIG. 39 illustrates a planet 6804 in outer space, for example.

Although not illustrated in FIG. 39, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. The long-term data management needs an increase in building size owing to installation of storages and servers for storing an enormous amount of data, stable electric power for data retention, cooling equipment necessary for data retention, and the like.

With use of the semiconductor device of one embodiment of the present invention for the storage system used in the data center, electric power required for data retention can be reduced and a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, it is possible to reduce adverse effects of the beat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

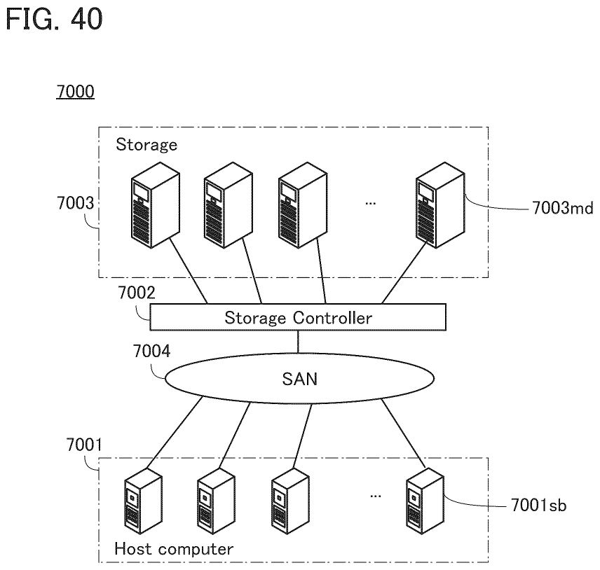

FIG. 40 illustrates a storage system applicable to a data center. A storage system 7000 illustrated in FIG. 40 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic appliance, a large computer, space equipment, and a data center will produce an effect of reducing power consumption. While the demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

This embodiment can be combined with any of the other embodiments as appropriate.

### Example 1

In this example, fabrication and evaluation results of the oxide semiconductor film of one embodiment of the present invention and the semiconductor device of one embodiment of the present invention will be described.

### [XPS]

First, the oxide semiconductor film of one embodiment of the present invention was formed and subjected to XPS analysis.

A sample was fabricated in the following manner: heat treatment was performed on a silicon substrate in a hydrogen chloride (HCl) atmosphere to form an approximately 100-nm-thick silicon oxide (SiOx) film as a base film, and then an approximately 20-nm-thick IGZO film was formed as an oxide semiconductor film by an ALD method.

Note that the SiOx film and the IGZO film were formed on both surfaces of the substrate. In this example, a deposition apparatus in which the IGZO films (corresponding to the film 4431a and the film 4431b) were formed on respective surfaces (corresponding to the front surface 4430a and the rear surface 4430b of the substrate 4430) of the substrate as illustrated in FIG. 10A and FIG. 10B was used.

For a specific method for forming the IGZO film, the following <Formation condition of IGZO film> was employed.

<Formation condition of IGZO film>

Precursors used for formation of the IGZO film are triethylindium (TEI), triethylgallium (TEG), and diethylzinc (DEZ). As an oxidizer, ozone (O₃) and oxygen (O₂) were used. The combined gas flow rate of an O₃ gas and an O₂ gas was 1000 sccm, and the ozone concentration was 19 wt %. As a carrier gas, an N₂ gas was used and the gas flow rate was 150 sccm.

The IGZO film was formed to have a composition of In:Ga:Zn=1:1:1 [atomic ratio] (hereinafter, the IGZO film is sometimes referred to as an IGZO(111) film). In one cycle of the film formation method, specifically, a gas containing TEI was introduced into the chamber for 0.1 seconds, the chamber was purged for 3 seconds, an O₃ gas and an O₂ gas were introduced for 45 seconds, and the chamber was purged for 3 seconds. Next, a gas containing TEG was introduced into the chamber for 0.1 seconds, the chamber was purged for 10 seconds, an O₃ gas and an O₂ gas were introduced for 45 seconds, and the chamber was purged for 3 seconds. Next, a gas containing DEZ was introduced into the chamber for 0.1 seconds, the chamber was purged for 3 seconds, an O₃ gas and an O₂ gas were introduced for 9 seconds, and the chamber was purged for 3 seconds. The substrate temperature in the film formation was 200 °C.

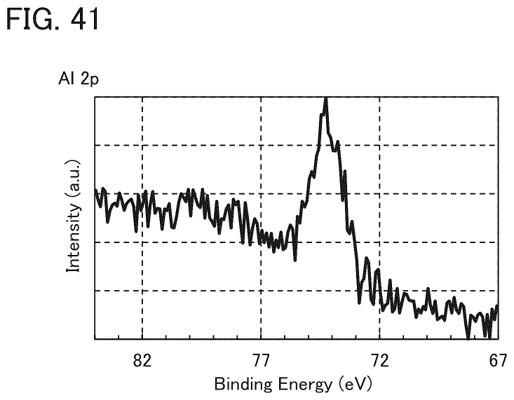

The vicinity of the surface of the IGZO film of the fabricated sample was subjected to XPS analysis. The XPS analysis was performed on the IGZO film formed on the front side of the sample. The obtained Al 2p spectrum is shown in FIG. 41. In FIG. 41, the horizontal axis represents the binding energy (Binding Energy) [eV], and the vertical axis represents the photoelectron intensity (Intensity) (arbitrary unit).

A peak derived from aluminum (Al) was detected by the XPS analysis of the IGZO film. In the case where the peak position is found in the range of 74.2 eV to 74.8 eV, it can be said that Al exists in an oxidized state. There is a peak at a position of approximately 74.3 eV as shown in FIG. 41; this reveals that Al in the IGZO film exists in a state of Al₂O₃ or the like.

In this specification and the like, a peak position of binding energy of an element in XPS analysis refers to a value of binding energy at which the local maximum intensity of an energy spectrum is obtained in a range corresponding to binding energy of the element.

The quantitative value of Al obtained from the XPS spectrum was approximately 4.0 atomic %. Note that the lower detection limit of Al is approximately 1.0 atomic %.

### [Hall Effect Measurement]

Next, the carrier concentration and resistivity of an oxide semiconductor film were measured by Hall effect measurement.

Samples were each fabricated by forming an approximately 35-nm-thick IGZO(111) film over a quartz substrate by an ALD method.

Three kinds of samples, Samples A, B, and C, were fabricated as samples for the Hall effect measurement. The three kinds of samples were fabricated in a similar manner except that the introduction time of an oxidizer was different among the samples.

For Sample C, the above-described <Formation condition of IGZO film> was employed. That is, the introduction time of the oxidizers (an O₃ gas and an O₂ gas) after the introduction of a gas containing TEI was 45 seconds, the introduction time of the oxidizers after the introduction of a gas containing TEG was 45 seconds, and the introduction time of the oxidizers after the introduction of a gas containing DEZ was 9 seconds. Furthermore, heat treatment was performed at 450 °C in an ultra-dry air atmosphere for one hour, and then heat treatment was performed in a reduced-pressure atmosphere for one hour. The heating temperature in a reduced-pressure atmosphere was set to six conditions: 150 °C, 200 °C, 250 °C, 300 °C, 350 °C, and 400 °C.

For Sample B, the introduction time of the oxidizers after the introduction of a gas containing TEI was 30 seconds, the introduction time of the oxidizers after the introduction of a gas containing TEG was 30 seconds, and the introduction time of the oxidizers after the introduction of a gas containing DEZ was 6 seconds. Except for these conditions, Sample B was fabricated under the same conditions as Sample C.

For Sample A, the introduction time of the oxidizers after the introduction of a gas containing TEI was 15 seconds, the introduction time of the oxidizers after the introduction of a gas containing TEG was 15 seconds, and the introduction time of the oxidizers after the introduction of a gas containing DEZ was 3 seconds. Except for these conditions, Sample A was fabricated under the same conditions as Sample C. The heating temperature in a reduced-pressure atmosphere, in addition to the six conditions similar to those for Samples B and C, was 100 °C.

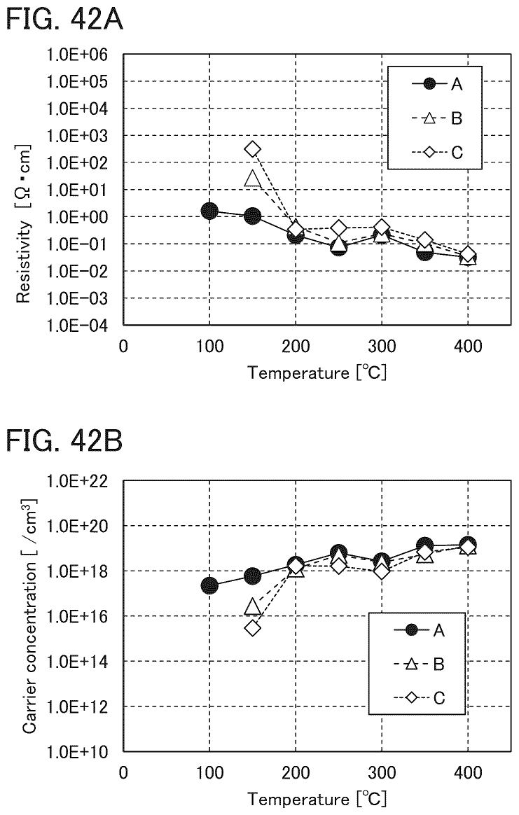

FIG. 42A shows the resistivities of the IGZO films formed on the rear surfaces of the three samples. In FIG. 42A, the horizontal axis represents the heating temperature [°C] in a reduced-pressure atmosphere, and the vertical axis represents the resistivity [(2 cm].

FIG. 42B shows the carrier concentrations of the IGZO films formed on the rear surfaces of the three samples. In FIG. 42B, the horizontal axis represents the heating temperature [°C] in a reduced-pressure atmosphere, and the vertical axis represents the carrier concentration [/cm³]. As shown in FIG. 42A and FIG. 42B, it was confirmed that the heat treatment performed in a reduced-pressure atmosphere decreased the resistivity and increased the carrier concentration. In particular, it was found that the higher the heating temperature was, the lower the resistivity was and the higher the carrier concentration was.

Sample C, in which the introduction time of the oxidizers was longer than those of Samples A and B, tended to have a higher resistivity and a lower carrier concentration than Samples A and B under the conditions where the heating temperature was low (e.g., 150 °C), whereas under the conditions where the heating temperature was high (e.g., higher than or equal to 200 °C), the results of both the resistivity and the carrier concentration were equivalent to those of Samples A and B.

Meanwhile, it was confirmed that the IGZO film formed on the front surface of each sample tended to have a higher resistivity and a lower carrier concentration than the IGZO film formed on the rear surface. In particular, it was confirmed that the higher the heating temperature was (e.g., higher than or equal to 200 °C), the higher the resistivity was and the lower the carrier concentration was.

### [Cross-Sectional STEM-EDX Measurement]

Next, a detection amount of Al in an oxide film was evaluated by cross-sectional STEM-EDX measurement.

Samples were each fabricated in the following manner: heat treatment was performed on a silicon substrate in an HCl atmosphere to form an approximately 100-nm-thick SiOx film as a base film, and then an oxide film was formed by an ALD method. Four kinds of films were formed as the oxide films: an InOx film, a GaOx film, a ZnOx film, and an IGZO(111) film.

The IGZO film was formed to have a thickness of approximately 35 nm. The formation method of the IGZO film is similar to that of Sample A described above. That is, the introduction time of the oxidizers (an O₃ gas and an O₂ gas) after the introduction of a gas containing TEI was 15 seconds, the introduction time of the oxidizers after the introduction of a gas containing TEG was 15 seconds, and the introduction time of the oxidizers after the introduction of a gas containing DEZ was 3 seconds. The substrate temperature in film formation was 200 °C; after the film formation, heat treatment was performed at 450 °C in an ultra-dry air atmosphere for one hour, and then heat treatment was performed at 400 °C in a reduced-pressure atmosphere for one hour.

The InOx film, the GaOx film, and the ZnOx film were each formed to have a thickness of approximately 10 nm using a precursor used to form the IGZO film.

In one cycle of the film formation method for the InOx film, specifically, a gas containing TEI was introduced into the chamber for 0.1 seconds, the chamber was purged for 3 seconds, an O₃ gas and an O₂ gas were introduced for 30 seconds, and the chamber was purged for 3 seconds.

In one cycle of the film formation method for the GaOx film, specifically, a gas containing TEG was introduced into the chamber for 0.1 seconds, the chamber was purged for 10 seconds, an O₃ gas and an O₂ gas were introduced for 30 seconds, and the chamber was purged for 3 seconds.

In one cycle of the film formation method for the ZnOx film, specifically, a gas containing DEZ was introduced into the chamber for 0.1 seconds, the chamber was purged for 3 seconds, an O₃ gas and an O₂ gas were introduced for 6 seconds, and the chamber was purged for 3 seconds.

For each of the InOx film, the GaOx film, and the ZnOx film, the substrate temperature in the film formation was 200 °C and after the film formation, heat treatment was performed at 450 °C in an ultra-dry air atmosphere for one hour.

The cross-sectional STEM (Scanning Transmission Electron Microscopy) observation was performed using HD-2300 manufactured by Hitachi High-Tech Corporation at an acceleration voltage of 200 kV with a magnification accuracy of ±10% and a beam diameter of 0.5 nmφ.

Table I shows the results of EDX analysis.

TABLE 1

| | Detection amount of Al in film (STEM-EDX) | |
|---|---|---|
| Film type | Front surface | Rear surface |
| ALD-InOx | 7.7 atomic % | 1.2 atomic % |
| ALD-GaOx | Lower than or equal to | Lower than or equal to |
| | 0.2 atomic % | 0.1 atomic % |
| ALD-ZnOx | Lower than or equal to | Lower than or equal to |
| | 0.1 atomic % | 0.3 atomic % |
| ALD-IGZO(111) | 2.38 atomic % | 0.62 atomic % |

In the InOx film, the proportion of Al detected by the EDX analysis was 7.7 atomic % on the front surface and 1.2 atomic % on the rear surface of the sample.

In the GaOx film, the proportion of Al detected by the EDX analysis was lower than or equal to the lower detection limit on both the front surface and the rear surface: lower than or equal to 0.2 atomic % on the front surface and lower than or equal to 0.1 atomic % on the rear surface of the sample.

In the ZnOx film, the proportion of Al detected by the EDX analysis was lower than or equal to the lower detection limit on both the front surface and the rear surface: lower than or equal to 0.1 atomic % on the front surface and lower than or equal to 0.3 atomic % on the rear surface of the sample.

As described above, Al was detected more clearly in InOx than in GaOx and ZnOx. Thus, it was found that the InOx film formation cycle was the main entry source of Al in the formation of the IGZO film by an ALD method. Al is used as a starting material for synthesis of the precursor (TEI) used for film formation of InOx. Thus, it suggested a possibility that Al remaining in the precursor entered in the film formation. Furthermore, the Al content was found to be lower on the rear surface than on the front surface of the sample.

In the IGZO film, the proportion of Al detected by the EDX analysis was 2.4 atomic % on the front surface and 0.6 atomic % on the rear surface of the sample. This shows that the amount of Al detected in the IGZO film is smaller than that in the single film of InOx. Furthermore, the Al content was found to be lower on the rear surface than on the front surface of the sample.

The results of the Hall effect measurement and the EDX analysis reveal that the IGZO film formed on the front surface of the substrate contains a large amount of Al, and the higher the temperature of the heat treatment in a reduced-pressure atmosphere is, the more likely it is that aluminum oxide, which is an insulator, is formed. It is probable that this caused an increase in the resistivity and a decrease in the carrier concentration. Meanwhile, the IGZO film formed on the rear surface of the substrate has a lower proportion of Al than the IGZO film formed on the surface; thus, it is probable that the influence of Al (formation of aluminum oxide) is small even when the temperature of the heat treatment in a reduced-pressure atmosphere is high and the amount of oxygen vacancies (V_{O}) in the IGZO increases, leading to an increase in carrier concentration and a decrease in resistance.

### [SIMS Analysis 1]

Next, the hydrogen concentration, the carbon concentration, and the nitrogen concentration in the oxide semiconductor film were measured by SIMS measurement.

Samples were each fabricated in the following manner: heat treatment was performed on a silicon substrate in an HCl atmosphere to form an approximately 100-nm-thick SiOx film as a base film, and then an approximately 20-nm-thick IGZO film was formed by an ALD method.

As the samples for the SIMS measurement, six kinds of samples were fabricated: Samples D1, D2, E1, E2, F1, and F2. The samples were fabricated in a similar manner except that the introduction time of an oxidizer was different among Samples D, E, and F.

For Sample D1, the above-described <Formation condition of IGZO film> was employed. That is, the introduction time of the oxidizers (an O₃ gas and an (2 gas) after the introduction of a gas containing TEI was 45 seconds, the introduction time of the oxidizers after the introduction of a gas containing TEG was 45 seconds, and the introduction time of the oxidizers after the introduction of a gas containing DEZ was 9 seconds. Sample D2 was further subjected to heat treatment at 450 °C in an ultra-dry air atmosphere for one hour. It can be said that the time for supplying the oxidizers in a step of forming one layer of IGZO is 99 seconds for each of Sample D1 and Sample D2. The time is hereinafter also referred to as ozone supply time for one layer.

For Sample E1, the introduction time of the oxidizers after the introduction of a gas containing DEZ was 45 seconds. Except for these conditions, Sample E1 was fabricated under the same conditions as Sample D1. Sample E2 was further subjected to heat treatment at 450 °C in an ultra-dry air atmosphere for one hour. The ozone supply time for one layer in each of Sample E1 and Sample E2 was 135 seconds.

For Sample F1, the introduction time of the oxidizers after the introduction of a gas containing TEI was 60 seconds, the introduction time of the oxidizers after the introduction of a gas containing TEG was 60 seconds, and the introduction time of the oxidizers after the introduction of a gas containing DEZ was 60 seconds. Sample F2 was further subjected to heat treatment at 450 °C in an ultra-dry air atmosphere for one hour. The ozone supply time for one layer in each of Sample F1 and Sample F2 was 180 seconds.

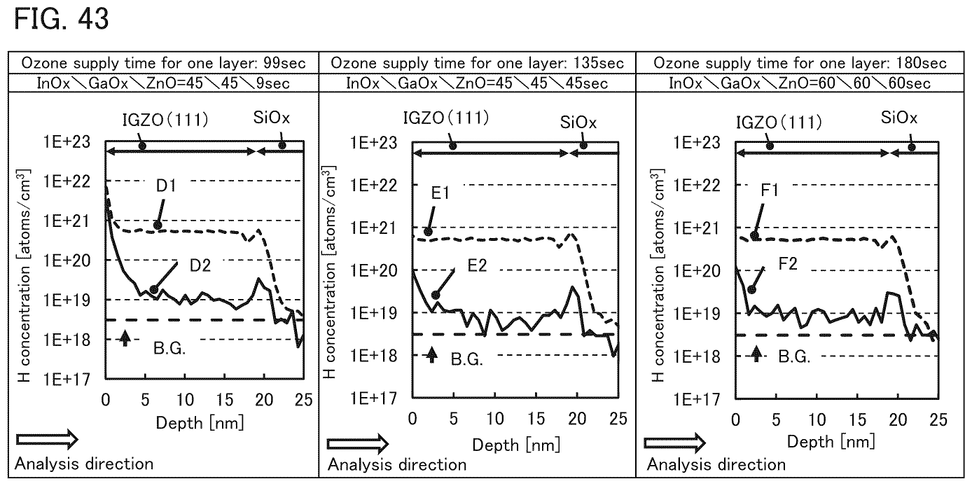

FIG. 43 to FIG. 45 show the SIMS analysis results of the hydrogen concentrations (H concentrations), the carbon concentrations (C concentrations), and the nitrogen concentrations (N concentrations) of the IGZO films formed on the rear surfaces of the samples. The horizontal axis represents the depth from a sample surface, and the point at the left end where the depth is 0 nm corresponds to the sample surface (a surface of the IGZO film).

As shown in FIG. 43, the H concentrations were approximately 5×10²⁰ atoms/cm³ in Samples D1, E1, and F1 regardless of the ozone supply time. In Samples D2, E2, and F2 subjected to the heat treatment at 450 °C, the H concentrations were able to be reduced to approximately 5.5×10¹⁸ atoms/cm³.

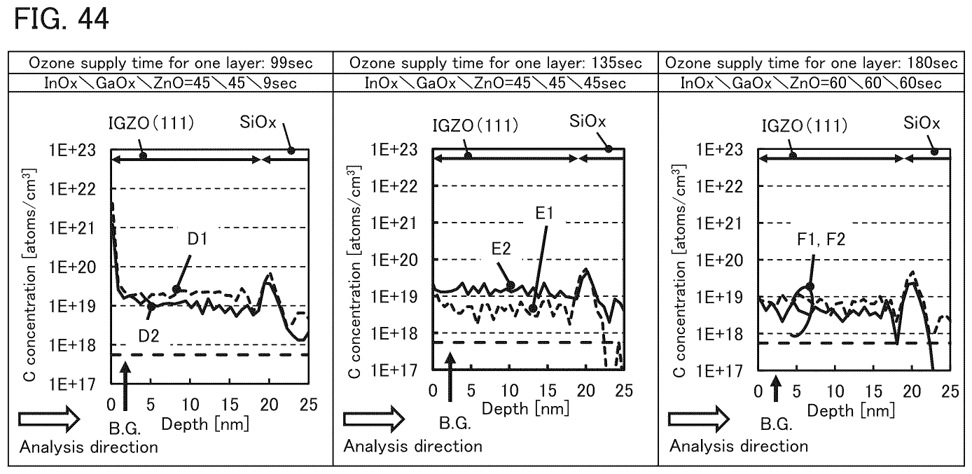

As shown in FIG. 44, it was confirmed that the C concentration was able to be reduced by a longer ozone supply time. In Samples F1 and F2 each having an ozone supply time of 180 seconds (sec), the C concentrations were able to be reduced to approximately 5×10¹⁸ atoms/cm³. It is probable that carbon derived from an ethyl group contained in the precursor can be removed owing to the long ozone supply time.

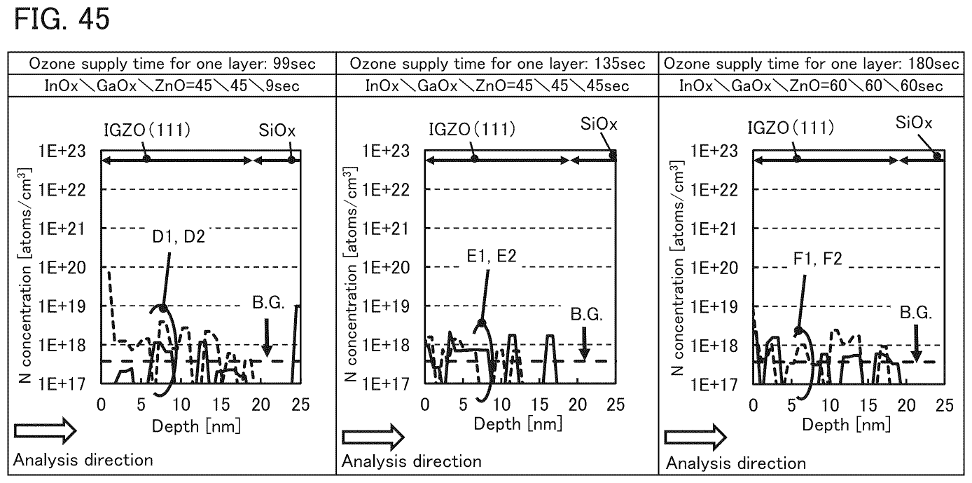

As shown in FIG. 45, the N concentrations were low, i.e., lower than or equal to the lower detection limit (3.7×10¹⁷ atoms/cm³), regardless of the ozone supply time and whether or not the heat treatment was performed.

It was found from the above results that the hydrogen concentration in the IGZO film was able to be reduced by the heat treatment at 450 °C. Furthermore, it was found that the carbon concentration in the IGZO film was able to be reduced by a longer ozone supply time.

### [SIMS Analysis 2]

Next, the aluminum concentration in the oxide semiconductor film was measured by SIMS measurement.

Samples were each fabricated in the following manner: an approximately 100-nm-thick silicon oxide (SiOx) film was formed as a base film on a silicon substrate by a thermal oxidation method, and then an approximately 20-nm-thick oxide film was formed by an ALD method. Four kinds of films were formed as the oxide films: an InOx film, a GaOx film, a ZnOx film, and the IGZO(111) film.

Note that the SiOx film and the IGZO film were formed on both surfaces of the substrate. In this example, an ALD apparatus in which the oxide films were formed on respective surfaces (the front surface 4430a and the rear surface 4430b) of the substrate as illustrated in FIG. 10A and FIG. 10B was used.

For the formation of the IGZO film, the above-described <Formation condition of IGZO film> was employed. That is, the introduction time of the oxidizers (an O₃ gas and an Oz gas) after the introduction of a gas containing TEI was 45 seconds, the introduction time of the oxidizers after the introduction of a gas containing TEG was 45 seconds, and the introduction time of the oxidizers after the introduction of a gas containing DEZ was 9 seconds. The substrate temperature in the film formation was 200 °C.

The InOx film, the GaOx film, and the ZnOx film were each formed using a precursor used to form the IGZO film. The introduction time of the oxidizers was 15 seconds for each of the InOx film and the GaOx film and 3 seconds for the ZnOx film.

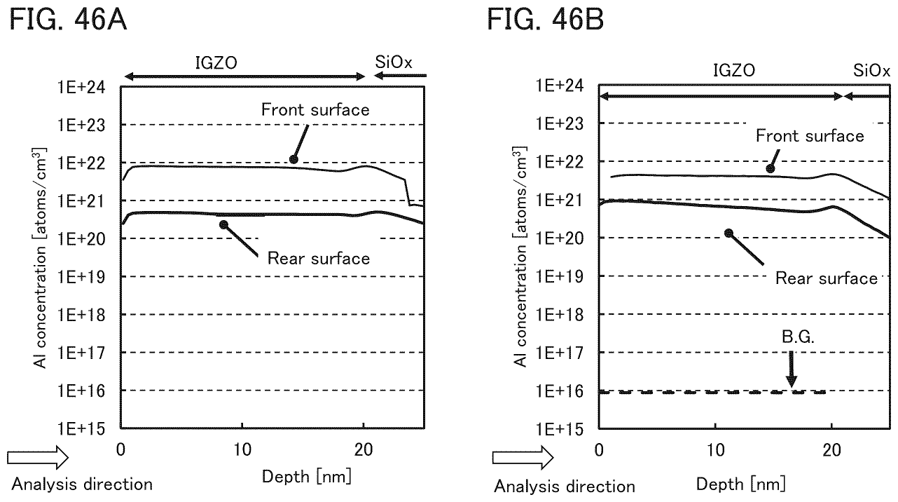

FIG. 46A and FIG. 46B show the SIMS analysis results of the aluminum concentration (Al concentration) in the IGZO film. The horizontal axis represents the depth from a sample surface, and the point at the left end where the depth is 0 nm corresponds to the sample surface (a surface of the IGZO film).

FIG. 46A and FIG. 46B show measurement results of the same sample obtained with different apparatuses. It can be said from FIG. 46A and FIG. 46B that the same degree of quantification can be achieved regardless of the measurement apparatus. The Al concentration in the IGZO film formed on the front surface was approximately 7.7×10²¹ atoms/cm³ in FIG. 46A and approximately 4.1×10²¹ atoms/cm³ in FIG. 46B. Meanwhile, the Al concentration in the IGZO film formed on the rear surface was approximately 4.4×10²⁰ atoms/cm³ in FIG. 46A and approximately 6.8×10²⁰ atoms/cm³ in FIG. 46B. As described above, it was found from the SIMS analysis results that the IGZO film formed on the rear surface had a lower Al concentration than the IGZO film formed on the front surface.

As illustrated in FIG. 10A, in the deposition apparatus used in this example, the precursor is supplied from above the substrate and adsorbed onto the front surface of the substrate. The precursor is also adsorbed onto the rear surface. For example, it is probable that impurities (Al) contained in the precursor are preferentially adsorbed onto the front surface. It is possible that this caused the IGZO film formed on the rear surface to have a lower Al concentration than the IGZO film formed on the front surface.

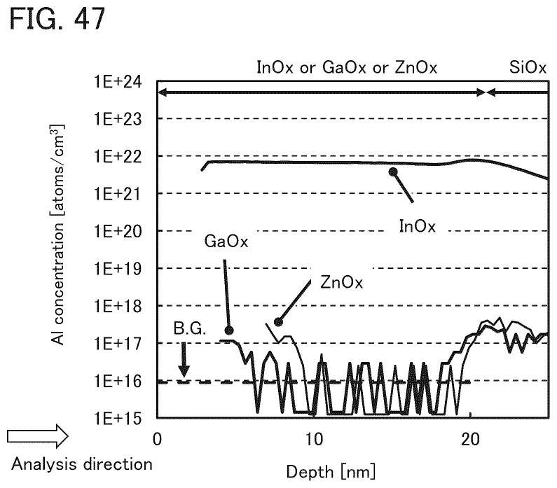

FIG. 47 shows the SIMS analysis results of the aluminum concentration (Al concentration) in the InOx film, the GaOx film, and the ZnOx film each formed on the front surface of the substrate. The horizontal axis represents the depth from a sample surface, and the point at the left end where the depth is 0 nm corresponds to the sample surface (a surface of the InOx film, the GaOx film, or the ZnOx film).

The Al concentration in the InOx film formed on the front surface was approximately 7×10²¹ atoms/cm³. The Al concentration in each of the GaOx film and the ZnOx film that were formed on the front surface was approximately 9×10¹⁵ atoms/cm³, which was lower than or equal to the lower detection limit.

As in the EDX analysis, the results of the SIMS analysis also show that InOx has a higher Al concentration than GaOx and ZnOx.

It was found from the results of the EDX analysis and the SIMS analysis that the IGZO film formed on the front surface of the substrate had a higher Al concentration than the IGZO film formed on the rear surface. It was found from the XPS analysis that Al exists in a state of Al₂O₃ or the like in the IGZO film. The Hall effect measurement showed that the IGZO film formed on the front surface of the substrate tended to have a higher resistivity and a lower carrier concentration than the IGZO film formed on the rear surface. It is probable that the resistance increased due to the IGZO film formed on the front surface containing a larger amount of Al than the IGZO film formed on the rear surface and the Al existing in an oxidated state.

### [Electrical Characteristics of Transistor]

Next, a transistor having the structure illustrated in FIG. 21A to FIG. 21D was fabricated, and the electrical characteristics thereof were evaluated.

As the insulator 215, silicon nitride having a thickness of approximately 60 nm and aluminum oxide having a thickness of approximately 40 nm were deposited by a sputtering method. As the insulator 216, silicon oxide having a thickness of approximately 130 nm was deposited by a sputtering method. As the conductor 205, a three-layer stacked structure of titanium nitride, tungsten, and titanium nitride was formed to have a total thickness of approximately 130 nm by a metal CVD method.

As the insulator 221, silicon nitride having a thickness of approximately 5 nm was deposited by a PEALD method, and as the insulator 222, hafnium oxide having a thickness of approximately 15 nm was deposited by an ALD method. As the insulator 224, silicon oxide having a thickness of approximately 20 nm was deposited by a sputtering method.

As the oxide 220a, IGZO having a thickness of approximately 10 nm was deposited by a sputtering method. The oxide 220a was deposited to have a composition of In:Ga:Zn=1:3:2 [atomic ratio] (IGZO(132)). As the oxide 220b, IGZO(111) having a thickness of approximately 15 nm was deposited by an ALD method. For the formation conditions of the IGZO(111), the above-described <Formation condition of IGZO film> was employed. The IGZO(111) deposited in this example corresponds to the above-described IGZO film formed on the rear surface of the substrate.

As each of the conductors 242al and 242b1, tantalum nitride having a thickness of approximately 5 nm was deposited by a sputtering method, and as each of the conductors 242a2 and 242b2, tungsten having a thickness of approximately 15 nm was deposited by a sputtering method. As each of the insulators 271a and 271b, a stack of silicon nitride having a thickness of approximately 5 nm and silicon oxide having a thickness of approximately 10 nm was formed by a sputtering method. As the insulator 275, silicon nitride having a thickness of approximately 5 nm was deposited by a PEALD method.

To form the insulator 280, a stack of silicon oxide having a thickness of approximately 125 nm and silicon nitride having a thickness of approximately 120 nm was formed by a sputtering method and then was planarized by CMP treatment.

As the insulator 255, silicon nitride having a thickness of approximately 10 nm was deposited by a PEALD method. As the insulator 250, silicon oxide having a thickness of approximately 1.5 nm was deposited by a PEALD method, then hafnium oxide having a thickness of approximately 1 nm was deposited by an ALD method, and then silicon nitride having a thickness of approximately 1 nm was deposited by an ALD method. As the conductor 260, titanium nitride having a thickness of approximately 5 nm and tungsten having a thickness of approximately 150 nm were deposited by a metal CVD method. Over the conductor 260, aluminum oxide having a thickness of approximately 10 nm, silicon nitride having a thickness of approximately 20 nm, and silicon oxide having a thickness of approximately 50 nm were deposited by a sputtering method (corresponding to the insulators 282 and 283).

The maximum temperature applied to the transistor in the fabrication process was 450 °C.

The transistor fabricated in this example was an n-channel transistor and was fabricated such that its channel length (L) and channel width (W) were each 20 nm.

The electrical characteristics of the transistor fabricated in the above manner were evaluated. Here, the I_{d}−V_{g} characteristics were measured as the electrical characteristics. The I_{d}−V_{g} characteristics were measured in such a manner that the drain voltage V_{d} was 1.2 V, the source voltage Vₛ was 0 V, and the gate voltage V_{g} was swept from −4 V to +4 V in increments of 0.1 V. The measurement was performed in an environment at room temperature.

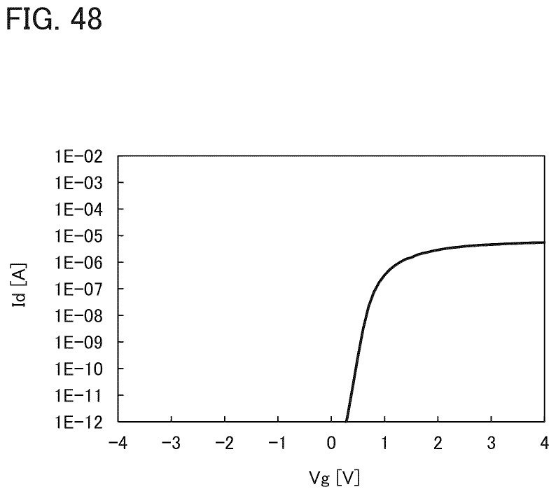

FIG. 48 shows the I_{d}−V_{g} characteristics of the transistor included in the fabricated sample. In FIG. 48, the vertical axis represents a drain current I_{d}[A] and the horizontal axis represents a gate-source voltage (V_{g}) [V].

As shown in FIG. 48, a transistor having favorable switching characteristics was able to be fabricated using the oxide semiconductor of one embodiment of the present invention.

### [Microwave Treatment]

Next, microwave treatment was performed on an approximately 3-nm-thick IGZO film formed by employing the above-described <Formation condition of IGZO film>, and cross-sectional STEM observation was performed. Here, cross-sectional observation was performed on the IGZO film formed on the front surface of the substrate.

In the microwave treatment, an Ar gas at 150 sccm and an O₂ gas at 50 sccm were used as treatment gases, the pressure was 400 Pa, the power was 4000 W, and the treatment temperature was 250 °C. The treatment time was set to three patterns: 10 minutes, 30 minutes, and 60 minutes. In addition, a sample that has not been subjected to microwave treatment was fabricated.

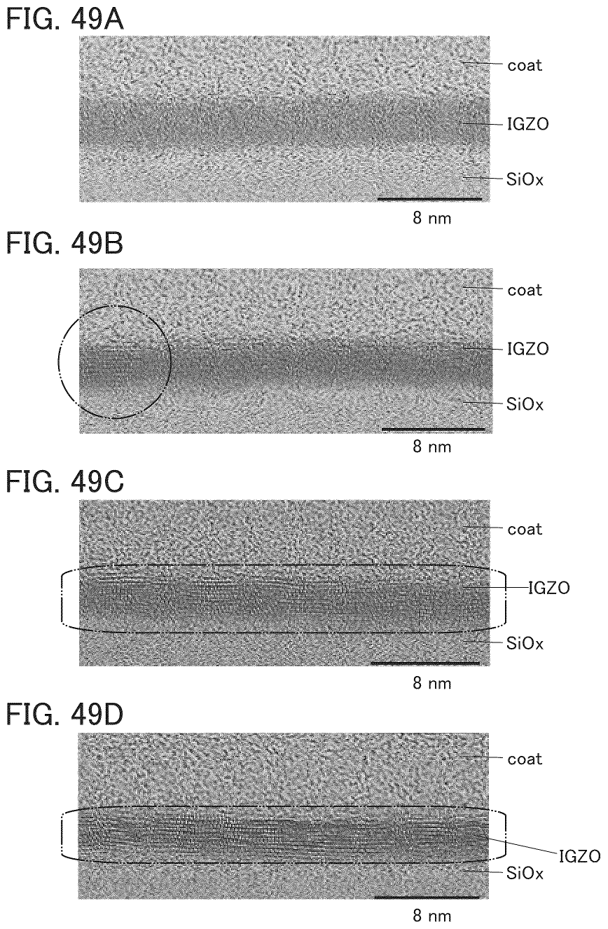

A cross-sectional STEM image of the fabricated sample was taken with “HD-2700” produced by Hitachi High-Technologies Corporation. FIG. 49A to FIG. 49D show captured cross-sectional TEM images.

FIG. 49A shows a cross-sectional STEM image of the sample including the IGZO film, which was fabricated without performing microwave treatment.

FIG. 49B to FIG. 49D are cross-sectional STEM images of the samples subjected to the microwave treatment. The treatment time is 10 minutes, 30 minutes, and 60 minutes in FIG. 49B, FIG. 49C, and FIG. 49D, respectively.

As shown in FIG. 49B to FIG. 49D, in the samples subjected to the microwave treatment, layered crystal structures were observed in the IGZO films (see regions surrounded by dashed double-dotted lines). In FIG. 49B, a layered crystal structure was partly observed in the IGZO film. In each of FIG. 49C and FIG. 49D, which is a cross-sectional STEM image of the sample with a longer treatment time than FIG. 49B, a layered crystal structure was observed in the IGZO film entirely from the interface with the base to the surface portion. Meanwhile, a layered crystal structure was not observed in the IGZO film in FIG. 47A.

The above reveals that the microwave treatment enables the formation of a metal oxide having a layered crystal structure with high crystallinity.

### Example 2

In this example, fabrication and evaluation results of the oxide semiconductor film of one embodiment of the present invention will be described.

### [SIMS Analysis 3]

In this example, an IGZO film was formed using an In precursor with a lower aluminum content than the In precursor used in Example 1, and SIMS measurement was performed.

A sample was fabricated in the following manner: heat treatment was performed on a silicon substrate in a hydrogen chloride (HCl) atmosphere to form an approximately 100-nm-thick silicon oxide (SiOx) film as a base film, and then an approximately 20-nm-thick IGZO film was formed as an oxide semiconductor film by an ALD method.

Note that the SiOx film and the IGZO film were formed on both surfaces of the substrate. In this example, a deposition apparatus in which the IGZO films (corresponding to the film 4431a and the film 4431b) were formed on respective surfaces (corresponding to the front surface 4430a and the rear surface 4430b of the substrate 4430) of the substrate as illustrated in FIG. 10A and FIG. 10B was used.

Precursors used for formation of the IGZO film are triethylindium (TEI), triethylgallium (TEG), and diethylzinc (DEZ). As an oxidizer, ozone (O₃) and oxygen (O₂) were used. The combined gas flow rate of an O₃ gas and an O₂ gas was 1000 sccm, and the ozone concentration was 19 wt %. As a carrier gas, an N₂ gas was used and the gas flow rate was 150 sccm.

The IGZO film was formed to have a composition of In:Ga:Zn=1:1:1 [atomic ratio] (hereinafter, the IGZO film is sometimes referred to as the IGZO(111) film). In one cycle of the film formation method, specifically, a gas containing TEI was introduced into the chamber for 0.1 seconds, the chamber was purged for 3 seconds, an O₃ gas and an O₂ gas were introduced for 60 seconds, and the chamber was purged for 3 seconds. Next, a gas containing TEG was introduced into the chamber for 0.1 seconds, the chamber was purged for 10 seconds, an O₃ gas and an O₂ gas were introduced for 60 seconds, and the chamber was purged for 3 seconds. Next, a gas containing DEZ was introduced into the chamber for 0.1 seconds, the chamber was purged for 3 seconds, an O₃ gas and an O₂ gas were introduced for 60 seconds, and the chamber was purged for 3 seconds. The substrate temperature in the film formation was 200 °C. A sample fabricated by the above method is referred to as Sample G1. Furthermore, a sample further subjected to heat treatment at 450 °C in an ultra-dry air atmosphere for one hour is referred to as Sample G2.

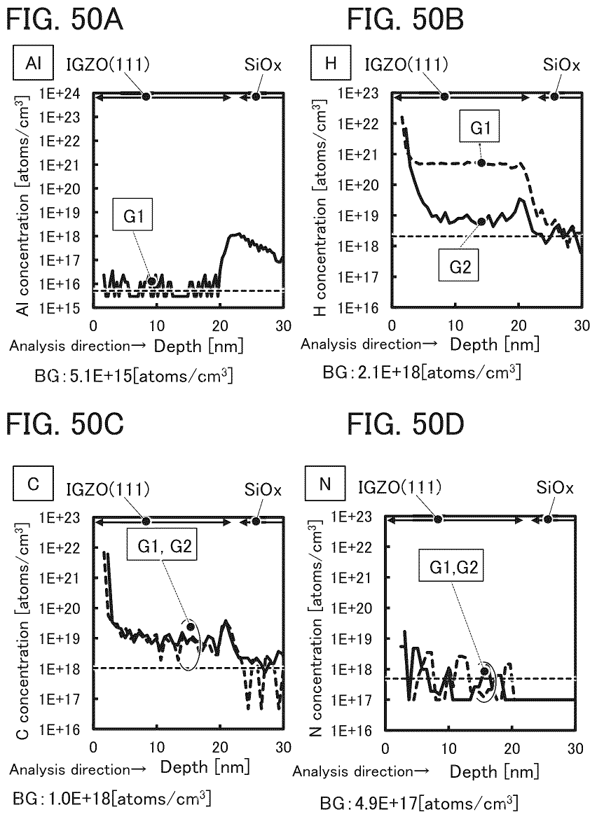

FIG. 50A to FIG. 50D show the SIMS analysis results of, the aluminum concentration (Al concentration) in the IGZO film formed on the front surface of Sample G1, and the hydrogen concentrations (H concentrations), the carbon concentrations (C concentrations), and the nitrogen concentrations (N concentrations), of the IGZO films formed on the front surfaces of the samples. The horizontal axis represents the depth from a sample surface, and the point at the left end where the depth is 0 nm corresponds to the sample surface (a surface of the IGZO film). In addition, the background (BG, the lower measurement limit) is denoted by a dashed line.

As shown in FIG. 50A, the Al concentration in the IGZO film was lower than or equal to the lower measurement limit (5.1×10¹⁵ atoms/cm³). In Example 1, the IGZO film formed on the front surface tended to have a higher Al concentration than the IGZO film formed on the rear surface. As described above, in this example, the In precursor having a lower aluminum content than the In precursor used in Example 1 was used. It can be thus considered that the Al concentration in the IGZO film formed on the front surface was sufficiently reduced.

As shown in FIG. 50B, it was confirmed that the H concentration of Sample G2 subjected to the heat treatment was lower than that of Sample G1 not subjected to the heat treatment.

As shown in FIG. 50C and FIG. 50D, it was confirmed that the C concentration and the N concentration were sufficiently low regardless of whether or not the heat treatment was performed.

From the above, it was found that when a metal oxide that does not contain aluminum as its main component was formed using a precursor having a low aluminum content, an increase in the concentration of aluminum in the formed metal oxide film was able to be inhibited.

### REFERENCE NUMERALS

ADDR: signal, BL: wiring, BLB: wiring, BW: signal, CA: component, CE: signal, CL: wiring, CLK: signal, CSEL: signal, EQ: signal, EQB: signal, GW: signal, PL: wiring, RDA: signal, SA_OUT: wiring, SA_OUTB: wiring, SAN: wiring, SAP: wiring, Tr: transistor, WAKE: signal, WDA: signal, WL: wiring, 10: substrate, 11a: precursor, 11b: precursor, 12a: reactant, 12b: reactant, 13a: oxide, 13b: oxide, 13c: oxide, 14: stacked-layer structure, 20: layer, 21: layer, 22: peripheral circuit, 23: layer, 30: element layer, 31: layer, 32: memory cell, 37: transistor, 38: capacitor, 40: driver circuit, 41: layer, 42: row decoder, 43: row driver, 44: column decoder, 45: column driver, 46: sense amplifier, 47: input circuit, 48: output circuit, 50: structure body, 53: region, 54: region, 56: region, 58: region, 60: oxide, 62: oxide, 64: oxide, 70: layer, 71: power switch, 72: power switch, 73: control circuit, 74: voltage generation circuit, 80: memory device, 82_1: transistor, 82_2: transistor, 82: switch circuit, 83_1: transistor, 83_3: transistor, 83: precharge circuit, 84_1: transistor, 84_3: transistor, 84: precharge circuit, 85_1: transistor, 85_2: transistor, 85_3: transistor, 85_4: transistor, 85: amplifier circuit, 100a: capacitor, 100b: capacitor, 100c: capacitor, 100d: capacitor, 100: capacitor, 110: conductor, 115: conductor, 120: conductor, 125: conductor, 130; insulator, 140: insulator, 150a: memory cell, 150b: memory cell, 150c: memory cell, 150d: memory cell, 150: memory cell, 160: memory unit, 170[1]: layer, 170[2]: layer, 170[m−1]: layer, 170[m]: layer, 180a: insulator, 180b: insulator, 180: insulator, 190: opening portion, 200A: transistor, 200B: transistor, 200C: transistor, 200D: transistor, 200E: transistor, 200a: transistor, 200b: transistor, 200c: transistor, 200d: transistor, 200p: transistor, 200; transistor, 201a: transistor, 201b: transistor, 201: transistor, 205a: conductor, 205b: conductor, 205: conductor, 215: insulator, 216: insulator, 220a: oxide, 220b: oxide, 220: oxide, 221: insulator, 222: insulator, 224: insulator, 225: insulator, 230a: oxide semiconductor, 230b: oxide semiconductor, 230i: region, 230na: region, 230nb: region, 230: oxide semiconductor, 239a: conductor, 239b: conductor, 240: conductor, 241a: insulator, 241b: insulator, 242a: conductor, 242b: conductor, 245: conductor, 246: conductor, 250a: insulator, 250b: insulator, 250c: insulator, 250d: insulator, 250: insulator, 255: insulator, 260a: conductor, 260b: conductor, 260: conductor, 271a: insulator, 271b: insulator, 272: insulator, 275: insulator, 280a: insulator, 280b; insulator, 280c: insulator, 280: insulator, 282: insulator, 283: insulator, 285: insulator, 287: insulator, 290: opening portion, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 641: insulator, 642: conductor, 643: conductor, 644: conductor, 645: conductor, 646: conductor, 647: insulator, 648: insulator, 700: electronic component, 702: printed circuit board, 704: mounting board, 710: semiconductor device, 711: mold, 712: land, 713: electrode pad, 714: wire, 715: driver circuit layer, 716: memory layer, 730: electronic component, 731: interposer, 732: package board, 733: electrode, 735: semiconductor device, 4000: deposition apparatus, 4002: carrying-in/out chamber, 4004: carrying-in/out chamber, 4006: transfer chamber, 4008: deposition chamber, 4009: deposition chamber, 4011: treatment chamber, 4014: transfer arm, 4020: chamber, 4021a: source material supply portion, 4021b: source material supply portion, 4021c: source material supply portion, 4021: source material supply portion, 4022a: high-speed valve, 4022d: high-speed valve, 4023: source material introduction port, 4024: source material exhaust port, 4025: evacuation unit, 4026: substrate holder, 4027: heater, 4028: plasma generation apparatus, 4029: coil, 4030: substrate, 4031: source material supply portion, 4032: gas supply portion, 4033: source material introduction port, 4034a: pipe heater, 4034b: pipe heater, 4111: plasma generation chamber, 4120: reaction chamber, 4123: source material introduction port, 4124: source material exhaust port, 4126: substrate holder, 4128: plasma generation apparatus, 4130: substrate, 4131: plasma, 4133: source material introduction port, 4213: electrode, 4214: shower head, 4215: power source, 4217: capacitor, 4220: chamber, 4223: source material introduction port, 4224: source material exhaust port, 4226: substrate holder, 4230: substrate, 4231: plasma, 4313: electrode, 4314: shower head, 4315: power source, 4317: capacitor, 4319: mesh, 4320: chamber, 4321: power source, 4322: capacitor, 4323: source material introduction port, 4324: source material exhaust port, 4326: substrate holder, 4330: substrate, 4331: plasma, 4400: ALD apparatus, 4410: outer chamber, 4414: source material supply port, 4420: chamber, 4423: source material introduction port, 4424: source material exhaust port, 4426: substrate holder, 4427: heater, 4430a: front surface, 4430b: rear surface, 4430: substrate, 4431a: film, 4431b: film, 4520: chamber, 4521a: source material supply portion, 4521b: source material supply portion, 4521c: source material supply portion, 4521: source material supply portion, 4522a: high-speed valve, 4522c: high-speed valve, 4522d: high-speed valve, 4523: source material introduction port, 4524: source material exhaust port, 4525: evacuation unit, 4526: substrate holder, 4527: heater, 4530: substrate, 4531: source material supply portion, 4532: gas supply portion, 4534a: pipe heater, 4534b: pipe heater, 5600: large computer, 5610: rack, 5620: computer, 5621; PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6600: electronic appliance, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A semiconductor device comprising:
an oxide semiconductor, a first conductor, a second conductor, a third conductor, and a first insulator,
wherein the first conductor and the second conductor each comprise a portion in contact with the oxide semiconductor,
wherein the third conductor overlaps with the oxide semiconductor with the first insulator therebetween,
wherein the oxide semiconductor comprises a first portion provided along a first surface and a second portion provided along a second surface inclined to the first surface,
wherein a ratio of a thickness of the second portion to a thickness of the first portion is greater than or equal to 0.8 and less than or equal to 1.2,
wherein the oxide semiconductor comprises indium and one or more selected from gallium, tin, and zinc, and
wherein an aluminum concentration in the oxide semiconductor is higher than or equal to 0.01 atomic % and lower than or equal to 10 atomic %.

2. (canceled)

3. A semiconductor device comprising:
an oxide semiconductor, a first conductor, a second conductor, a third conductor, a first insulator, and a second insulator,
wherein the first insulator is in contact with a top surface of the first conductor,
wherein the second conductor is positioned over the first insulator,
wherein the first insulator and the second conductor comprise a first opening portion reaching the first conductor,
wherein, inside the first opening portion, the oxide semiconductor comprises a first portion in contact with the top surface of the first conductor, a second portion in contact with a side surface of the first insulator, and a third portion in contact with the second conductor,
wherein the second insulator is positioned over the oxide semiconductor,
wherein the third conductor is positioned over the second insulator and overlaps with the oxide semiconductor with the second insulator therebetween, in a position overlapping with the first opening portion,
wherein a ratio of a thickness of the second portion to a thickness of the first portion is greater than or equal to 0.8 and less than or equal to 1.2,
wherein the oxide semiconductor comprises indium and one or more selected from gallium, tin, and zinc, and
wherein an aluminum concentration in the oxide semiconductor is higher than or equal to 0.01 atomic % and lower than or equal to 10 atomic %.

4. A semiconductor device comprising:
a first insulator;
an oxide semiconductor covering the first insulator;
a first conductor and a second conductor over the oxide semiconductor;
a second insulator placed over the first conductor and the second conductor and comprising an opening overlapping with a region between the first conductor and the second conductor;
a third insulator placed in the opening and placed over the oxide semiconductor; and
a third conductor placed in the opening and placed over the third insulator,
wherein in a cross-sectional view in a channel width direction, a height of the first insulator is longer than a width of the first insulator,
wherein the oxide semiconductor comprises a first portion provided along a first surface and a second portion provided along a second surface inclined to the first surface,
wherein a ratio of a thickness of the second portion to a thickness of the first portion is greater than or equal to 0.8 and less than or equal to 1.2,
wherein the oxide semiconductor comprises indium and one or more selected from gallium, tin, and zinc, and
wherein an aluminum concentration in the oxide semiconductor is higher than or equal to 0.01 atomic % and lower than or equal to 10 atomic %.

5. The semiconductor device according to claim 4,
wherein in a plan view, a side surface of the opening in the second insulator is aligned or substantially aligned with a side surface of the first conductor and a side surface of the second conductor.

6. The semiconductor device according to claim 4,
wherein the first conductor is configured to be one of a source electrode and a drain electrode of a transistor,
wherein the second conductor is configured to be the other of the source electrode and the drain electrode of the transistor, and
wherein the third conductor is configured to be a gate electrode of the transistor.

7. The semiconductor device according to claim 6,
wherein on a first side surface of the first insulator, the oxide semiconductor and the third conductor face each other with the third insulator therebetween in a cross-sectional view in a channel width direction of the transistor, and
wherein on a second side surface of the first insulator opposite to the first side surface of the first insulator, the oxide semiconductor and the third conductor face each other with the third insulator therebetween in the cross-sectional view in the channel width direction of the transistor.

8. The semiconductor device according to claim 6,
wherein in a first side surface of the first insulator and a second side surface of the first insulator opposite to the first side surface of the first insulator, the first conductor is in contact with the oxide semiconductor in a cross-sectional view in a channel width direction of the transistor, and
wherein in a first side surface of the first insulator and a second side surface of the first insulator opposite to the first side surface of the first insulator, the second conductor is in contact with the oxide semiconductor in the cross-sectional view in the channel width direction of the transistor.

9. The semiconductor device according to claim 6,
wherein the height of the first insulator is greater than or equal to 2 times and less than or equal to 20 times the width of the first insulator in a cross-sectional view in a channel width direction of the transistor.

10. The semiconductor device according to claim 1,
wherein the aluminum concentration in the oxide semiconductor is higher than or equal to 0.01 atomic % and lower than or equal to 5 atomic %.

11. The semiconductor device according to claim 1,
wherein a carbon concentration in the oxide semiconductor is higher than or equal to 1×10¹⁷ atoms/cm³ and lower than or equal to 5×10¹⁹ atoms/cm³.

12. A memory device comprising the semiconductor device according to claim 3, a fourth conductor, a third insulator, and a capacitor,
wherein the capacitor comprises a fifth conductor, a fourth insulator over the fifth conductor, and the first conductor over the fourth insulator,
wherein a second opening portion reaching the fourth conductor is provided in the third insulator, and
wherein at least part of the fifth conductor, at least part of the fourth insulator, and at least part of the first conductor are placed in the second opening portion.

13. A memory device comprising the semiconductor device according to claim 4, and a capacitor,
wherein one electrode of the capacitor is electrically connected to the first conductor of the semiconductor device.

14. The memory device according to claim 13,
wherein the capacitor is placed over the third conductor, and
wherein at least part of the capacitor overlaps with the oxide semiconductor and the third conductor.

15-19. (canceled)

20. The semiconductor device according to claim 3,
wherein the aluminum concentration in the oxide semiconductor is higher than or equal to 0.01 atomic % and lower than or equal to 5 atomic %.

21. The semiconductor device according to claim 4,
wherein the aluminum concentration in the oxide semiconductor is higher than or equal to 0.01 atomic % and lower than or equal to 5 atomic %.

22. The semiconductor device according to claim 3,
wherein a carbon concentration in the oxide semiconductor is higher than or equal to 1×10¹⁷ atoms/cm³ and lower than or equal to 5×10¹⁹ atoms/cm³.

23. The semiconductor device according to claim 4,
wherein a carbon concentration in the oxide semiconductor is higher than or equal to 1×10¹⁷ atoms/cm³ and lower than or equal to 5×10¹⁹ atoms/cm³.
